(19) United States
(12) Patent Application Publication
(10) Pub. No.: US 2023/0051087 A1
(43) Pub. Date: Feb. 16, 2023

(54) ORGANOMETALLIC COMPOUND AND ORGANIC ELECTROLUMINESCENT DEVICE INCLUDING THE SAME

(71) Applicants: LG DISPLAY CO., LTD., Seoul (KR); LT MATERIALS CO., LTD., Yongin-si (KR)

(72) Inventors: Sungjin PARK, Paju-si (KR); Inbum SONG, Seoul (KR); Dohan KIM, Goyang-si (KR); Jaemin MOON, Seoul (KR); Yong Woo KIM, Osan-si (KR); Ji Young KIM, Yongin-si (KR); Hyun Ju LA, Osan-si (KR)

(73) Assignees: LG DISPLAY CO., LTD., Seoul (KR); LT MATERIALS CO., LTD., Yongin-si (KR)

(21) Appl. No.: 17/825,706

(22) Filed: May 26, 2022

(30) Foreign Application Priority Data
May 27, 2021 (KR) 10-2021-0068599
Apr. 26, 2022 (KR) 10-2022-0051552

(51) Int. Cl. C07F 15/00; H01L 51/00; H01L 51/50

(52) U.S. Cl. CPC C07F 15/0033; H01L 51/0085; H01L 51/5056; H01L 51/5072; H01L 51/5092; H01L 51/5024

(57) ABSTRACT

Disclosed is an organometallic compound represented by a following Chemical Formula 1. When the organometallic compound is used as dopant of a light-emitting layer of an organic electroluminescent device, rigidity is imparted to the organometallic compound molecule such that a full width at half maximum (FWHM) is narrow and thus color purity is improved. Further, a non-luminescent recombination process is reduced such that luminous efficiency and lifespan of the organic electroluminescent device are improved. Chemical Formula 1 is shown below:

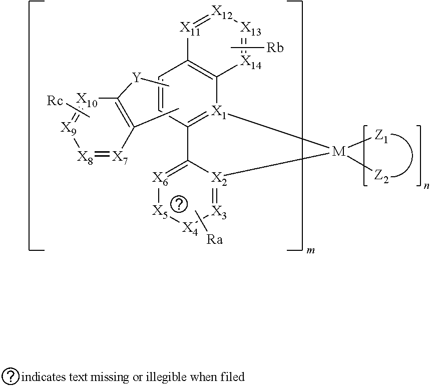

### CROSS-REFERENCE TO RELATED APPLICATION

This application claims priority under 35 U.S.C. § 119 to Korean Patent Application Nos. 10-2021-0068599 filed on May 27, 2021 and 10-2022-0051552 filed on Apr. 26, 2022 in the Republic of Korea, the entire contents of all these applications are herein incorporated by reference in the present application.

### BACKGROUND OF THE INVENTION

### Field of the Invention

The present disclosure relates to an organometallic compound, and more particularly, to an organometallic compound having phosphorescent properties and an organic electroluminescent device including the same.

### Discussion of Related Art

Display devices are important to several fields, and there continues to be a demand for improved performance. One example of such display devices is an organic light emitting display device, such as an organic light emitting diode: OLED display.

In the organic electroluminescent device, when electric charges are injected into a light-emitting layer formed between a positive electrode and a negative electrode, an electron and a hole are recombined with each other in the light-emitting layer to form an exciton and thus energy of the exciton is converted to light. Thus, the organic electroluminescent device emits the light. Compared to conventional display devices, the organic electroluminescent device can operate at a low voltage, consume relatively little power, render excellent colors, and can be used in a variety of ways because a flexible substrate can be applied thereto. Further, the size of the organic electroluminescent device can be freely adjustable.

### SUMMARY OF THE INVENTION

The organic electroluminescent device (OLED) according to the invention has superior viewing angle and contrast ratio compared to a liquid crystal display (LCD), and is lightweight and is ultra-thin because the OLED does not require a backlight. The organic electroluminescent device includes a plurality of organic layers between a negative electrode (electron injection electrode; cathode) and a positive electrode (hole injection electrode; anode). The plurality of organic layers can include a hole injection layer, a hole transport layer, a hole transport auxiliary layer, an electron blocking layer, and a light-emitting layer, an electron transport layer, etc.

In this organic electroluminescent device structure, when a voltage is applied across the two electrodes, electrons and holes are injected from the negative and positive electrodes, respectively, into the light emitting layer and thus excitons are generated in the light-emitting layer and then fall to a ground state to emit light.

Organic materials used in the organic electroluminescent device can be largely classified into light-emitting materials and charge-transporting materials. The light-emitting material is an important factor determining luminous efficiency of the organic electroluminescent device. The luminescent material must have high quantum efficiency, excellent electron and hole mobility, and must exist uniformly and stably in the light-emitting layer. The light-emitting materials can be classified into light-emitting materials emitting light of blue, red, and green colors based on colors of the light. A color-generating material can include a host and dopants to increase the color purity and luminous efficiency through energy transfer.

In the organic electroluminescent device, low driving voltage, high efficiency, and long life is continuously required. In addition, in the organic electroluminescent device, demand for a light-emitting material that can render high-purity colors covering a wide CIE color coordinate range is increasing. In particular, in a white organic light-emitting diode using a color filter, there is a greater need for a light-emitting material that exhibits excellent luminous efficiency and renders high-purity color.

However, as the color purity become higher (a CIE color coordinate X value increases), visibility decreases. Thus, there is a problem that it is difficult to obtain high luminous efficiency with the same internal quantum efficiency. Thus, it is required to develop a phosphorescent light emitting material that can realize a low driving voltage, high efficiency, long lifespan, and excellent color purity.

Therefore, a purpose of the present disclosure is to provide an organometallic compound capable of realizing high color purity and high luminance of the organic electroluminescent device, and lowering driving voltage of the organic electroluminescent device, and improving luminous efficiency and lifespan of the organic electroluminescent device, and to provide the organic electroluminescent device in which an organic light-emitting layer contains the same.

Purposes of the present disclosure are not limited to the above-mentioned purpose. Other purposes and advantages of the present disclosure that are not mentioned can be understood based on following descriptions, and can be more clearly understood based on embodiments of the present disclosure. Further, it will be easily understood that the purposes and advantages of the present disclosure can be realized using means shown in the claims and combinations thereof.

In order to achieve the above purpose, the present disclosure provides an organometallic compound having a novel structure represented by a following Chemical Formula 1 and an organic electroluminescent device in which a light-emitting layer contains the same as dopants thereof.

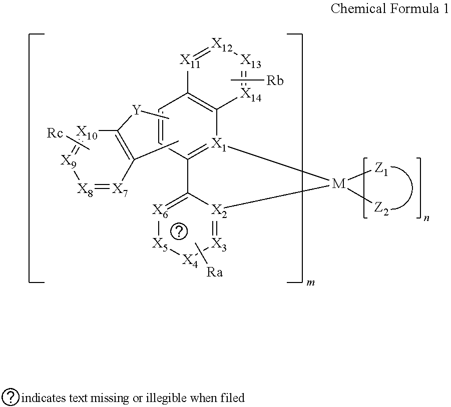

where in the Chemical Formula 1,
M represents a central coordination metal, and includes one selected from a group consisting of molybdenum (Mo), tungsten (W), rhenium (Re), ruthenium (Ru), osmium (Os), rhodium (Rh), iridium (Ir), palladium (Pd), platinum (Pt) and gold (Au);
Y is the same as or different from each other, and independently represents one selected from a group consisting of BR₁, CR₁R₂, C═O, C═NR₁, SiR₁R₂, NR₁, PR₁, AsR₁, SbR₁, BiR₁, P(O)R₁, P(S)R₁, P(Se)R₁, As(O)R₁, As(S)R₁, As(Se)R₁, Sb(O)R₁, Sb(S)R₁, Sb(Se)R₁, Bi(O)R₁, Bi(S)R₁, Bi(Se)R₁, oxygen (O), sulfur (S), cerium (Se), tellurium (Te), SO, SO₂, SeO, SeO₂, TeO, and TeO₂;
X₁ and X₂ are different from each other and each of X₁ and X₂ independently represents one selected from a group consisting of carbon (C), nitrogen (N) and phosphorus (P);
one of X₁ and X₂ is carbon (C) and the other thereof is one of nitrogen (N) or phosphorus (P);
each of R₁ and R₂ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;

each of Ra, Rb and Rc independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted A cyclic C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group;

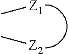

is a bidentate ligand;
m is an integer of 1, 2 or 3, n is an integer of 0, 1 or 2, and m+n is an oxidation number of the metal M.

When the organometallic compound according to the present disclosure is used as the dopant of the light-emitting layer of the organic electroluminescent device, the driving voltage of the organic electroluminescent device can be lowered and the luminous efficiency and lifespan characteristics of the organic electroluminescent device can be improved.

In addition, when the organometallic compound according to the present disclosure is used as the dopant of the light-emitting layer of the organic electroluminescent device, rigidity can be imparted to the organometallic compound molecule such that a full width at half maximum (FWHM) can be narrow and thus the color purity can be improved. Further, a non-luminescent recombination process can be reduced such that the luminous efficiency and lifespan of the organic electroluminescent device can be improved.

Effects of the present disclosure are not limited to the above-mentioned effects, and other effects as not mentioned will be clearly understood by those skilled in the art from following descriptions. All components of each light emitting display apparatus according to all embodiments of the present disclosure are operatively coupled and configured.

### BRIEF DESCRIPTION OF THE DRAWINGS

FIG. 1 is a cross-sectional view schematically showing an organic electroluminescent device to which an organometallic compound according to some embodiments of the present disclosure is applied to a light-emitting layer.

FIG. 2 is a cross-sectional view schematically illustrating an organic light-emitting display device including an organic electroluminescent device according to some embodiments of the present disclosure as an organic light-emitting element.

FIG. 3 is a graph plotting an emission wavelength and a full width at half maximum of an organic electroluminescent device to which a compound 232 of Present Example 12 of the present disclosure is applied, wherein a vertical axis indicates photoluminescence (PL) intensity, and a horizontal axis indicates a wavelength (nm).

FIG. 4 is a cross-sectional view schematically illustrating an organic electroluminescent device having a tandem structure having two light-emitting stacks and including the organometallic compound represented by the Chemical Formula 1 according to some embodiments of the present disclosure.

### DETAILED DESCRIPTION OF THE EMBODIMENTS

Advantages and features of the present disclosure, and the methods of achieving the advantages and features will become apparent with reference to embodiments described later in detail together with the accompanying drawings. However, the present disclosure is not limited to the embodiments as disclosed below, but can be implemented in various forms. Thus, these embodiments are set forth as examples only, and not intended to be limiting.

A shape, a size, a ratio, an angle, a number, etc. disclosed in the drawings for describing the embodiments of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first element or layer is referred to as being present “on” a second element or layer, the first element can be disposed directly on the second element or can be disposed indirectly on the second element with a third element or layer being disposed between the first and second elements or layers. It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

Further, as used herein, when a layer, film, region, plate, or the like is disposed “on” or “on a top” of another layer, film, region, plate, or the like, the former can directly contact the latter or still another layer, film, region, plate, or the like can be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still another layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section, and may not define order or sequence. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

In interpreting a numerical value, the value is interpreted as including an error range unless there is no separate explicit description thereof.

It will be understood that when an element or layer is referred to as being “connected to”, or “coupled to” another element or layer, it can be directly on, connected to, or coupled to the other element or layer, or one or more intervening elements or layers can be present. In addition, it will also be understood that when an element or layer is referred to as being “between” two elements or layers, it can be the only element or layer between the two elements or layers, or one or more intervening elements or layers can also be present.

The features of the various embodiments of the present disclosure can be partially or entirely combined with each other, and can be technically associated with each other or operate with each other. The embodiments can be implemented independently of each other and can be implemented together in an association relationship.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, a term “hetero” means that one or more of carbon atoms constituting an aromatic or alicyclic ring, for example, 1 to 5 carbon atoms are substituted with one or more heteroatoms selected from a group consisting of N, O, S, and combinations thereof.

Hereinafter, a structure and preparation examples of an organometallic compound according to the present disclosure and an organic electroluminescent device including the same will be described.

The organometallic compound according to one implementation of the present disclosure can be represented by a following Chemical Formula 1 and can be used as dopant of a light-emitting layer to impart rigidity to the organometallic compound molecule to narrow the full width at half maximum (FWHM) to improve the color purity. In addition, luminous efficiency and lifespan can be improved.

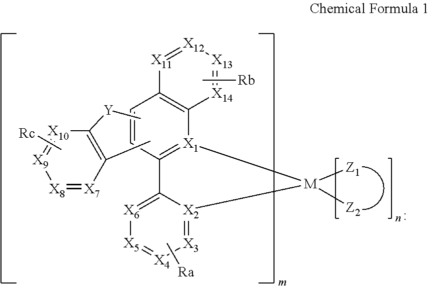

where in the Chemical Formula 1,
M represents a central coordination metal, and includes one selected from a group consisting of molybdenum (Mo), tungsten (W), rhenium (Re), ruthenium (Ru), osmium (Os), rhodium (Rh), iridium (Ir), palladium (Pd), platinum (Pt) and gold (Au);
Y is the same as or different from each other, and independently represents one selected from a group consisting of BR₁, CR₁R₂, C═O, C═NR₁, SiR₁R₂, NR₁, PR₁, AsR₁, SbR₁, BiR₁, P(O)R₁, P(S)R₁, P(Se)R₁, As(O)R₁, As(S)R₁, As(Se)R₁, Sb(O)R₁, Sb(S)R₁, Sb(Se)R₁, Bi(O)R₁, Bi(S)R₁, Bi(Se)R₁, oxygen (O), sulfur (S), cerium (Se), tellurium (Te), SO, SO₂, SeO, SeO₂, TeO, and TeO₂;
X₁ and X₂ are different from each other and each of X₁ and X₂ independently represents one selected from a group consisting of carbon (C), nitrogen (N) and phosphorus (P);
one of X₁ and X₂ is carbon (C) and the other thereof is one of nitrogen (N) or phosphorus (P);
each of R₁ and R₂ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of Ra, Rb and Rc independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted A cyclic C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group;

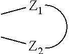

is a bidentate ligand;
m is an integer of 1, 2 or 3, n is an integer of 0, 1 or 2, and m+n is an oxidation number of the metal M.

The compound represented by the Chemical Formula 1 as the organometallic compound according to one implementation of the present disclosure can be represented by a structure of following Chemical Formula 2 or Chemical Formula 3, based on a position where a main ligand is bonded to the central coordination metal.

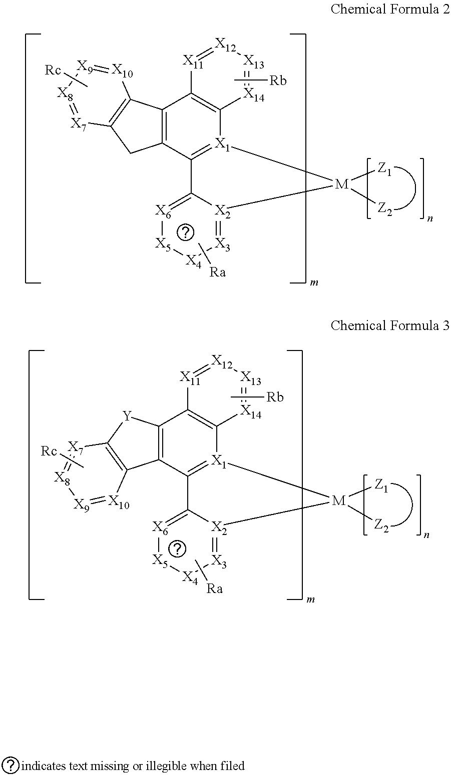

where in each of the Chemical Formula 2 to Chemical Formula 3, X₃, X₄, X₅, X₆, X₇, X₈, X₉, X₁₀, X₁₁, X₁₂, X₁₃ and X₁₄ are the same as or different from each other, and each of X₃, X₄, X₅, X₆, X₇, X₈, X₉, X₁₀, X₁₁, X₁₂, X₁₃ and X₁₄ independently represents CR, nitrogen (N), phosphorus (P), sulfur (S) and oxygen (O); adjacent groups selected from a group consisting of X₃, X₄, X₅, X₆, X₇, X₈, X₉, X₁₀, X₁₁, X₁₂, X₁₃ and X₁₄ are combined with each other to form a C5 ring structure or a C6 ring structure;
R independently represents hydrogen, deuterium, halogen, a hydroxyl group, a cyano group, an nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
definitions of M, Y, X₁, X₂, R₁, R₂, Ra, Rb, Rc,

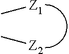

m and n are respectively the same as the definitions as described above.

In the organometallic compound according to one implementation of the present disclosure, a bidentate ligand can be used as an auxiliary ligand to the central coordination metal. The bidentate ligand according to the present disclosure can include an electron donor to increase an amount of metal to ligand charge transfer (MLCT), thereby improving luminescent properties such as luminous efficiency and external quantum efficiency of the organic electroluminescent device.

A structure of the Chemical Formula 1 exhibiting the characteristics of the auxiliary ligand as described above can be represented by one selected from a group consisting of following Chemical Formula 4 to Chemical Formula 11.

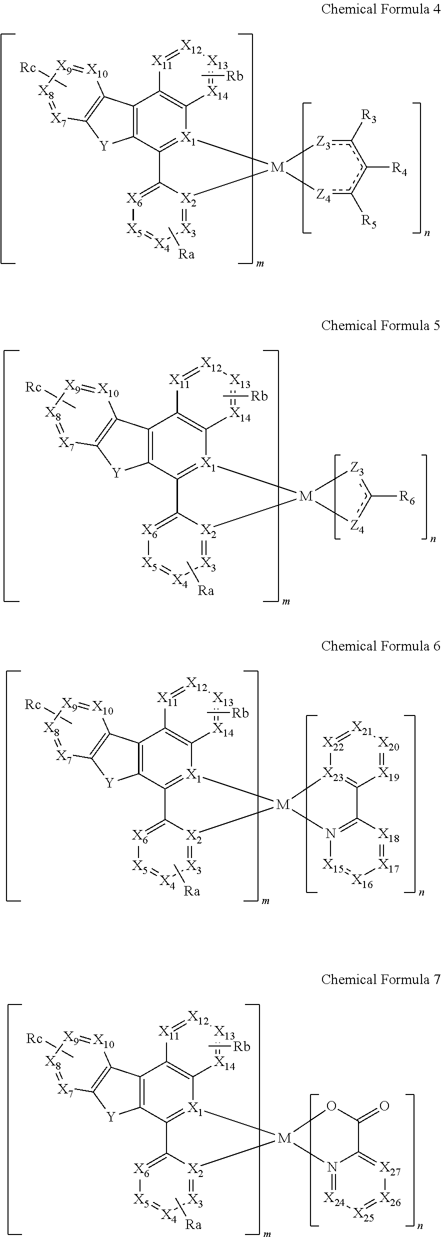

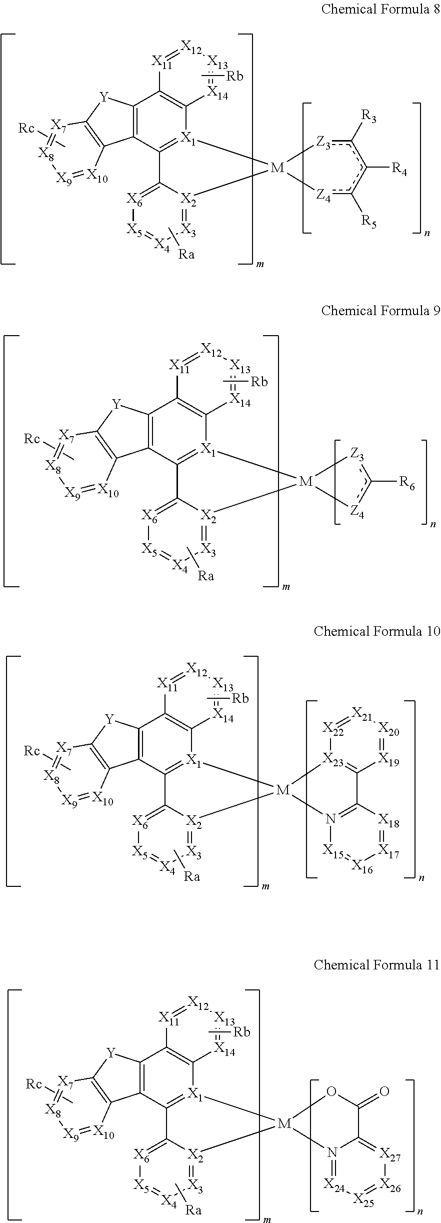

where in each of the Chemical Formula 4 to Chemical Formula 11,
X₁₅, X₁₆, X₁₇, X₁₈, X₁₉, X₂₀, X₂₁, X₂₂, X₂₃, X₂₄, X₂₅, X₂₆ and X₂₇ are the same as or different from each other, and each of X₁₅, X₁₆, X₁₇, X₁₈, X₁₉, X₂₀, X₂₁, X₂₂, X₂₃, X₂₄, X₂₅, X₂₆ and X₂₇ independently represents CR, nitrogen (N), phosphorus (P), sulfur (S) and oxygen (O);
adjacent groups selected from a group consisting of X₁₅, X₁₆, X₁₇, X₁₈, X₁₉, X₂₀, X₂₁, X₂₂, X₂₃, X₂₄, X₂₅, X₂₆ and X₂₇ are combined with each other to form a C5 ring structure or a C6 ring structure;
each of Z₃, Z₄ and Z₅ independently represents one selected from a group consisting of oxygen (O), sulfur (S) and NR₇;
each of R₃, R₄, R₅, R₆ and R₇ independently represents hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 a heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group,
wherein definitions of M, Y, X₁, X₂, R₁, R₂, Ra, Rb, Rc, X₃, X₄, X₅, X₆, X₇, X₈, X₉, X₁₀, X₁₁, X₁₂, X₁₃, X₁₄, m and n are respectively the same as the definitions as described above.

Phosphorescence can be efficiently obtained at room temperature using an iridium (Ir) or platinum (Pt) metal complex with a large atomic number. Thus, in the organometallic compound according to one implementation of the present disclosure, the central coordination metal (M) can be preferably iridium (Ir) or platinum (Pt), more preferably, iridium (Ir). However, the disclosure is not limited thereto.

In addition, in the organometallic compound according to one implementation of the present disclosure, Y in the Chemical Formula 1 can be one selected from a group consisting of oxygen (O), sulfur (S) and carbon (C).

A specific example of the compound represented by the Chemical Formula 1 of the present disclosure can include one selected from a group consisting of following compounds 1 to 466. However, the disclosure is not limited thereto as long as the compound falls within the definition of the Chemical Formula 1.

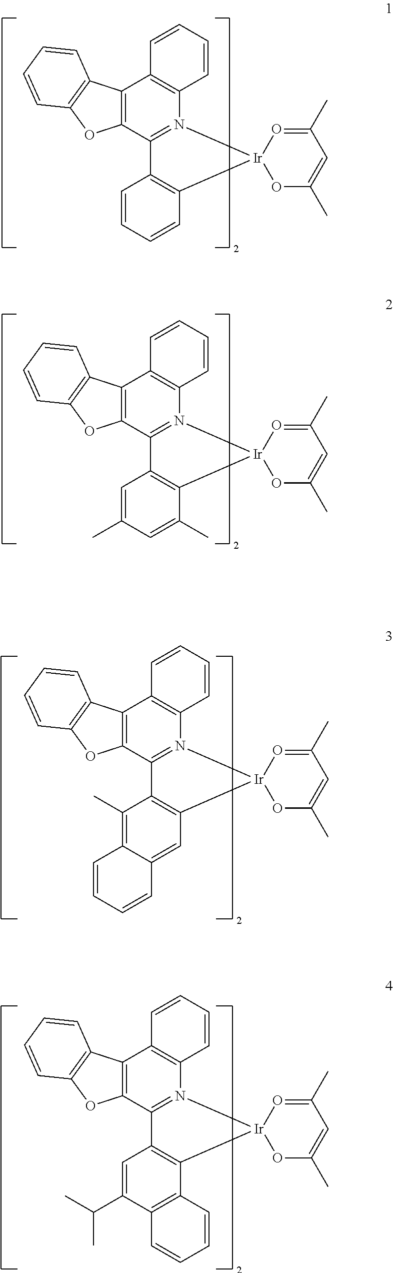

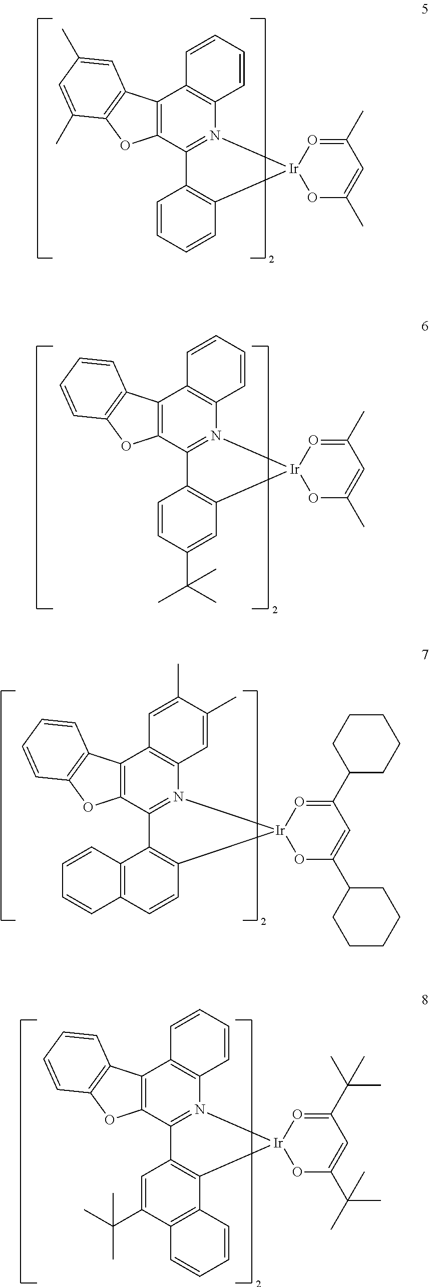

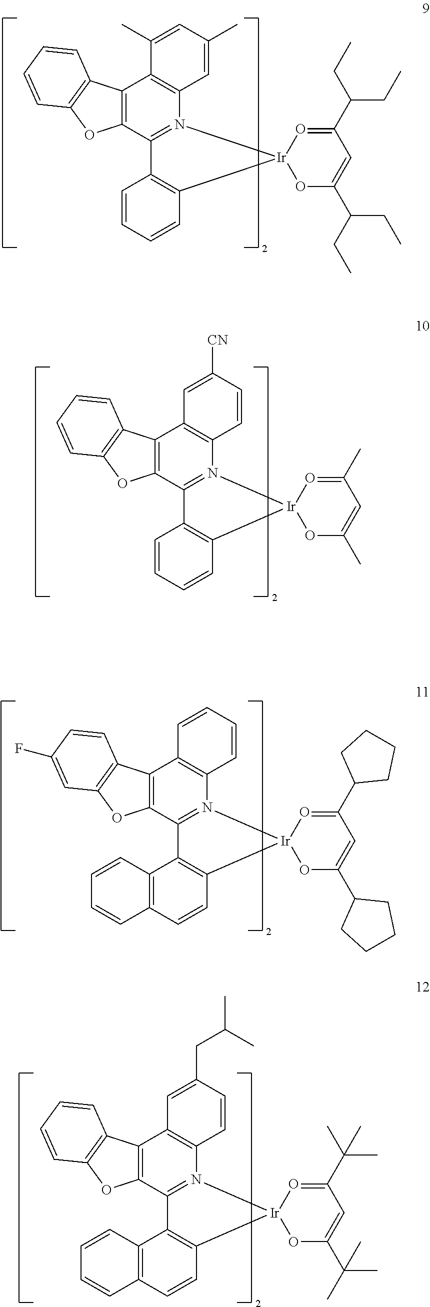

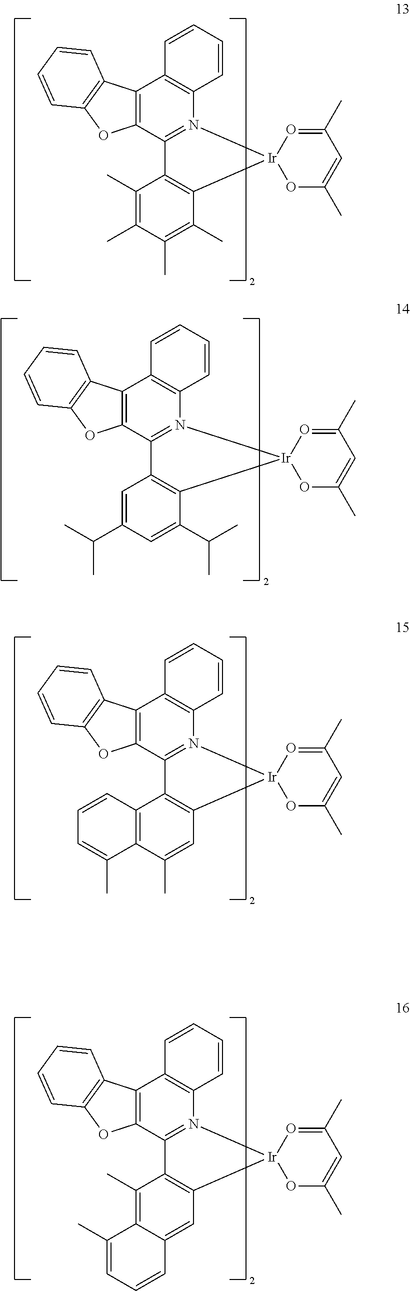

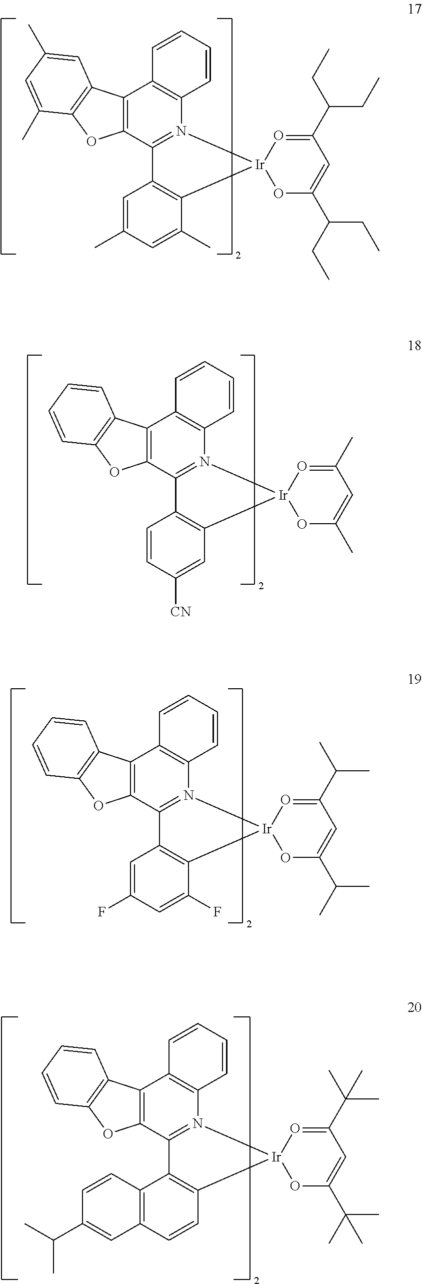

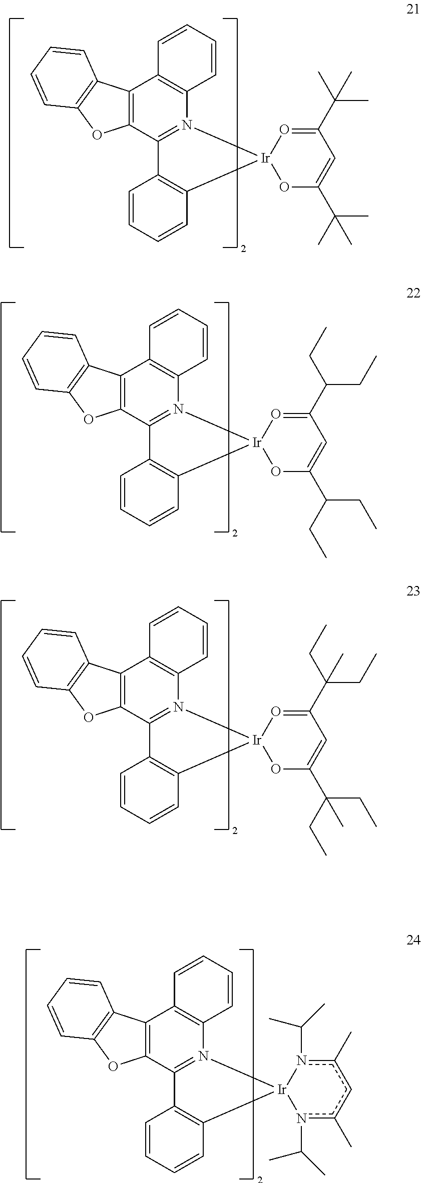

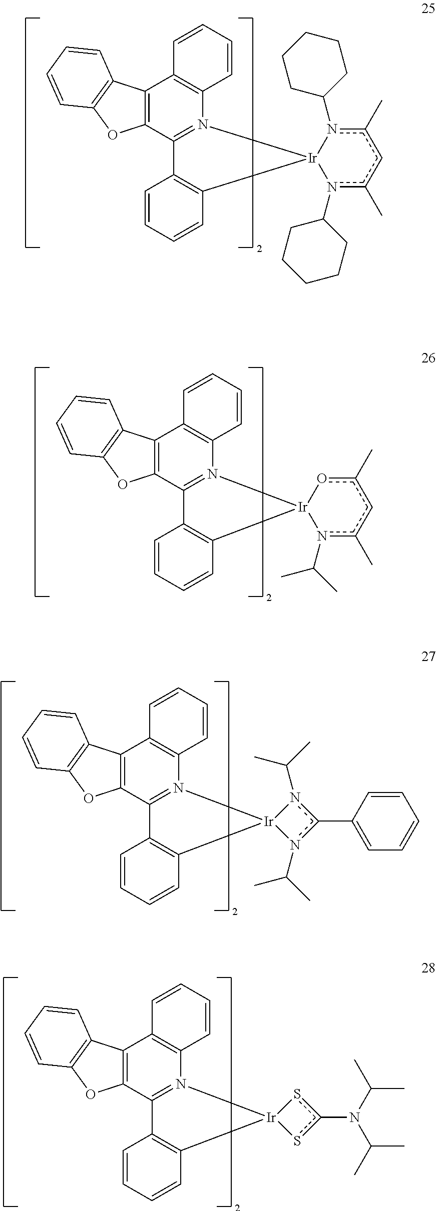

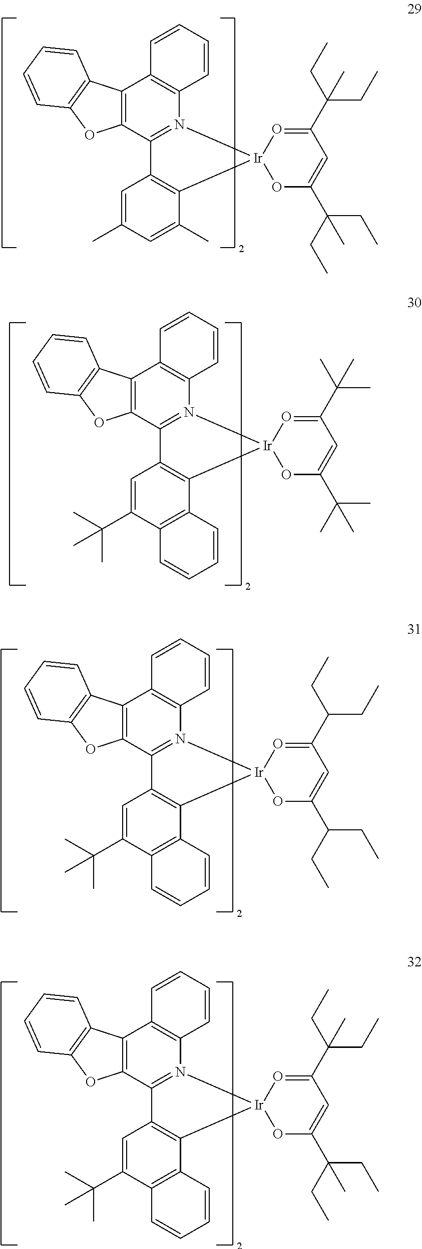

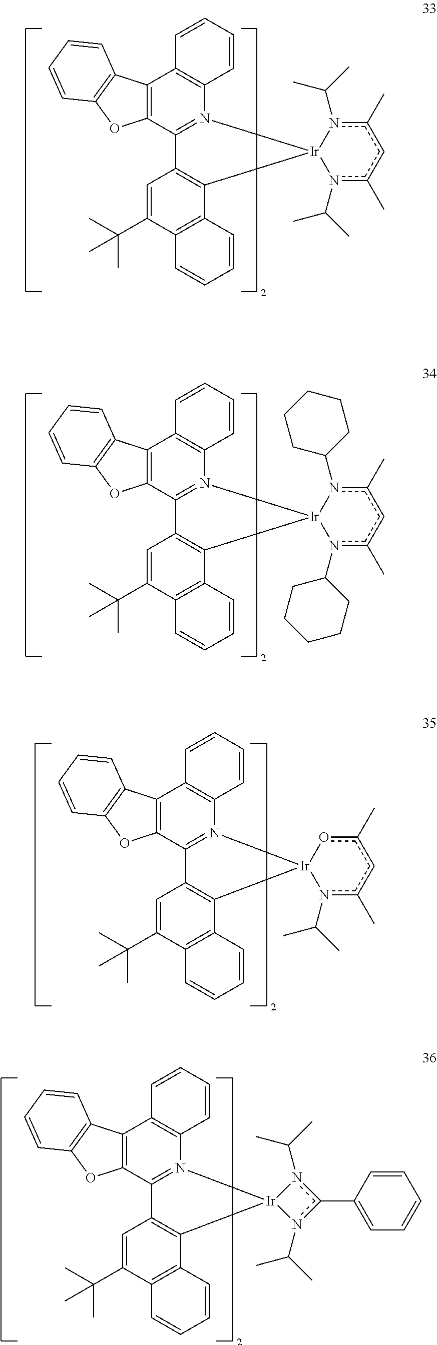

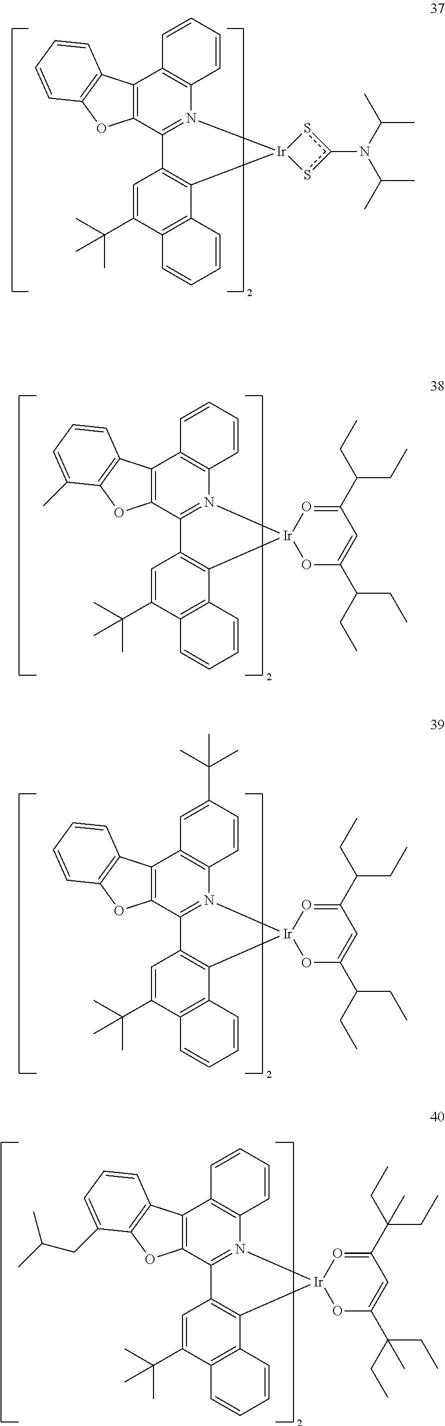

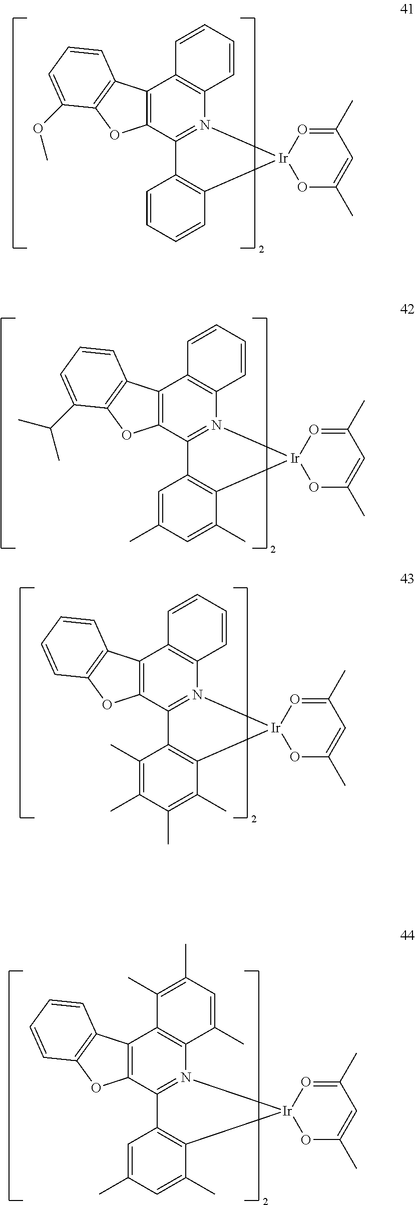

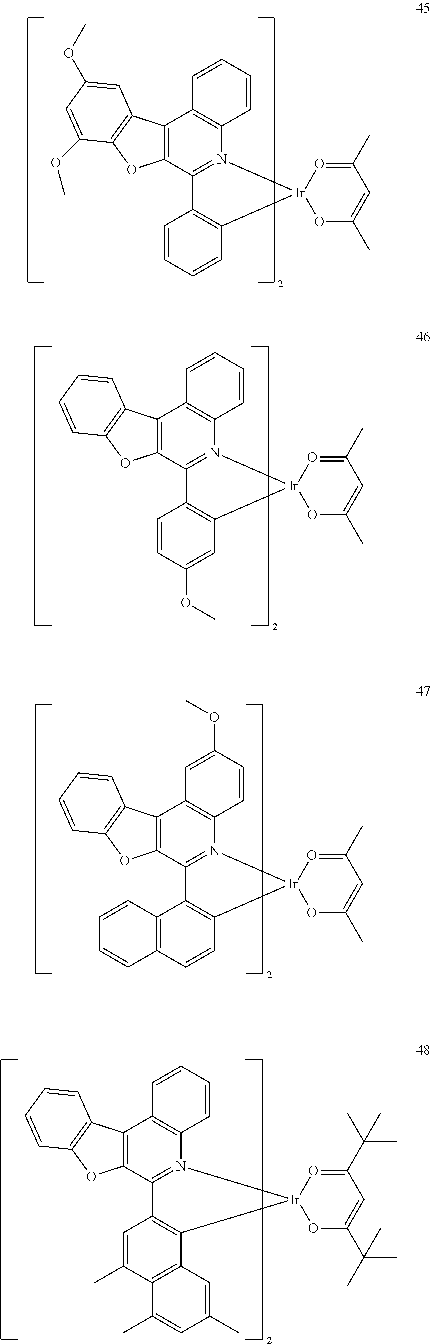

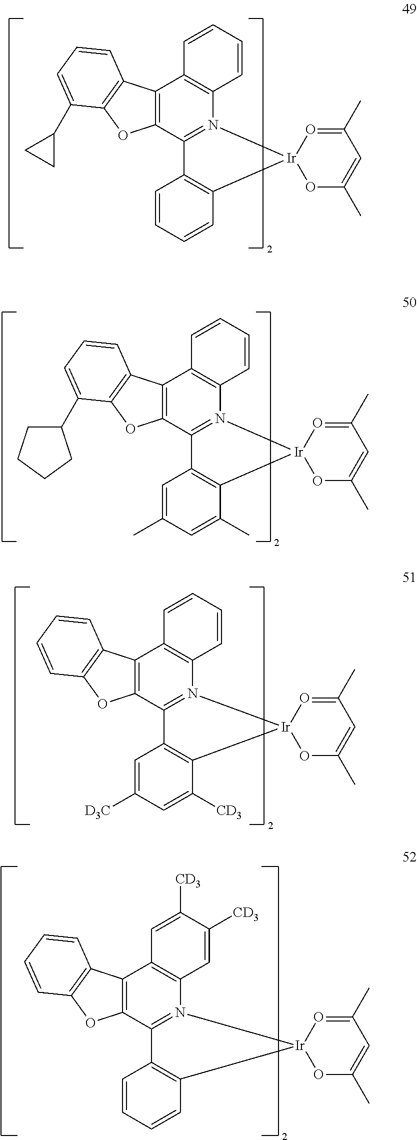

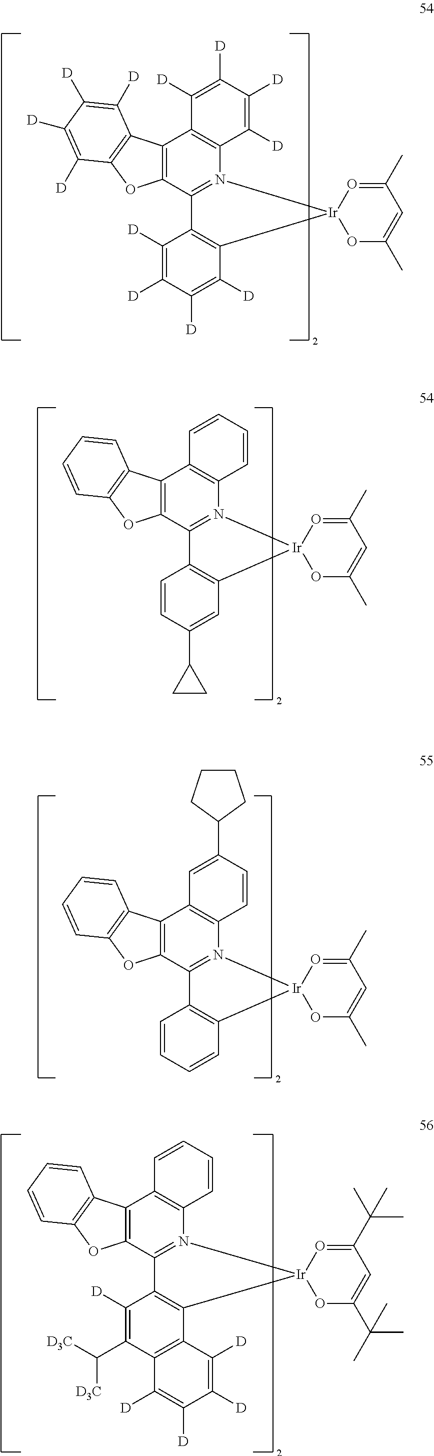

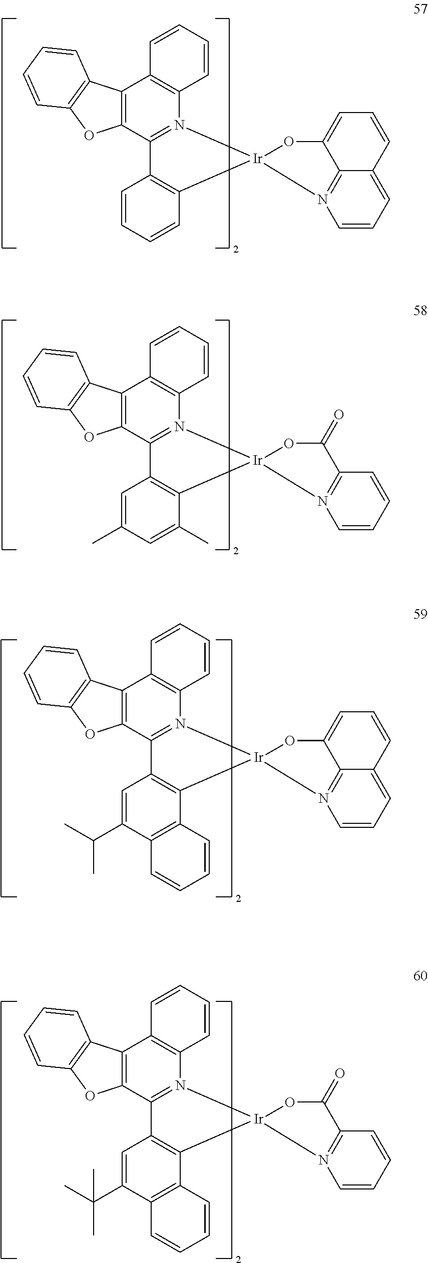

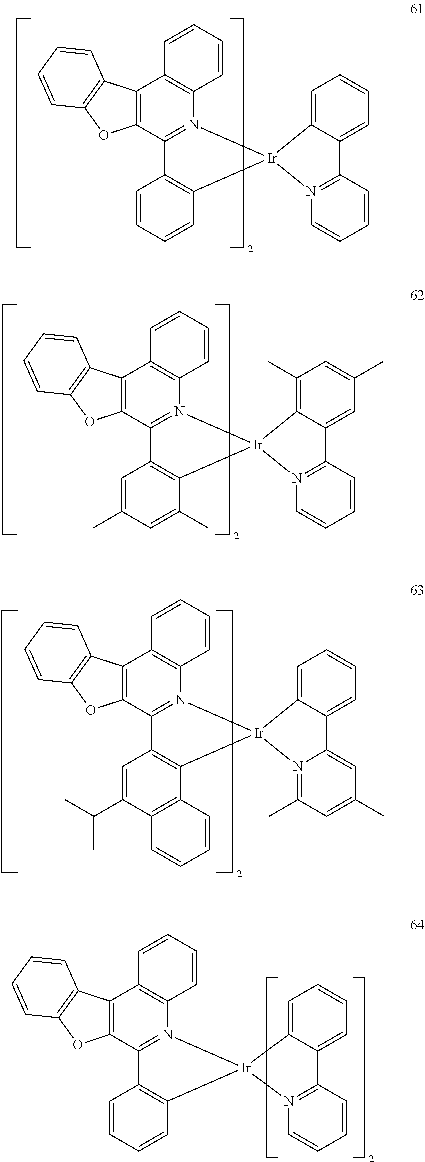

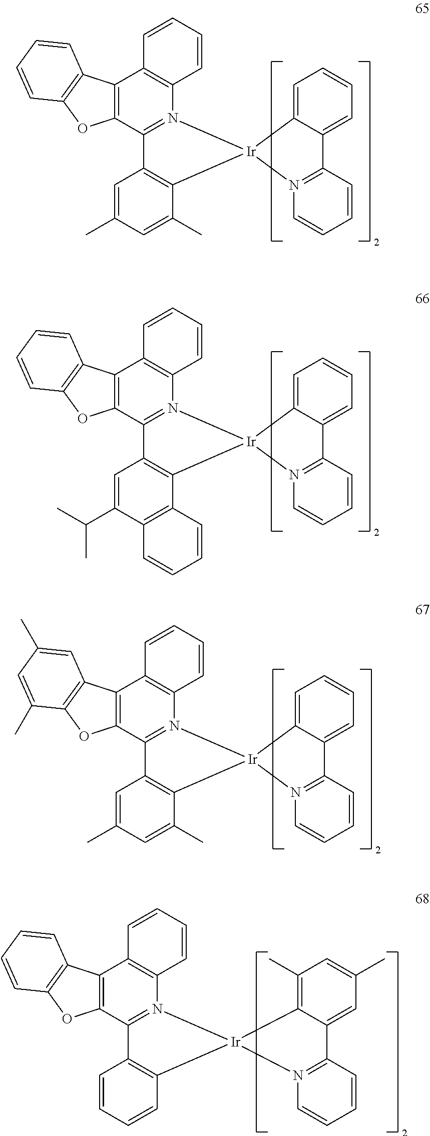

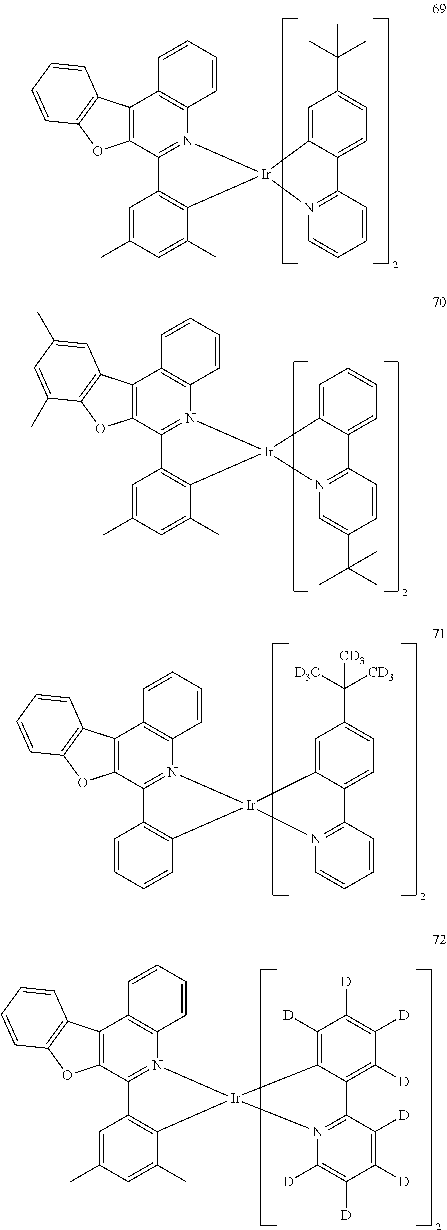

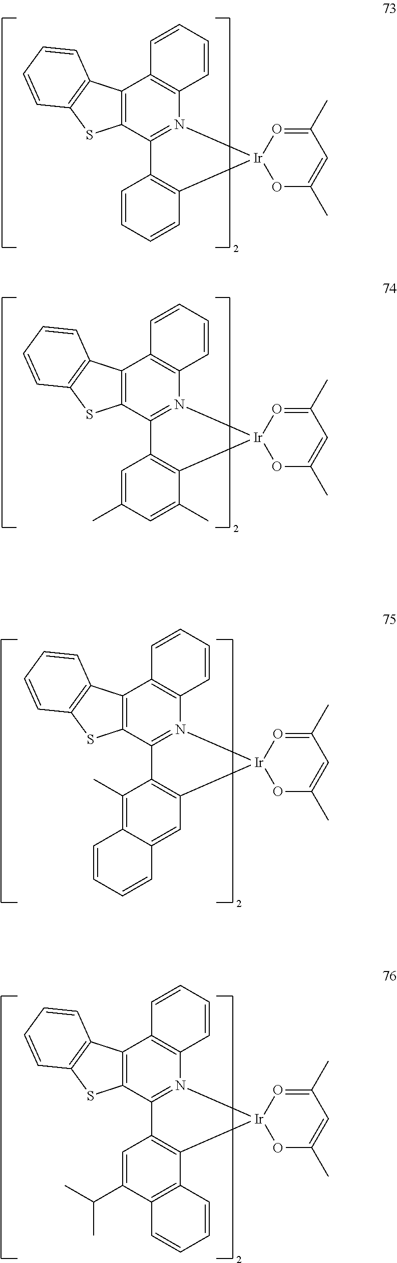

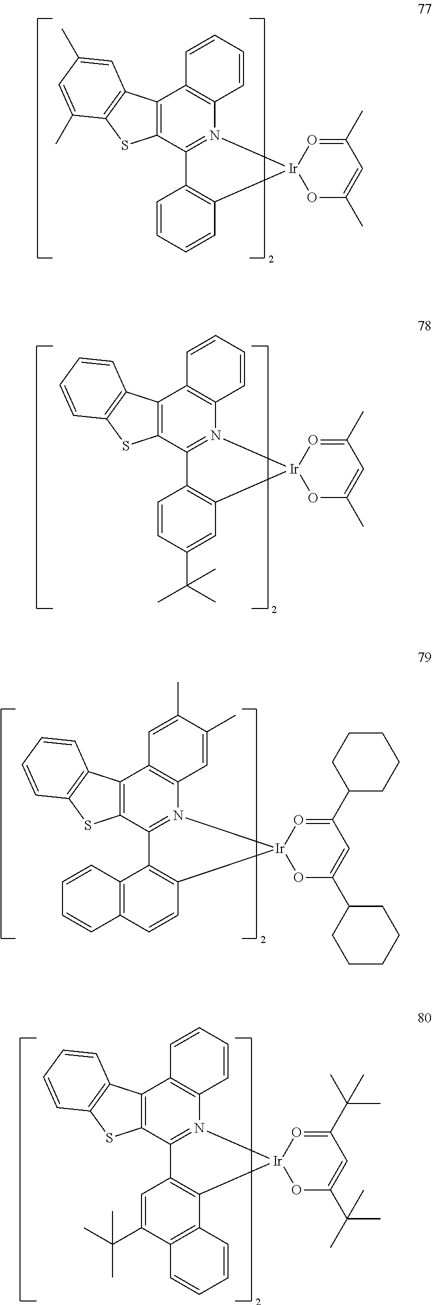

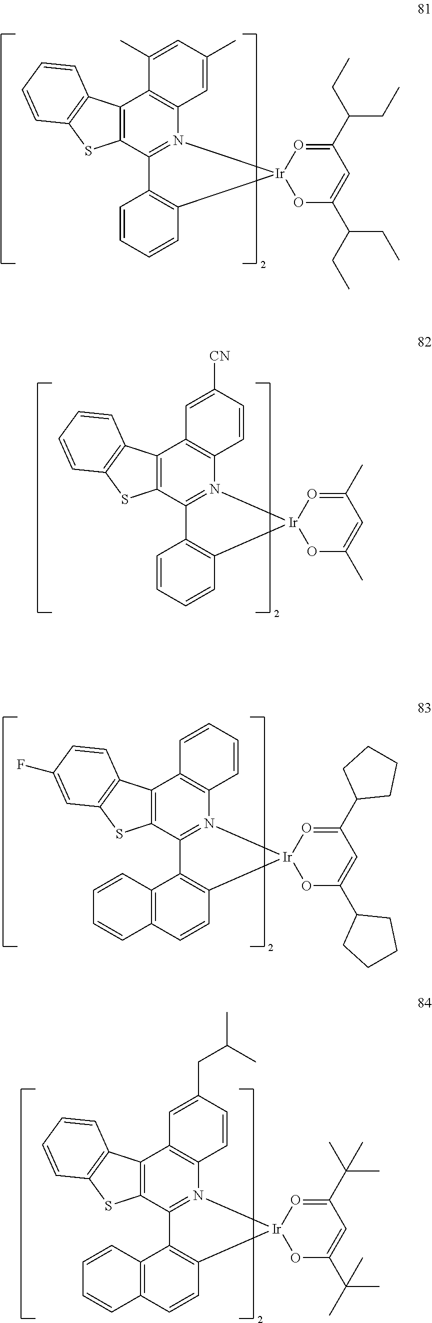

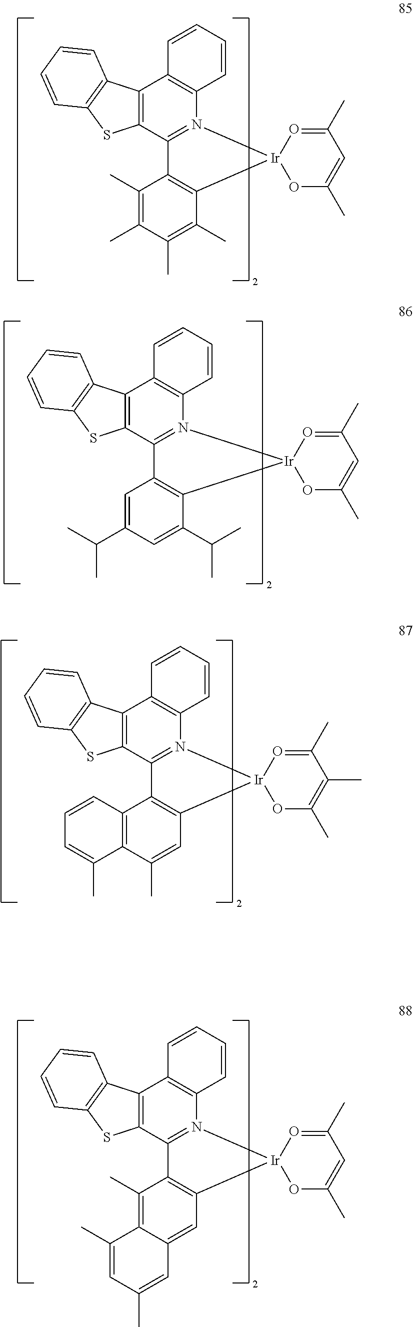

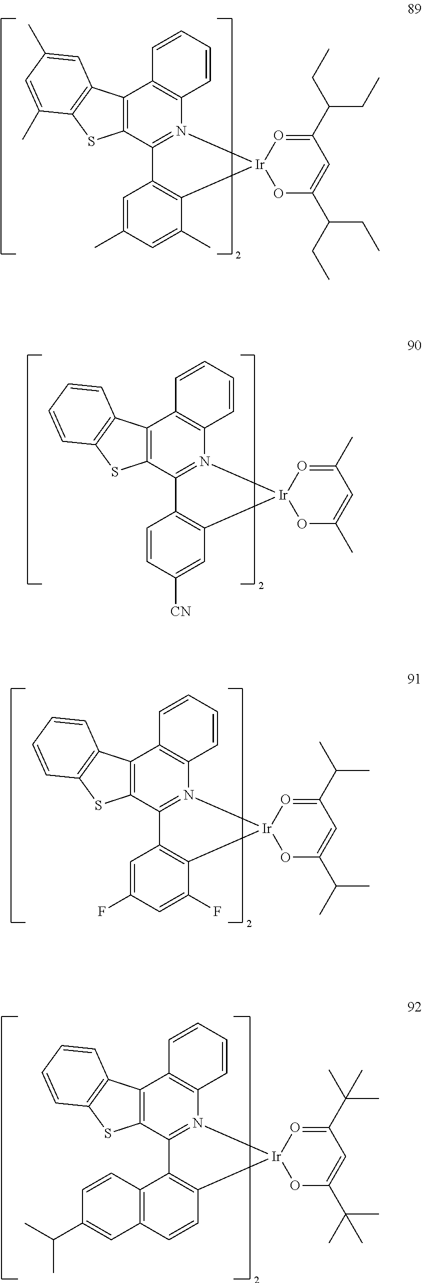

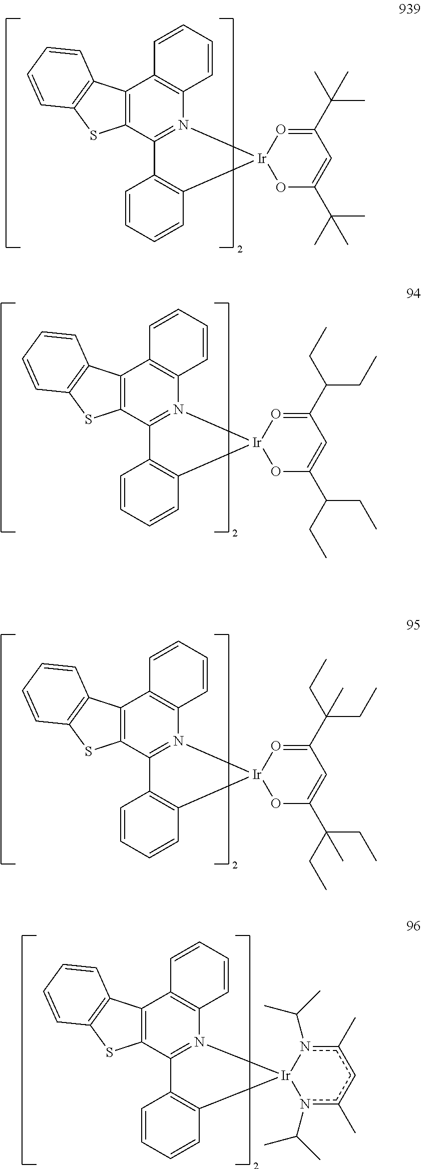

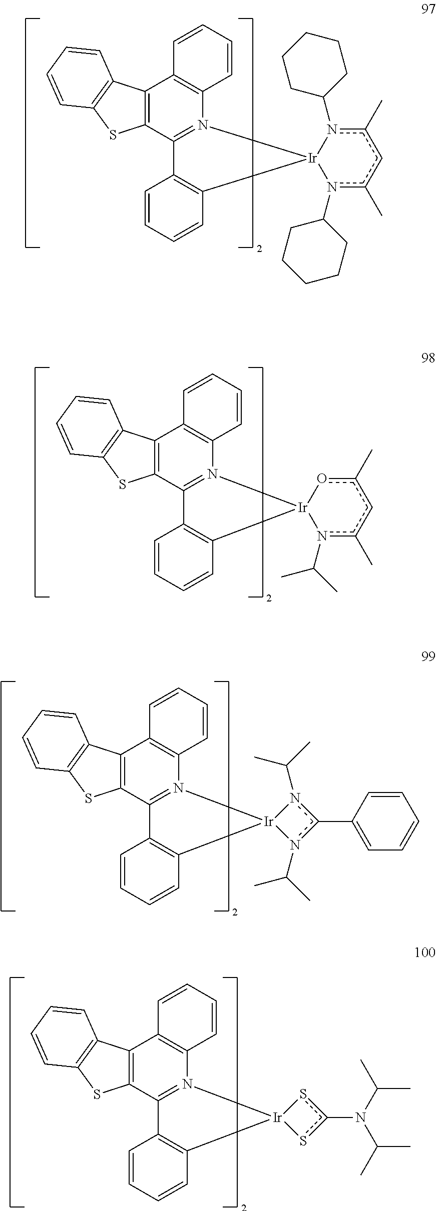

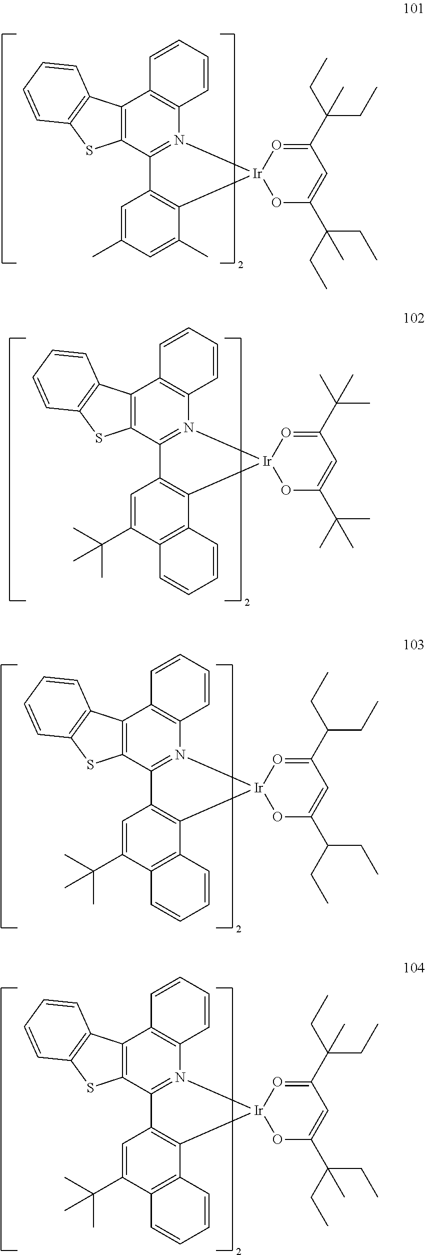

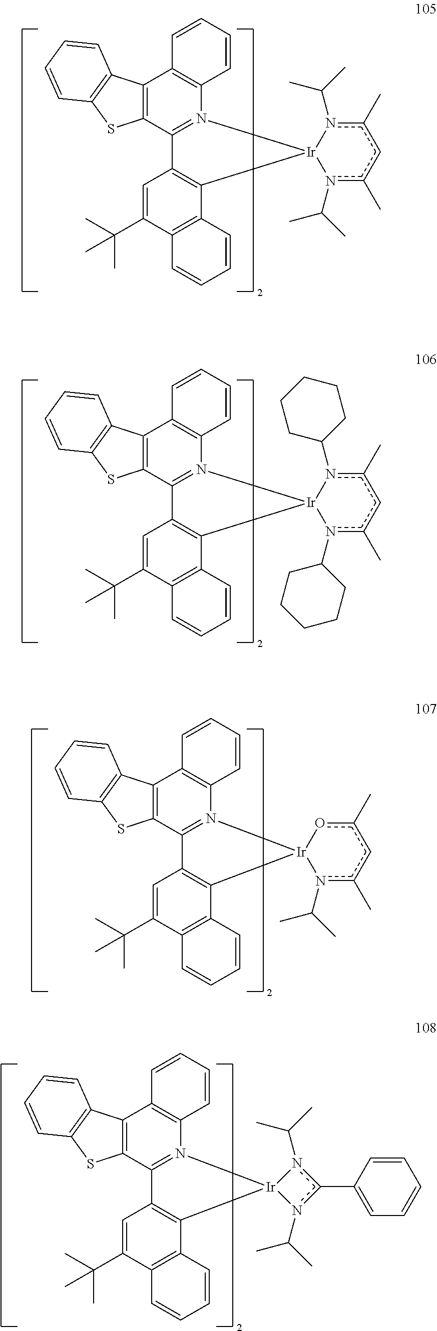

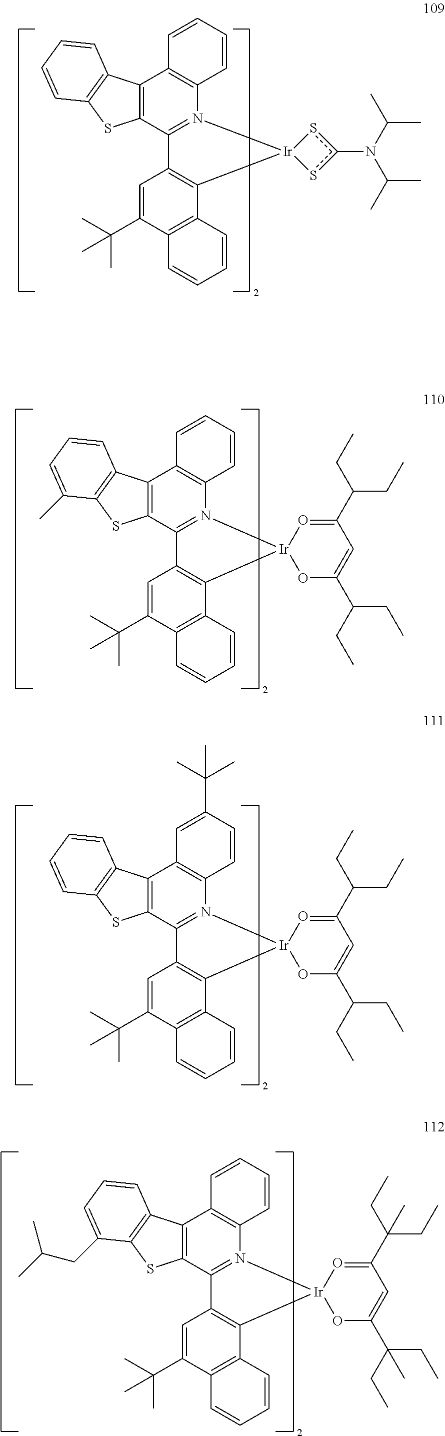

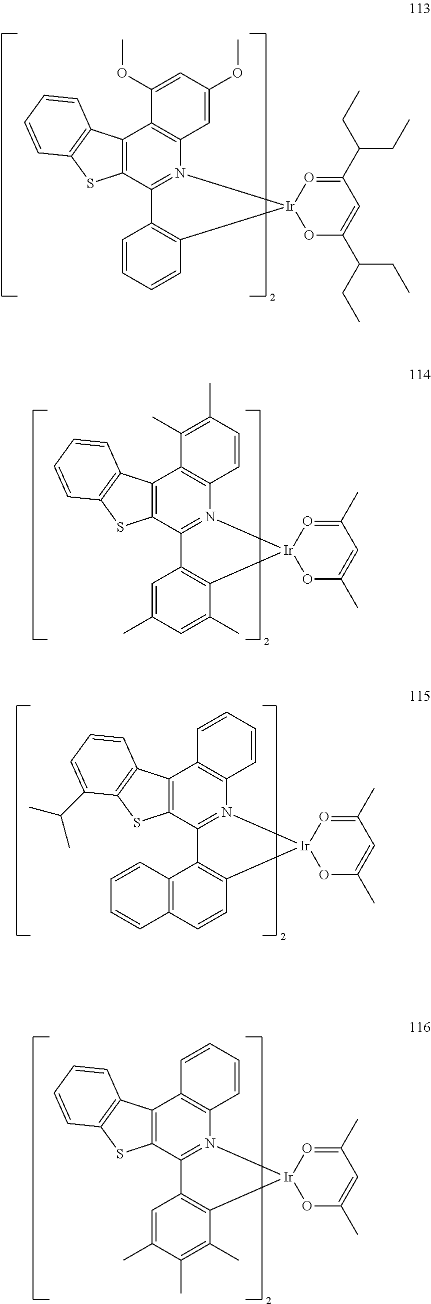

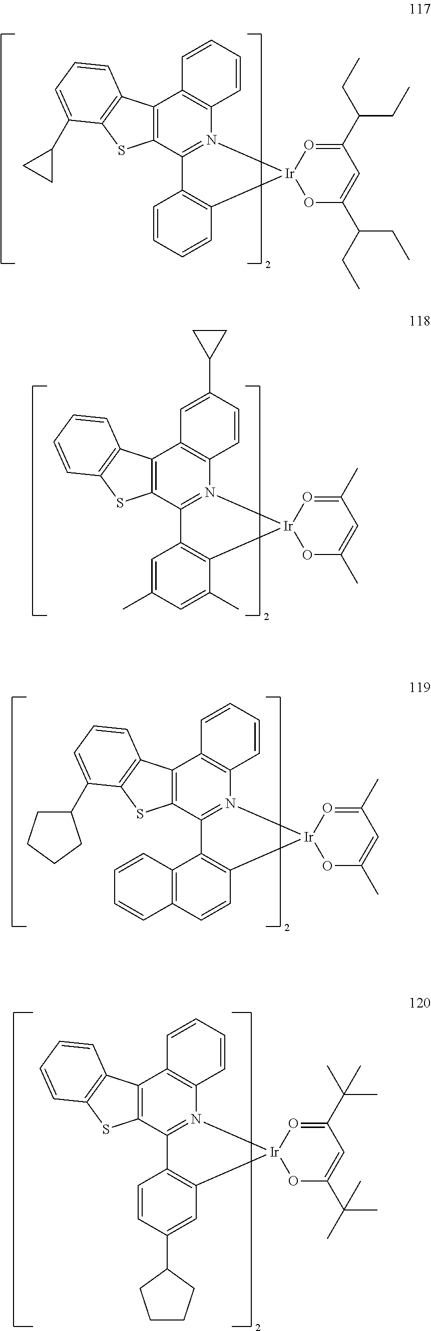

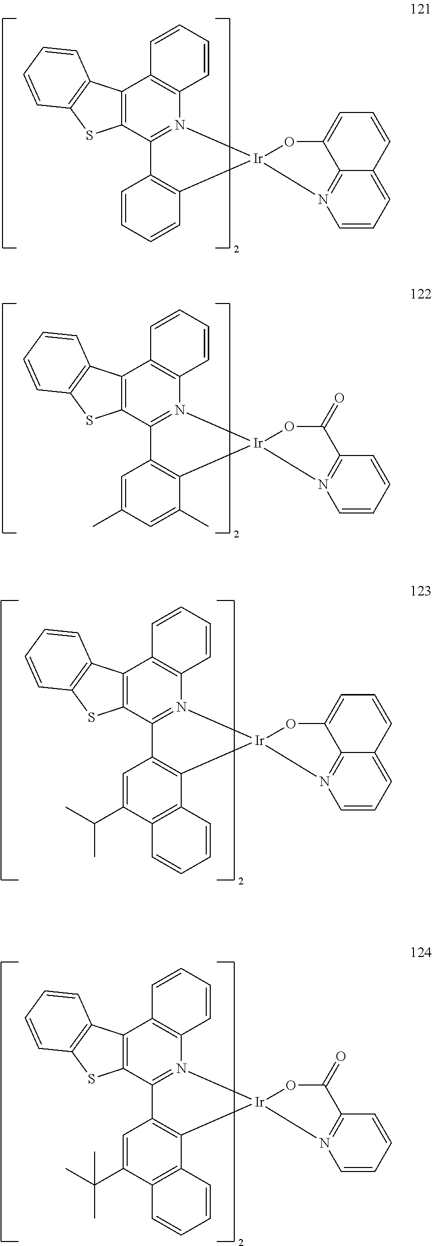

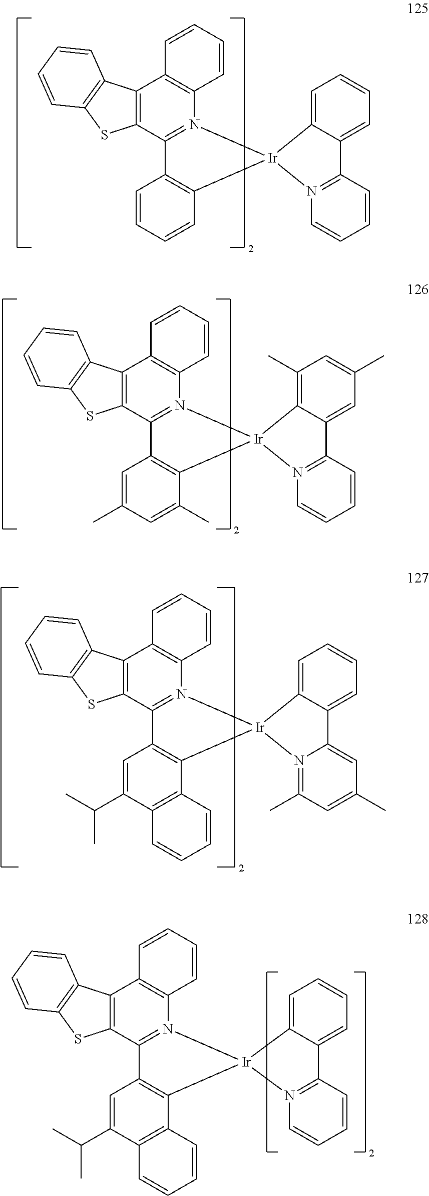

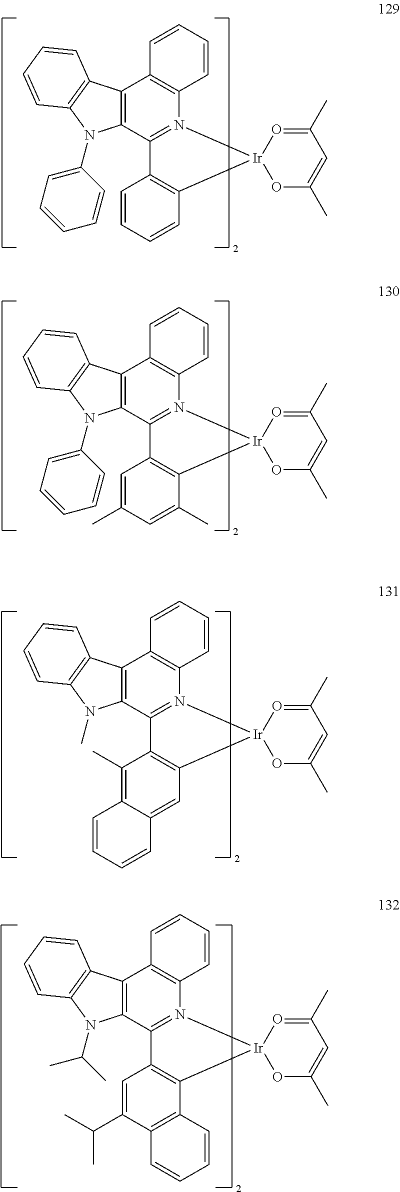

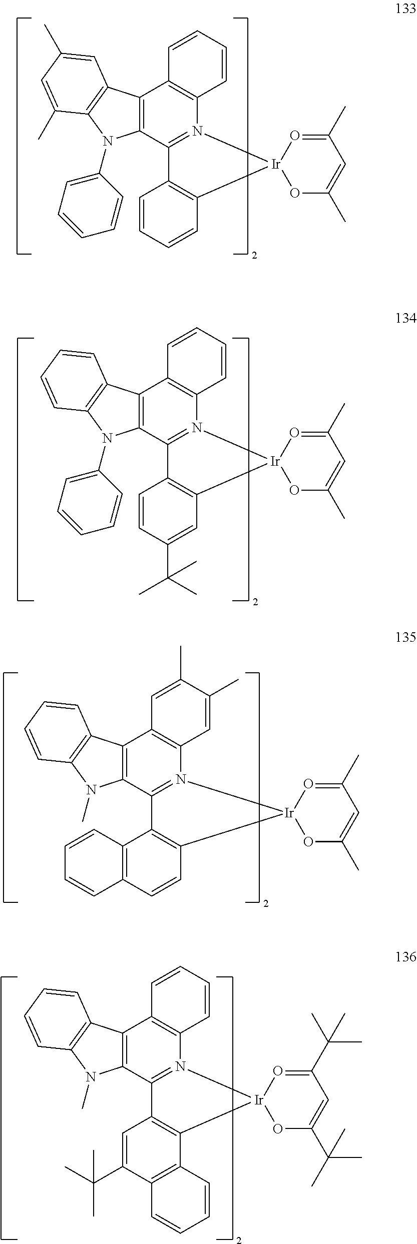

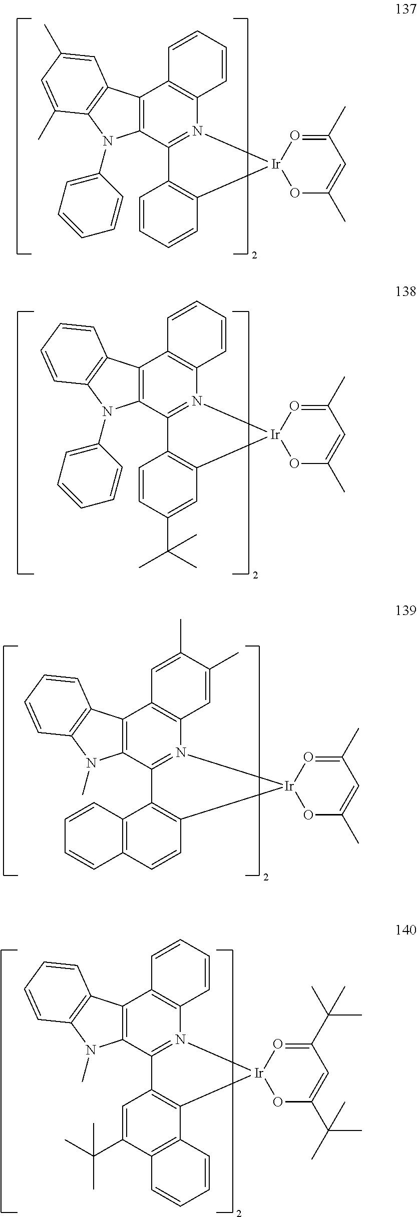

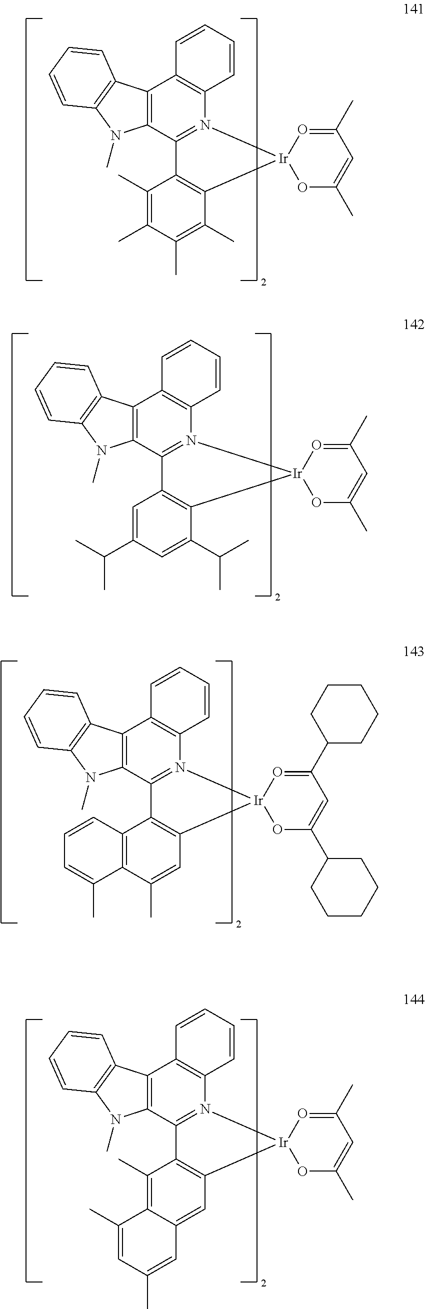

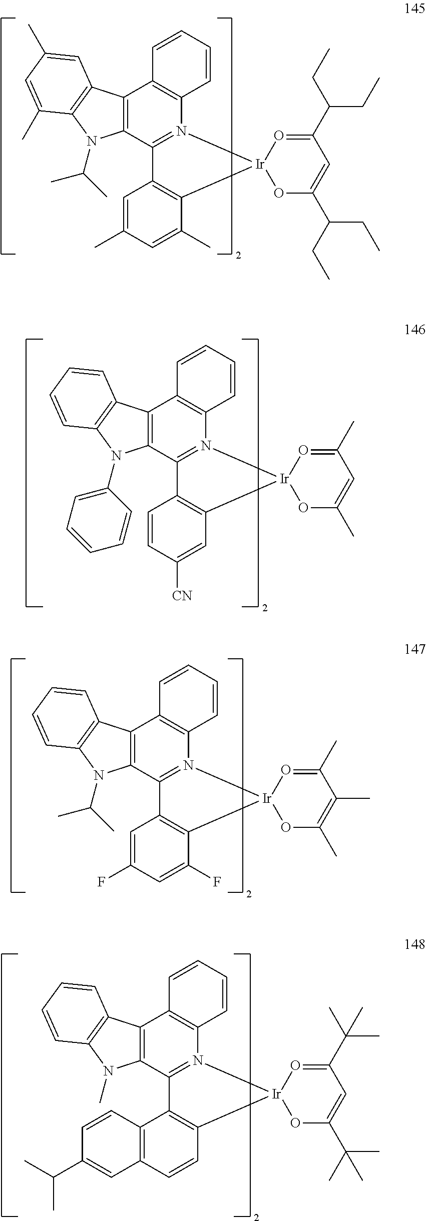

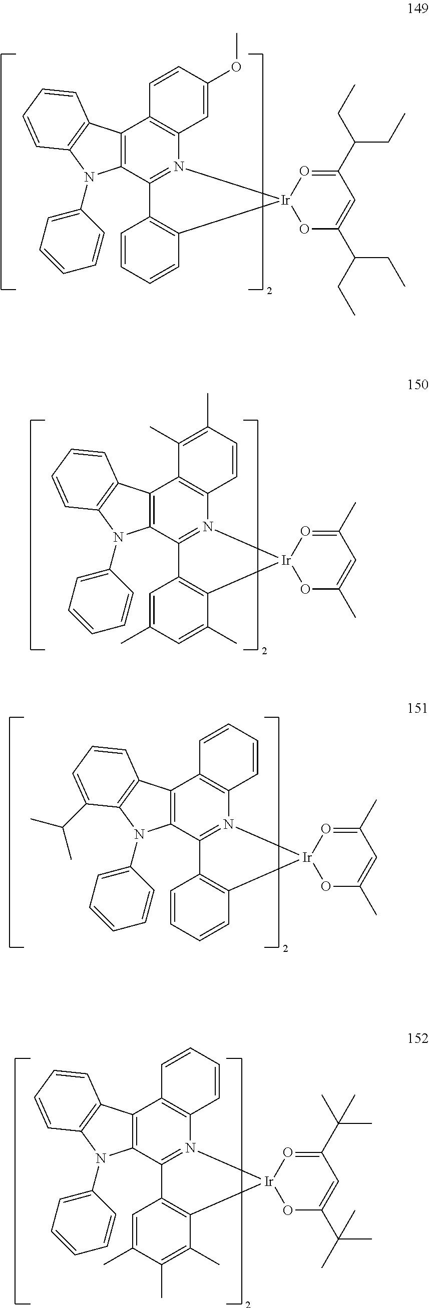

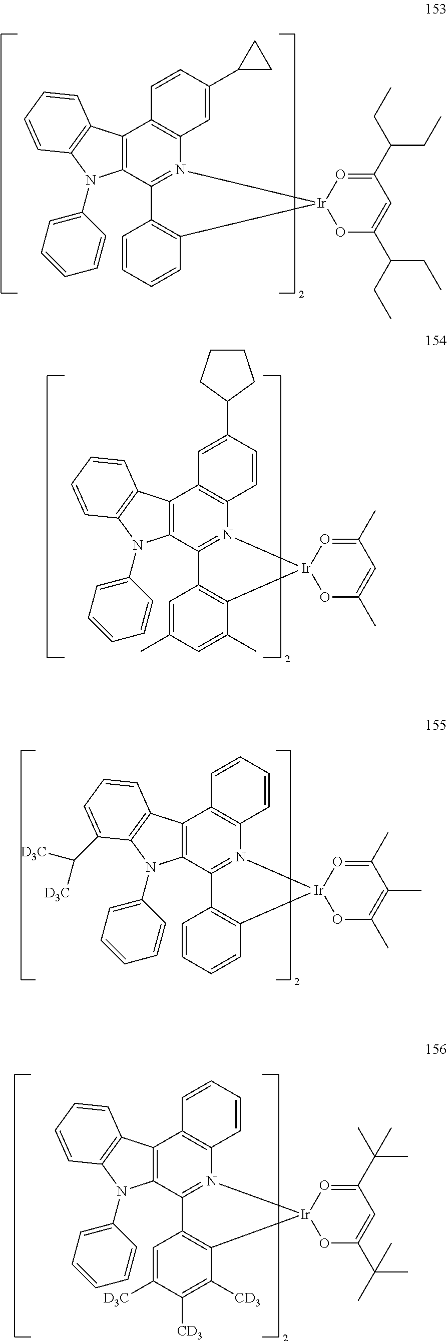

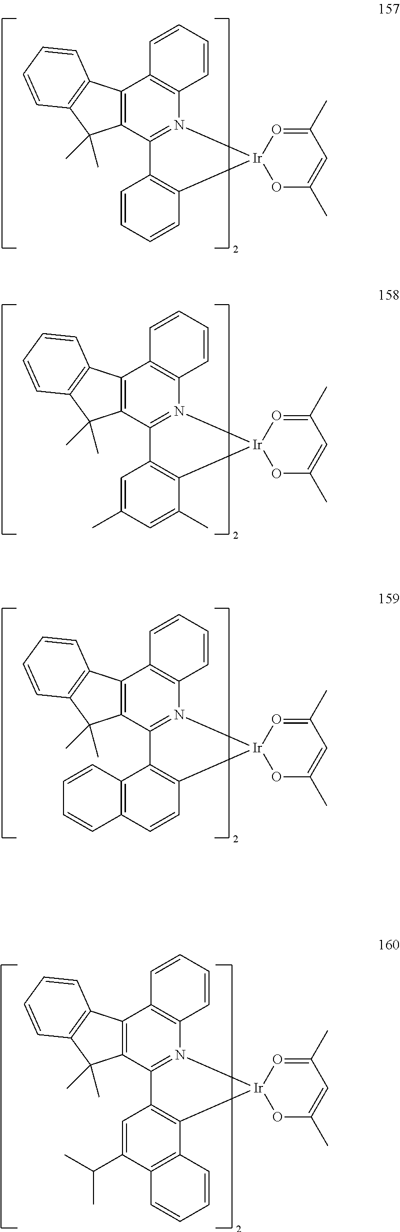

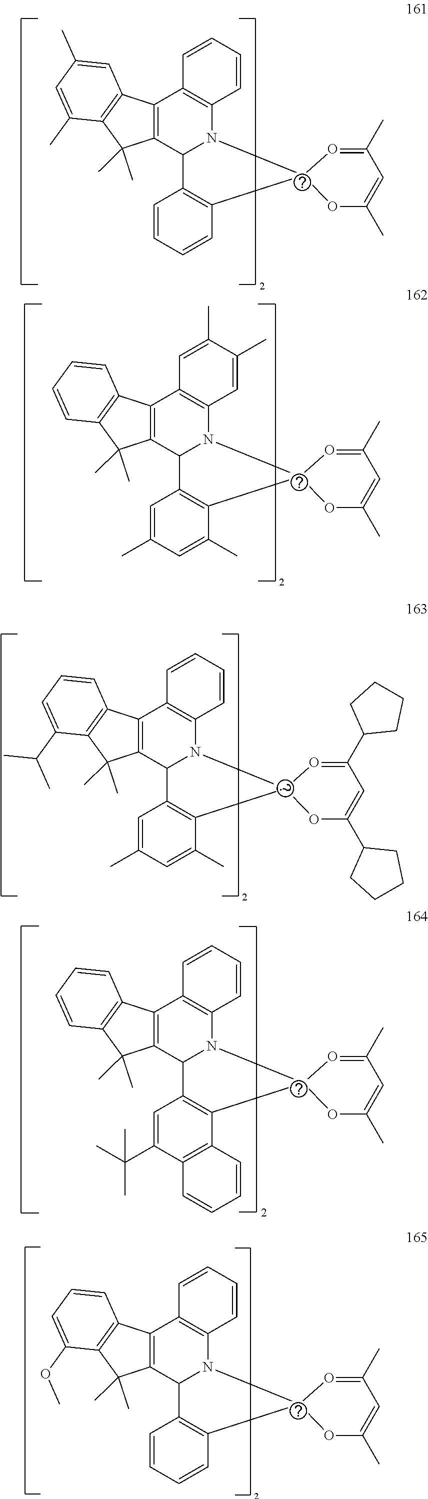

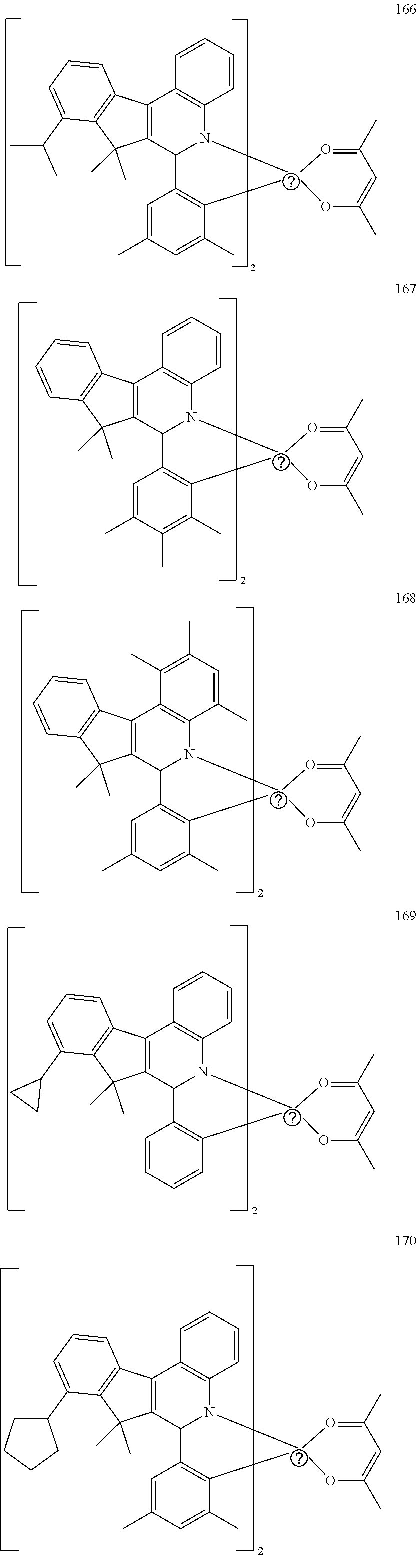

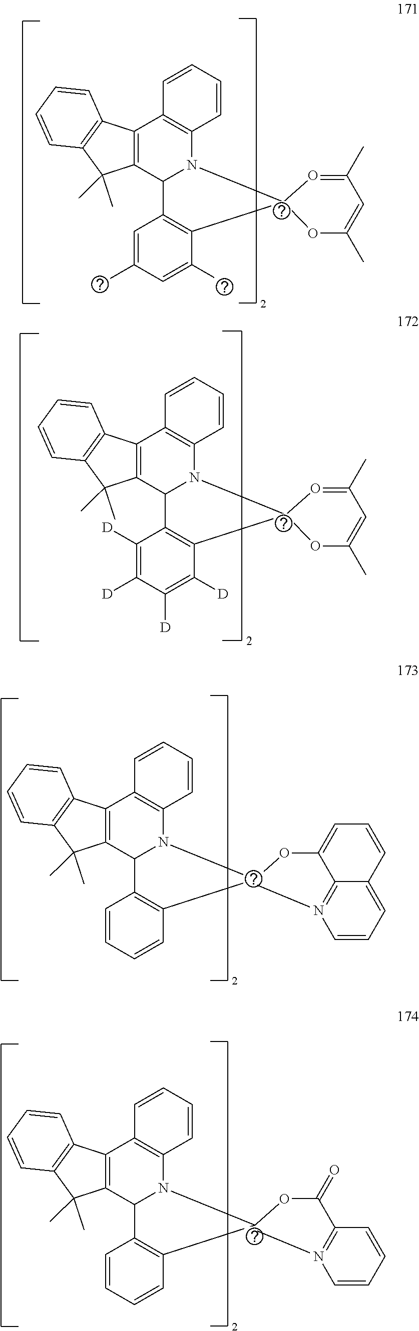

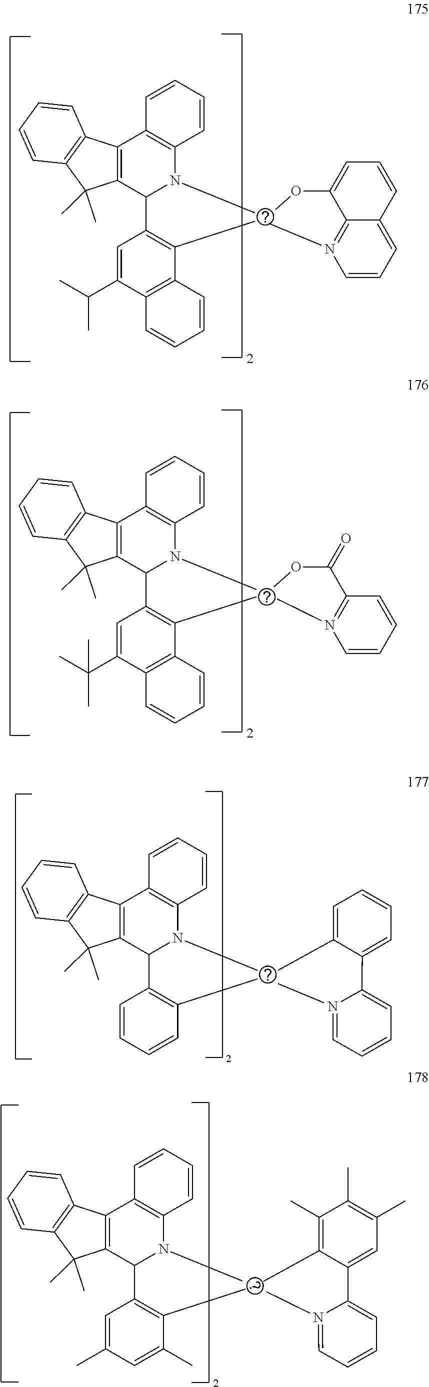

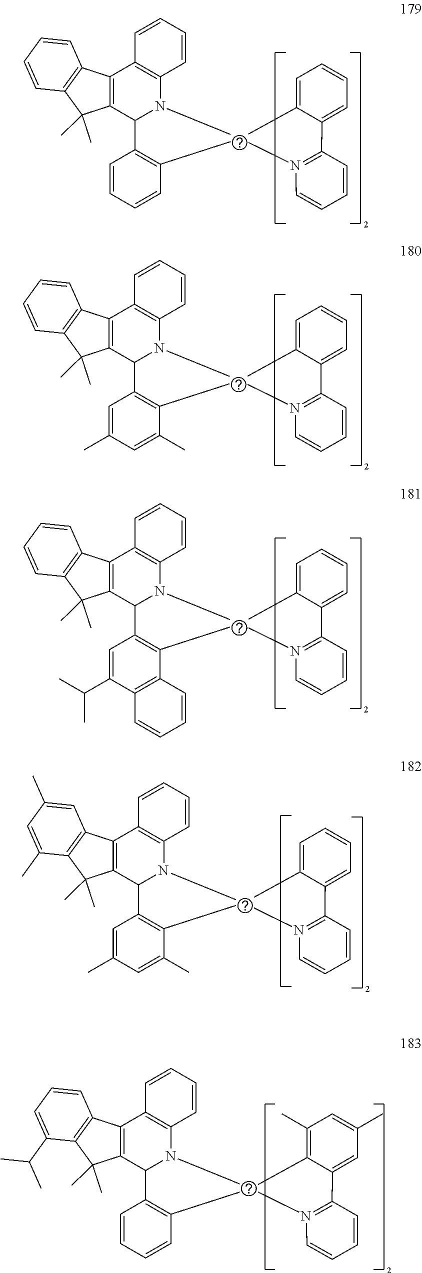

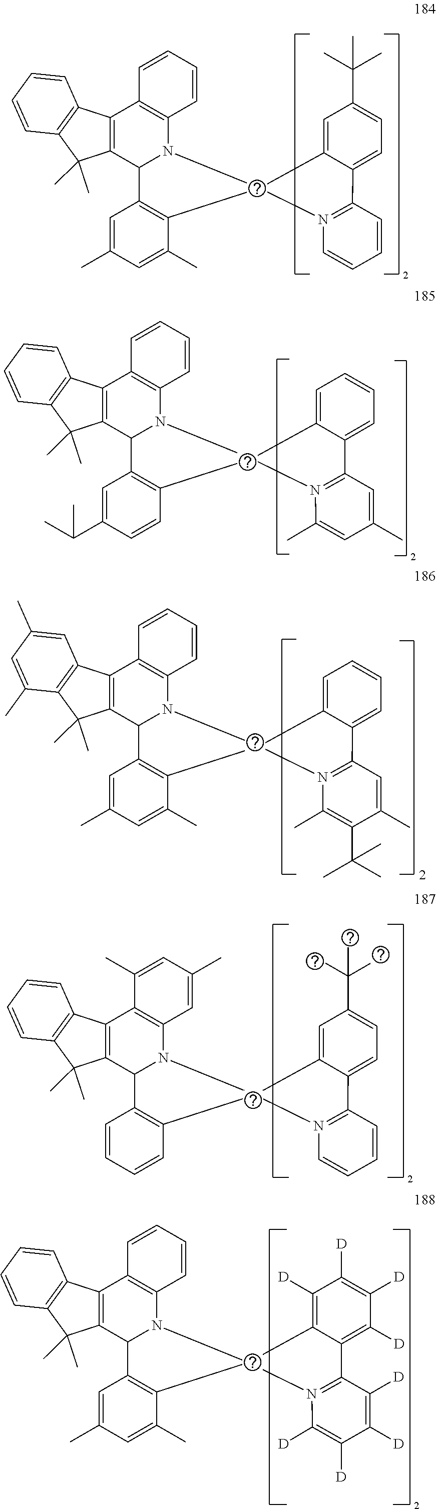

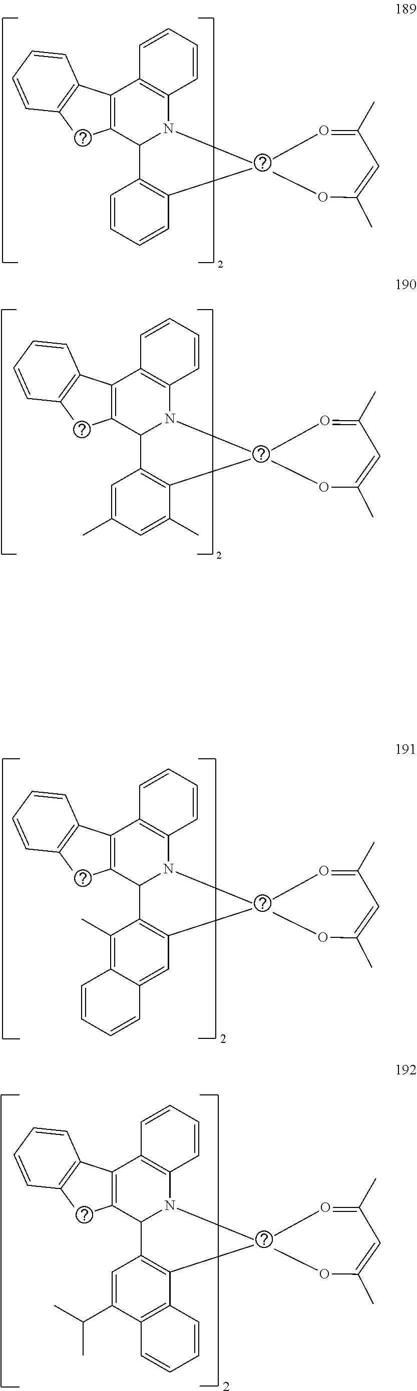

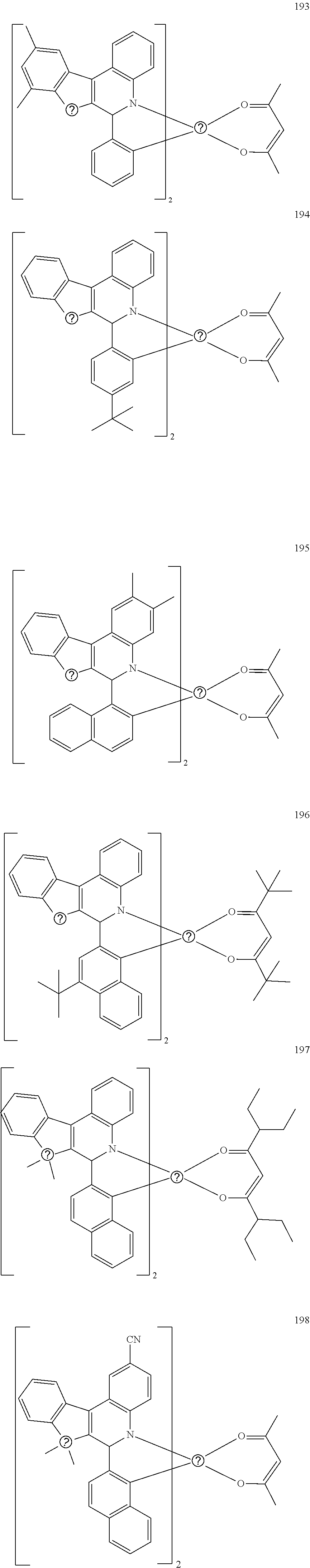

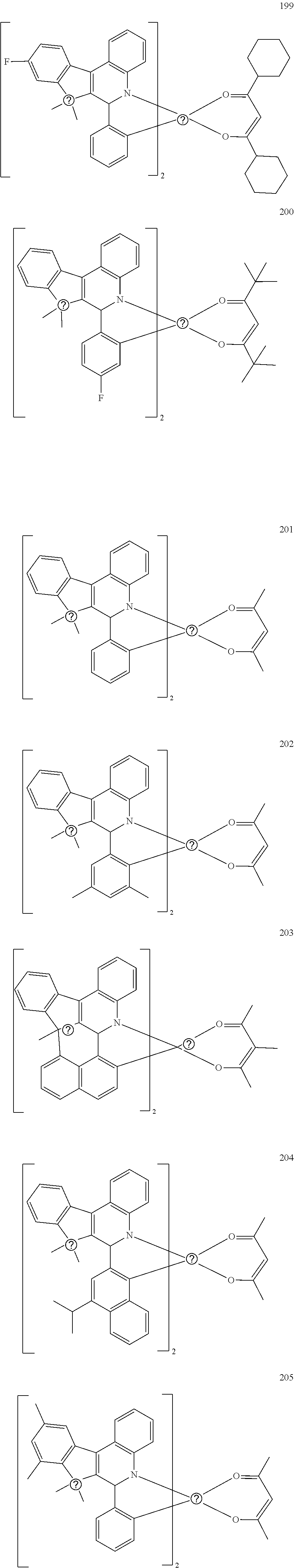

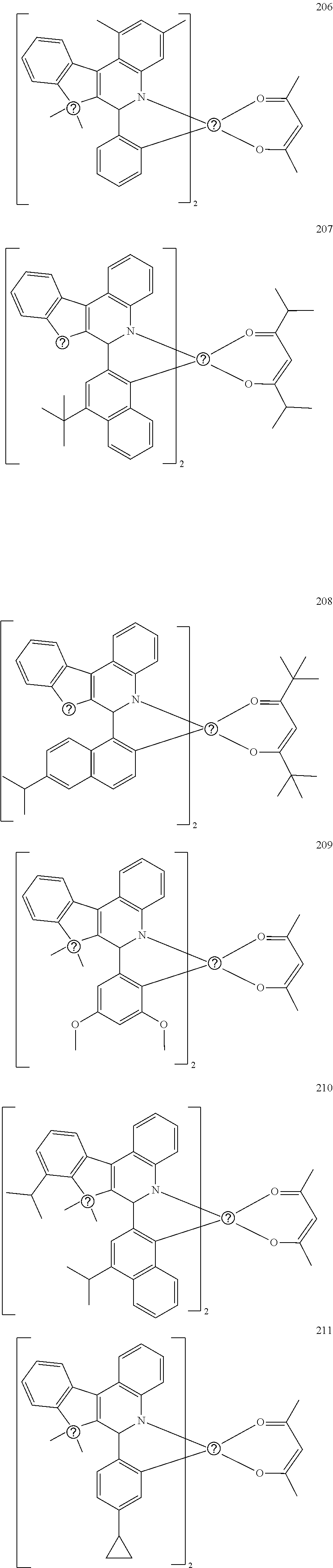

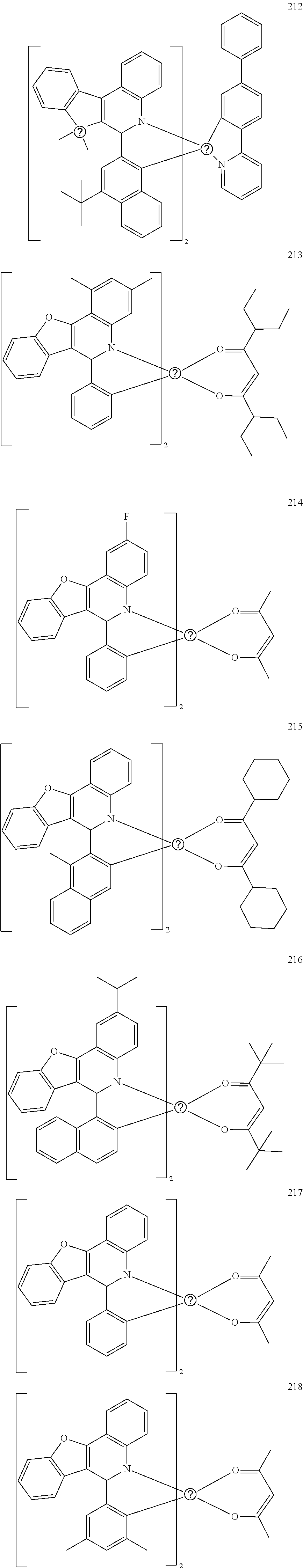

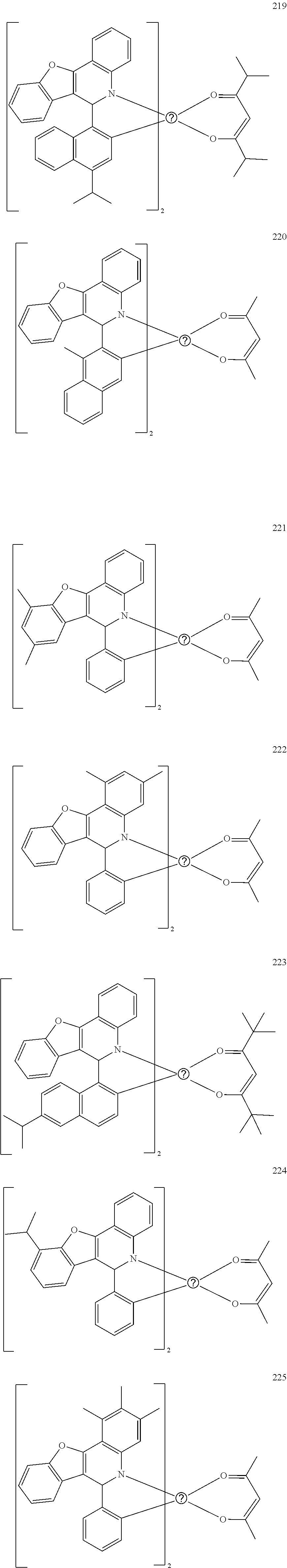

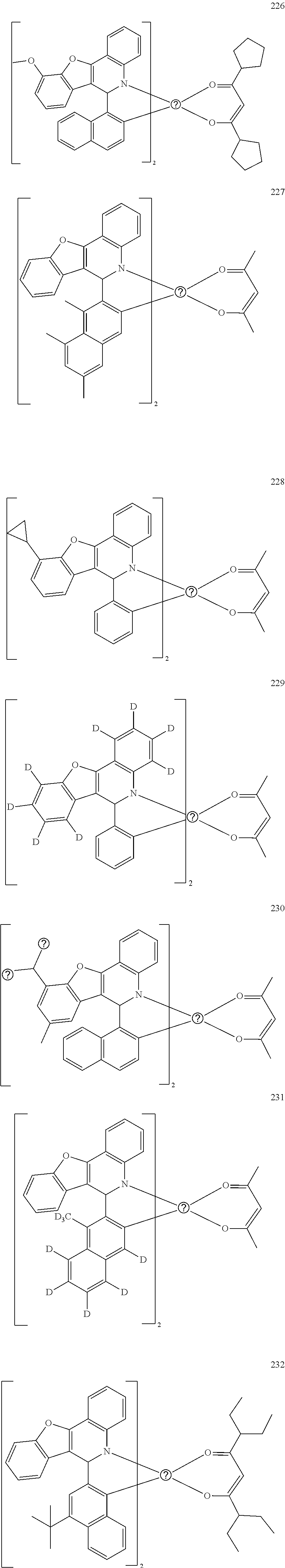

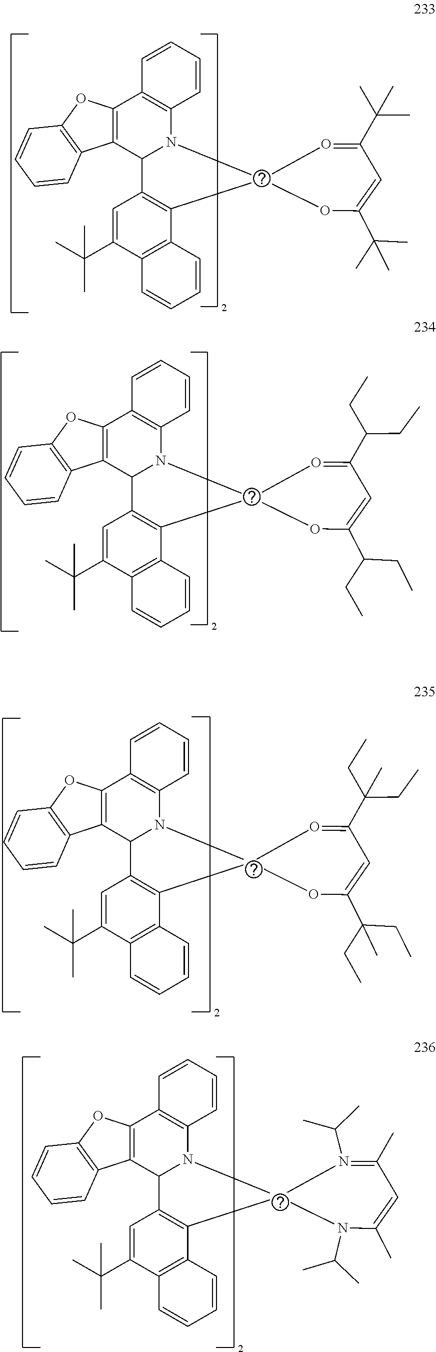

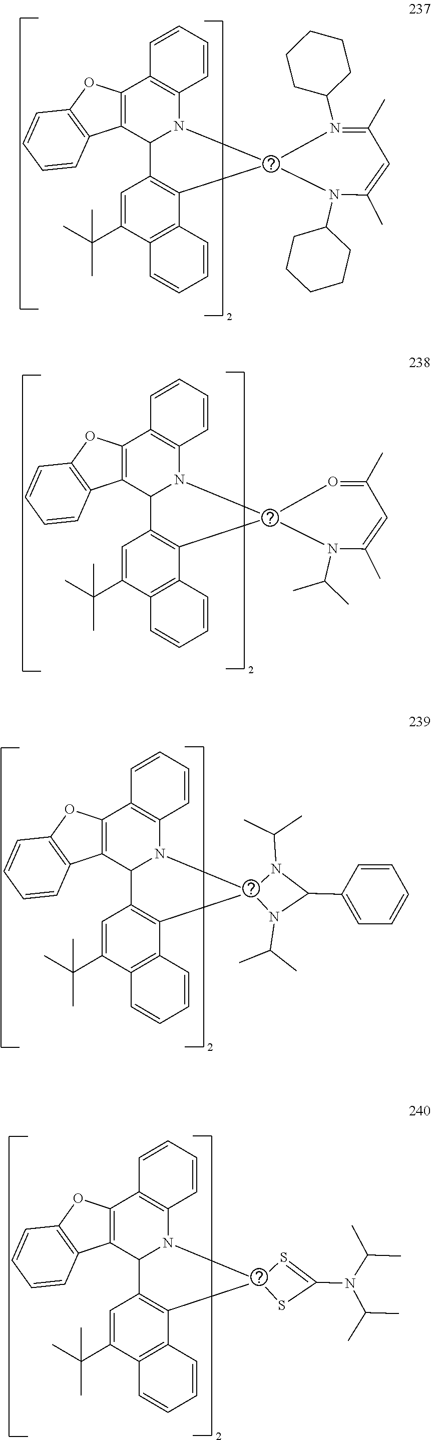

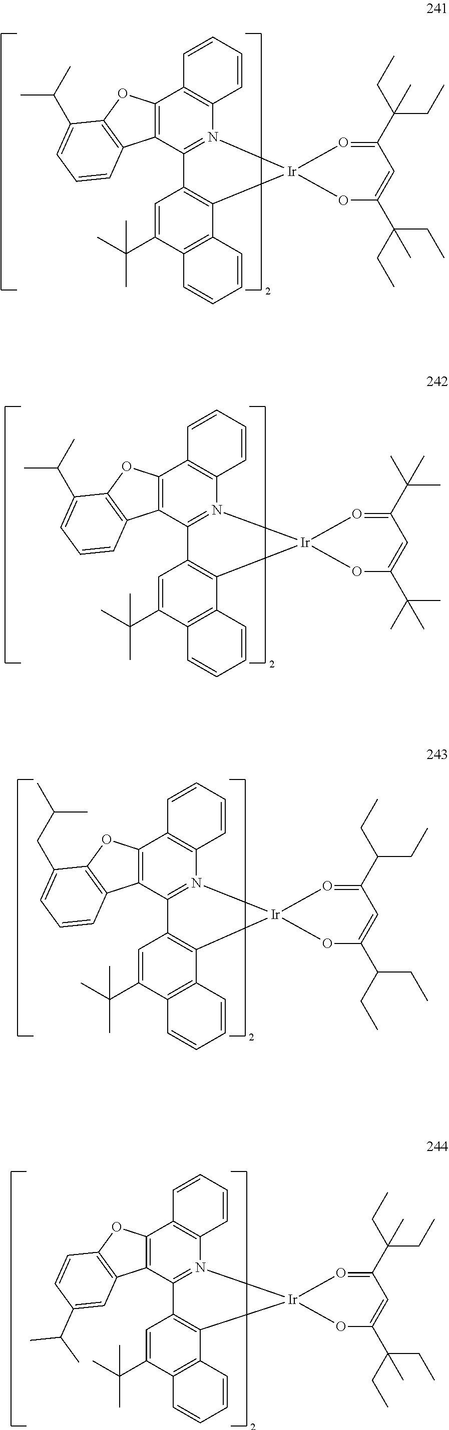

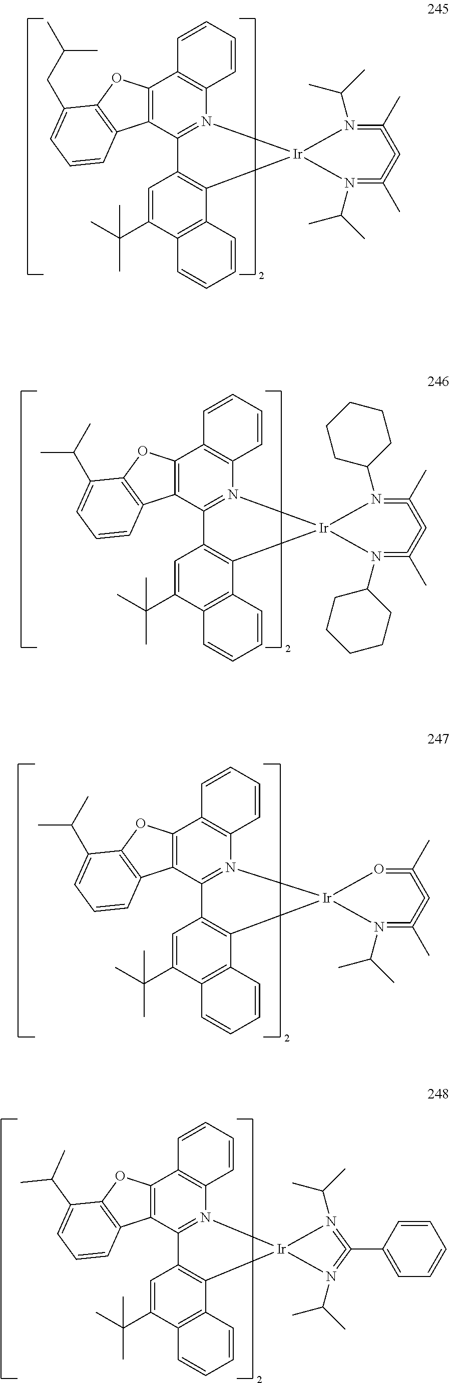

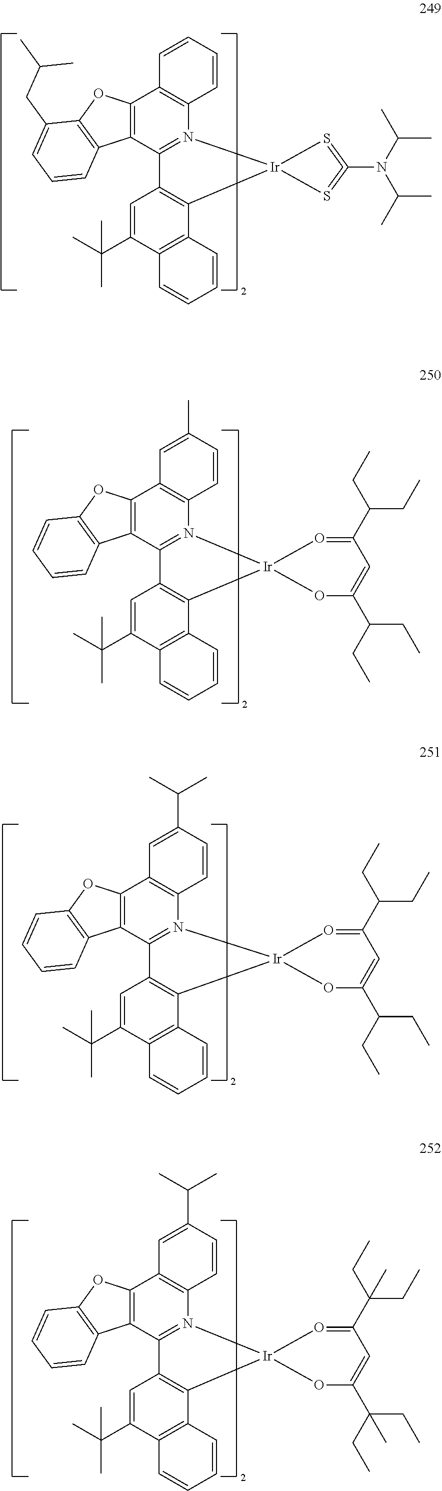

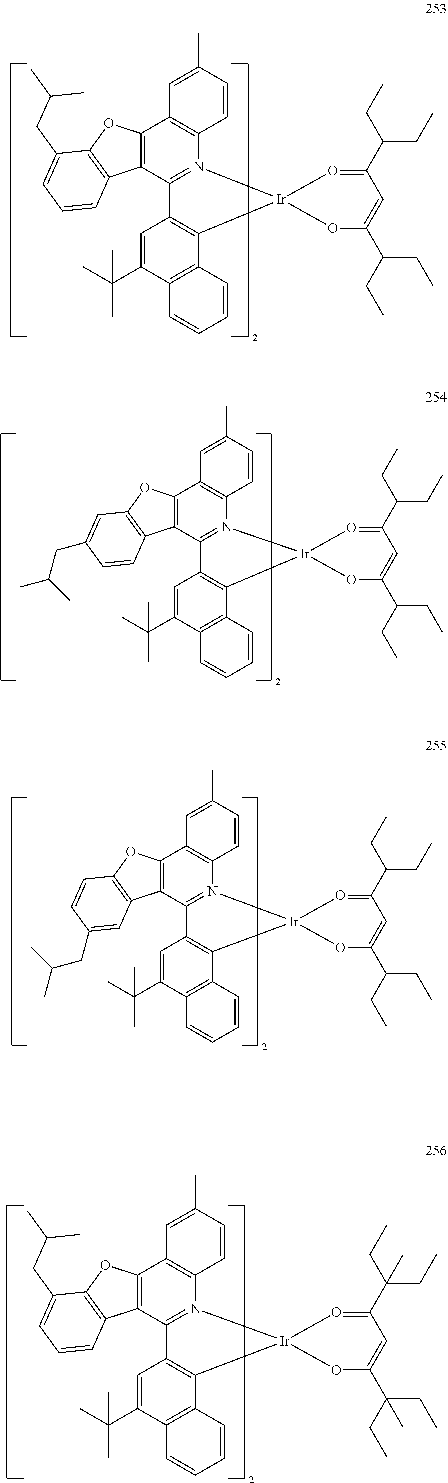

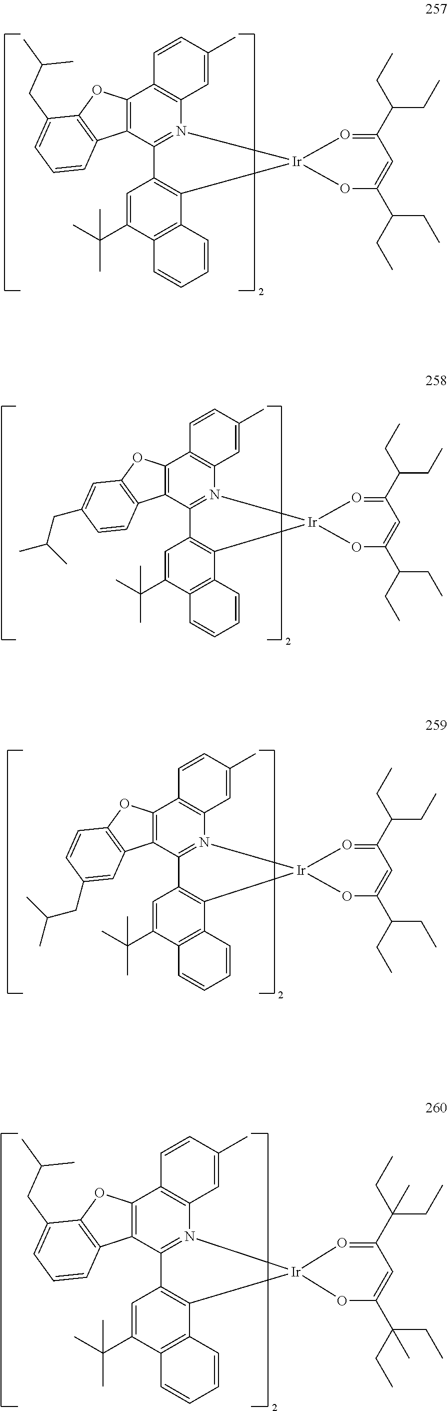

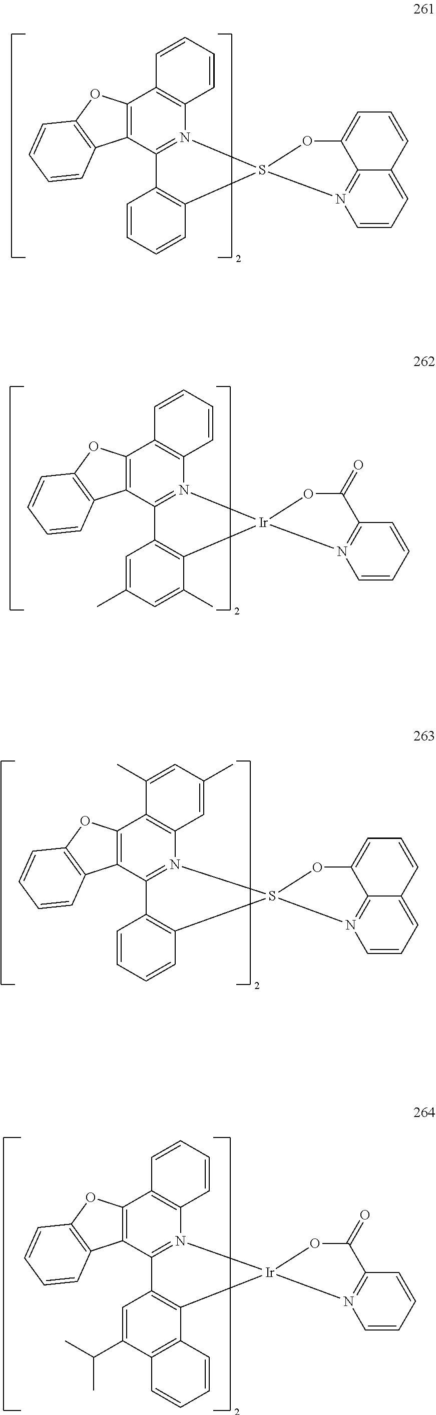

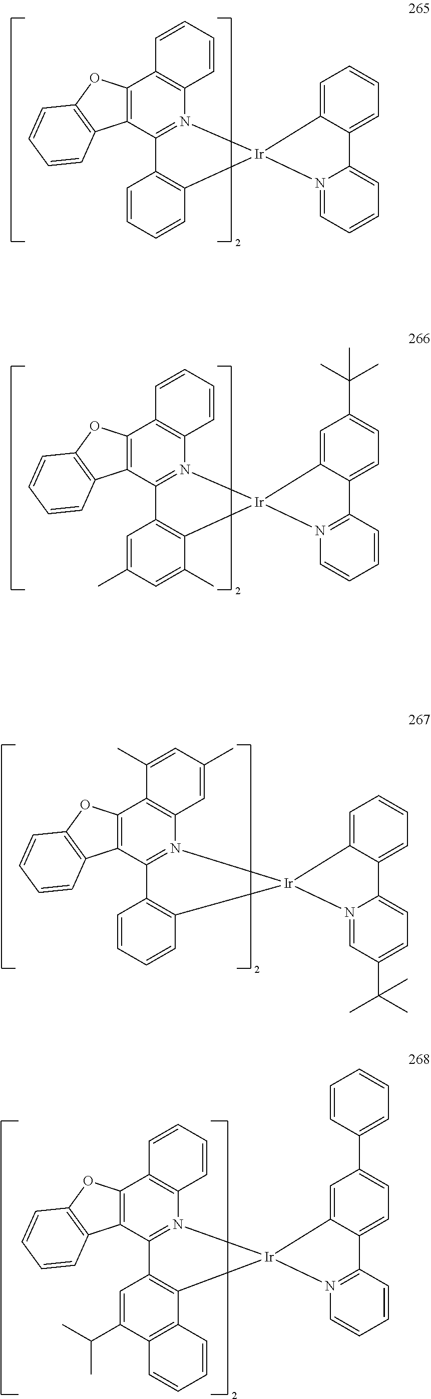

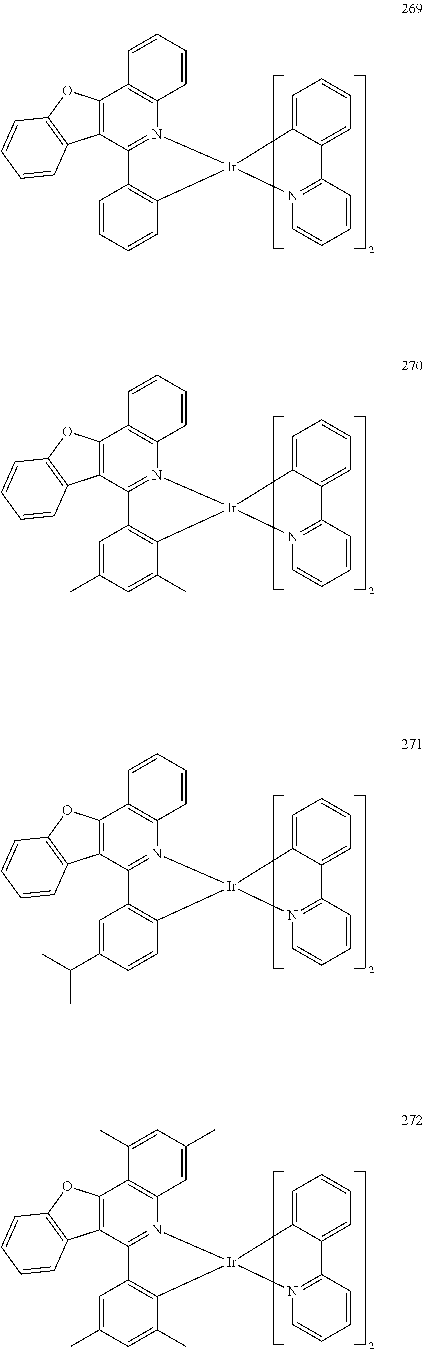

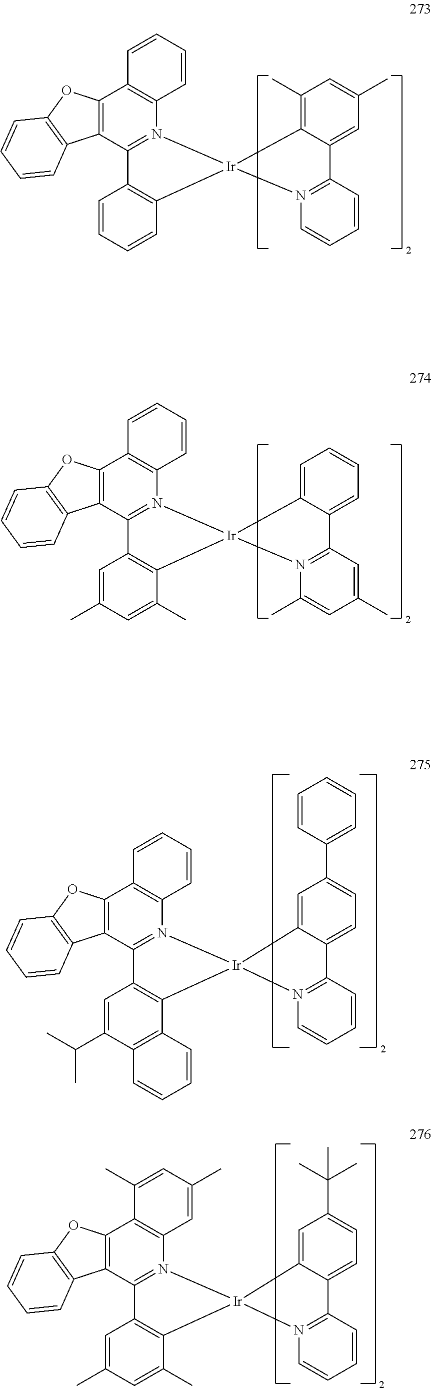

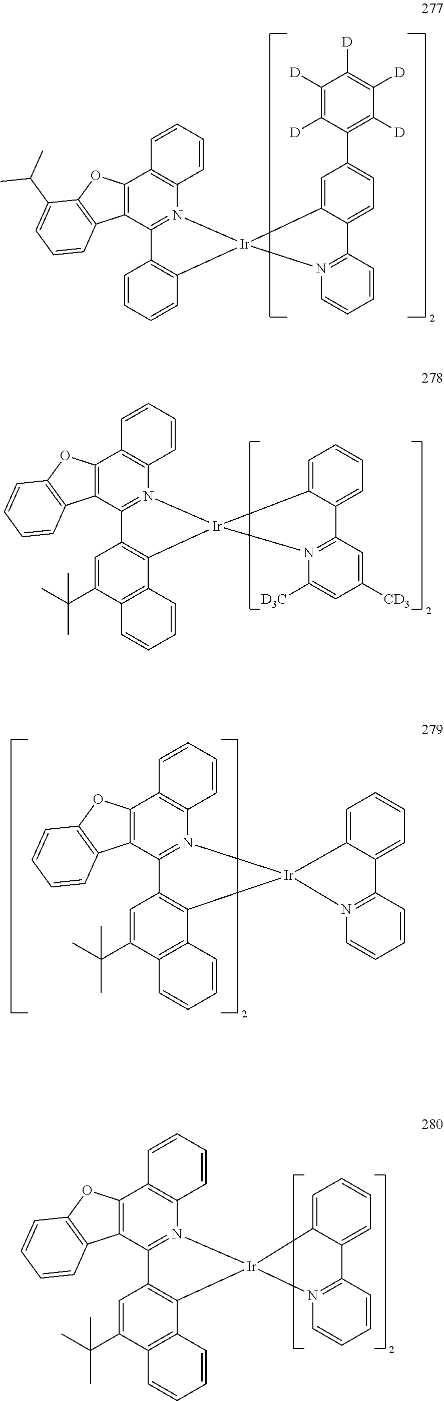

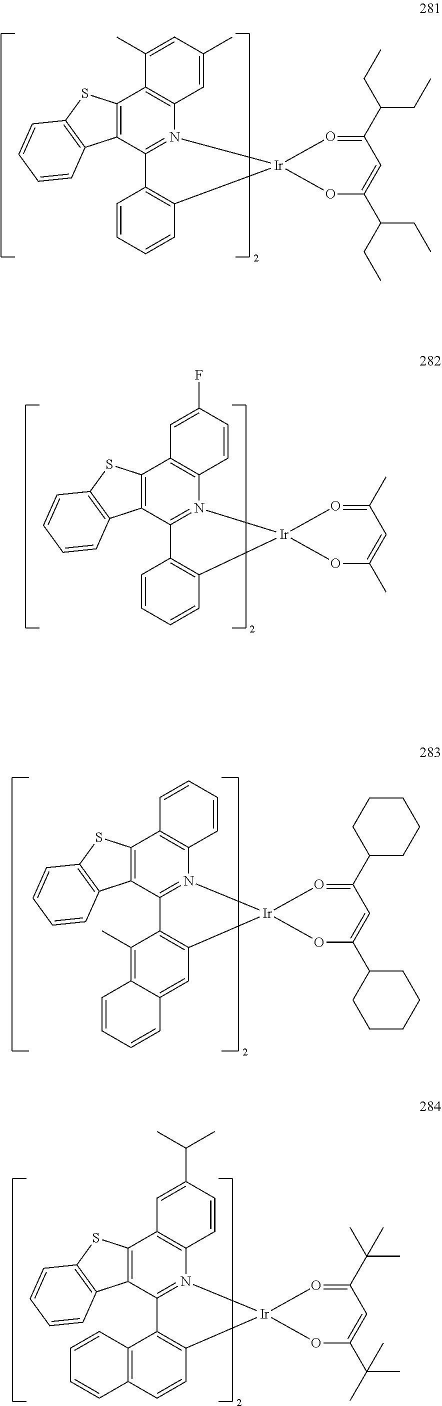

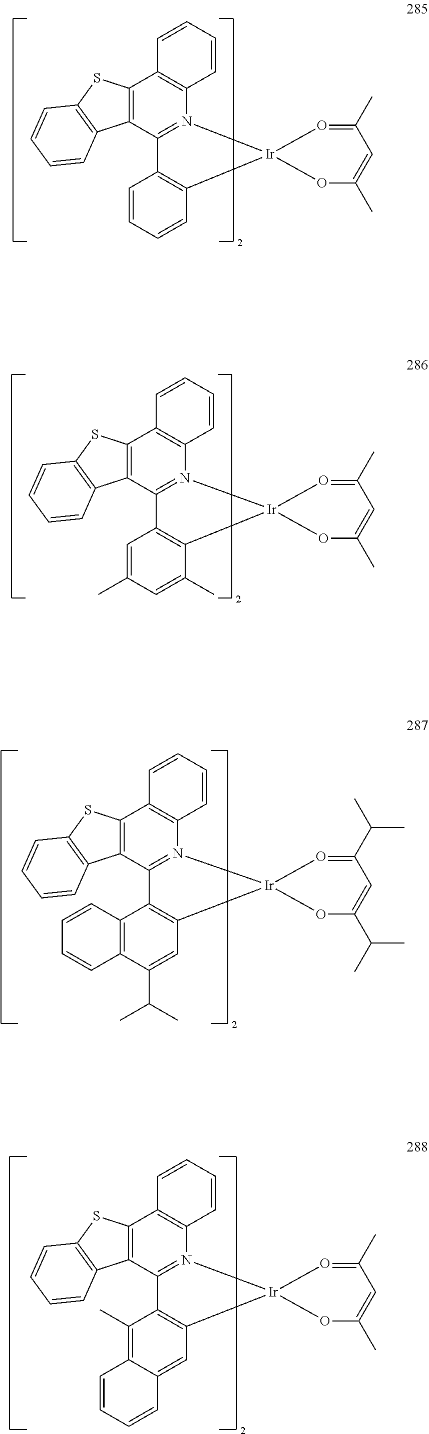

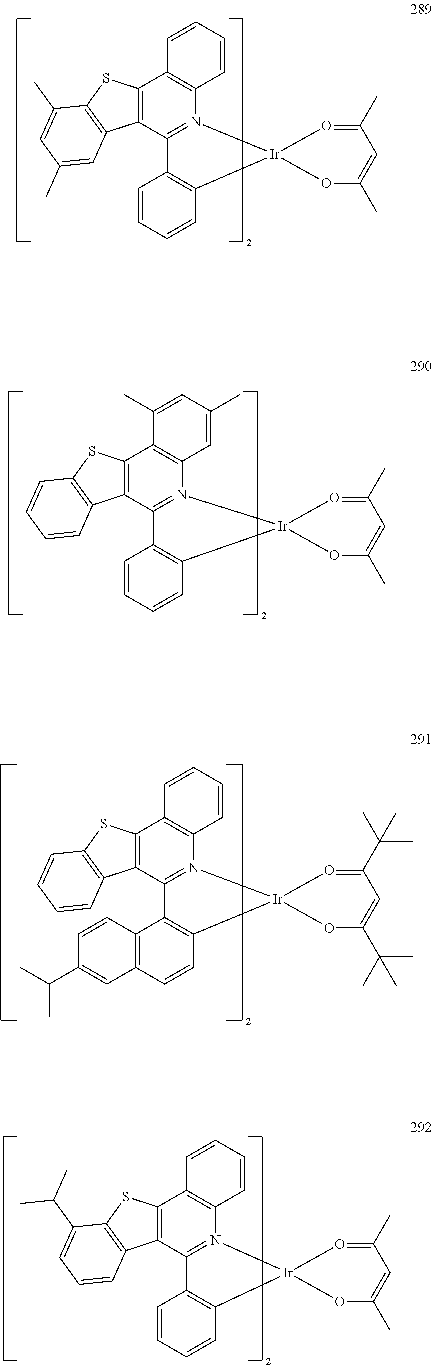

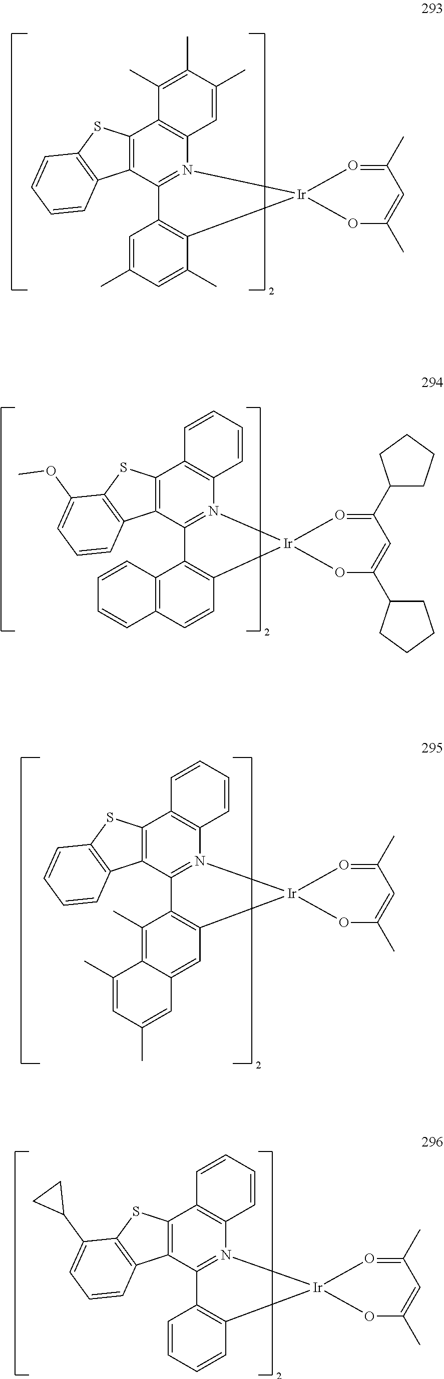

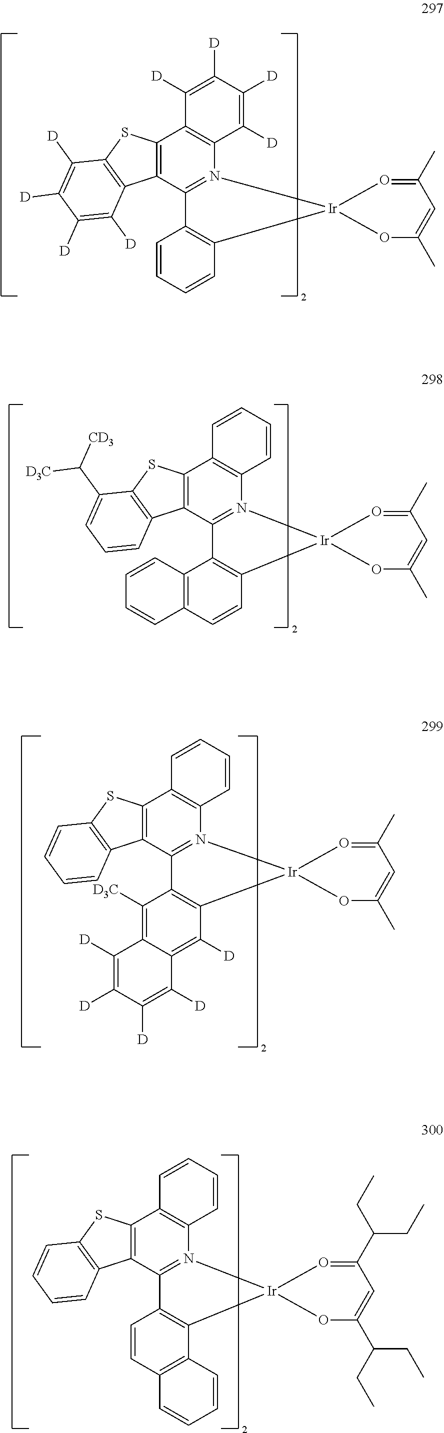

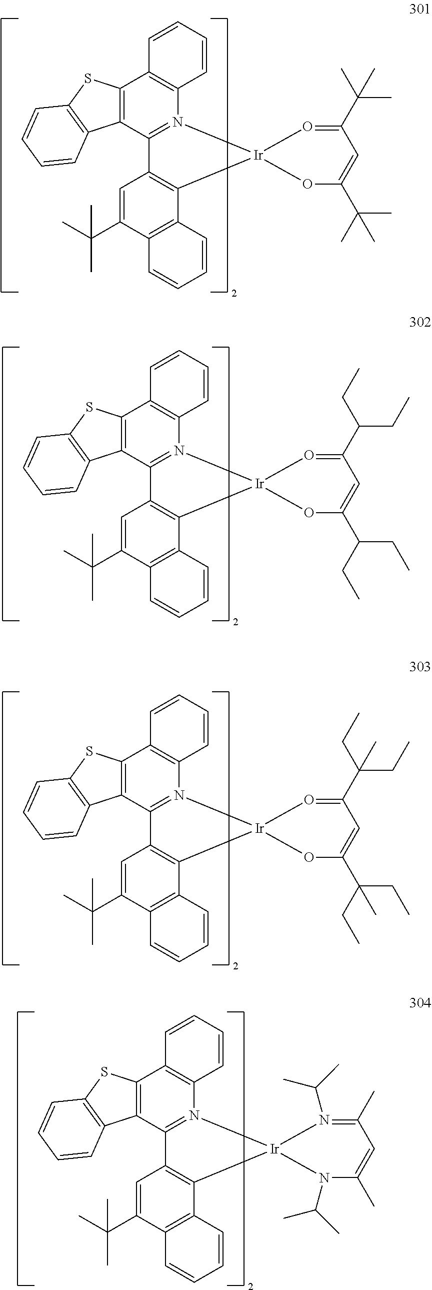

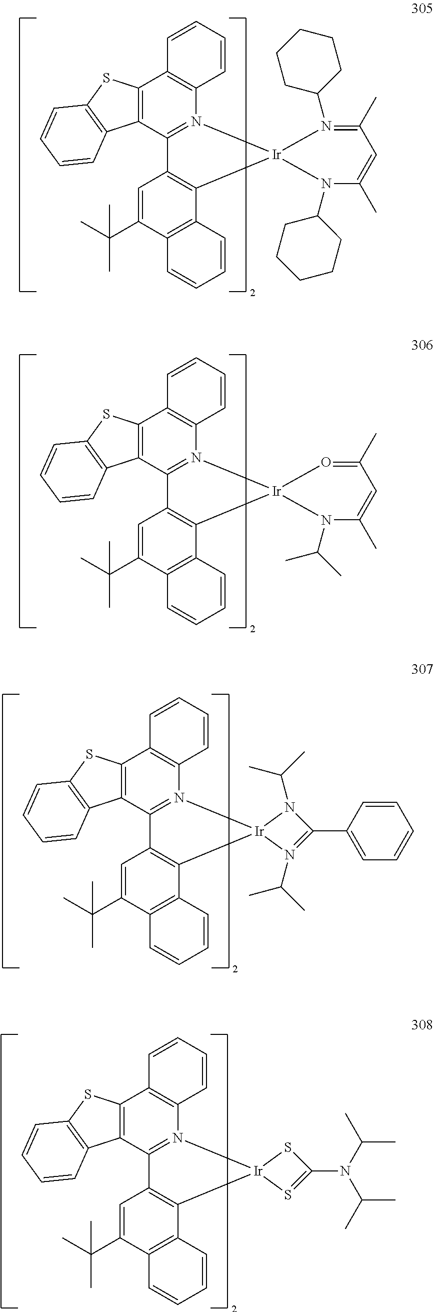

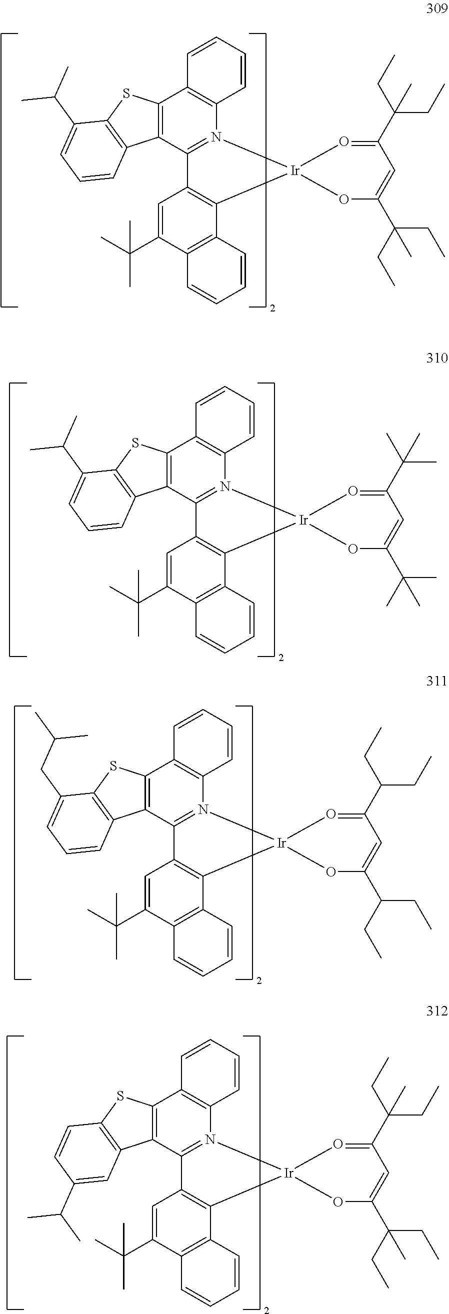

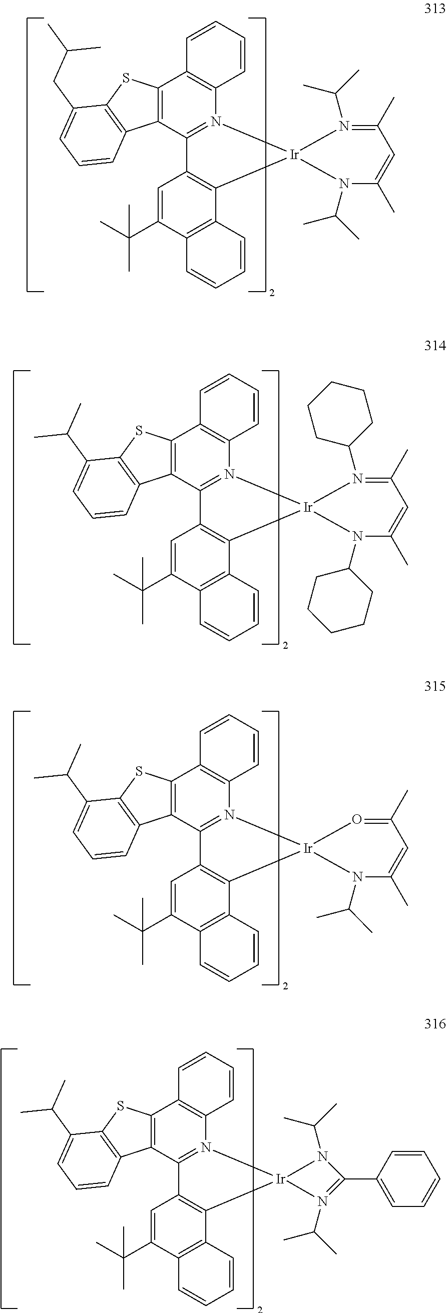

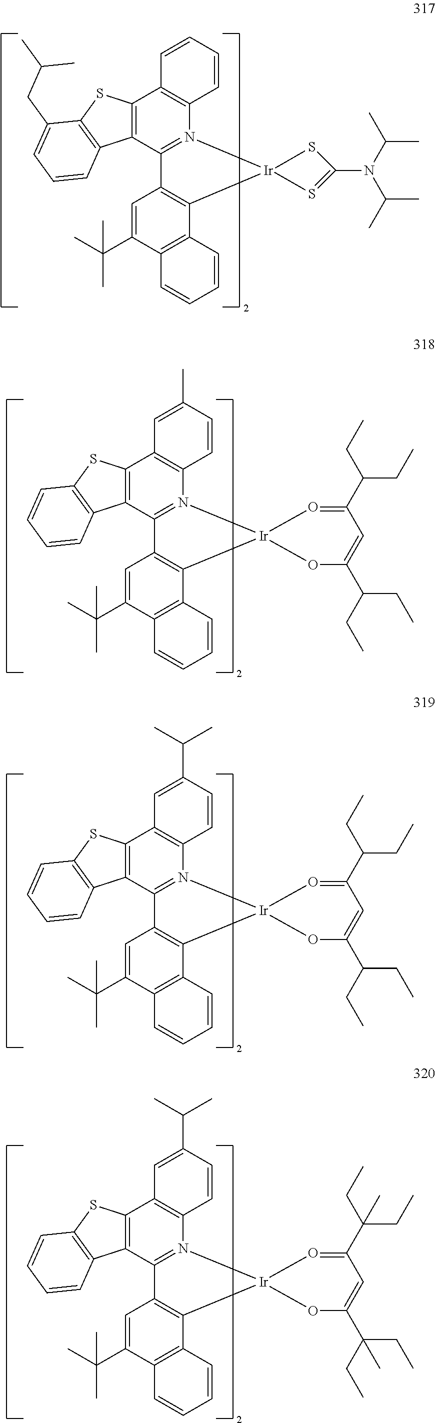

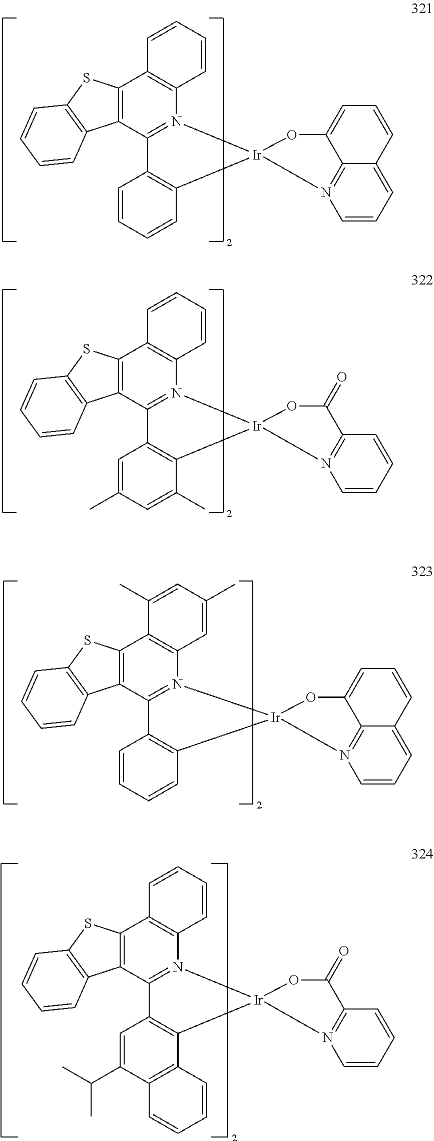

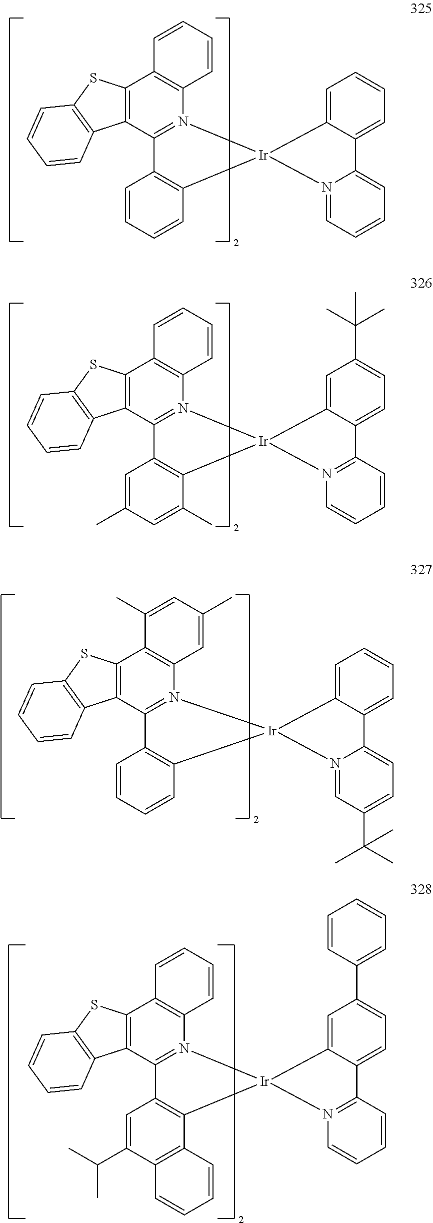

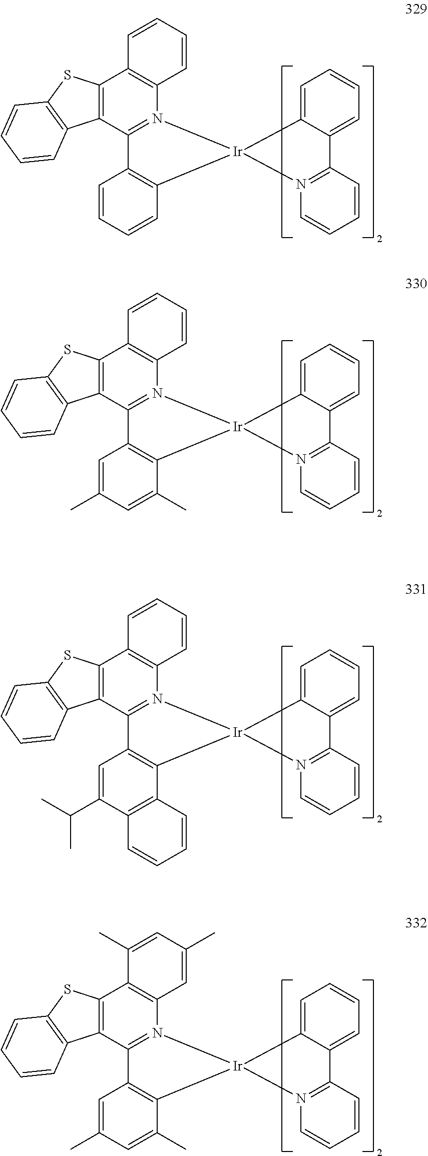

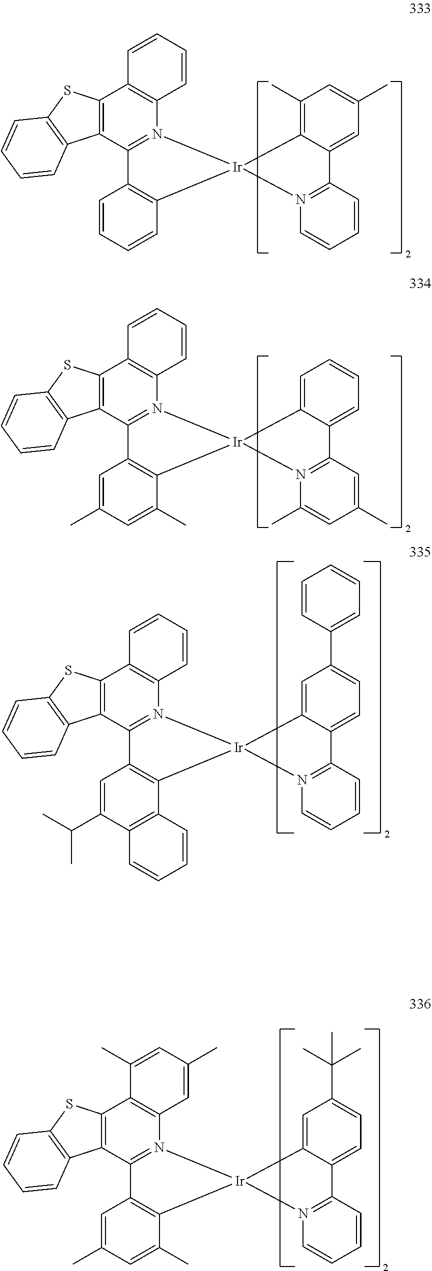

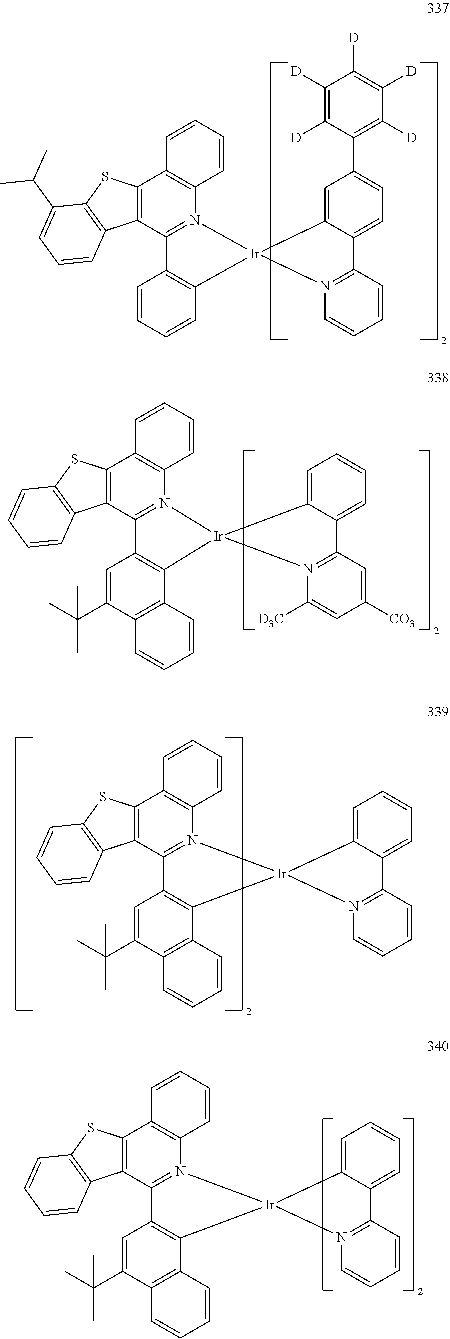

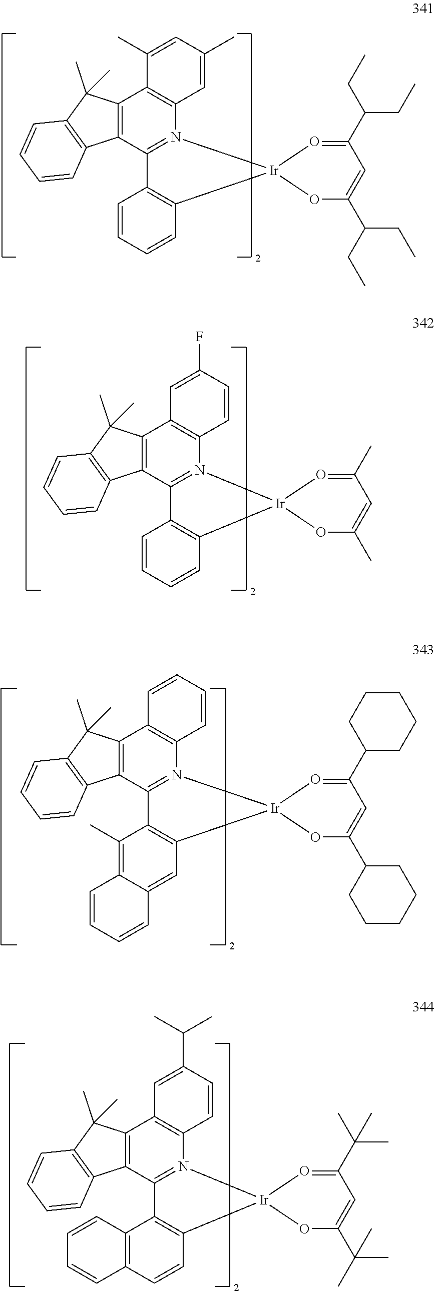

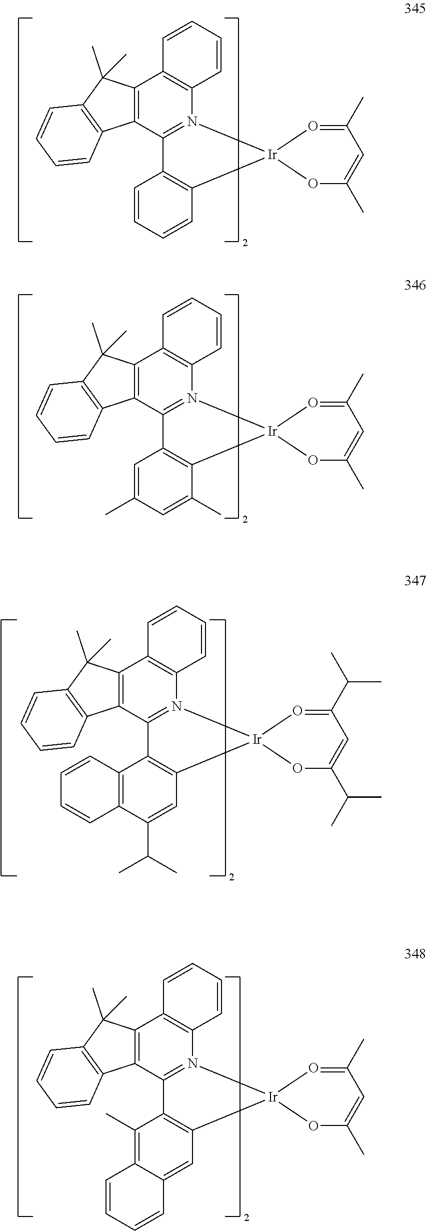

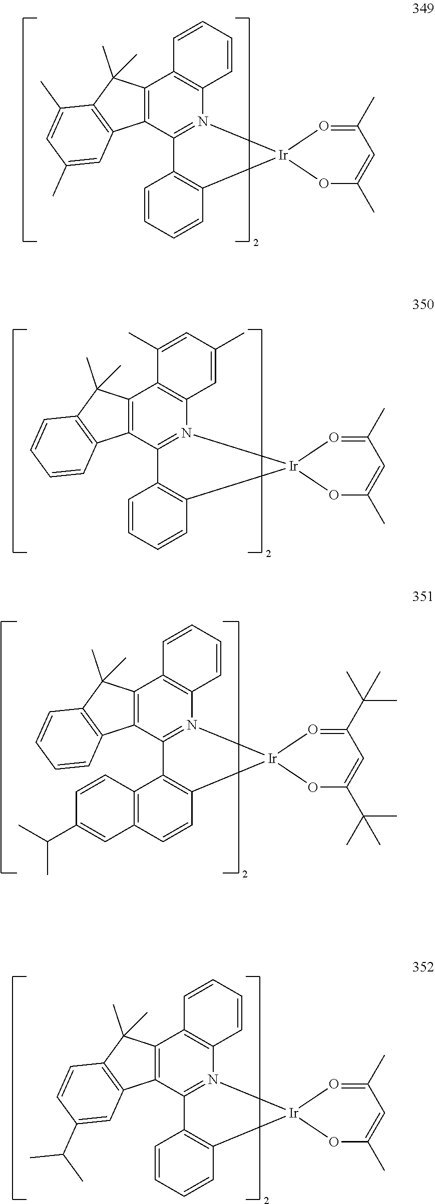

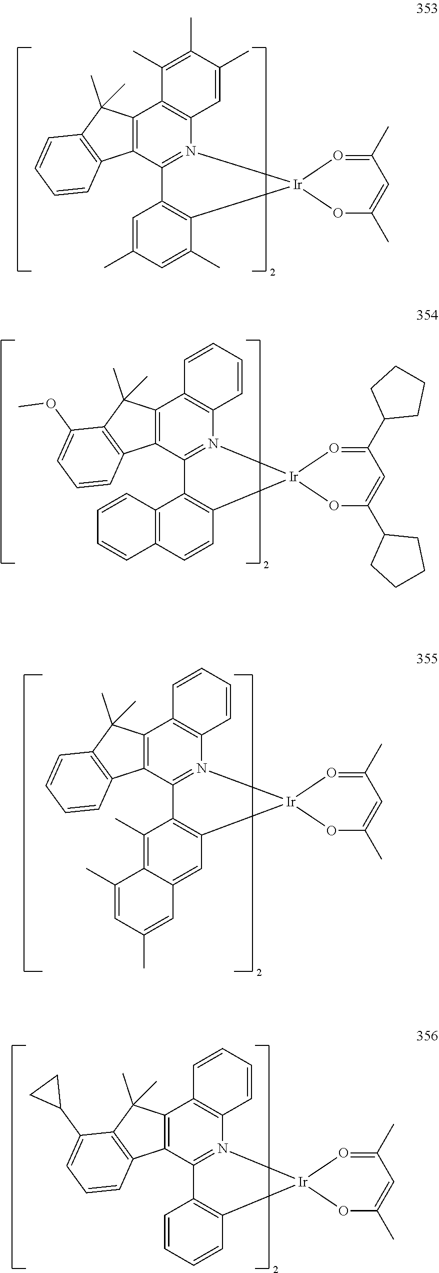

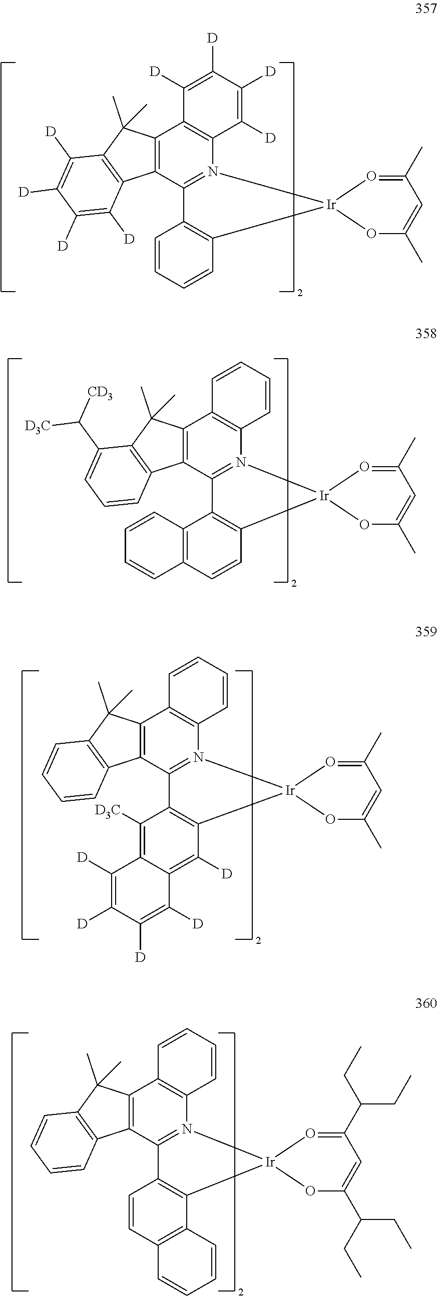

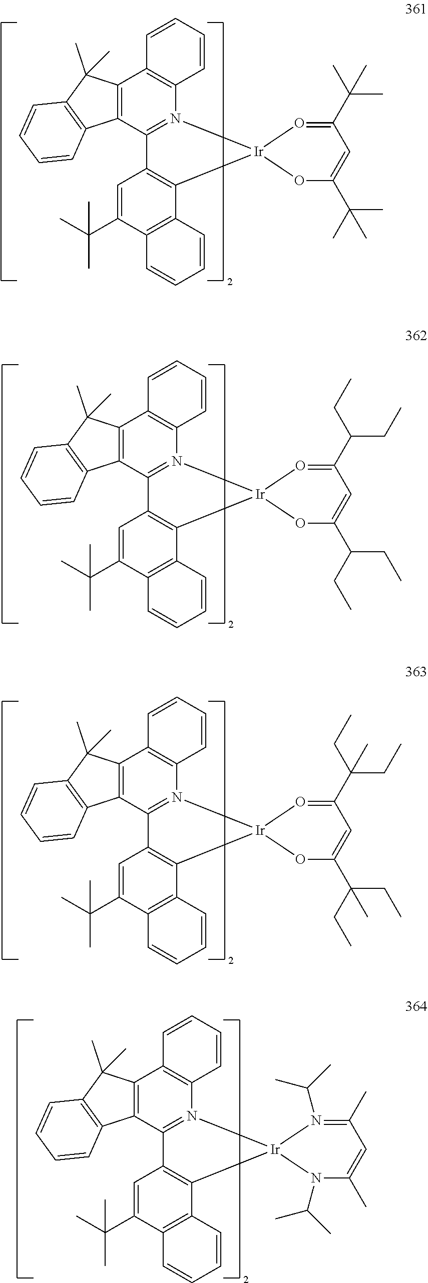

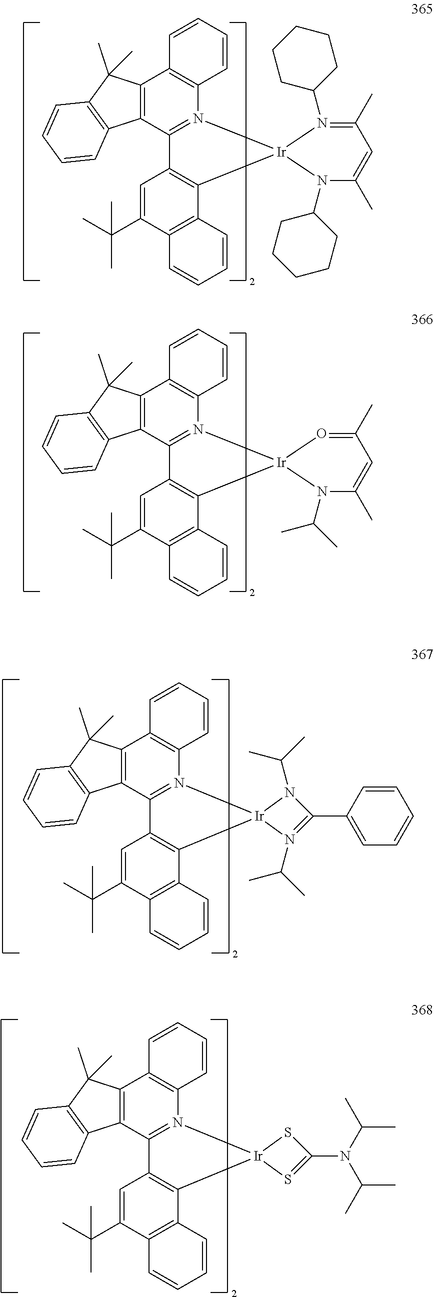

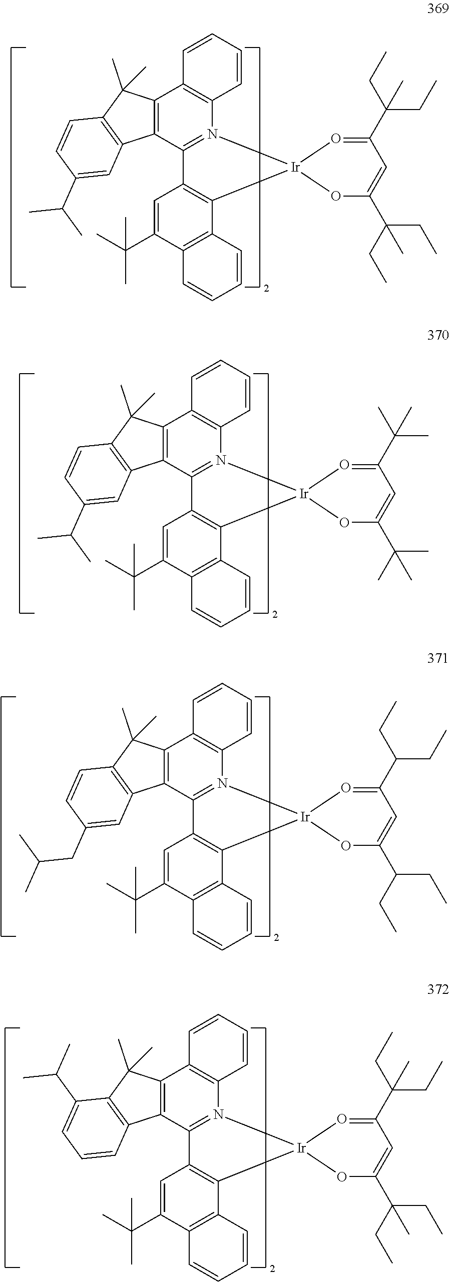

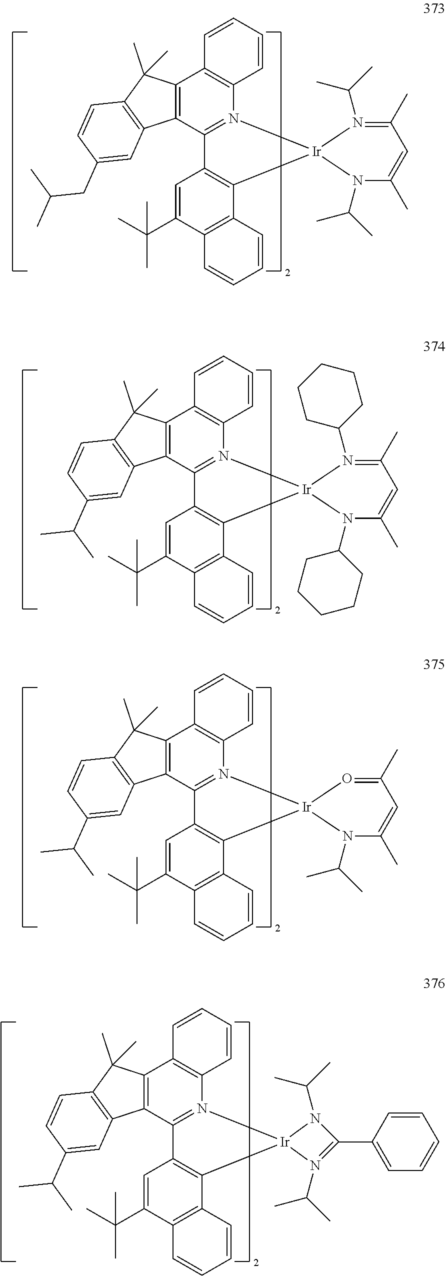

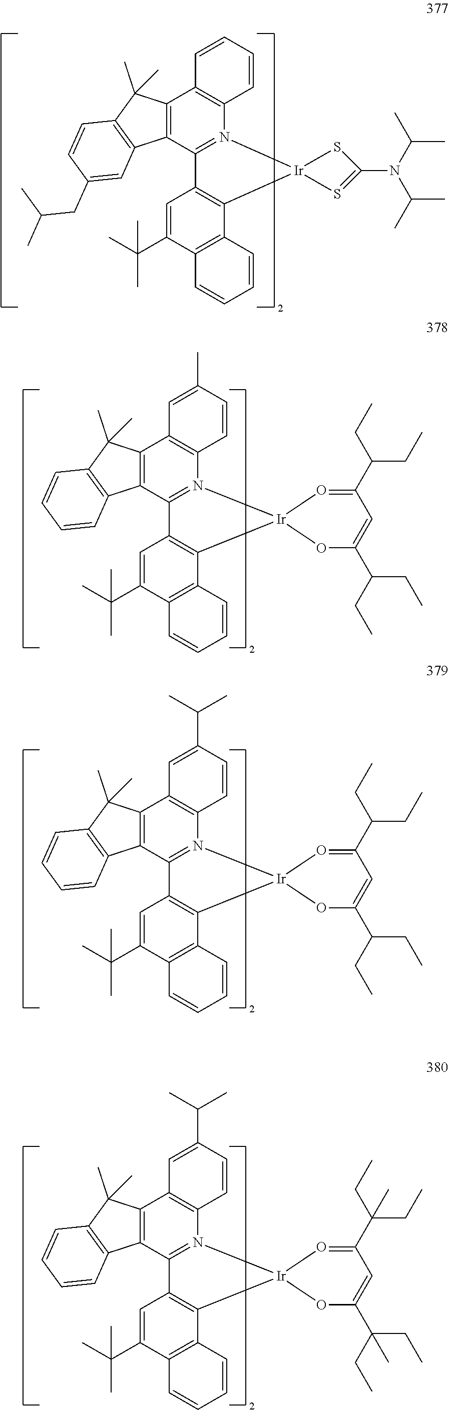

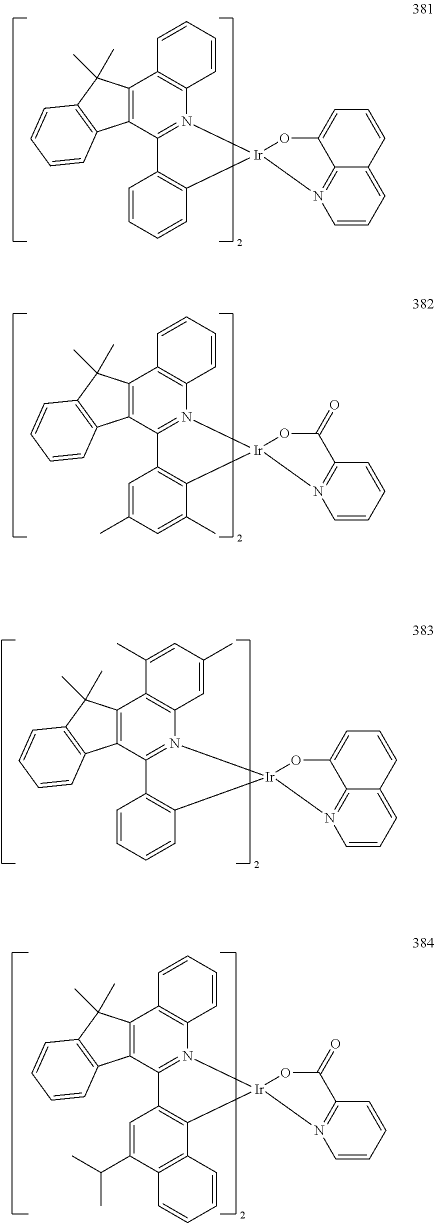

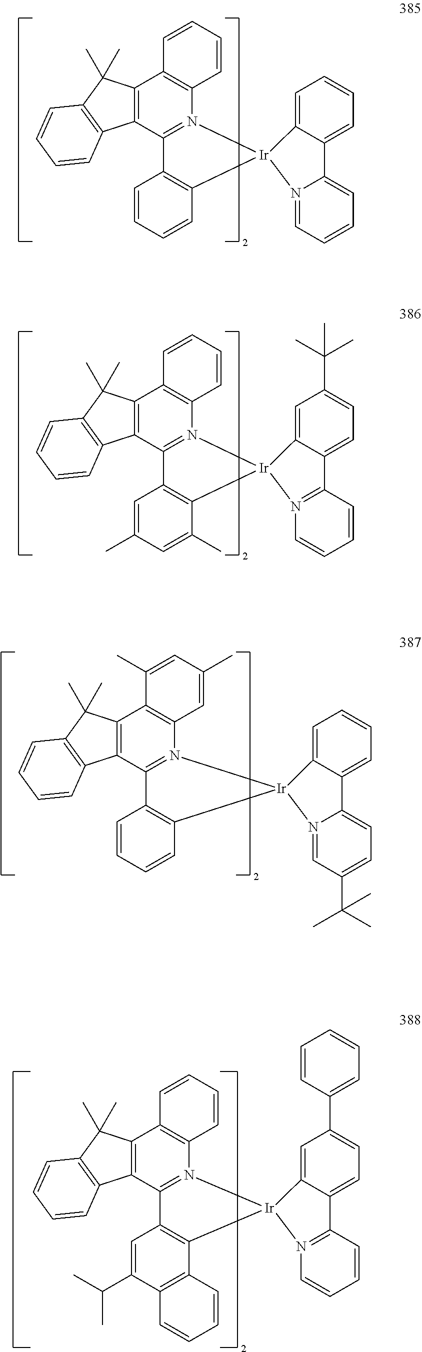

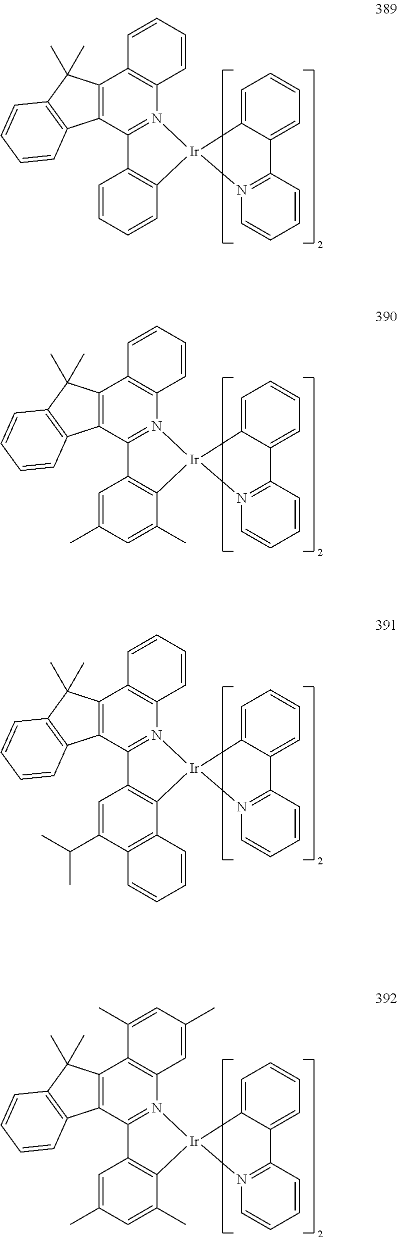

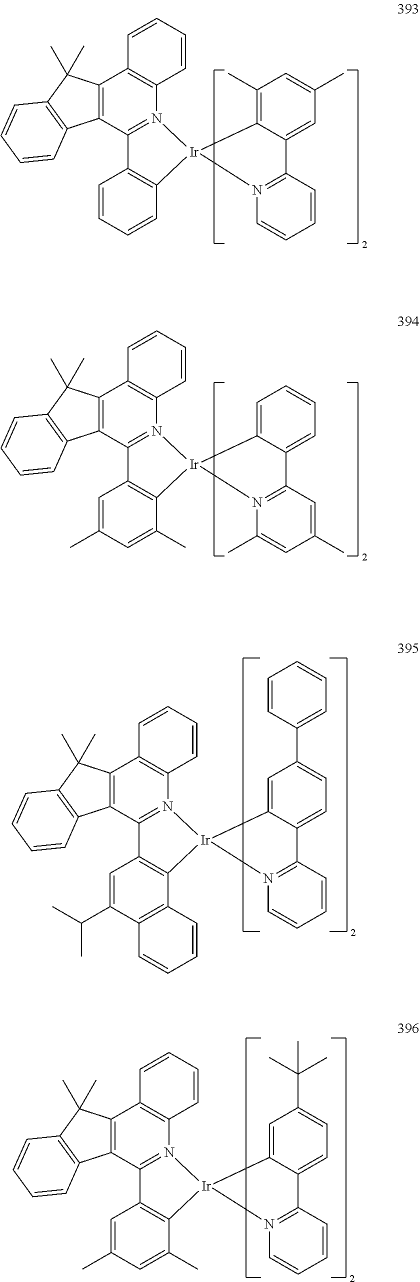

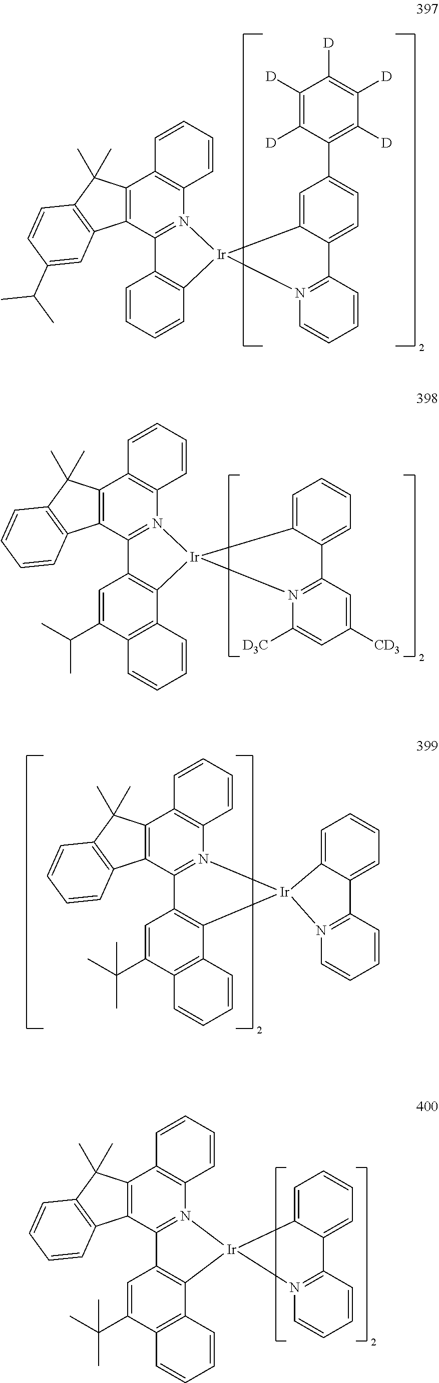

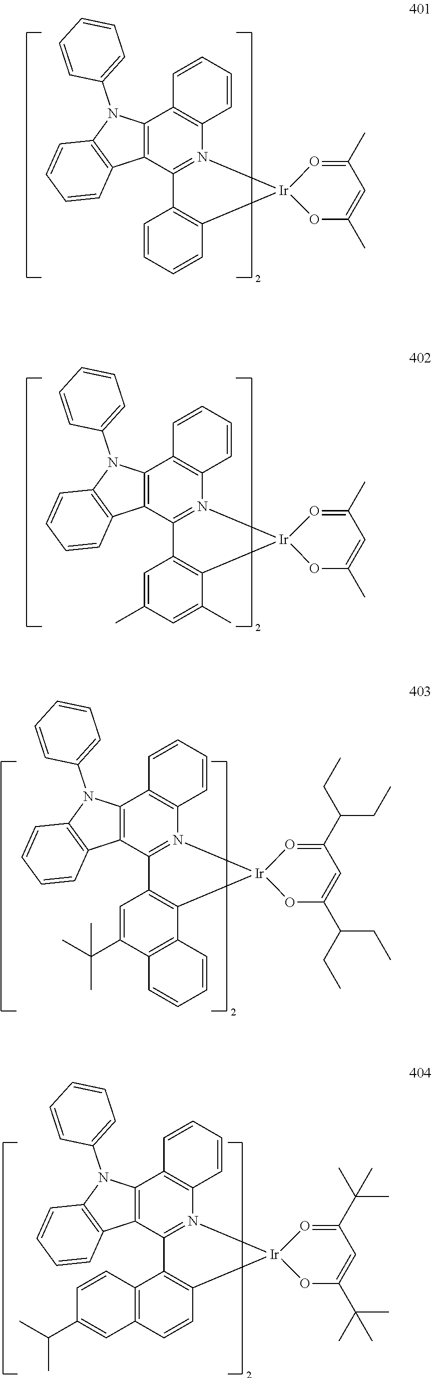

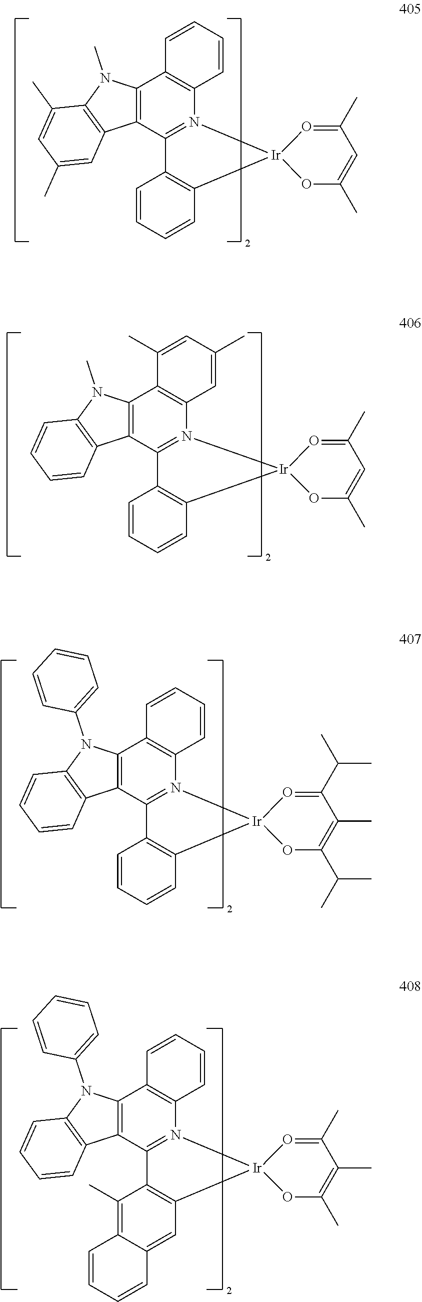

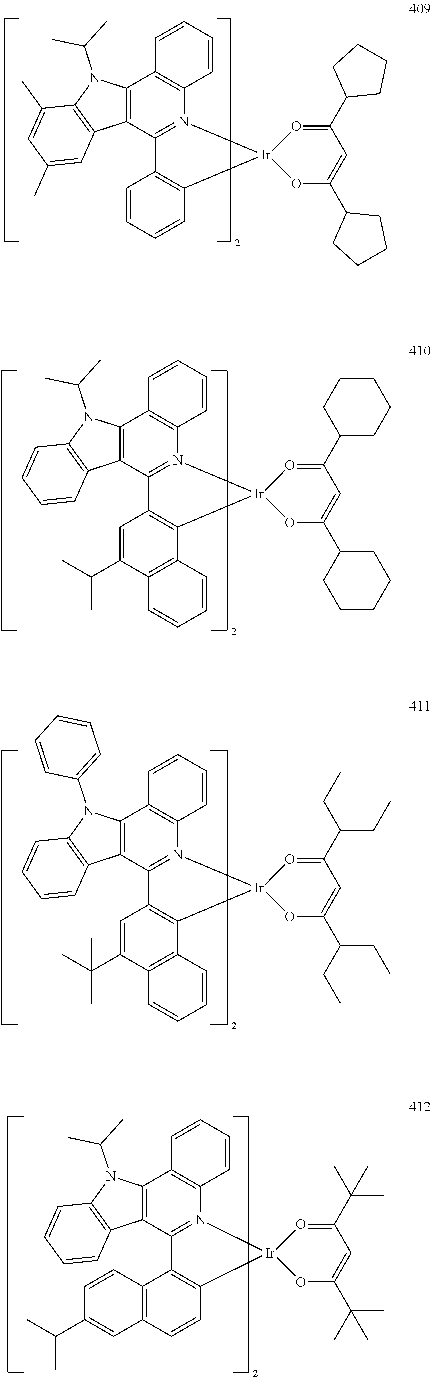

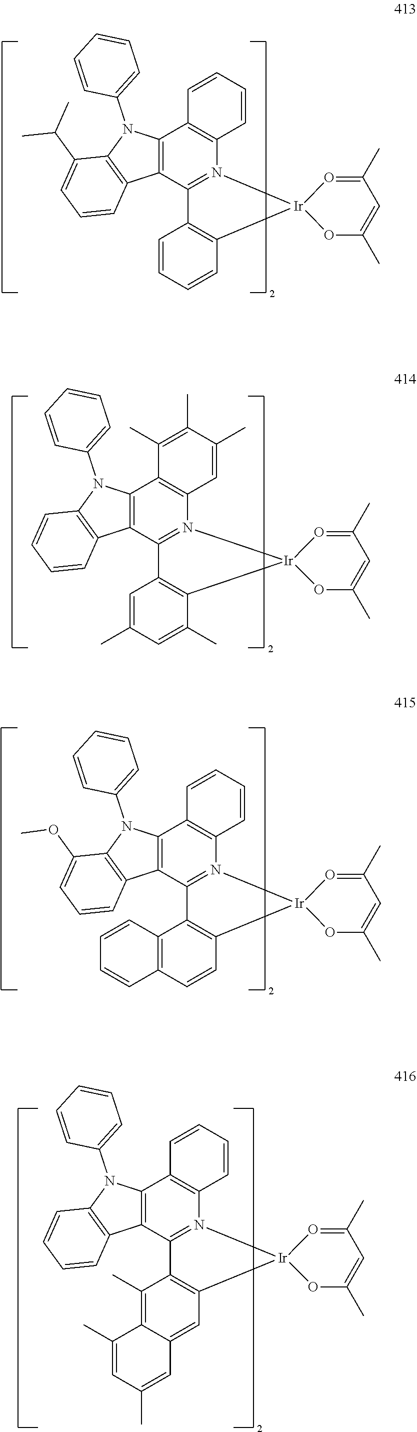

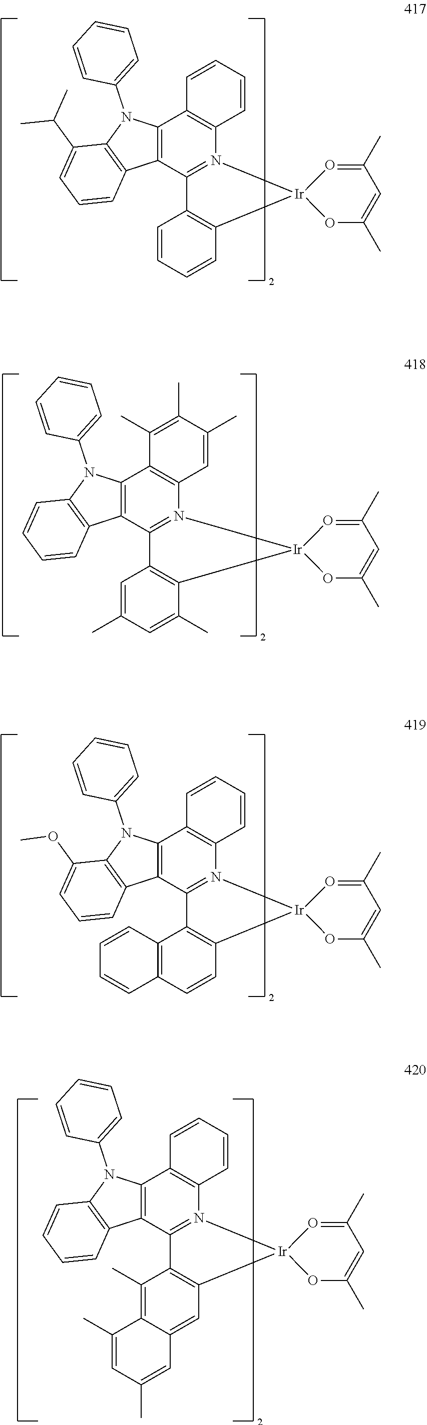

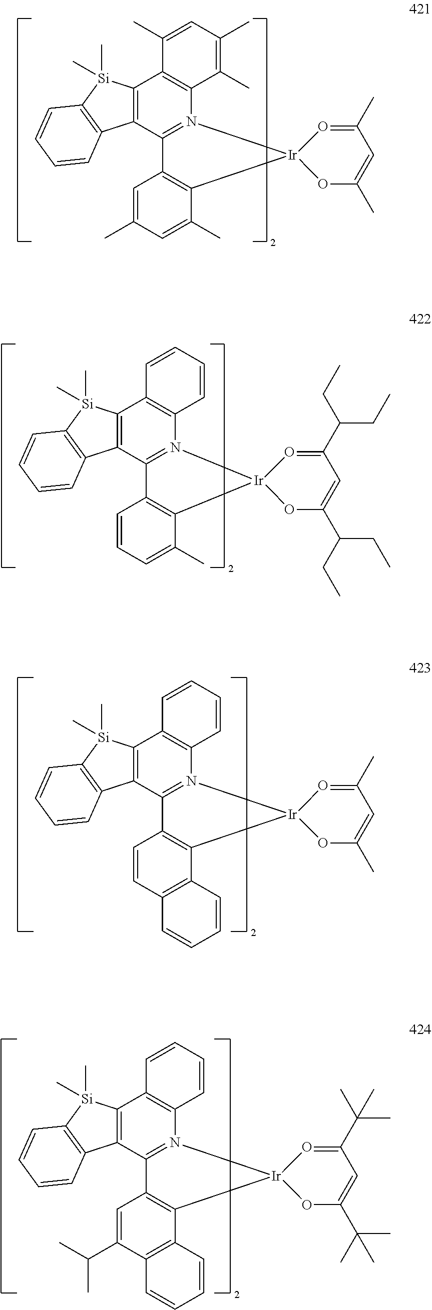

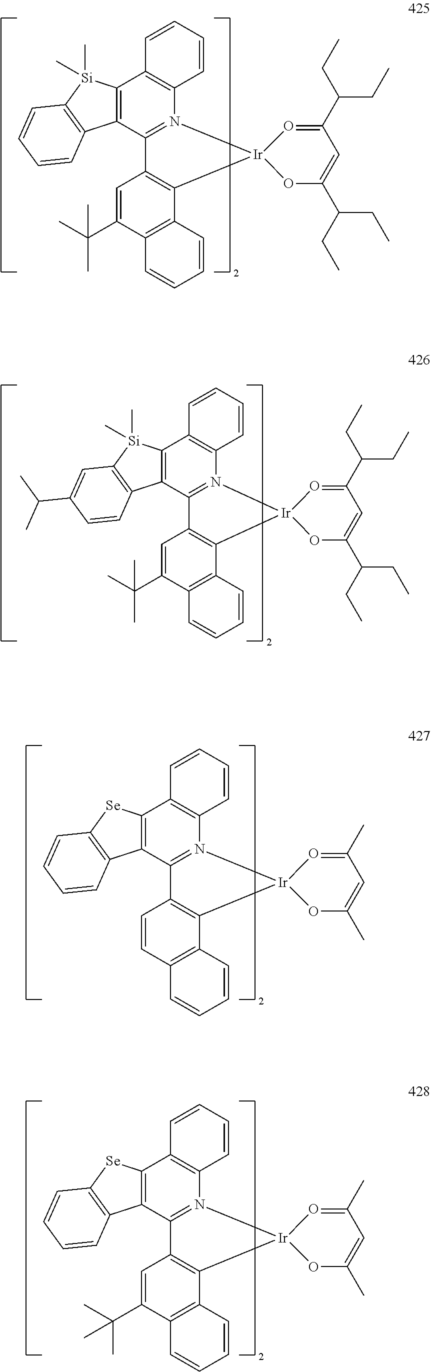

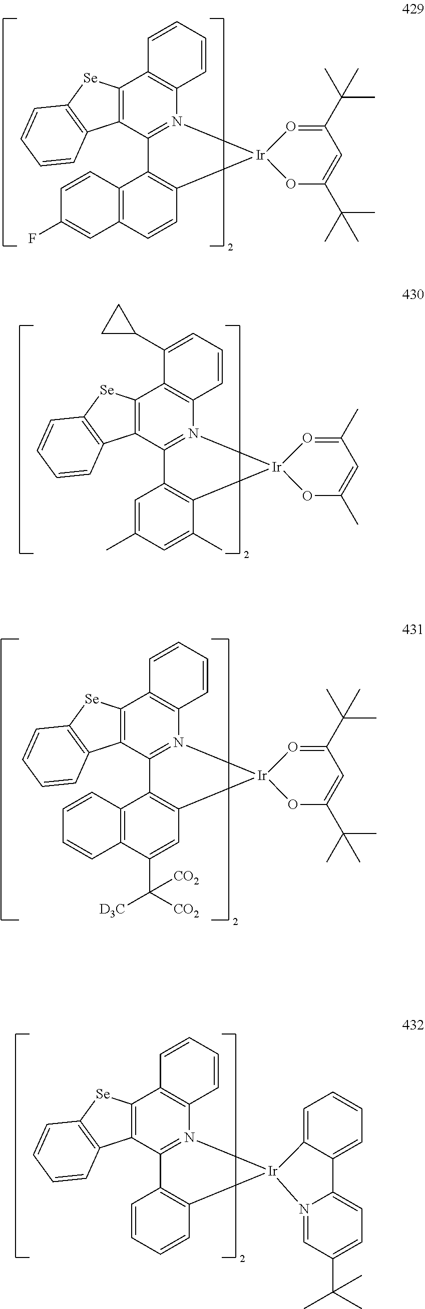

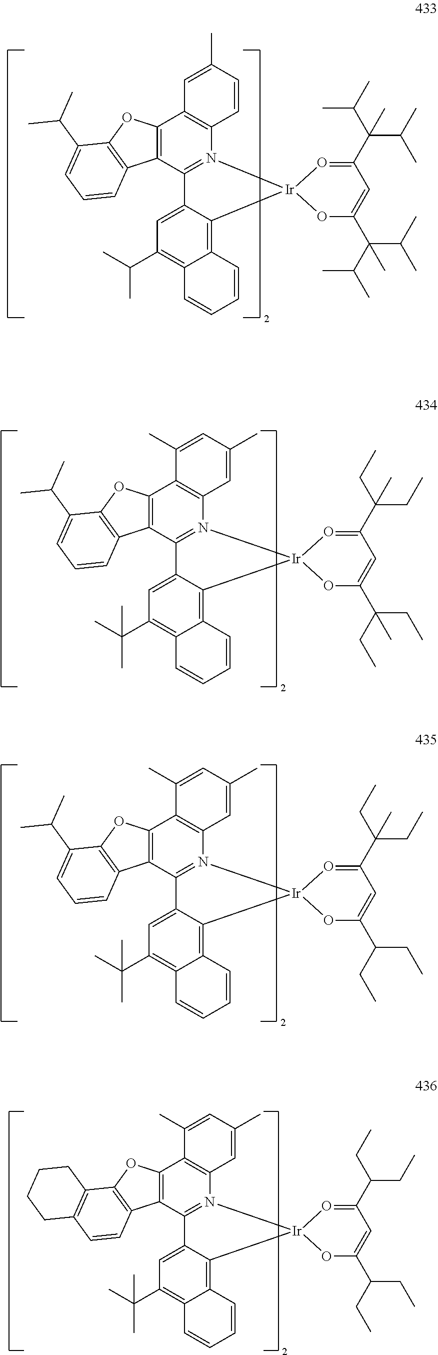

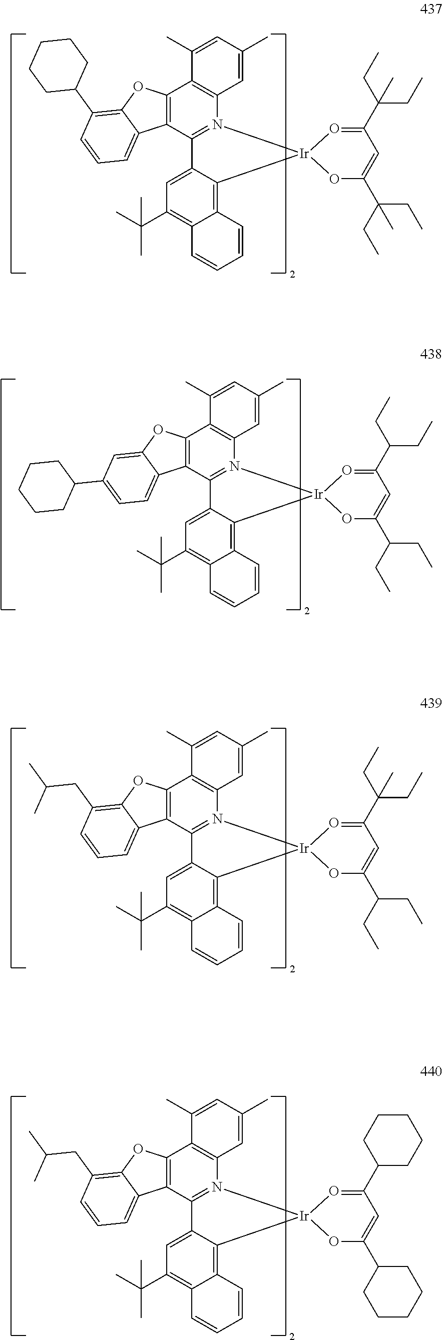

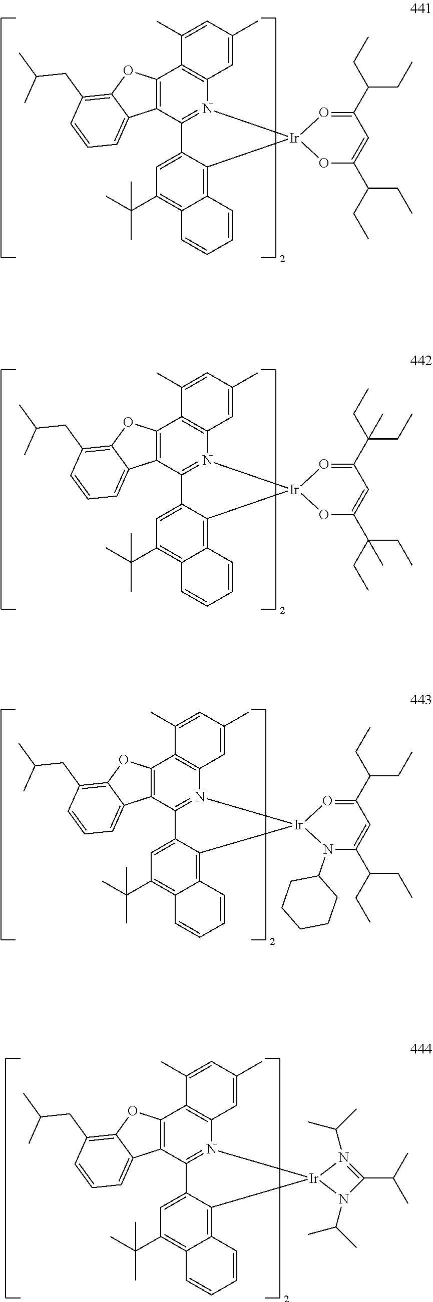

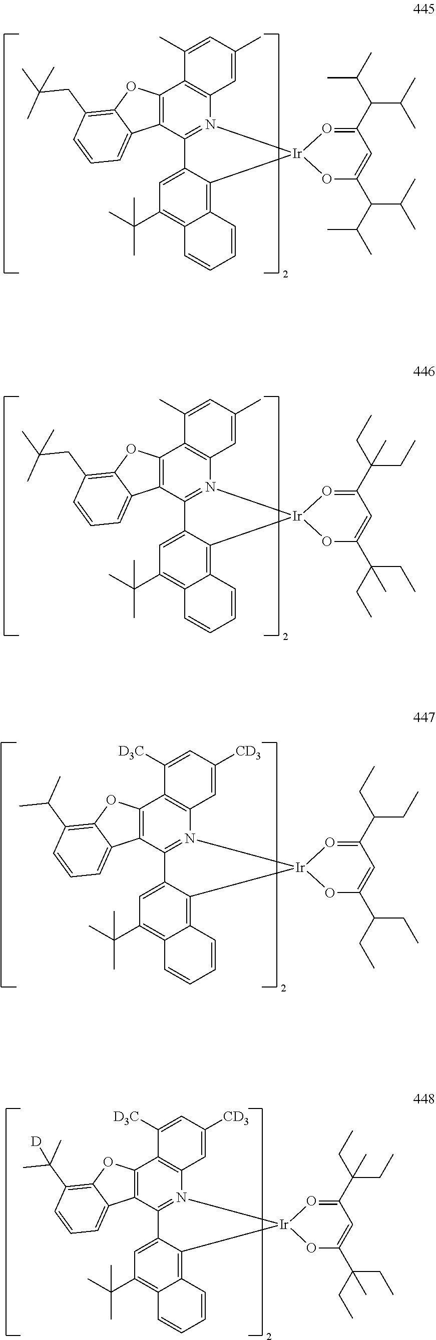

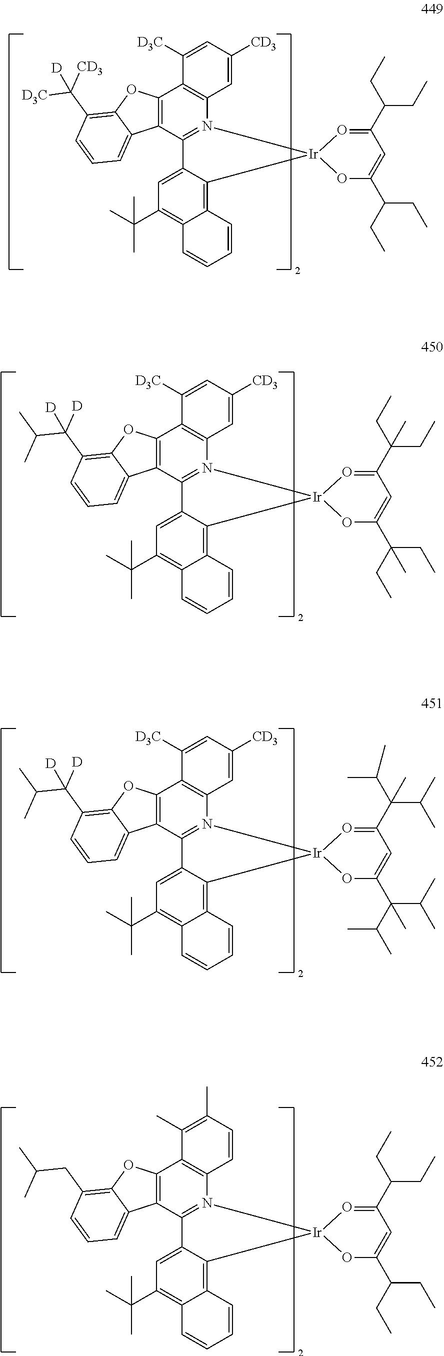

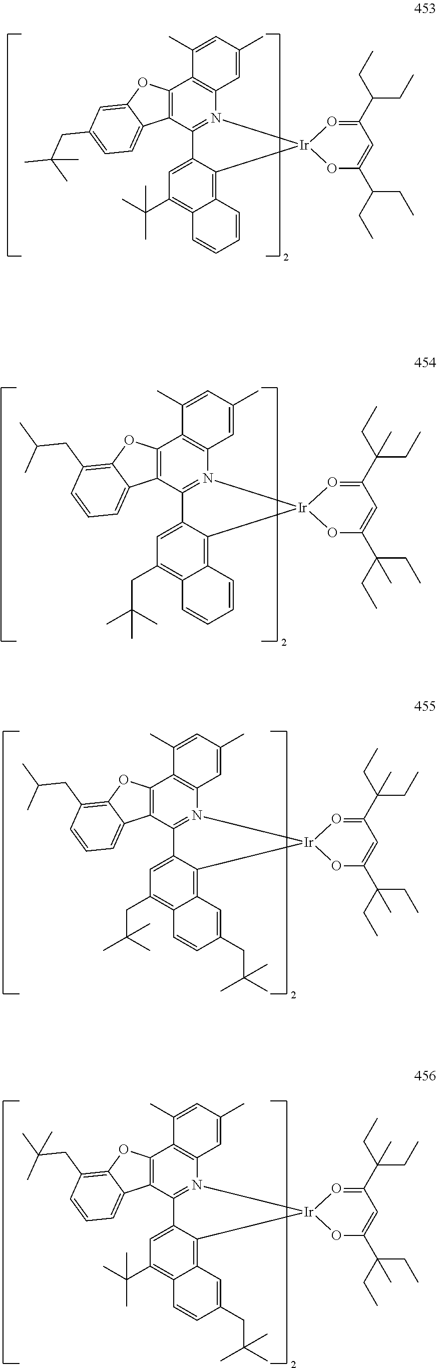

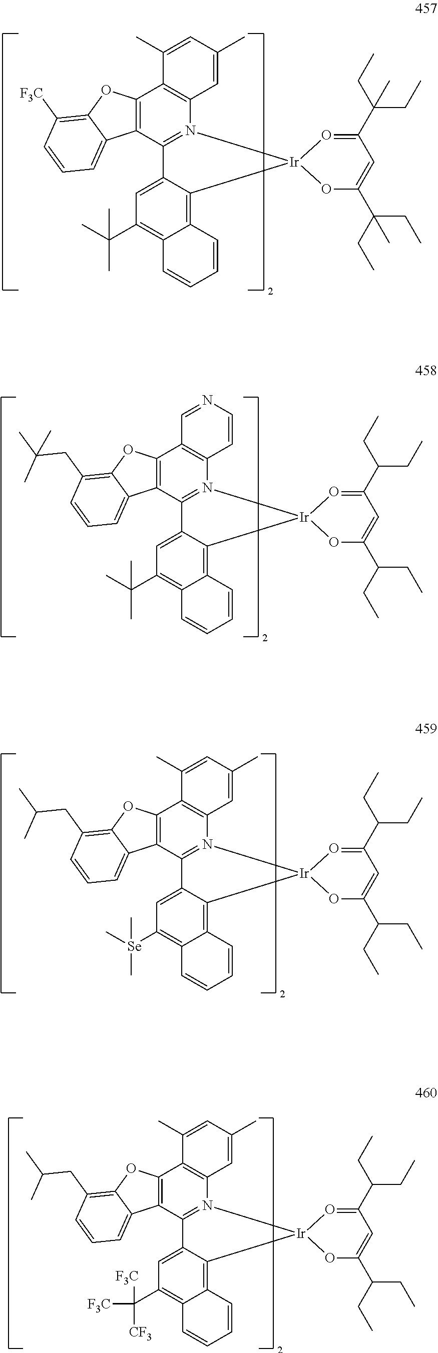

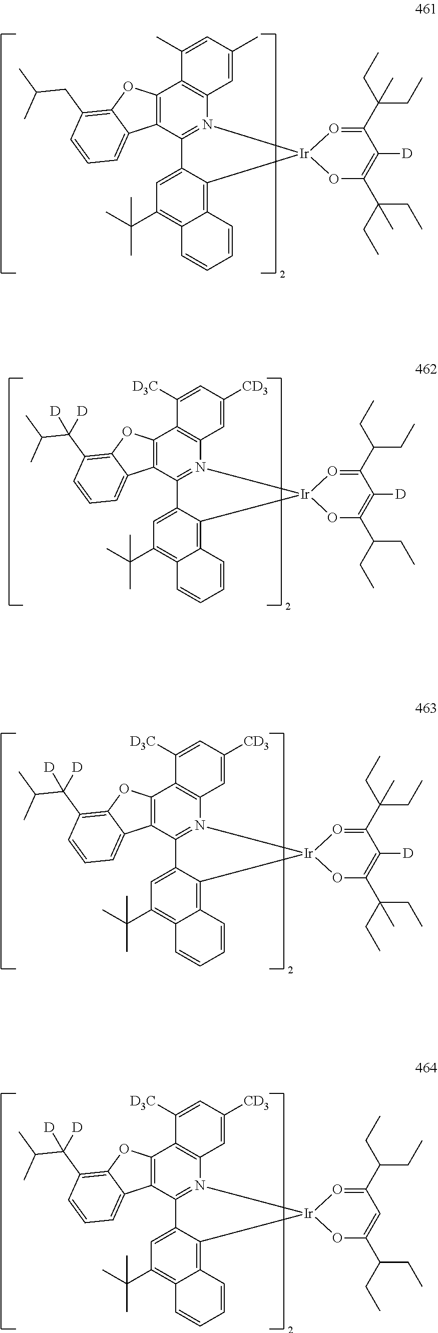

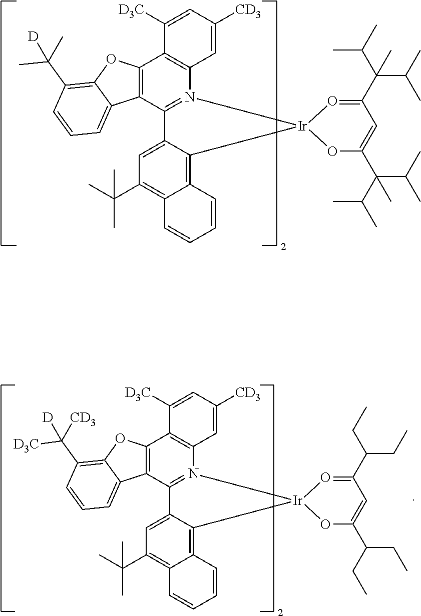

According to one implementation of the present disclosure, the organometallic compound represented by the Chemical Formula 1 of the present disclosure can be used as a red phosphorescent material or a green phosphorescent material.

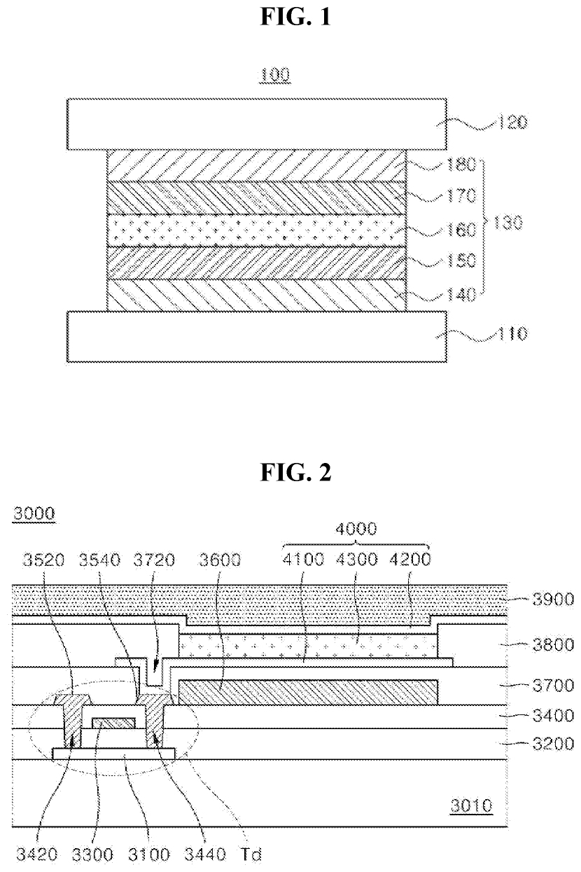

Referring to FIG. 1 according to one implementation of the present disclosure, an organic electroluminescent device can be provided which includes a first electrode 110; a second electrode 120 facing the first electrode 110; and an organic layer 130 disposed between the first electrode 110 and the second electrode 120. The organic layer 130 can include a light-emitting layer 160, and the light-emitting layer 160 can include the organometallic compound represented by the Chemical Formula 1. In addition, in the organic electroluminescent device, the organic layer 130 disposed between the first electrode 110 and the second electrode 120 can be formed by sequentially stacking a hole injection layer 140 (HIL), a hole transport layer 150 (HTL), a light emission layer 160 (EML), an electron transport layer 170 (ETL) and an electron injection layer 180 (EIL) on the first electrode 110. The second electrode 120 can be formed on the electron injection layer 180, and a protective layer can be formed thereon.

The first electrode 110 can act as a positive electrode, and can be made of ITO, IZO, tin-oxide, or zinc-oxide as a conductive material having a relatively large work function value. However, the present disclosure is not limited thereto.

The second electrode 120 can act as a negative electrode, and can include Al, Mg, Ca, or Ag as a conductive material having a relatively small work function value, or an alloy or combination thereof. However, the present disclosure is not limited thereto.

The hole injection layer 140 can be positioned between the first electrode 110 and the hole transport layer 150. A material of the hole injection layer 140 can include a compound selected from a group consisting of MTDATA, CuPc, TCTA, NPB(NPD), HATCN, TDAPB, PEDOT/PSS, N-(biphenyl-4-yl)-9,9-dimethyl-N-(4-(9-phenyl-9H-carbazol-3-yl)phenyl)-9H-luoren-2-amine, NPNPB (N,N′-diphenyl-N,N′-di[4-(N,N-diphenyl-amino)phenyl]benzidine) and preferably can include NPNPB. However, the present disclosure is not limited thereto.

The hole transport layer 150 can be positioned adjacent to the light-emitting layer and between the first electrode 110 and the light-emitting layer 160. A material of the hole transport layer 150 can include a compound selected from a group consisting of TPD, NPD, CBP, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl)-4-amine, etc. However, the present disclosure is not limited thereto.

According to the present disclosure, the light-emitting layer 160 can include a host and the organometallic compound represented by the Chemical Formula 1 as dopant doped into the host in order to improve luminous efficiency of the host and the organic electroluminescent device. The light-emitting layer 160 can be formed by adding about 1 to 30% by weight of the organometallic compound of the Chemical Formula 1 of the present disclosure to the host material, and can emit light of a green or red color.

For example, the light-emitting layer 160 can include the host material including one selected from a group consisting of CBP (carbazole biphenyl), mCP (1,3-bis (carbazol-9-yl), etc. However, the present disclosure is not limited thereto.

The electron transport layer 170 and the electron injection layer 180 can be sequentially stacked between the light-emitting layer 160 and the second electrode 120. A material of the electron transport layer 170 requires high electron mobility such that electrons can be stably supplied to the light-emitting layer under smooth electron transport.

For example, the material of the electron transport layer 170 can include a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzthiazole, ZADN (2-[4-(9,10-Di-naphthalen-2-yl-2-anthracen-2-yl)-phenyl]-1-phenyl-1H-benzoimidazole, and preferably can include ZADN. However, the present disclosure is not limited thereto.

The electron injection layer 180 serves to facilitate electron injection, and a material of the electron injection layer can include a compound selected from a group consisting of Alq3 (tris(8-hydroxyquinolino)aluminum), PBD, TAZ, Spiro-PBD, BAlq, SAlq, etc. However, the present disclosure is not limited thereto. Alternatively, the electron injection layer 180 can be made of a metal compound. The metal compound can include, for example, one or more selected from a group consisting of Liq, LiF, NaF, KF, RbF, CsF, FrF, BeF₂, MgF₂, CaF₂, SrF₂, BaF₂ and RaF₂. However, the present disclosure is not limited thereto.

The organic electroluminescent device according to the present disclosure can be used as an organic light-emitting element of each of an organic light-emitting display device and a lighting device. In one implementation, FIG. 2 is a cross-sectional view schematically illustrating an organic light-emitting display device including the organic electroluminescent device according to some embodiments of the present disclosure as the organic light-emitting element thereof.

As shown in FIG. 2, an organic light-emitting display device 3000 includes a substrate 3010, an organic electroluminescent element 4000, and an encapsulation film 3900 covering the organic electroluminescent device 4000. A driving thin-film transistor Td as a driving element, and the organic electroluminescent element 4000 connected to the driving thin-film transistor Td are positioned on the substrate 3010.

Optionally, a gate line and a data line that intersect each other to define a pixel area, a power line extending parallel to and spaced from one of the gate line and the data line, a switching thin film transistor connected to the gate line and the data line, and a storage capacitor connected to one electrode of the thin film transistor and the power line are further formed on the substrate 3010.

The driving thin-film transistor Td is connected to the switching thin film transistor, and includes a semiconductor layer 3100, a gate electrode 3300, a source electrode 3520, and a drain electrode 3540.

The semiconductor layer 3100 can be formed on the substrate 3010 and can be made of an oxide semiconductor material or polycrystalline silicon. When the semiconductor layer 3100 is made of an oxide semiconductor material, a light-shielding pattern can be formed under the semiconductor layer 3100. The light-shielding pattern prevents light from being incident into the semiconductor layer 3100 to prevent the semiconductor layer 3010 from being deteriorated due to the light. Alternatively, the semiconductor layer 3100 can be made of polycrystalline silicon. In this case, both edges of the semiconductor layer 3100 can be doped with impurities.

The gate insulating layer 3200 made of an insulating material is formed over an entirety of a surface of the substrate 3010 and on the semiconductor layer 3100. The gate insulating layer 3200 can be made of an inorganic insulating material such as silicon oxide or silicon nitride.

The gate electrode 3300 made of a conductive material such as a metal is formed on the gate insulating layer 3200 and corresponds to a center of the semiconductor layer 3100. The gate electrode 3300 is connected to the switching thin film transistor.

The interlayer insulating layer 3400 made of an insulating material is formed over the entirety of the surface of the substrate 3010 and on the gate electrode 3300. The interlayer insulating layer 3400 can be made of an inorganic insulating material such as silicon oxide or silicon nitride, or an organic insulating material such as benzocyclobutene or photo-acryl.

The interlayer insulating layer 3400 has first and second semiconductor layer contact holes 3420 and 3440 defined therein respectively exposing both opposing sides of the semiconductor layer 3100. The first and second semiconductor layer contact holes 3420 and 3440 are respectively positioned on both opposing sides of the gate electrode 3300 and are spaced apart from the gate electrode 3300.

The source electrode 3520 and the drain electrode 3540 made of a conductive material such as metal are formed on the interlayer insulating layer 3400. The source electrode 3520 and the drain electrode 3540 are positioned around the gate electrode 3300, and are spaced apart from each other, and respectively contact both opposing sides of the semiconductor layer 3100 via the first and second semiconductor layer contact holes 3420 and 3440, respectively. The source electrode 3520 is connected to a power line.

The semiconductor layer 3100, the gate electrode 3300, the source electrode 3520, and the drain electrode 3540 constitute the driving thin-film transistor Td. The driving thin-film transistor Td has a coplanar structure in which the gate electrode 3300, the source electrode 3520, and the drain electrode 3540 are positioned on top of the semiconductor layer 3100.

Alternatively, the driving thin-film transistor Td can have an inverted staggered structure in which the gate electrode is disposed under the semiconductor layer while the source electrode and the drain electrode are disposed above the semiconductor layer. In this case, the semiconductor layer can be made of amorphous silicon. In one example, the switching thin-film transistor can have substantially the same structure as that of the driving thin-film transistor (Td).

In one example, the organic light-emitting display device 3000 can include a color filter 3600 absorbing the light generated from the electroluminescent element (light-emitting diode) 4000. For example, the color filter 3600 can absorb red (R), green (G), blue (B), and white (W) light. In this case, red, green, and blue color filter patterns that absorb light can be formed separately in different pixel areas. Each of these color filter patterns can be disposed to overlap each organic layer 4300 of the organic electroluminescent element 4000 to emit light of a wavelength band corresponding to each color filter. Adopting the color filter 3600 can allow the organic light-emitting display device 3000 to realize full-color.

For example, when the organic light-emitting display device 3000 is of a bottom emission type, the color filter 3600 absorbing light can be positioned on a portion of the interlayer insulating layer 3400 corresponding to the organic electroluminescent element 4000. In an optional embodiment, when the organic light-emitting display device 3000 is of a top emission type, the color filter can be positioned on top of the organic electroluminescent element 4000, that is, on top of a second electrode 4200. For example, the color filter 3600 can be formed to have a thickness of 2 to 5 μm.

In one example, a protective layer 3700 having a drain contact hole 3720 defined therein exposing the drain electrode 3540 of the driving thin-film transistor Td is formed to cover the driving thin-film transistor Td.

On the protective layer 3700, each first electrode 4100 connected to the drain electrode 3540 of the driving thin-film transistor Td via the drain contact hole 3720 is formed individually in each pixel area.

The first electrode 4100 can act as a positive electrode (anode), and can be made of a conductive material having a relatively large work function value. For example, the first electrode 410 can be made of a transparent conductive material such as ITO, IZO or ZnO.

In one example, when the organic light-emitting display device 3000 is of a top-emission type, a reflective electrode or a reflective layer can be further formed under the first electrode 4100. For example, the reflective electrode or the reflective layer can be made of one of aluminum (Al), silver (Ag), nickel (Ni), and an aluminum-palladium-copper (APC) alloy.

A bank layer 3800 covering an edge of the first electrode 4100 is formed on the protective layer 3700. The bank layer 3800 exposes a center of the first electrode 4100 corresponding to the pixel area.

An organic layer 4300 is formed on the first electrode 4100. If necessary, the organic electroluminescent element 4000 can have a tandem structure.

The second electrode 4200 is formed on the substrate 3010 on which the organic layer 4300 has been formed. The second electrode 4200 is disposed over the entirety of the surface of the display area and is made of a conductive material having a relatively small work function value and can be used as a cathode. For example, the second electrode 4200 can be made of one of aluminum (Al), magnesium (Mg), and an aluminum-magnesium alloy (AlMg).

The first electrode 4100, the organic layer 4300, and the second electrode 4200 constitute the organic electroluminescent element 4000.

An encapsulation film 3900 is formed on the second electrode 4200 to prevent external moisture from penetrating into the organic electroluminescent element 4000. Optionally, the encapsulation film 3900 can have a triple-layer structure in which a first inorganic layer, an organic layer, and an inorganic layer are sequentially stacked. However, the present disclosure is not limited thereto.

The organic electroluminescent device according to the present disclosure can act as a white light emitting diode having a tandem structure. The organic electroluminescent element having the tandem structure according to one implementation of the present disclosure can have a structure in which at least two unit light emitting elements are connected to each other via a charge generation layer (CGL). The organic electroluminescent element includes first and second electrodes facing each other and disposed on a substrate, and two or more light-emitting stacks vertically arranged between the first and second electrodes to emit light beams in specific wavelength bands, respectively. In this regard, the light-emitting layer can contain the organometallic compound represented by the Chemical Formula 1 according to the present disclosure as the dopant thereof. Adjacent ones of the plurality of light-emitting stacks in the tandem structure can be connected to each other via the charge generation layer (CGL) including an N-type charge generation layer and a P-type charge generation layer.

FIG. 4 is a schematic cross-sectional view of an organic electroluminescent element in a tandem structure having two light-emitting stacks according to one implementation of the present disclosure. As shown in FIG. 4, the organic electroluminescent element 100 according to the present disclosure can include a first electrode 110 and a second electrode 120 facing each other, and an organic layer 230 positioned between the first electrode 110 and the second electrode 120. The organic layer 230 includes a first light-emitting stack (ST1) 240 positioned between the first electrode 110 and the second electrode 120 and including a first light-emitting layer 161; a second light-emitting stack (ST2) 250 positioned between the first light-emitting stack 240 and the second electrode 120 and including a second light-emitting layer 162; and a charge generation layer (CGL) 260) disposed between the first and second light-emitting stacks 240 and 250. The charge generation layer can include an N-type charge generation layer 191 and a P-type charge generation layer 192.

Further, the organic electroluminescent element according to one implementation of the present disclosure can have a tandem structure having three light-emitting stacks. Alternatively, four or more light-emitting stacks and three or more charge generating layers can be disposed between the first electrode and the second electrode.

Hereinafter, Synthesis Example and Present Example of the present disclosure will be described. However, following Present Example is only one example of the present disclosure. The present disclosure is not limited thereto.

### Synthesis Example

<Preparation of Compound A1>

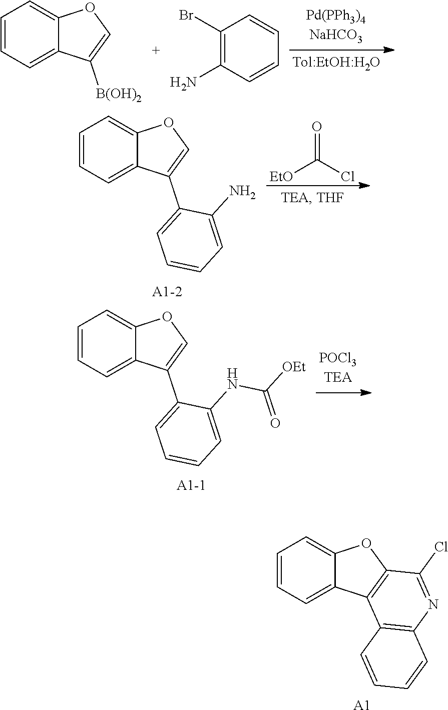

Step 1) Preparation of Compound A1-2

Benzofuran-3-ylboronic acid (50 g, 308.73 mmol), 2-bromoaniline (53 g, 308.73 mmol), Pd(PPh3)4 (17.8 g, 15.43 mmol), and NaHCO₃ (51 g, 617.46 mmol) were put to a reaction vessel and were dissolved in 500 mL of toluene, and 100 mL of ethanol and 100 mL of H₂O and the mixture was stirred at 100° C. for 6 hours. After completion of reaction, a temperature was lowered to room temperature, and the solvent was removed via concentration under reduced pressure. The concentrated solution was dissolved in an excess of dichloromethane (MC) and then was subjected MC/H₂O work up. Anhydrous MgSO₄ was added to an organic layer, and filtering was performed, and filtrate was concentrated under reduced pressure, and then the mixture was purified using a column (MC/Hex=1/1) to obtain the compound A1-2 (42 g, yield 66%).

MS (m/z): 209.08

Step 2) Preparation of Compound A1-1

The compound A1-2 (42 g, 200.72 mmol) was placed in the reaction vessel and dissolved in 500 mL of THF, followed by addition of triethylamine (56 mL, 401.43 mmol) thereto. After the reaction solution was cooled to 0° C., ethyl carbonochloridate (19 mL, 200.72 mmol) was slowly added thereto and the mixture was stirred at room temperature for 3 hours. After completion of the reaction, the mixture was dissolved in an excess of ethyl acetate (EA) and then was subjected to EA/H₂O work up. Anhydrous MgSO₄ was added to an organic layer, filtering was executed, and filtrate was concentrated under reduced pressure, and the mixture was purified using a column (MC/Hex=1/5) to obtain the compound A1-1 (50 g, yield 89%).

MS (m/z): 281.11

Step 3) Preparation of compound A1

The compound A1-1 (50 g, 177.74 mmol) was put into the reaction vessel, the temperature was lowered to 0° C., and POCl₃ (83 mL, 888.71 mmol) and triethylamine (25 mL, 177.74 mmol) were slowly added thereto in this order. The reaction solution was stirred at room temperature for 30 minutes and at 60° C. for 2 hours. After completion of the reaction, the temperature was lowered to 0° C., 3N NaOH (aq) was added thereto for neutralization. The mixture was dissolved in excessive MC for extraction. Anhydrous MgSO₄ was added to an organic layer, filtering was executed, and filtrate was concentrated under reduced pressure, and the mixture was recrystallized to obtain the compound A1 (25 g, yield 56%).

MS (m/z): 253.03

<Preparation of compound A2>

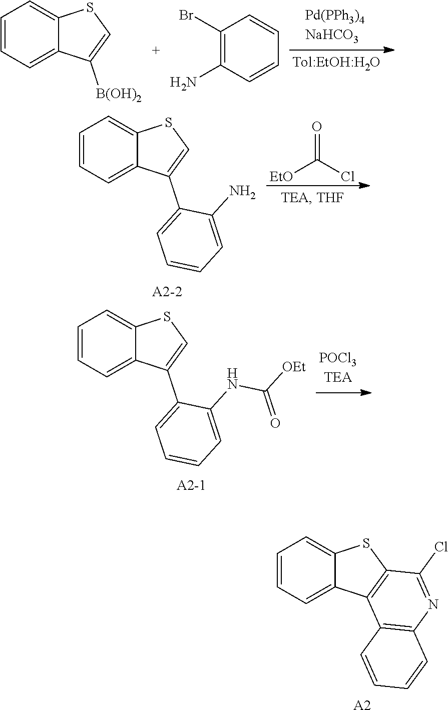

Step 1) Preparation of Compound A2-2

The compound A2-2 (41.7 g, yield 60%) was obtained in the same manner as in the preparation method of the compound A1-2 except that benzo[b]thiophen-3-ylboronic acid (55 g, 308.73 mmol) was used instead of benzofuran-3-ylboronic acid (50 g, 308.73 mmol).

MS (m/z): 225.06

Step 2) Preparation of Compound A2-1

The compound A2-1 (46.7 g, yield 85%) was prepared in the same manner as in the preparation method of the compound A1-1 except that A2-2 (41.7 g, 184.86 mmol) was used instead of A1-2 (42 g, 200.72 mmol).

MS (m/z): 297.08

Step 3) Preparation of Compound A2

The compound A2 (23.3 g, yield 55%) was obtained in the same manner as in the preparation method of the compound A1 except that A2-1 (46.7 g, 157.13 mmol) was used instead of A1-1 (50 g, 177.74 mmol).

MS (m/z): 269.01

<Preparation of Compound A3>

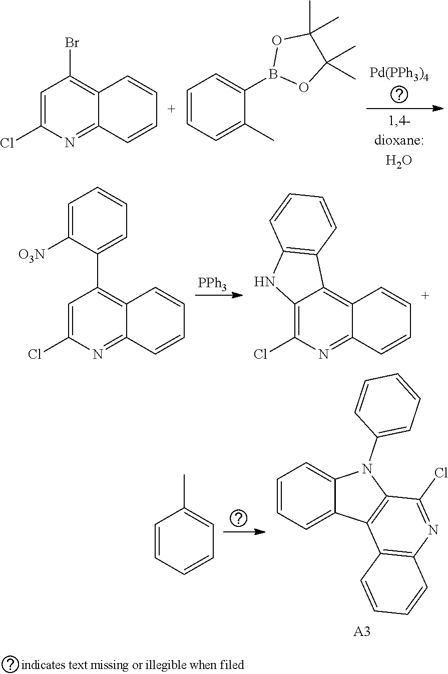

Step 1) Preparation of Compound A3-2

4-bromo-2-chloroquinoline (50 g, 206.18 mmol), 4,4,5,5-tetramethyl-2-(2-nitrophenyl)-1,3,2-dioxaborolane (51 g, 206.18 mmol), Pd (PPh₃)₄ (12 g, 10.31 mmol) and K₂CO₃ (57 g, 412.36 mmol) were added to a reaction vessel, and were dissolved in 1,4-dioxane 600 mL, and H₂O 100 mL, and the mixture was stirred at 100° C. for 5 hours. After completion of the reaction, the temperature was lowered to room temperature, and the solvent was removed via concentration under reduced pressure. The concentrated solution was dissolved in an excess of MC, and was subjected to MC/H₂O work up. Anhydrous MgSO₄ was added to an organic layer, filtering was executed, and filtrate was concentrated under reduced pressure, and the mixture was purified using a column (MC/Hex=1/2) to obtain the compound A3-2 (37 g, yield 63%).

MS (m/z): 284.04

Step 2) Preparation of Compound A3-1

The compound A3-2 (37 g, 129.96 mmol) and PPh₃ (68 g, 259.92 mmol) were put in a reaction vessel and dissolved in 500 mL of DCB, followed by stirring at 150° C. for 17 hours. After completion of the reaction, the temperature was lowered to room temperature and the mixture was dissolved in an excess of MC, followed by MC/H2O work up. Anhydrous MgSO₄ was added to an organic layer, filtering was executed, and filtrate was concentrated under reduced pressure, and the mixture was purified using a column (MC/Hex=2/1) to obtain the compound A3-1 (24 g, yield 74%).

MS (m/z): 252.05

Step 3) Preparation of Compound A3

The compound A3-1 (24 g, 94.97 mmol), Iodobenzene (19.3 g, 94.97 mmol), CuI (18 g, 94.97 mmol), trans-1,2-diaminocyclohexane (10.8 g, 94.97 mmol), K₃PO₄ (40 g, 189.94) mmol) was input to a reaction vessel, and were dissolved in 500 mL of 1,4-dioxane and then the mixture was stirred at 100° C. for 6 hours. After completion of the reaction, the temperature was lowered to room temperature, and insoluble inorganic salt was removed via filtering, and filtrate was dissolved in excess MC for extraction. Anhydrous MgSO₄ was added to an organic layer, filtering was executed and filtrate was concentrated under reduced pressure, and the mixture was purified using a column (MC/Hex=1/3) to obtain the compound A3 (26 g, yield 85%).

MS (m/z): 328.08

<Preparation of Compound A4>

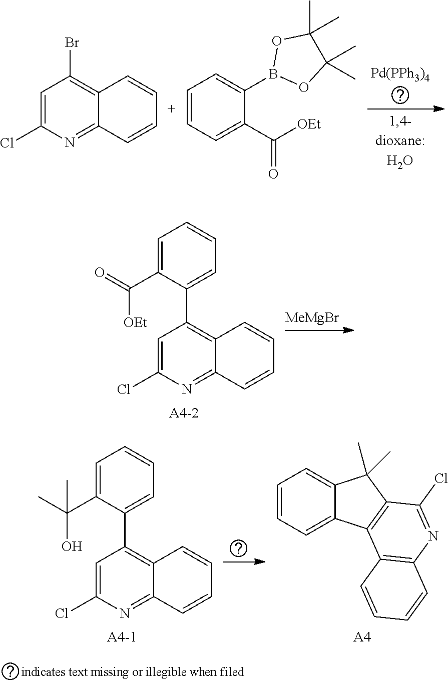

Step 1) Preparation of Compound A4-2

The compound A4-2 (44 g, yield 68%) was obtained in the same manner as in the preparation method of the compound A3-2 except that ethyl 2-(4,4,5,5-tetramethyl-1,3,2-dioxaborolan-2-yl)benzoate (57 g, 206.18 mmol) was used instead of 4,4,5,5-tetramethyl-2-(2-nitrophenyl)-1,3,2-dioxaborolane (51 g, 206.18 mmol).

MS (m/z): 311.07

Step 2) Preparation of Compound A4-1

The compound A4-2 (44 g, 141.13 mmol) was placed in a reaction vessel, dissolved in 500 mL of Ether, and then MeMgBr 3M (in ether) (94 mL, 282.26 mmol) was slowly added thereto. The reaction temperature was raised up to 60° C., and the mixture was stirred for 14 hours. After completion of the reaction, the temperature was lowered to 0° C., 100 mL of 5N NH₄Cl (aq) was slowly added thereto, and the mixture was dissolved in an excess of EA for extraction. Anhydrous MgSO₄ was added to an organic layer, filtering was executed, and filtrate was concentrated under reduced pressure, and the mixture was purified using a column (MC/Hex=1/1) to obtain the compound A4-1 (24 g, yield 59%).

MS (m/z): 297.09

Step 3) Preparation of Compound A4

The compound A4-1 (24 g, 80.59 mmol) was put in a reaction vessel, dissolved in 300 mL of dichloromethane, and BF₃OEt₂ (11 mL, 88.65 mmol) was slowly added thereto, and the mixture was stirred at room temperature for 2 hours. After completion of the reaction, 30 mL of 3N NaHCO₃ (aq) was added thereto, followed by extraction using an excess of MC. Anhydrous MgSO₄ was added to an organic layer, filtering was executed and filtrate was concentrated under reduced pressure, and the mixture was purified using a column (MC/Hex=1/3) to obtain the compound A4 (20 g, yield 89%).

MS (m/z): 279.08

<Preparation of Compound A5>

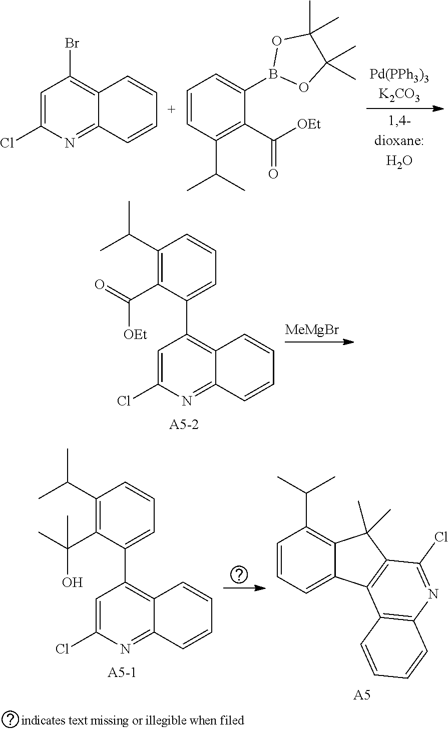

Step 1) Preparation of Compound A5-2

The compound A5-2 (48.2 g, yield 66%) was prepared in the same manner as in the preparation method of the compound A3-2 except that instead of 4,4,5,5-tetramethyl-2-(2-nitrophenyl)-1,3,2-dioxaborolane (51 g, 206.18 mmol), ethyl 2-isopropyl-6-(4,4,5,5-tetramethyl-1,3,2-dioxaborolan-2-yl)benzoate (65.6 g, 206.18 mmol) was used.

MS (m/z): 353.12

Step 2) Preparation of Compound A5-1

The compound A5-1 (25.4 g, yield 55%) was prepared in the same manner as in the preparation method of the compound A4-1 except that A5-2 (48.2 g, 136.08 mmol) was used instead of A4-2 (44 g, 141.13 mmol).

MS (m/z): 339.14

Step 3) Preparation of Compound A5

The compound A5 (21.7 g, yield 90%) was obtained in the same manner as in the preparation method of the compound A4 except that A5-1 (25.4 g, 74.84 mmol) was used instead of A4-1 (24 g, 80.59 mmol).

MS (m/z): 321.13

<Preparation of Compound A6>

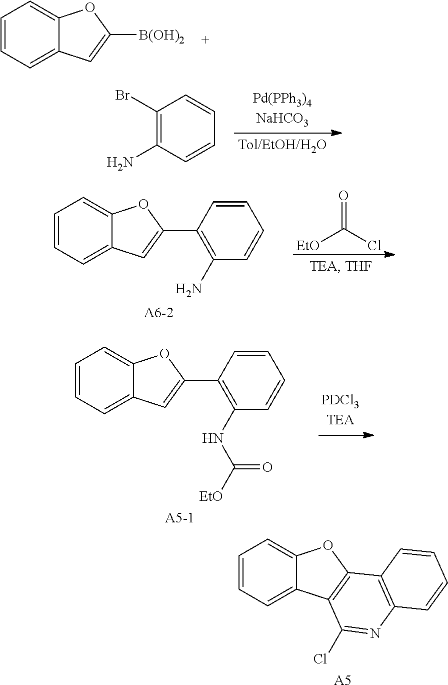

Step 1) Preparation of Compound A6-2

The compound A6-2 (40.7 g, yield 63%) was obtained in the same manner as in the preparation method of the compound A1-2 except that benzo[b]thiophen-2-ylboronic acid (50 g, 308.73 mmol) was used instead of benzofuran-3-ylboronic acid (50 g, 308.73 mmol).

MS (m/z): 209.08

Step 2) Preparation of Compound A6-1

The compound A2-1 (47.1 g, yield 86%) was prepared in the same manner as in the preparation method of the compound A1-1, except that A6-2 (40.7 g, 194.50 mmol) was used instead of A1-2 (42 g, 200.72 mmol).

MS (m/z): 281.11

Step 3) Preparation of Compound A6

The compound A6 (21.6 g, yield 51%) was obtained in the same manner as in the preparation method of the compound A1 except that A6-1 (47.1 g, 167.27 mmol) was used instead of A1-1 (50 g, 177.74 mmol).

MS (m/z): 253.03

<Preparation of Compound A7>

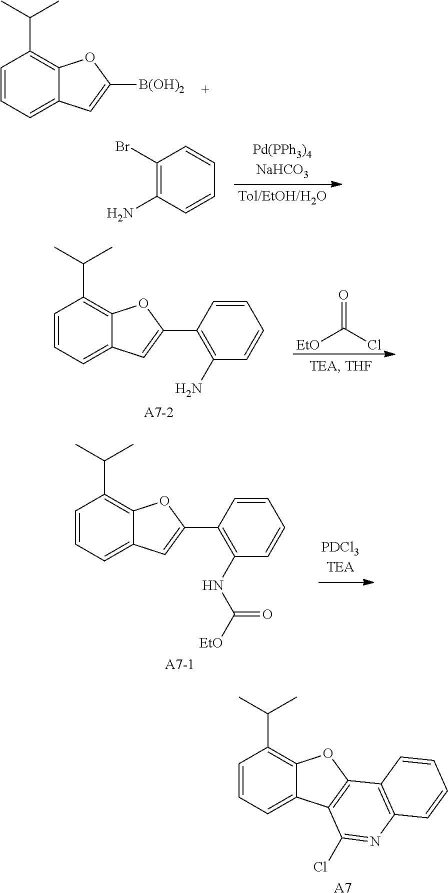

Step 1) Preparation of Compound A7-2

The compound A7-2 (36.3 g, yield 59%) was obtained in the same manner as in the preparation method of the compound A1-2 except that benzofuran-3-ylboronic acid (50 g, 308.73 mmol) was replaced with 7-isopropylbenzofuran-2-ylboronic acid (50 g, 245.06 mmol).

MS (m/z): 251.13

Step 2) Preparation of Compound A7-1

The compound A7-1 (36.9 g, yield 79%) was prepared in the same manner as in the preparation method of the compound A1-1, except that A7-2 (36.3 g, 144.59 mmol) was used instead of A1-2 (42 g, 200.72 mmol).

MS (m/z): 323.15

Step 3) Preparation of Compound A7

The compound A7 (19.4 g, yield 58%) was obtained in the same manner as in the preparation method of the compound A1 except that A7-1 (36.9 g, 114.22 mmol) was used instead of A1-1 (50 g, 177.74 mmol).

MS (m/z): 295.08

<Preparation of Compound A8>

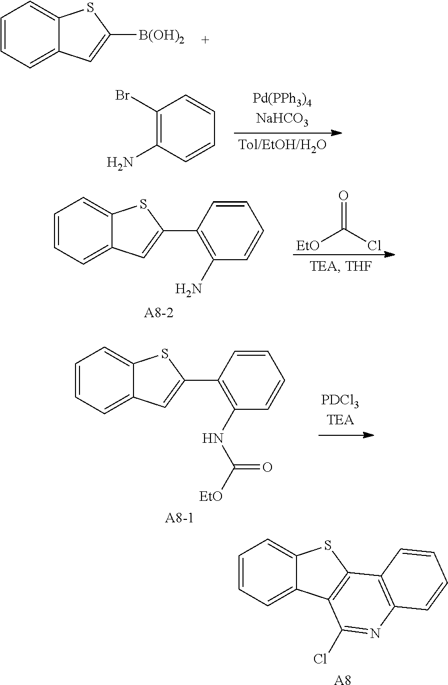

Step 1) Preparation of Compound A8-2

The compound A8-2 (41.8 g, yield 66%) was obtained in the same manner as in the preparation method of the compound A1-2 except that benzo[b]thiophen-2-ylboronic acid (50 g, 280.87 mmol) was used instead of benzofuran-3-ylboronic acid (50 g, 308.73 mmol)

MS (m/z): 225.06

Step 2) Preparation of Compound A8-1

The compound A8-1 (42.4 g, yield 77%) was prepared in the same manner as in the preparation method of the compound A1-1, except that A8-2 (41.8 g, 185.37 mmol) was used instead of A1-2 (42 g, 200.72 mmol).

MS (m/z): 297.08

Step 3) Preparation of Compound A8

The compound A8 (21.2 g, yield 55%) was obtained in the same manner as in the preparation method of the compound A1 except that A8-1 (42.4 g, 142.74 mmol) was used instead of A1-1 (50 g, 177.74 mmol).

MS (m/z): 269.01

<Preparation of Compound A9>

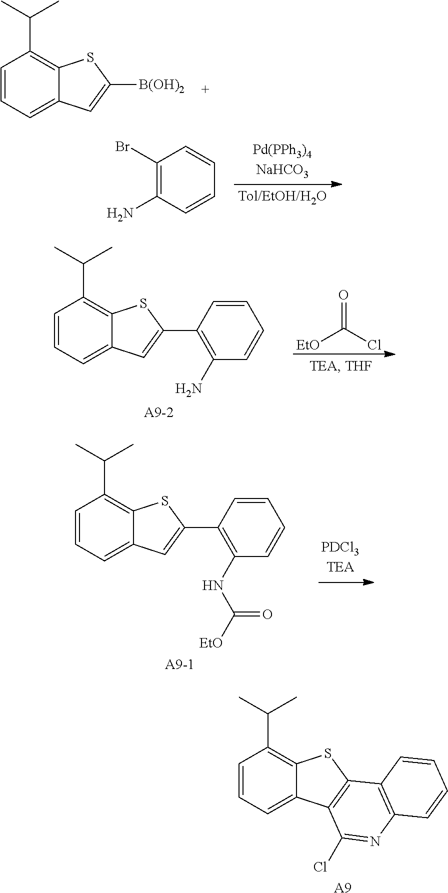

Step 1) Preparation of Compound A9-2

The compound A9-2 (42.5 g, yield 70%) was obtained in the same manner as in the preparation method of the compound A1-2 except that 7-isopropylbenzo[b]thiophen-2-ylboronic acid (50 g, 227.17 mmol) was used instead of benzofuran-3-ylboronic acid (50 g, 308.73 mmol).

MS (m/z): 267.11

Step 2) Preparation of Compound A9-1

The compound A9-1 (43.2 g, yield 80%) was prepared in the same manner as in the preparation method of the compound A1-1 except that A9-2 (42.5 g, 159.02 mmol) was used instead of A1-2 (42 g, 200.72 mmol).

MS (m/z): 339.13

Step 3) Preparation of Compound A9

The compound A9 (22.6 g, yield 57%) was obtained in the same manner as in the preparation method of the compound A1 except that A9-1 (43.2 g, 127.21 mmol) was used instead of A1-1 (50 g, 177.74 mmol).

MS (m/z): 311.05

<Preparation of Compound A10>

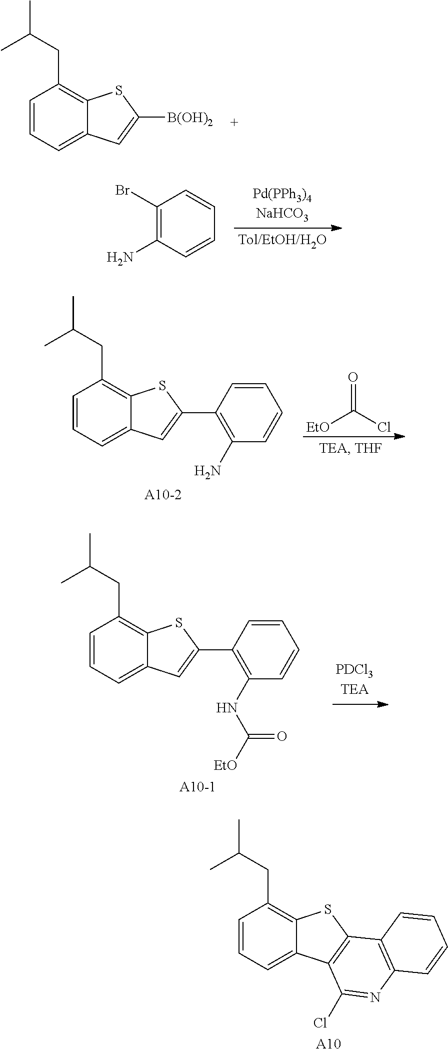

Step 1) Preparation of Compound A10-2

The compound A10-2 (39.1 g, yield 65%) was obtained in the same manner as in the preparation method of the compound A1-2 except that benzofuran-3-ylboronic acid (50 g, 308.73 mmol) was replaced with 77-isobutylbenzo[b]thiophen-2-ylboronic acid (50 g, 213.57 mmol).

MS (m/z): 281.12

Step 2) Preparation of Compound A10-1

The compound A10-1 (36.8 g, yield 75%) was prepared in the same manner as in the preparation method of the compound A1-1, except that A10-2 (39.1 g, 138.82 mmol) was used instead of A1-2 (42 g, 200.72 mmol).

MS (m/z): 353.14

Step 3) Preparation of Compound A10

The compound A10 (16.6 g, yield 49%) was obtained in the same manner as in the preparation method of the compound A1 except that A10-1 (36.8 g, 104.11 mmol) was used instead of A1-1 (50 g, 177.74 mmol).

MS (m/z): 325.07

<Preparation of Compound A11>

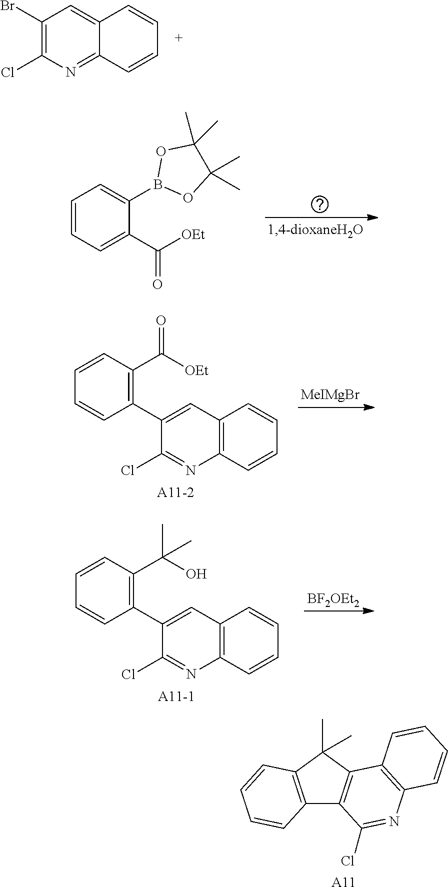

Step 1) Preparation of Compound A11-2

The compound A11-2 (48.9 g, yield 76%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with 3-bromo-2-chloroquinoline (50 g, 206.18 mmol), and ethyl 2-isopropyl-6-(4,4,5,5-tetramethyl-1,3,2-dioxaborolan-2-yl)benzoate (65.6 g, 206.18 mmol).

MS (m/z): 311.07

Step 2) Preparation of Compound A11-1

The compound A11-1 (21.0 g, yield 45%) was prepared in the same manner as in the preparation method of the compound A4-1 except that A11-2 (48.9 g, 156.70 mmol) was used instead of A4-2 (44 g, 141.13 mmol).

MS (m/z): 297.09

Step 3) Preparation of Compound A11

The compound A11 (16.2 g, yield 82%) was obtained in the same manner as in the preparation method of the compound A4 except that A11-1 (21.0 g, 70.52 mmol) was used instead of A4-1 (24 g, 80.59 mmol).

MS (m/z): 279.08

<Preparation of Compound A12>

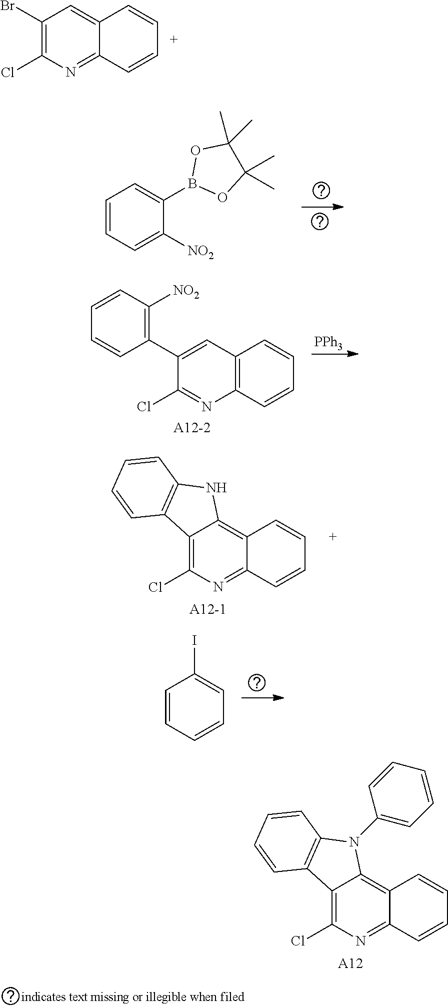

Step 1) Preparation of Compound A12-2

The compound A12-2 (34.0 g, yield 58%) was obtained in the same manner as in the preparation method of the compound A3-2 except that 4-bromo-2-chloroquinoline (50 g, 206.18 mmol) was replaced with 3-bromo-2-chloroquinoline (50 g, 206.18 mmol).

MS (m/z): 284.04

Step 2) Preparation of Compound A12-1

The compound A12-1 (22.7 g, yield 75%) was prepared in the same manner as in the preparation method of the compound A3-1 except that A12-2 (34.0 g, 119.59 mmol) was used instead of A3-2 (37 g, 129.96 mmol).

MS (m/z): 252.05

Step 3) Preparation of Compound A12

The compound A12 (11.4 g, yield 88%) was obtained in the same manner as in the preparation method of the compound A3 except that A12-1 (10 g, 39.57 mmol) was used instead of A3-1 (24 g, 94.97 mmol).

MS (m/z): 328.08

<Preparation of Compound A13>

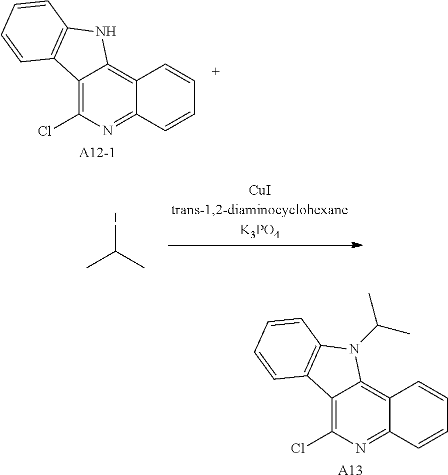

The compound A13 (9.1 g, yield 78%) was obtained in the same manner as in the preparation method of the compound A3 except that A3-1 (24 g, 94.97 mmol), and Iodobenzene (19.3 g, 94.97 mmol) were replaced with A12-1 (10 g, 39.57 mmol) and 2-iodopropane (6.7 g, 39.57 mmol).

MS (m/z): 294.09

<Preparation of Compound B1>

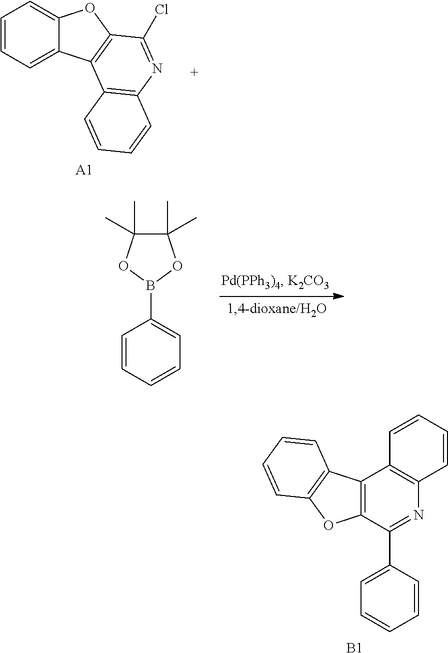

The compound B1 (8.8 g, yield 76%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A1 (10 g, 39.42 mmol), and 4,4,5,5-tetramethyl-2-phenyl-1,3,2-dioxaborolane (8.0 g, 39.42 mmol).

MS (m/z): 295.10

<Preparation of Compound B2>

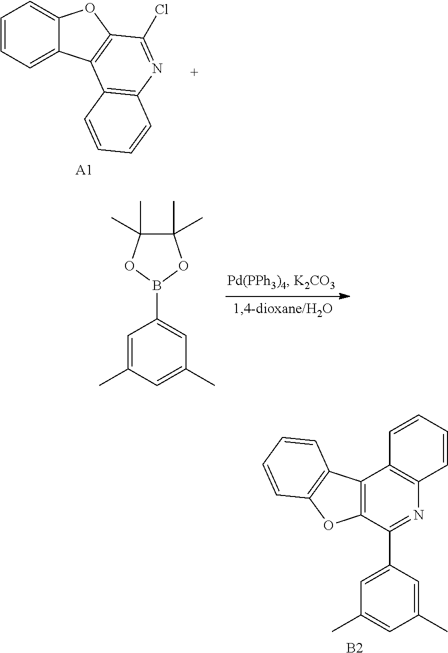

The compound B2 (9.4 g, yield 74%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A1 (10 g, 39.42 mmol), and 2-(3,5-dimethylphenyl)-4,4,5,5-tetramethyl-1,3,2-dioxaborolane (9.2 g, 39.42 mmol).

MS (m/z): 323.13

<Preparation of Compound B3>

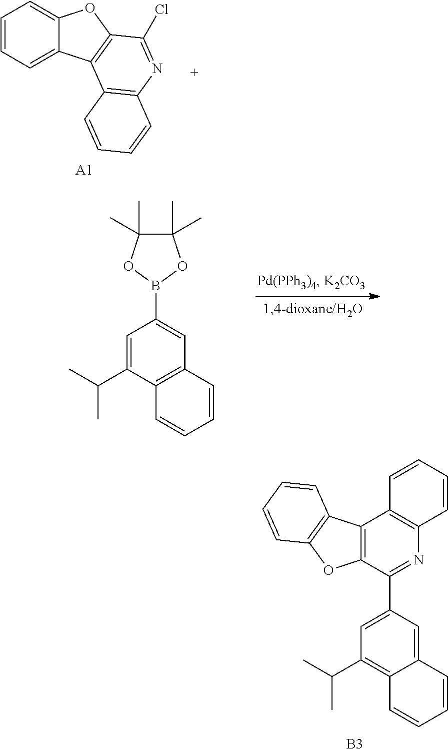

The compound B3 (12.2 g, yield 80%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A1 (10 g, 39.42 mmol), and 2-(4-isopropylnaphthalen-2-yl)-4,4,5,5-tetramethyl-1,3,2-dioxaborolane (11.6 g, 39.42 mmol).

MS (m/z): 387.16

<Preparation of Compound B4>

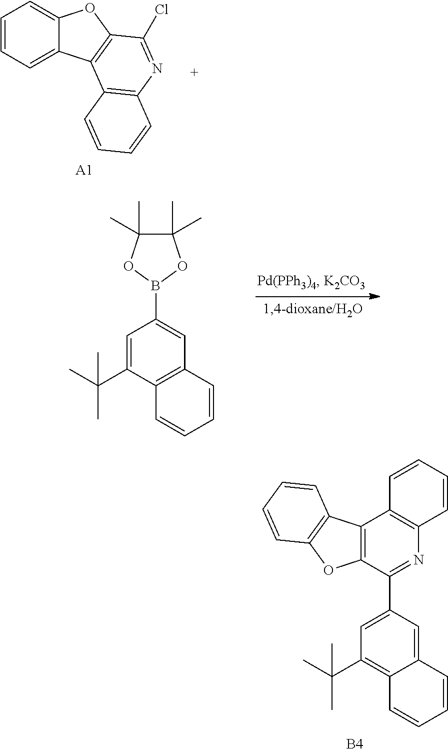

The compound B4 (12.3 g, yield 78%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A1 (10 g, 39.42 mmol), and 2-(4-tert-butylnaphthalen-2-yl)-4,4,5,5-tetramethyl-1,3,2-dioxaborolane (12.2 g, 39.42 mmol).

MS (m/z): 401.18

<Preparation of Compound B5>

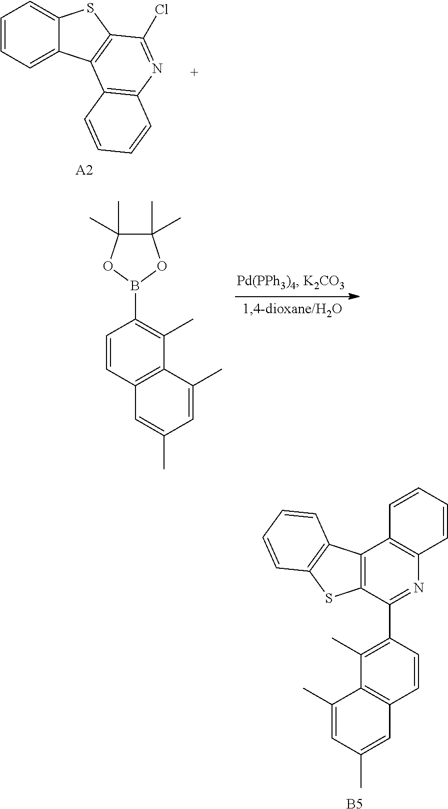

The compound B5 (10.9 g, yield 73%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A2 (10 g, 37.07 mmol), and 4,4,5,5-tetramethyl-2-(1,6,8-trimethylnaphthalen-2-yl)-1,3,2-dioxaborolane (11.0 g, 37.07 mmol).

MS (m/z): 403.14

<Preparation of Compound B6>

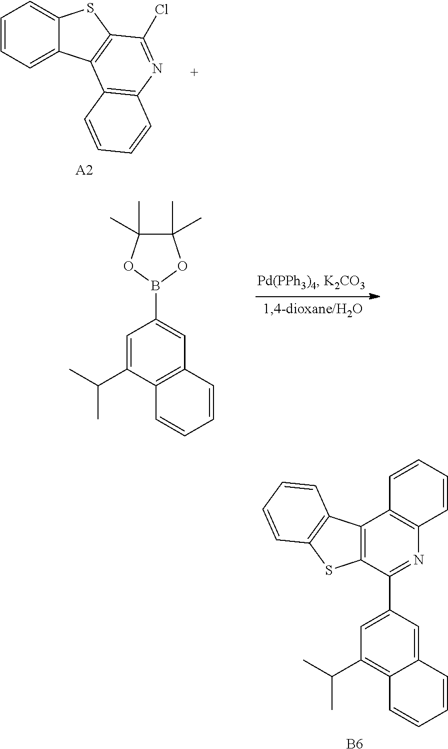

The compound B6 (11.1 g, yield 72%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A2 (10 g, 37.07 mmol), and 2-(4-isopropylnaphthalen-2-yl)-4,4,5,5-tetramethyl-1,3,2-dioxaborolane (11.5 g, 37.07 mmol).

<Preparation of Compound B7>

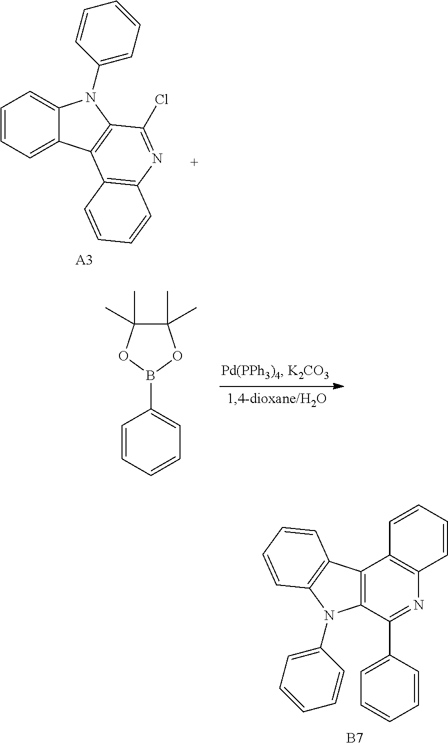

The compound B7 (9.5 g, yield 84%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A3 (10 g, 30.41 mmol), and 4,4,5,5-tetramethyl-2-phenyl-1,3,2-dioxaborolane (6.2 g, 30.41 mmol).

MS (m/z): 370.15

<Preparation of Compound B8>

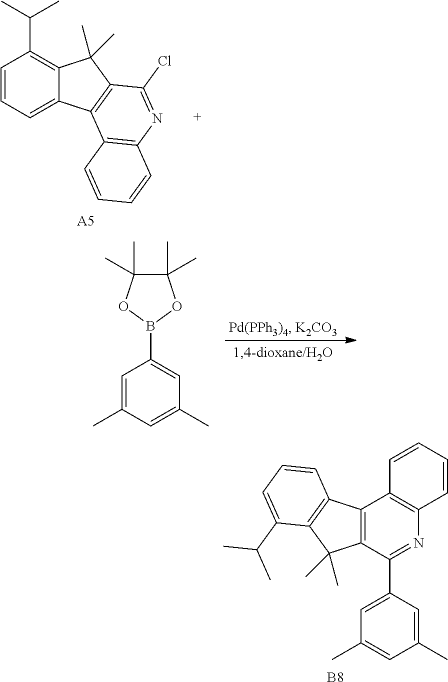

The compound B8 (10.2 g, yield 84%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A5 (10 g, 31.07 mmol), and 2-(3,5-dimethylphenyl)-4,4,5,5-tetramethyl-1,3,2-dioxaborolane (7.2 g, 31.07 mmol).

MS (m/z): 391.23

<Preparation of Compound B9>

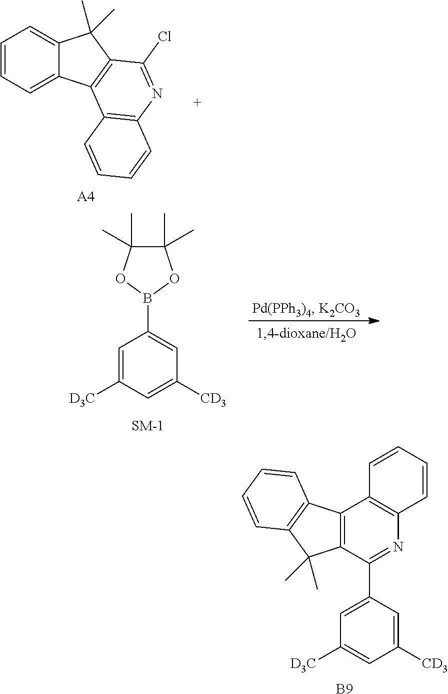

The compound B9 (10.4 g, yield 82%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A1 (10 g, 35.74 mmol), and SM-1 (8.0 g, 35.74 mmol).

MS (m/z): 355.22

<Preparation of Compound B10>

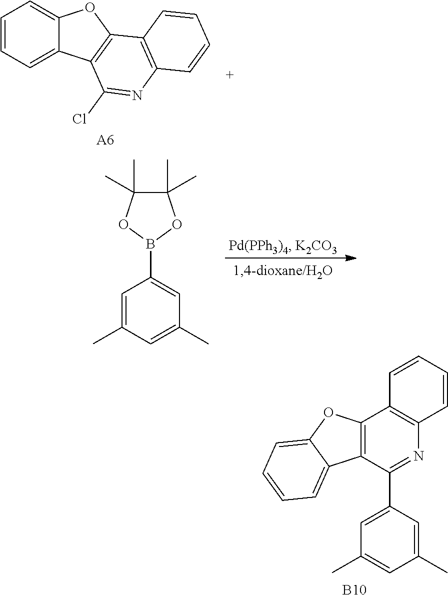

The compound B10 (9.7 g, yield 76%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A6 (10 g, 39.42 mmol), and 2-(3,5-dimethylphenyl)-4,4,5,5-tetramethyl-1,3,2-dioxaborolane (9.2 g, 39.42 mmol).

MS (m/z): 323.13

<Preparation of Compound B11>

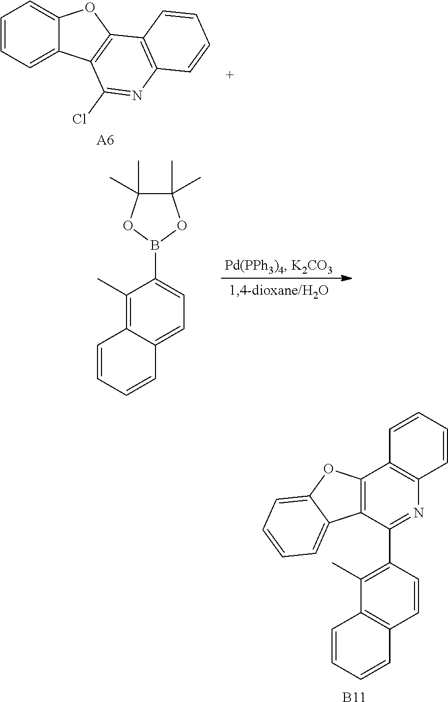

The compound B11 (11.3 g, yield 80%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A6 (10 g, 39.42 mmol), and 4,4,5,5-tetramethyl-2-(1-methylnaphthalen-2-yl)-1,3,2-dioxaborolane (10.6 g, 39.42 mmol).

MS (m/z): 359.13

<Preparation of Compound B12>

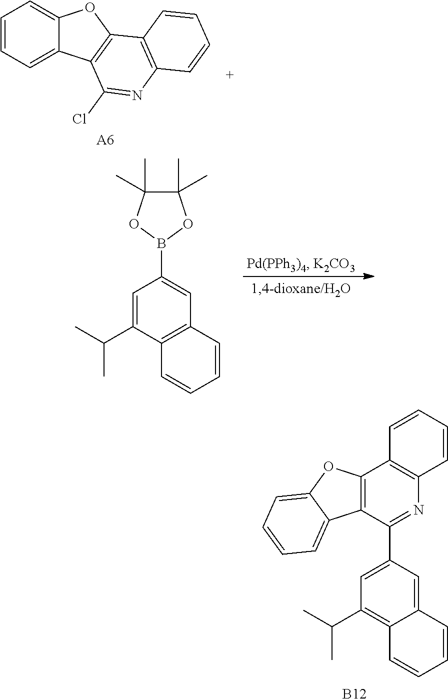

The compound B12 (11.9 g, yield 78%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A6 (10 g, 39.42 mmol), and 2-(4-isopropylnaphthalen-2-yl)-4,4,5,5-tetramethyl-1,3,2-dioxaborolane (11.7 g, 39.42 mmol).

MS (m/z): 387.16

<Preparation of Compound B13>

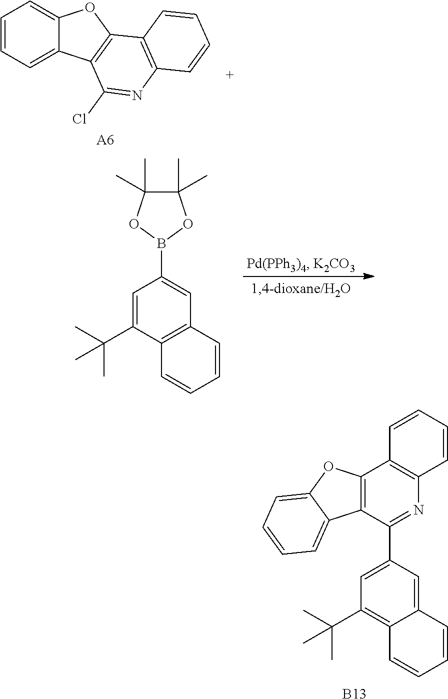

The compound B13 (12.2 g, yield 77%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A6 (10 g, 39.42 mmol), and 2-(4-tert-butylnaphthalen-2-yl)-4,4,5,5-tetramethyl-1,3,2-dioxaborolane (12.2 g, 39.42 mmol).

MS (m/z): 401.18

<Preparation of Compound B14>

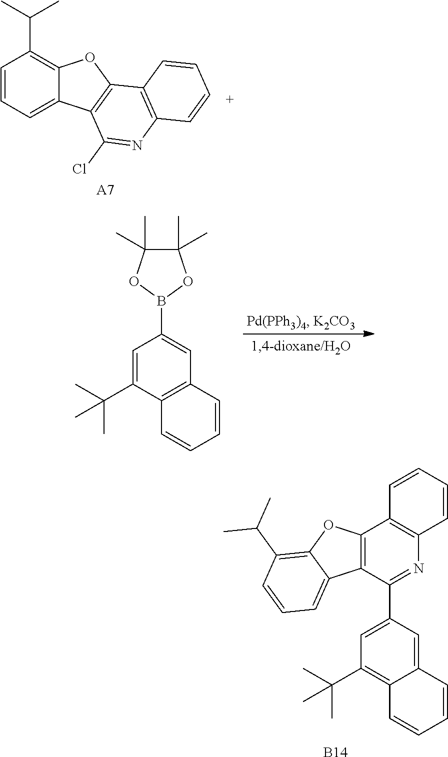

The compound B14 (10.8 g, yield 72%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A7 (10 g, 33.81 mmol), and 2-(4-tert-butylnaphthalen-2-yl)-4,4,5,5-tetramethyl-1,3,2-dioxaborolane (10.5 g, 33.81 mmol).

MS (m/z): 443.22

<Preparation of Compound B15>

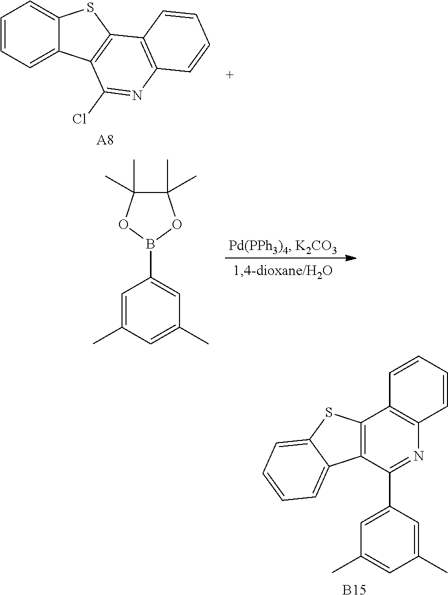

The compound B15 (11.1 g, yield 88%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A8 (10 g, 37.07 mmol), and 2-(3,5-dimethylphenyl)-4,4,5,5-tetramethyl-1,3,2-dioxaborolane (8.6 g, 37.07 mmol).

MS (m/z): 339.11

<Preparation of Compound B16>

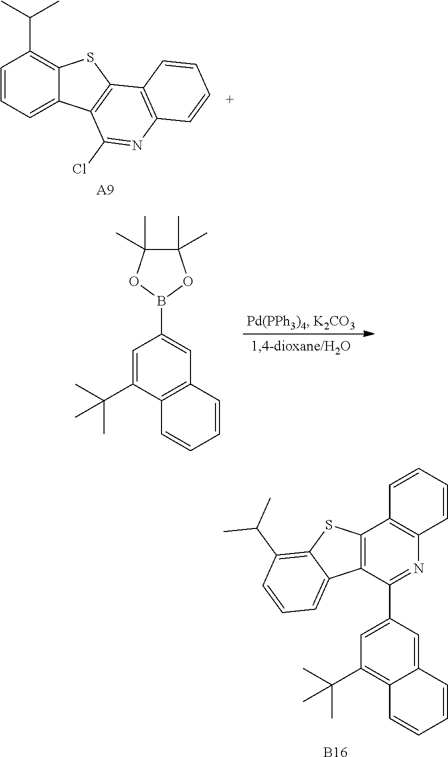

The compound B16 (11.1 g, yield 88%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A8 (10 g, 37.07 mmol), and 2-(3,5-dimethylphenyl)-4,4,5,5-tetramethyl-1,3,2-dioxaborolane (8.6 g, 37.07 mmol).

MS (m/z): 339.11

<Preparation of Compound B17>

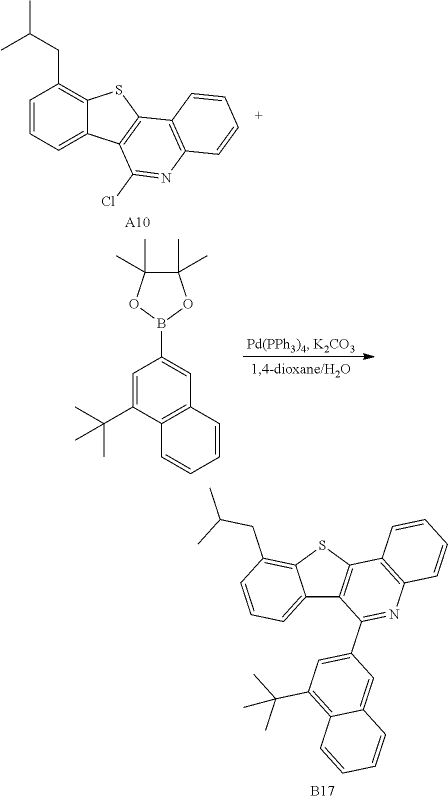

The compound B17 (11.0 g, yield 76%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A10 (10 g, 30.69 mmol), and 2-(4-tert-butylnaphthalen-2-yl)-4,4,5,5-tetramethyl-1,3,2-dioxaborolane (9.5 g, 30.69 mmol).

MS (m/z): 473.22

<Preparation of Compound B18>

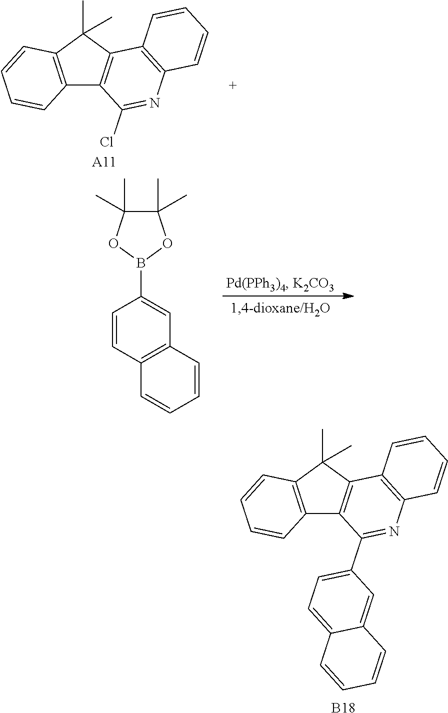

The compound B18 (10.8 g, yield 81%) was obtained in the same manner as in the preparation method of the compound A3-2, except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A11 (10 g, 35.74 mmol), and 4,4,5,5-tetramethyl-2-(naphthalen-2-yl)-1,3,2-dioxaborolane (9.1 g, 35.74 mmol).

MS (m/z): 371.17

<Preparation of Compound B19>

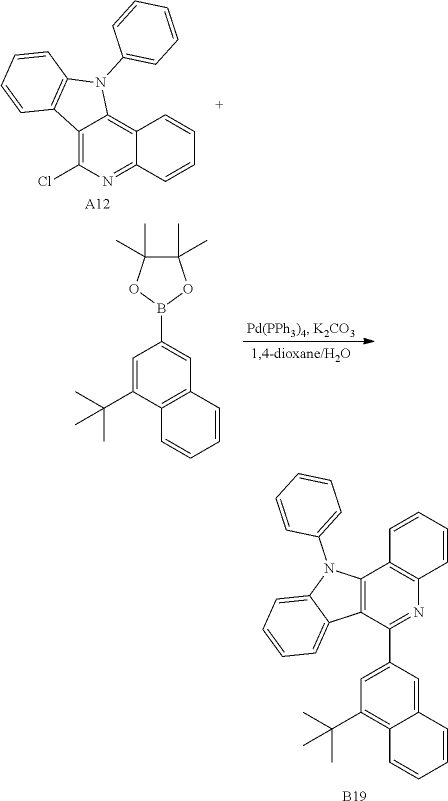

The compound B19 (10.4 g, yield 72%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A12 (10 g, 30.41 mmol), and 2-(4-tert-butylnaphthalen-2-yl)-4,4,5,5-tetramethyl-1,3,2-dioxaborolane (9.4 g, 30.41 mmol).

MS (m/z): 476.23

<Preparation of Compound B20>

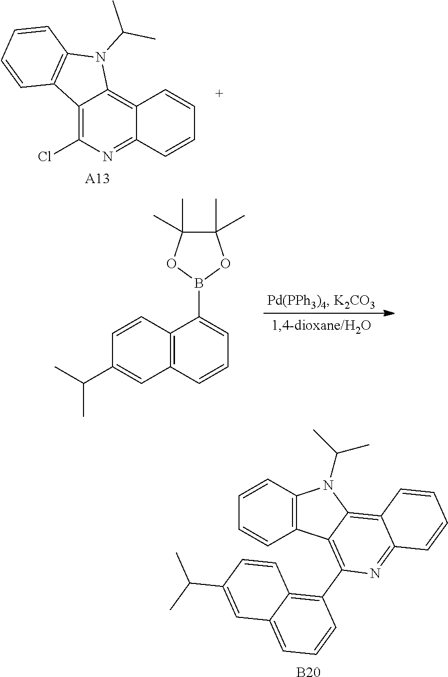

The compound B20 (11.2 g, yield 77%) was obtained in the same manner as in the preparation method of the compound A3-2 except that 4-bromo-2-chloroquinoline (50 g, 206.18 mmol), and 4,4,5,5-tetramethyl-2-(2-nitrophenyl)-1,3,2-dioxaborolane (51 g, 206.18 mmol) were replaced with A13 (10 g, 33.92 mmol), and 2-(6-isopropylnaphthalen-1-yl)-4,4,5,5-tetramethyl-1,3,2-dioxaborolane (10.0 g, 33.92 mmol).

MS (m/z): 428.23

<Preparation of Compound 1>

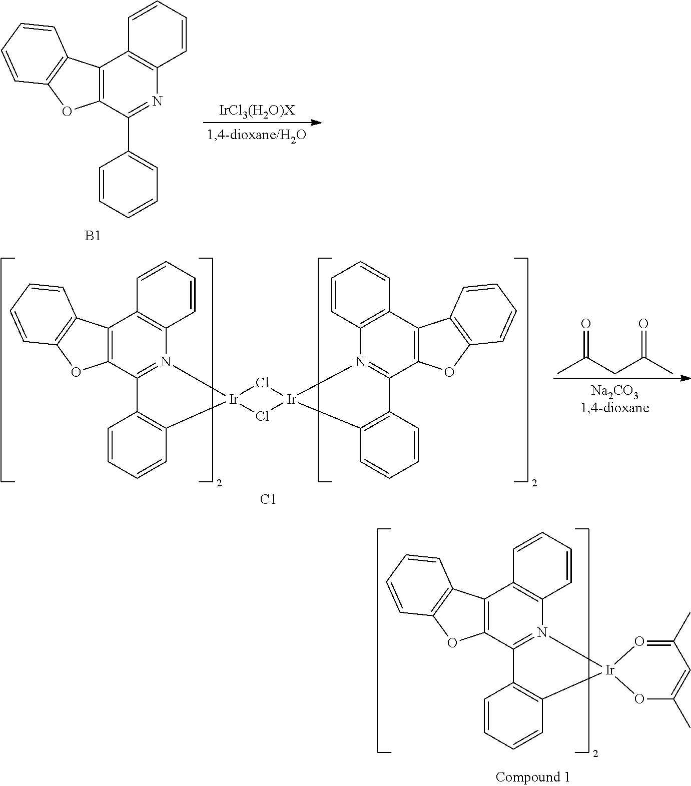

Step 1) Preparation of Compound C1

B1 (5.5 g, 18.72 mmol), 80 mL of 1,4-dioxane, 20 mL of H₂O were input to a reaction vessel and were subjected to nitrogen bubbling for 1 hour, and then IrCl₃(H₂O)X (3 g, 8.51 mmol) was added thereto and the mixture was stirred for 15 hours at 100° C. After completion of the reaction, the temperature was lowered to room temperature and the resulting solid was filtered. The filtered solid was dried to obtain an intermediate C1 (5.7 g, yield 38%).

Step 2) Preparation of Compound 1

C1 (5.7 g, 3.50 mmol), pentane-2,4-dione (3.5 g, 7.35 mmol), and Na₂CO₃ (7.5 g, 70.39 mmol) were added to a reaction vessel, and were dissolved in 100 mL of 1,4-dioxane, and the mixture was stirred for 24 hours. After completion of the reaction, the mixture was dissolved in an excess of MC for extraction. Anhydrous MgSO₄ was added to an organic layer, filtering was executed and filtrate was concentrated under reduced pressure, and the mixture was recrystallized to obtain the compound 1 (1.9 g, yield 61%).

MS (m/z): 880.19

<Preparation of Compound 4>

An intermediate C2 (5.6 g, yield 35%) was obtained in the same manner as in the preparation method of the compound C1 except that B3 (7.3 g, 18.72 mmol) was used instead of B1 (5.5 g, 18.72 mmol). The compound 4 (1.8 g, yield 58%) was obtained in the same manner as in the preparation method of the compound 1 except that C2 (5.6 g, 2.98 mmol) was used instead of C1 (5.7 g, 3.50 mmol).

MS (m/z): 1038.3

<Preparation of Compound 24>

The compound 24 (0.7 g, yield 38%) was obtained in the same manner as in the preparation method of the compound 1, except that C1 (5.7 g, 3.50 mmol), and pentane-2,4-dione (3.5 g, 7.35 mmol) were replaced with C1 (3 g, 1.85 mmol), and pentane-2,4-dione (0.7 g, 3.89 mmol).

MS (m/z): 949.31

<Preparation of Compound 36>

An intermediate C3 (6.8 g, yield 41%) was obtained in the same manner as in the preparation method of the compound C1 except for using B4 (7.5 g, 18.72 mmol) instead of B1 (5.5 g, 18.72 mmol). The compound 36 (2.2 g, yield 55%) was obtained in the same manner as in the preparation method of the compound 1, except that C1 (5.7 g, 3.50 mmol), and pentane-2,4-dione (3.5 g, 7.35 mmol) were replaced with C3 (6.8 g, 3.49 mmol), and (E)-N,N′-diisopropylbenzimidamide (1.4 g, 6.98 mmol).

MS (m/z): 1144.43

<Preparation of Compound 58>

An intermediate C4 (7.7 g, yield 52%) was obtained in the same manner as in the preparation method of the compound C1 except for using B2 (6.1 g, 18.72 mmol) instead of B1 (5.5 g, 18.72 mmol). The compound 58 (2.2 g, yield 55%) was obtained in the same manner as in the preparation method of the compound 1 except that C4 (7.7 g, 4.45 mmol) and picolinic acid (1.1 g, 9.34 mmol) were used instead of C1 (5.7 g, 3.50 mmol) and pentane-2,4-dione (3.5 g, 7.35 mm ol).

MS (m/z): 959.23

<Preparation of Compound 88>

An intermediate C5 (7.8 g, yield 48%) was obtained in the same manner as in the preparation method of the compound C1 except for using B5 (7.6 g, 18.72 mmol) instead of B1 (5.5 g, 18.72 mmol). The compound 88 (1.8 g, yield 41%) was obtained in the same manner as in the preparation method of the compound 1, except that C1 (5.7 g, 3.50 mmol) were replaced with C5 (7.8 g, 4.08 mmol).

MS (m/z): 1081.25

<Preparation of Compound 127>

An intermediate C6 (7.6 g, yield 46%) was obtained in the same manner as in the preparation method of the compound C1 except for using B5 (7.6 g, 18.72 mmol) instead of B1 (5.5 g, 18.72 mmol). The compound 127 (1.8 g, yield 39%) was obtained in the same manner as in the preparation method of the compound 1 except that C1 (5.7 g, 3.50 mmol), and pentane-2,4-dione (3.5 g, 7.35 mmol) were replaced with C6 (7.6 g, 3.91 mmol), and 2,4-dimethyl-6-phenylpyridine (1.5 g, 8.21 mmol).

MS (m/z): 1166.32

<Preparation of Compound 129>

An intermediate C7 (5.2 g, yield 32%) was obtained in the same manner as in the preparation method of the compound C1 except for using B7 (6.9 g, 18.72 mmol) instead of B1 (5.5 g, 18.72 mmol). The compound 129 (1.6 g, yield 57%) was obtained in the same manner as in the preparation method of the compound 1, except that C7 (5.2 g, 2.72 mmol) was used instead of C1 (5.7 g, 3.50 mmol).

MS (m/z): 1030.20

<Preparation of Compound 163>

An intermediate C8 (7.0 g, yield 41%) was obtained in the same manner as in the preparation method of the compound C1 except that B8 (7.3 g, 18.72 mmol) was used instead of B1 (5.5 g, 18.72 mmol). The compound 163 (2.1 g, yield 52%) was obtained in the same manner as in the preparation method of the compound 1, except that C1 (5.7 g, 3.50 mmol), and pentane-2,4-dione (3.5 g, 7.35 mmol) were replaced with C4 (7.0 g, 3.49 mmol), and (Z)-1,3-dicyclopentyl-3-hydroxyprop-2-en-1-one (1.5 g, 7.32 mmol).

MS (m/z): 1180.55

<Preparation of Compound 171>

An intermediate C9 (7.1 g, yield 45%) was obtained in the same manner as in the preparation method of the compound C1 except for using B9 (6.5 g, 18.72 mmol) instead of B1 (5.5 g, 18.72 mmol). The compound 171 (1.4 g, yield 37%) was obtained in the same manner as in the preparation method of the compound 1, except that C9 (7.1 g, 3.83 mmol) was used instead of C1 (5.7 g, 3.50 mmol).

MS (m/z): 975.23

<Preparation of compound 220>

An intermediate C10 (6.6 g, yield 43%) was obtained in the same manner as in the preparation method of the compound C1 except for using B11 (6.7 g, 18.72 mmol) instead of B1 (5.5 g, 18.72 mmol). The compound 220 (1.5 g, yield 40%) was obtained in the same manner as in the preparation method of the compound 1, except that C10 (6.6 g, 3.66 mmol) was used instead of C1 (5.7 g, 3.50 mmol).

MS (m/z): 1008.25

<Preparation of Compound 232>

An intermediate C11 (8.9 g, yield 51%) was obtained in the same manner as in the preparation method of the compound C1 except for using B13 (7.5 g, 18.72 mmol) instead of B1 (5.5 g, 18.72 mmol). The compound 232 (1.9 g, yield 38%) was obtained in the same manner as in the preparation method of the compound 1 except that C1 (5.7 g, 3.50 mmol), and pentane-2,4-dione (3.5 g, 7.35 mmol) were replaced with C11 (8.9 g, 4.34 mmol), and (Z)-3,7-diethyl-6-hydroxynon-5-en-4-one (1.9 g, 9.11 mmol).

MS (m/z): 1178.46

<Preparation of Compound 236>

The compound 236 (1.1 g, yield 38%) was obtained in the same manner as in the preparation method of the compound 1, except that C1 (5.7 g, 3.50 mmol), and pentane-2,4-dione (3.5 g, 7.35 mmol) were replaced with C11 (5.0 g, 2.43 mmol), and (E)-N,N′—((Z)-pent-2-ene-2-yl-4-ylidene)dipropan-2-amine (0.9 g, 5.10 mmol).

MS (m/z): 1148.46

<Preparation of Compound 239>

The compound 239 (1.0 g, yield 35%) was obtained in the same manner as in the preparation method of the compound 1 except that C1 (5.7 g, 3.50 mmol), and pentane-2,4-dione (3.5 g, 7.35 mmol) were replaced with C11 (5.0 g, 2.43 mmol), and (E)-N,N′-diisopropylbenzimidamide (1.0 g, 5.10 mmol).

MS (m/z): 1196.46

<Preparation of Compound 241>

An intermediate C12 (7.8 g, yield 42%) was obtained in the same manner as in the preparation method of the compound C1 except for using B14 (8.3 g, 18.72 mmol) instead of B1 (5.5 g, 18.72 mmol). The compound 241 (2.4 g, yield 52%) was obtained in the same manner as in the preparation method of the compound 1 except that C1 (5.7 g, 3.50 mmol), and pentane-2,4-dione (3.5 g, 7.35 mmol) were replaced with C12 (7.8 g, 3.57 mmol), and (Z)-3,7-diethyl-6-hydroxy-3,7-dimethylnon-5-en-4-one (1.8 g, 8.21 mmol).

MS (m/z): 1290.58

<Preparation of Compound 264>

An intermediate C13 (8.0 g, yield 47%) was obtained in the same manner as in the preparation method of the compound C1 except for using B12 (7.3 g, 18.72 mmol) instead of B1 (5.5 g, 18.72 mmol). The compound 264 (1.8 g, yield 43%) was obtained in the same manner as in the preparation method of the compound 1 except that C1 (5.7 g, 3.50 mmol), and pentane-2,4-dione (3.5 g, 7.35 mmol) were replaced with C13 (8.0 g, 3.99 mmol), and picolinic acid (1.0 g, 8.40 mmol).

MS (m/z): 1061.28

<Preparation of Compound 266>

An intermediate C14 (6.4 g, yield 43%) was obtained in the same manner as in the preparation method of the compound C1 except for using B10 (6.1 g, 18.72 mmol) instead of B1 (5.5 g, 18.72 mmol). The compound 266 (2.1 g, yield 56%) was obtained in the same manner as in the preparation method of the compound 1, except that C1 (5.7 g, 3.50 mmol), and pentane-2,4-dione (3.5 g, 7.35 mmol) were replaced with C14 (6.4 g, 3.66 mmol), and (Z)-1,3-dicyclopentyl-3-hydroxyprop-2-en-1-one (1.6 g, 7.68 mmol).

MS (m/z): 1034.33

<Preparation of Compound 286>

An intermediate C15 (6.2 g, yield 40%) was obtained in the same manner as in the preparation method of the compound C1 except for using B15 (6.4 g, 18.72 mmol) instead of B1 (5.5 g, 18.72 mmol). The compound 286 (1.4 g, yield 43%) was obtained in the same manner as in the preparation method of the compound 1 except that C15 (6.2 g, 3.40 mmol) was used instead of C1 (5.7 g, 3.50 mmol).

MS (m/z): 968.21

<Preparation of Compound 310>

An intermediate C16 (7.3 g, yield 38%) was obtained in the same manner as in the preparation method of the compound C1 except for using B16 (8.6 g, 18.72 mmol) instead of B1 (5.5 g, 18.72 mmol). The compound 310 (2.3 g, yield 57%) was obtained in the same manner as in the preparation method of the compound 1, except that C1 (5.7 g, 3.50 mmol), and pentane-2,4-dione (3.5 g, 7.35 mmol) were replaced with C16 (7.3 g, 3.23 mmol), and (Z)-5-hydroxy-2,2,6,6-tetramethylhept-4-en-3-one (1.3 g, 6.78 mmol).

MS (m/z): 1266.47

<Preparation of Compound 311>

An intermediate C17 (7.6 g, yield 39%) was obtained in the same manner as in the preparation method of the compound C1 except for using B17 (8.9 g, 18.72 mmol) instead of B1 (5.5 g, 18.72 mmol). The compound 311 (2.2 g, yield 50%) was obtained in the same manner as in the preparation method of the compound 1, except that C1 (5.7 g, 3.50 mmol), and pentane-2,4-dione (3.5 g, 7.35 mmol) were replaced with C17 (7.6 g, 3.32 mmol), and (Z)-3,7-diethyl-6-hydroxynon-5-en-4-one (1.5 g, 6.97 mmol).

MS (m/z): 1307.51

<Preparation of Compound 360>

An intermediate C18 (5.3 g, yield 32%) was obtained in the same manner as in the preparation method of the compound C1 except for using B18 (7.0 g, 18.72 mmol) instead of B1 (5.5 g, 18.72 mmol). The compound 360 (1.6 g, yield 54%) was obtained in the same manner as in the preparation method of the compound 1, except that C1 (5.7 g, 3.50 mmol), and pentane-2,4-dione (3.5 g, 7.35 mmol) were replaced with C18 (5.3 g, 2.72 mmol), and (Z)-3,7-diethyl-6-hydroxynon-5-en-4-one (1.2 g, 5.72 mmol).

MS (m/z): 1118.44

<Preparation of Compound 403>

An intermediate C19 (8.5 g, yield 43%) was obtained in the same manner as in the preparation method of the compound C1 except for using B19 (8.9 g, 18.72 mmol) instead of B1 (5.5 g, 18.72 mmol). The compound 403 (1.7 g, yield 37%) was obtained in the same manner as in the preparation method of the compound 1, except that C1 (5.7 g, 3.50 mmol), and pentane-2,4-dione (3.5 g, 7.35 mmol) were replaced with C19 (8.5 g, 3.66 mmol), and (Z)-3,7-diethyl-6-hydroxynon-5-en-4-one (1.6 g, 7.68 mmol).

MS (m/z): 1276.52

<Preparation of Compound 412>

An intermediate C20 (8.0 g, yield 44%) was obtained in the same manner as in the preparation method of the compound C1 except for using B20 (8.0 g, 18.72 mmol) instead of B1 (5.5 g, 18.72 mmol). The compound 412 (1.9 g, yield 41%) was obtained in the same manner as in the preparation method of the compound 1, except that C1 (5.7 g, 3.50 mmol), and pentane-2,4-dione (3.5 g, 7.35 mmol) were replaced with C20 (8.0 g, 3.74 mmol), and (Z)-5-hydroxy-2,2,6,6-tetramethylhept-4-en-3-one (1.4 g, 7.86 mmol).

MS (m/z): 1230.54

<Preparation of Compound 433>

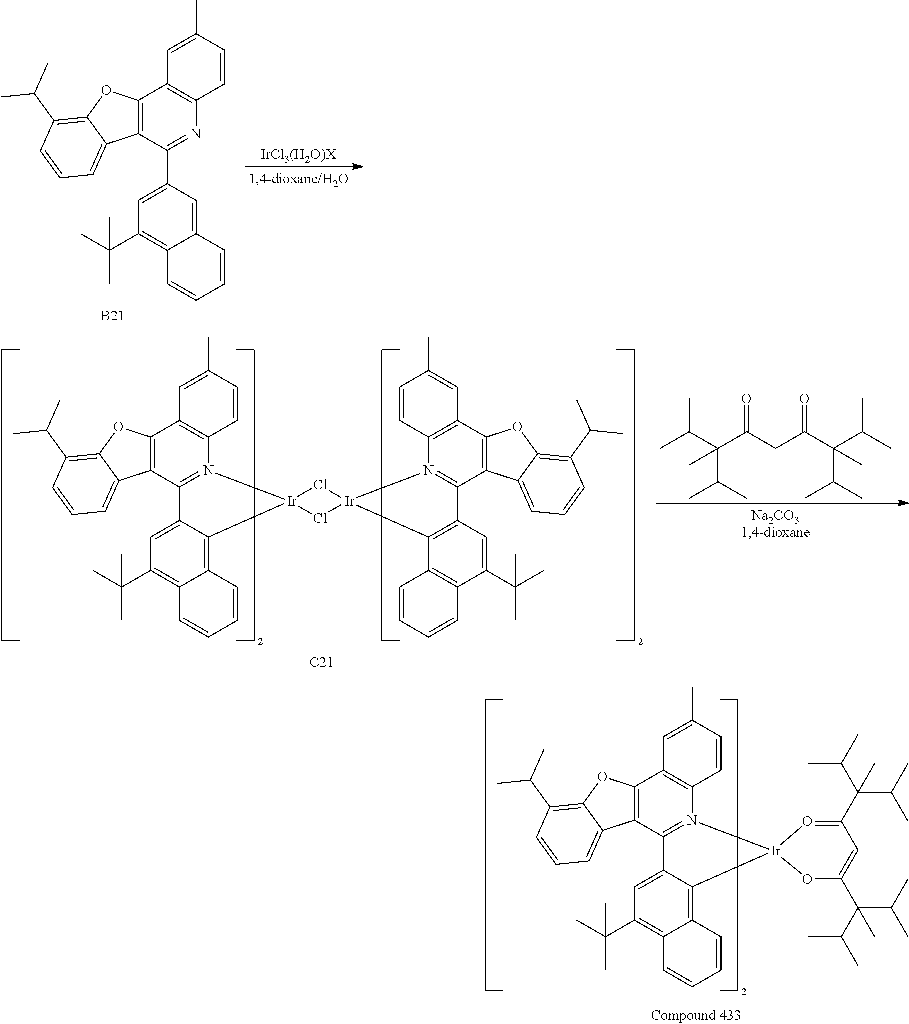

Step 1) Preparation of Compound C21

B21 (8.6 g, 18.72 mmol), 100 mL of 1,4-dioxane, 20 mL of H₂O were input to a reaction vessel and were subjected to nitrogen bubbling for 1 hour, and then IrCl₃(H₂O)X (3 g, 8.51 mmol) was added thereto and the mixture was stirred for 15 hours at 100° C. After completion of the reaction, the temperature was lowered to room temperature and the resulting solid was filtered. The filtered solid was dried to obtain an intermediate C21 (7.9 g).

Step 2) Preparation of Compound 433

C21 (7.9 g, 3.46 mmol), 3,7-diisopropyl-2,3,7,8-tetramethylnonane-4,6-dione (2.2 g, 7.27 mmol), and Na₂CO₃ (7.3 g, 69.24 mmol) were added to a reaction vessel, and were dissolved in 100 mL of 1,4-dioxane, and the mixture was stirred for 24 hours. After completion of the reaction, the mixture was dissolved in an excess of MC for extraction. Anhydrous MgSO₄ was added to an organic layer, filtering was executed and filtrate was concentrated under reduced pressure, and the mixture was recrystallized to obtain the compound 433 (2.1 g).

MS (m/z): 1400.69

### EXAMPLES

### Present Example 1

A glass substrate having a thin film made of ITO (indium tin oxide) of a thickness of 1,000 Å coated thereon was washed and was subjected to ultrasonic cleaning using a solvent such as isopropyl alcohol, acetone, or methanol and was dried.

HI-1 as a hole injection material of a thickness of 60 nm was formed on the prepared ITO transparent electrode via thermal vacuum deposition. NPB as a hole transport material was thermally vacuum deposited to have a thickness of 80 nm on the hole injection layer. A light-emitting layer was thermally vacuum deposited on the hole transport material. In this regard, the light-emitting layer contains CBP as a host material and the compound 1 as the dopant. A doping concentration was 5% and a thickness of the light emission layer was 30 nm. ET-1:Liq (1:1) (30 nm) as materials for the electron transport layer and the electron injection layer was thermally vacuum deposited on the light-emitting layer. Then, 100 nm thick aluminum was deposited thereon to form a negative electrode. Thus, an organic electroluminescent device was fabricated. The materials used in above Present Example 1 are as follows.

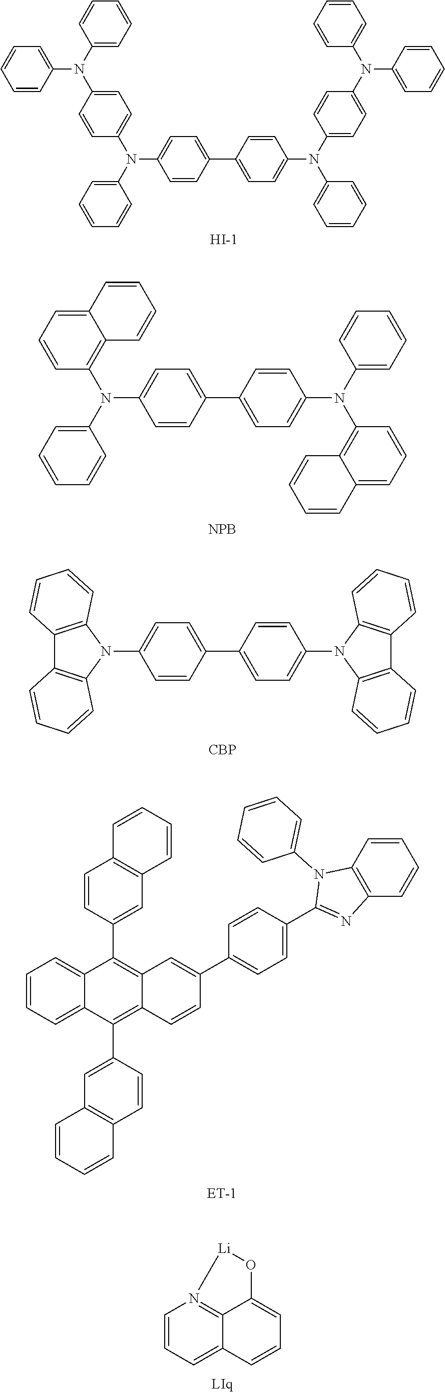

In this material, HI-1 is NNPPB and ET-1 is ZADN.

### Present Example 2

An organic electroluminescent device was manufactured in the same manner as in above Present Example 1, except that the compound 4 was used instead of the compound 1 in above Present Example 1.

### Present Example 3

An organic electroluminescent device was fabricated in the same manner as in above Present Example 1, except that the compound 24 was used instead of the compound 1 in above Present Example 1.

### Present Example 4

An organic electroluminescent device was fabricated in the same manner as in above Present Example 1, except that the compound 36 was used instead of the compound 1 in above Present Example 1.

### Present Example 5

An organic electroluminescent device was fabricated in the same manner as in above Present Example 1, except that the compound 58 was used instead of the compound 1 in above Present Example 1.

### Present Example 6

An organic electroluminescent device was fabricated in the same manner as in above Present Example 1, except that the compound 88 was used instead of the compound 1 in above Present Example 1.

### Present Example 7

An organic electroluminescent device was fabricated in the same manner as in above Present Example 1, except that the compound 127 was used instead of the compound 1 in above Present Example 1.

### Present Example 8

An organic electroluminescent device was manufactured in the same manner as in above Present Example 1, except that the compound 129 was used instead of the compound 1 in above Present Example 1.

### Present Example 9

An organic electroluminescent device was fabricated in the same manner as in above Present Example 1, except that the compound 163 was used instead of the compound 1 in above Present Example 1.

### Present Example 10

An organic electroluminescent device was manufactured in the same manner as in above Present Example 1, except that the compound 171 was used instead of the compound 1 in above Present Example 1.

### Present Example 11

An organic electroluminescent device was fabricated in the same manner as in above Present Example 1, except that the compound 220 was used instead of the compound 1 in above Present Example 1.

### Present Example 12

An organic electroluminescent device was fabricated in the same manner as in above Present Example 1, except that the compound 232 was used instead of the compound 1 in above Present Example 1.

### Present Example 13

An organic electroluminescent device was fabricated in the same manner as in above Present Example 1, except that the compound 236 was used instead of the compound 1 in above Present Example 1.

### Present Example 14

An organic electroluminescent device was fabricated in the same manner as in above Present Example 1, except that the compound 239 was used instead of the compound 1 in above Present Example 1.

### Present Example 15

An organic electroluminescent device was manufactured in the same manner as in above Present Example 1, except that the compound 241 was used instead of the compound 1 in above Present Example 1.

### Present Example 16

An organic electroluminescent device was manufactured in the same manner as in above Present Example 1, except that the compound 264 was used instead of the compound 1 in above Present Example 1.

### Present Example 17

An organic electroluminescent device was fabricated in the same manner as in above Present Example 1, except that the compound 266 was used instead of the compound 1 in above Present Example 1.

### Present Example 18

An organic electroluminescent device was manufactured in the same manner as in above Present Example 1, except that the compound 286 was used instead of the compound 1 in above Present Example 1.

### Present Example 19

An organic electroluminescent device was manufactured in the same manner as in above Present Example 1, except that the compound 310 was used instead of the compound 1 in above Present Example 1.

### Present Example 20

An organic electroluminescent device was manufactured in the same manner as in above Present Example 1, except that the compound 311 was used instead of the compound 1 in above Present Example 1.

### Present Example 21

An organic electroluminescent device was manufactured in the same manner as in above Present Example 1, except that the compound 360 was used instead of the compound 1 in above Present Example 1.

### Present Example 22

An organic electroluminescent device was fabricated in the same manner as in above Present Example 1, except that the compound 403 was used instead of the compound 1 in above Present Example 1.

### Present Example 23

An organic electroluminescent device was manufactured in the same manner as in above Present Example 1, except that the compound 412 was used instead of the compound 1 in above Present Example 1.

### Present Example 24

An organic electroluminescent device was manufactured in the same manner as in above Present Example 1, except that the compound 433 was used instead of the compound 1 in above Present Example 1.

### Present Example 25

An organic electroluminescent device was manufactured in the same manner as in above Present Example 1, except that the compound 434 was used instead of the compound 1 in above Present Example 1.

### Present Example 26

An organic electroluminescent device was manufactured in the same manner as in above Present Example 1, except that the compound 435 was used instead of the compound 1 in above Present Example 1.

### Present Example 27

An organic electroluminescent device was manufactured in the same manner as in above Present Example 1, except that the compound 436 was used instead of the compound 1 in above Present Example 1.

### Present Example 28

An organic electroluminescent device was manufactured in the same manner as in above Present Example 1, except that the compound 437 was used instead of the compound 1 in above Present Example 1.

### Present Example 29

An organic electroluminescent device was manufactured in the same manner as in above Present Example 1, except that the compound 438 was used instead of the compound 1 in above Present Example 1.

### Present Example 30

An organic electroluminescent device was manufactured in the same manner as in above Present Example 1, except that the compound 439 was used instead of the compound 1 in above Present Example 1.

### Present Example 31

An organic electroluminescent device was manufactured in the same manner as in above Present Example 1, except that the compound 440 was used instead of the compound 1 in above Present Example 1.

### Present Example 32

An organic electroluminescent device was manufactured in the same manner as in above Present Example 1, except that the compound 441 was used instead of the compound 1 in above Present Example 1.

### Present Example 33

An organic electroluminescent device was manufactured in the same manner as in above Present Example 1, except that the compound 442 was used instead of the compound 1 in above Present Example 1.

### Present Example 34

An organic electroluminescent device was manufactured in the same manner as in above Present Example 1, except that the compound 443 was used instead of the compound 1 in above Present Example 1.

### Present Example 35

An organic electroluminescent device was manufactured in the same manner as in above Present Example 1, except that the compound 444 was used instead of the compound 1 in above Present Example 1.

### Present Example 36

An organic electroluminescent device was manufactured in the same manner as in above Present Example 1, except that the compound 445 was used instead of the compound 1 in above Present Example 1.

### Present Example 37

An organic electroluminescent device was manufactured in the same manner as in above Present Example 1, except that the compound 446 was used instead of the compound 1 in above Present Example 1.

### Present Example 38

An organic electroluminescent device was manufactured in the same manner as in above Present Example 1, except that the compound 447 was used instead of the compound 1 in above Present Example 1.

### Present Example 39

An organic electroluminescent device was manufactured in the same manner as in above Present Example 1, except that the compound 448 was used instead of the compound 1 in above Present Example 1.

### Present Example 40

An organic electroluminescent device was manufactured in the same manner as in above Present Example 1, except that the compound 449 was used instead of the compound 1 in above Present Example 1.

### Present Example 41

An organic electroluminescent device was manufactured in the same manner as in above Present Example 1, except that the compound 450 was used instead of the compound 1 in above Present Example 1.

### Present Example 42

An organic electroluminescent device was manufactured in the same manner as in above Present Example 1, except that the compound 451 was used instead of the compound 1 in above Present Example 1.

### Present Example 43

An organic electroluminescent device was manufactured in the same manner as in above Present Example 1, except that the compound 452 was used instead of the compound 1 in above Present Example 1.

### Present Example 44

An organic electroluminescent device was manufactured in the same manner as in above Present Example 1, except that the compound 453 was used instead of the compound 1 in above Present Example 1.

### Present Example 45

An organic electroluminescent device was manufactured in the same manner as in above Present Example 1, except that the compound 454 was used instead of the compound 1 in above Present Example 1.

### Present Example 46

An organic electroluminescent device was manufactured in the same manner as in above Present Example 1, except that the compound 455 was used instead of the compound 1 in above Present Example 1.

### Present Example 47

An organic electroluminescent device was manufactured in the same manner as in above Present Example 1, except that the compound 456 was used instead of the compound 1 in above Present Example 1.

### Present Example 48

An organic electroluminescent device was manufactured in the same manner as in above Present Example 1, except that the compound 457 was used instead of the compound 1 in above Present Example 1.

### Present Example 49

An organic electroluminescent device was manufactured in the same manner as in above Present Example 1, except that the compound 458 was used instead of the compound 1 in above Present Example 1.

### Present Example 50

An organic electroluminescent device was manufactured in the same manner as in above Present Example 1, except that the compound 459 was used instead of the compound 1 in above Present Example 1.

### Present Example 51

An organic electroluminescent device was manufactured in the same manner as in above Present Example 1, except that the compound 460 was used instead of the compound 1 in above Present Example 1.

### Present Example 52

An organic electroluminescent device was manufactured in the same manner as in above Present Example 1, except that the compound 461 was used instead of the compound 1 in above Present Example 1.

### Present Example 53

An organic electroluminescent device was manufactured in the same manner as in above Present Example 1, except that the compound 462 was used instead of the compound 1 in above Present Example 1.

### Present Example 54

An organic electroluminescent device was manufactured in the same manner as in above Present Example 1, except that the compound 463 was used instead of the compound 1 in above Present Example 1.

### Present Example 55

An organic electroluminescent device was manufactured in the same manner as in above Present Example 1, except that the compound 464 was used instead of the compound 1 in above Present Example 1.

### Present Example 56

An organic electroluminescent device was manufactured in the same manner as in above Present Example 1, except that the compound 465 was used instead of the compound 1 in above Present Example 1.

### Present Example 57

An organic electroluminescent device was manufactured in the same manner as in above Present Example 1, except that the compound 466 was used instead of the compound 1 in above Present Example 1.

### Comparative Example 1

An organic electroluminescent device was fabricated in the same manner as in above Present Example 1, except that RD having a following structure was used instead of the compound 1 in above Present Example 1.

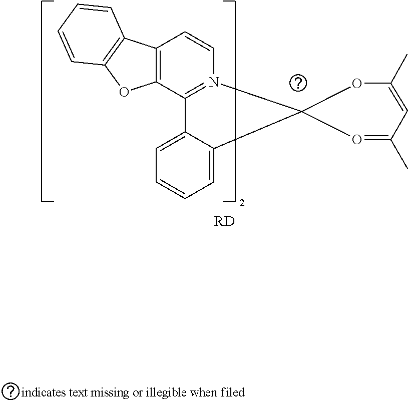

### Experimental Examples

Each of the organic electroluminescent devices prepared in Present Examples 1 to 57 and Comparative Example 1, respectively, was connected to an external power source, and the organic electroluminescent device characteristics were evaluated at room temperature using a current source and a photometer.

Specifically, a driving voltage, external quantum efficiency (EQE), lifespan characteristics (LT95) and a full width at half maximum (FWHM) were measured under a current of 10 mA/cm², and the results are shown in Table 1 and Table 2 below.

LT95 lifetime refers to a time it takes for a display element to lose 5% of initial brightness thereof. The LT95 lifetime is the most difficult customer specification to meet, and determines whether the display will experience image burn-in.

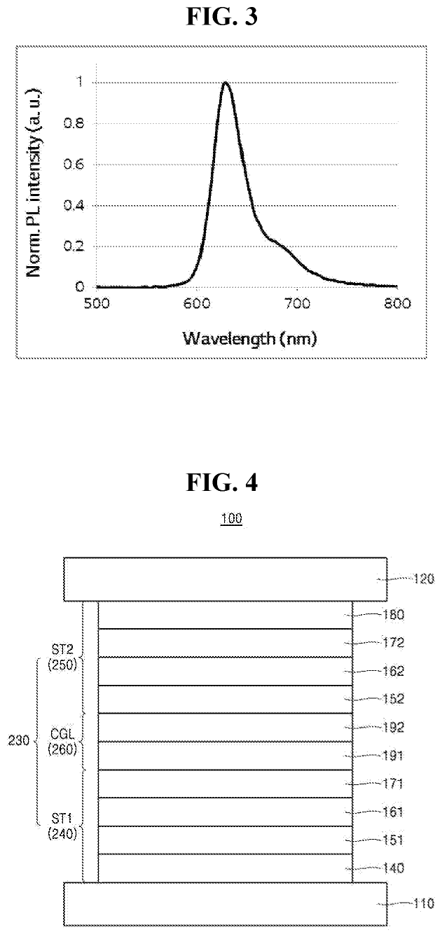

The full Width at Half Maximum (FWHM) means a wavelength width corresponding to ½ of the maximum value of a curve (kr) representing a wavelength (see FIG. 3). A narrow FWHM means that a range of colors that can be rendered is wide, and thus means that colors closer to natural colors can be realized and color gamut is improved. The full width at half maximum (FWHM) was evaluated based on photoluminescence (PL) intensity measurement, and a Model/Maker of the measuring equipment is FS-5/Edinburgh Instruments.

TABLE 1

| | | Drive | | | | Kr |
|---|---|---|---|---|---|---|
| | | voltage | EQE | LT95 | | (×10⁵s⁻¹) |
| | | (%, | (%, | (%, | | (%, |
| | | relative | relative | relative | FWHM | relative |
| | Dopant | value) | value) | value) | (nm) | value) |
| Comparative | RD | 100 | 100 | 100 | 65 | 100 |
| Example 1 | | | | | | |
| Present | Compound | 97.5 | 110 | 103 | 51 | 102 |
| Example 1 | 1 | | | | | |
| Present | Compound | 96.7 | 120 | 131 | 39 | 110 |
| Example 2 | 4 | | | | | |
| Present | Compound | 97.0 | 112 | 102 | 55 | 105 |
| Example 3 | 24 | | | | | |
| Present | Compound | 96.5 | 122 | 101 | 41 | 112 |
| Example 4 | 36 | | | | | |
| Present | Compound | 98.2 | 105 | 105 | 50 | 103 |
| Example 5 | 58 | | | | | |
| Present | Compound | 96.2 | 107 | 120 | 38 | 111 |
| Example 6 | 88 | | | | | |
| Present | Compound | 98.8 | 115 | 125 | 42 | 122 |
| Example 7 | 127 | | | | | |
| Present | Compound | 97.6 | 102 | 100 | 47 | 102 |
| Example 8 | 129 | | | | | |
| Present | Compound | 97.7 | 109 | 118 | 45 | 104 |
| Example 9 | 163 | | | | | |
| Present | Compound | 97.8 | 105 | 115 | 45 | 103 |
| Example 10 | 171 | | | | | |
| Present | Compound | 96.9 | 111 | 120 | 37 | 118 |
| Example 11 | 220 | | | | | |
| Present | Compound | 95.1 | 122 | 144 | 35 | 120 |
| Example 12 | 232 | | | | | |
| Present | Compound | 94.6 | 125 | 130 | 39 | 125 |
| Example 13 | 236 | | | | | |
| Present | Compound | 94.8 | 127 | 129 | 40 | 128 |
| Example 14 | 239 | | | | | |
| Present | Compound | 95.5 | 123 | 150 | 36 | 122 |
| Example 15 | 241 | | | | | |
| Present | Compound | 96.7 | 111 | 136 | 38 | 109 |
| Example 16 | 264 | | | | | |
| Present | Compound | 97.1 | 128 | 132 | 50 | 118 |
| Example 17 | 266 | | | | | |
| Present | Compound | 98.1 | 108 | 110 | 51 | 106 |
| Example 18 | 286 | | | | | |
| Present | Compound | 96.4 | 116 | 128 | 37 | 124 |
| Example 19 | 310 | | | | | |
| Present | Compound | 96.7 | 119 | 133 | 35 | 122 |
| Example 20 | 311 | | | | | |
| Present | Compound | 97.5 | 110 | 125 | 36 | 119 |
| Example 21 | 360 | | | | | |
| Present | Compound | 97.3 | 108 | 111 | 36 | 117 |
| Example 22 | 403 | | | | | |
| Present | Compound | 97.0 | 104 | 103 | 39 | 115 |
| Example 23 | 412 | | | | | |

TABLE 2

| | | Drive | | | | Kr |
|---|---|---|---|---|---|---|
| | | voltage | EQE | LT95 | | (×10⁵s⁻¹) |
| | | (%, | (%, | (%, | | (%, |
| | | relative | relative | relative | FWHM | relative |
| | Dopant | value) | value) | value) | (nm) | value) |
| Comparative | RD | 100 | 100 | 100 | 65 | 100 |
| Example 1 | | | | | | |
| Present | Compound | 94.3 | 121 | 151 | 34 | 125 |
| Example 24 | 433 | | | | | |
| Present | Compound | 95.0 | 124 | 154 | 36 | 127 |
| Example 25 | 434 | | | | | |
| Present | Compound | 95.5 | 126 | 150 | 35 | 128 |
| Example 26 | 435 | | | | | |
| Present | Compound | 96.2 | 125 | 151 | 35 | 127 |
| Example 27 | 436 | | | | | |
| Present | Compound | 96.2 | 123 | 154 | 34 | 126 |
| Example 28 | 437 | | | | | |
| Present | Compound | 96.7 | 120 | 155 | 35 | 123 |
| Example 29 | 438 | | | | | |
| Present | Compound | 96.4 | 134 | 151 | 35 | 131 |
| Example 30 | 439 | | | | | |
| Present | Compound | 97.1 | 137 | 156 | 35 | 132 |
| Example 31 | 440 | | | | | |
| Present | Compound | 96.5 | 137 | 160 | 36 | 133 |
| Example 32 | 441 | | | | | |
| Present | Compound | 96.0 | 139 | 158 | 34 | 135 |
| Example 33 | 442 | | | | | |
| Present | Compound | 94.6 | 142 | 120 | 37 | 136 |
| Example 34 | 443 | | | | | |
| Present | Compound | 94.3 | 145 | 116 | 36 | 137 |
| Example 35 | 444 | | | | | |
| Present | Compound | 95.8 | 140 | 153 | 35 | 134 |
| Example 36 | 445 | | | | | |
| Present | Compound | 96.1 | 138 | 152 | 34 | 132 |
| Example 37 | 446 | | | | | |
| Present | Compound | 95.9 | 133 | 167 | 35 | 127 |
| Example 38 | 447 | | | | | |
| Present | Compound | 96.4 | 134 | 164 | 36 | 127 |
| Example 39 | 448 | | | | | |
| Present | Compound | 96.1 | 133 | 170 | 35 | 127 |
| Example 40 | 449 | | | | | |
| Present | Compound | 95.3 | 135 | 172 | 34 | 129 |
| Example 41 | 450 | | | | | |
| Present | Compound | 95.1 | 137 | 174 | 34 | 130 |
| Example 42 | 451 | | | | | |
| Present | Compound | 96.3 | 129 | 148 | 35 | 127 |
| Example 43 | 452 | | | | | |
| Present | Compound | 97.2 | 120 | 145 | 35 | 120 |
| Example 44 | 453 | | | | | |
| Present | Compound | 95.8 | 121 | 144 | 34 | 119 |
| Example 45 | 454 | | | | | |
| Present | Compound | 95.5 | 119 | 149 | 36 | 118 |
| Example 46 | 455 | | | | | |
| Present | Compound | 95.7 | 119 | 152 | 34 | 115 |
| Example 47 | 456 | | | | | |
| Present | Compound | 95.7 | 115 | 120 | 35 | 114 |
| Example 48 | 457 | | | | | |
| Present | Compound | 96.0 | 110 | 117 | 35 | 112 |
| Example 49 | 458 | | | | | |
| Present | Compound | 96.4 | 118 | 121 | 36 | 118 |
| Example 50 | 459 | | | | | |
| Present | Compound | 96.1 | 114 | 115 | 35 | 117 |
| Example 51 | 460 | | | | | |
| Present | Compound | 96.0 | 134 | 177 | 36 | 130 |
| Example 52 | 461 | | | | | |
| Present | Compound | 96.5 | 135 | 181 | 35 | 129 |
| Example 53 | 462 | | | | | |
| Present | Compound | 95.8 | 138 | 180 | 35 | 133 |
| Example 54 | 463 | | | | | |
| Present | Compound | 96.5 | 121 | 149 | 34 | 124 |
| Example 55 | 464 | | | | | |
| Present | Compound | 96.1 | 127 | 137 | 35 | 122 |
| Example 56 | 465 | | | | | |
| Present | Compound | 96.8 | 123 | 152 | 36 | 121 |
| Example 57 | 466 | | | | | |

RD as the dopant compound of the light-emitting layer in Comparative Example 1 of the present disclosure has a structural difference from the compound represented by the Chemical Formula 1 in Present Example of the present disclosure in that no additional ring is introduced into a 6-membered ring into which X₁ is introduced.

As can be identified from the results in Table 1 and Table 2, the organic electroluminescent device in which the organometallic compound used in each of Present Examples 1 to 57 of the present disclosure is used as the dopant of the light-emitting layer has lowered driving voltage, improved external quantum Efficiency (EQE) and lifespan (LT95), and improved color purity due to the narrow full width at half maximum (FWHM), compared to Comparative Example 1.

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure can be implemented in various modified manners within the scope not departing from the technical idea of the present disclosure. Accordingly, the embodiments disclosed in the present disclosure are not intended to limit the technical idea of the present disclosure, but to describe the present disclosure. The scope of the technical idea of the present disclosure is not limited by the embodiments. Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. An organometallic compound represented by Chemical Formula 1: 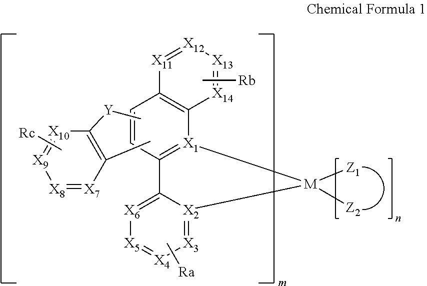
where in the Chemical Formula 1,
M represents a central coordination metal, and includes one selected from a group consisting of molybdenum (Mo), tungsten (W), rhenium (Re), ruthenium (Ru), osmium (Os), rhodium (Rh), iridium (Ir), palladium (Pd), platinum (Pt) and gold (Au);
Y is the same as or different from each other, and independently represents one selected from a group consisting of BR₁, CR₁R₂, C═O, C═NR₁, SiR₁R₂, NR₁, PR₁, AsR₁, SbR₁, BiR₁, P(O)R₁, P(S)R₁, P(Se)R₁, As(O)R₁, As(S)R₁, As(Se)R₁, Sb(O)R₁, Sb(S)R₁, Sb(Se)R₁, Bi(O)R1, Bi(S)R₁, Bi(Se)R₁, oxygen (O), sulfur (S), cerium (Se), tellurium (Te), SO, SO₂, SeO, SeO₂, TeO, and TeO₂;
X₁ and X₂ are different from each other and each of X₁ and X₂ independently represents one selected from a group consisting of carbon (C), nitrogen (N) and phosphorus (P);
one of X₁ and X₂ is carbon (C) and the other thereof is one of nitrogen (N) or phosphorus (P);
each of R₁ and R₂ independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group;
each of Ra, Rb and Rc independently represents one selected from a group consisting of hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted A cyclic C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group; 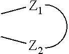
is a bidentate ligand;
m is an integer of 1, 2 or 3, n is an integer of 0, 1 or 2, and m+n is an oxidation number of the metal M.

2. The organometallic compound of claim 1, wherein the compound represented by the Chemical Formula 1 includes a compound represented by one selected from a group consisting of following Chemical Formula 2 to Chemical Formula 3: 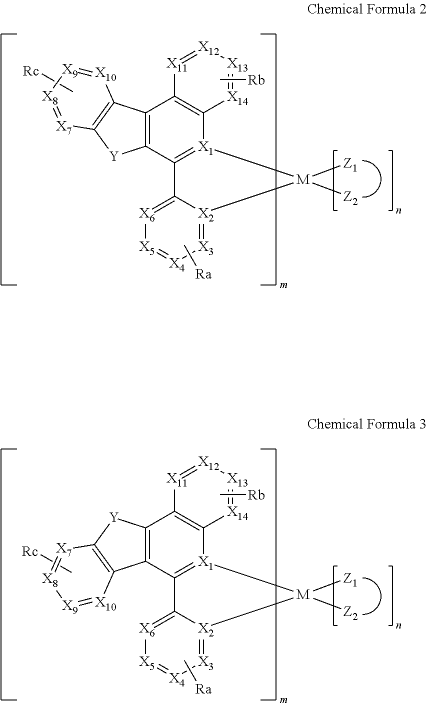
where in each of the Chemical Formula 2 to Chemical Formula 3,
X₃, X₄, X₅, X₆, X₇, X₈, X₉, X₁₀, X₁₁, X₁₂, X₁₃ and X₁₄ are the same as or different from each other, and each of X₃, X₄, X₅, X₆, X₇, X₈, X₉, X₁₀, X₁₁, X₁₂, X₁₃ and X₁₄ independently represents CR, nitrogen (N), phosphorus (P), sulfur (S) and oxygen (O);
adjacent groups selected from a group consisting of X₃, X₄, X₅, X₆, X₇, X₈, X₉, X₁₀, X₁₁, X₁₂, X₁₃ and X₁₄ are combined with each other to form a C5 ring structure or a C6 ring structure;
R independently represents hydrogen, deuterium, halogen, a hydroxyl group, a cyano group, an nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group, and a phosphino group.

3. The organometallic compound of claim 1, wherein the compound represented by the Chemical Formula 1 includes a compound represented by one selected from a group consisting of following Chemical Formula 4 to Chemical Formula 11. 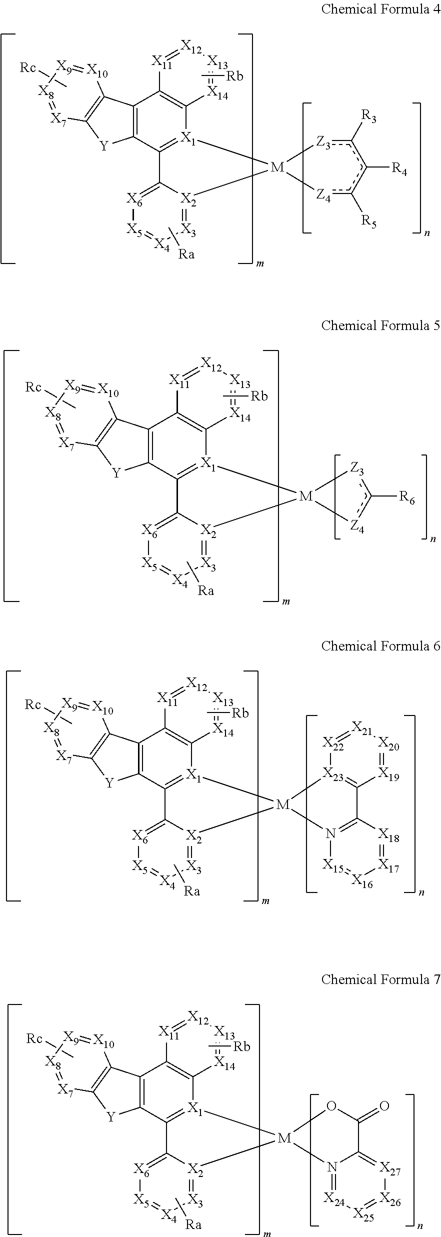 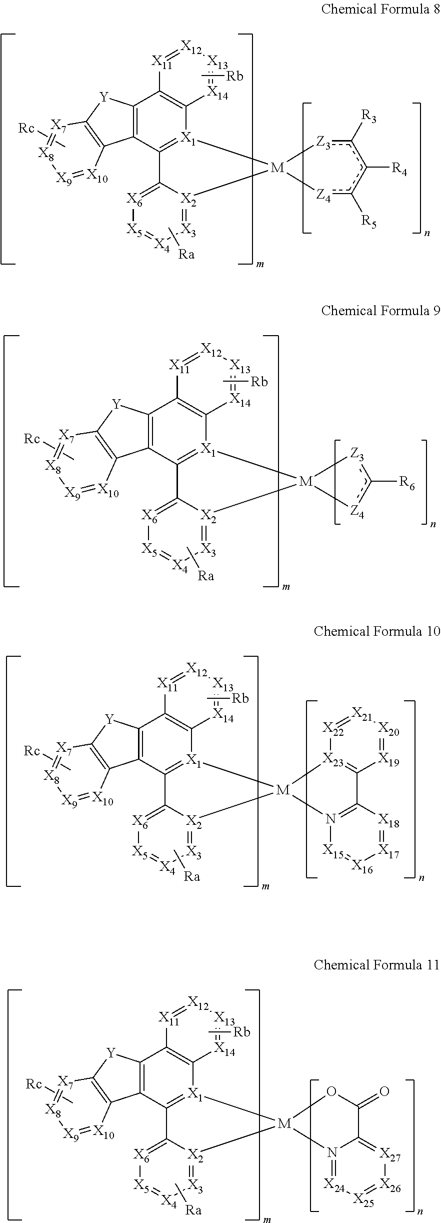
where in each of the Chemical Formula 4 to Chemical Formula 11,
X₁₅, X₁₆, X₁₇, X₁₈, X₁₉, X₂₀, X₂₁, X₂₂, X₂₃, X₂₄, X₂₅, X₂₆ and X₂₇ are the same as or different from each other, and each of X₁₅, X₁₆, X₁₇, X₁₈, X₁₉, X₂₀, X₂₁, X₂₂, X₂₃, X₂₄, X₂₅, X₂₆ and X₂₇ independently represents CR, nitrogen (N), phosphorus (P), sulfur (S) and oxygen (O);
adjacent groups selected from a group consisting of X₁₅, X₁₆, X₁₇, X₁₈, X₁₉, X₂₀, X₂₁, X₂₂, X₂₃, X₂₄, X₂₅, X₂₆ and X₂₇ are combined with each other to form a C5 ring structure or a C6 ring structure;
each of Z₃, Z₄ and Z₅ independently represents one selected from a group consisting of oxygen (O), sulfur (S) and NR₇;
each of R₃, R₄, R₅, R₆ and R₇ independently represents hydrogen, deuterium, halogen, a hydroxyl group, a cyano group, a nitro group, an amidino group, a hydrazine group, a hydrazone group, a substituted or unsubstituted C1-C20 alkyl group, a substituted or unsubstituted C3-C20 cycloalkyl group, a substituted or unsubstituted C1-C20 heteroalkyl group, a substituted or unsubstituted C7-C20 arylalkyl group, a substituted or unsubstituted C1-C20 alkenyl group, a substituted or unsubstituted C3-C20 cycloalkenyl group, a substituted or unsubstituted C1-C20 heteroalkenyl group, an alkynyl group, a substituted or unsubstituted C6-C30 aryl group, a substituted or unsubstituted C3-C30 a heteroaryl group, an alkoxy group, an amino group, a silyl group, an acyl group, a carbonyl group, a carboxylic acid group, an ester group, a nitrile group, an isonitrile group, a sulfanyl group, a sulfinyl group, a sulfonyl group and a phosphino group.

4. The organometallic compound of claim 1, wherein M represents iridium (Ir).

5. The organometallic compound of claim 1, wherein Y represents one selected from a group consisting of oxygen (O), sulfur (S) and CR₁R₂.

6. The organometallic compound of claim 1, wherein the compound represented by the Chemical Formula 1 includes one selected from a group consisting of following compounds 1 to 466:

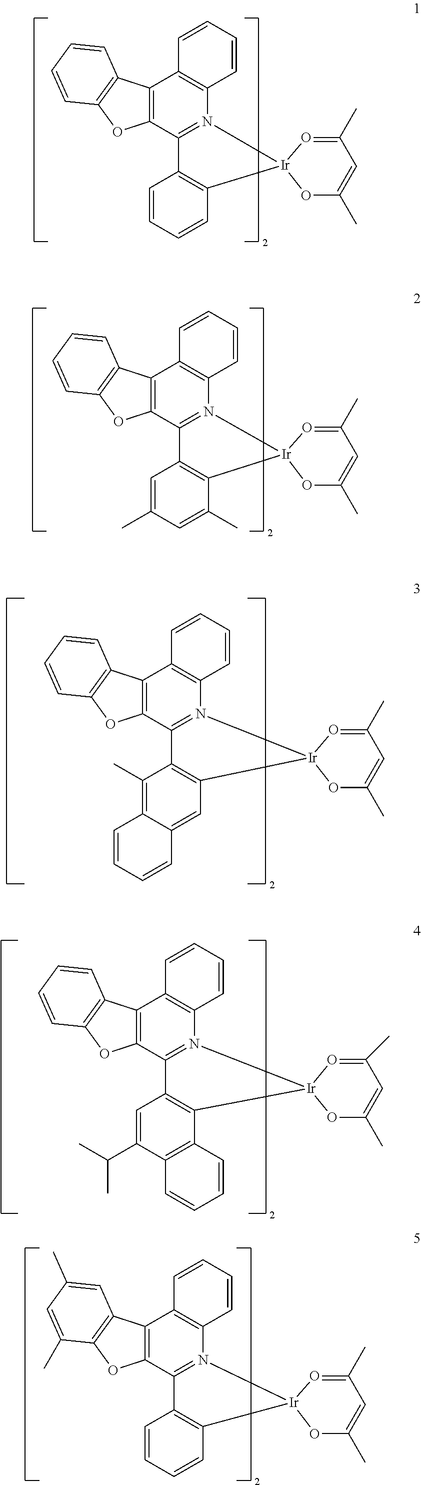

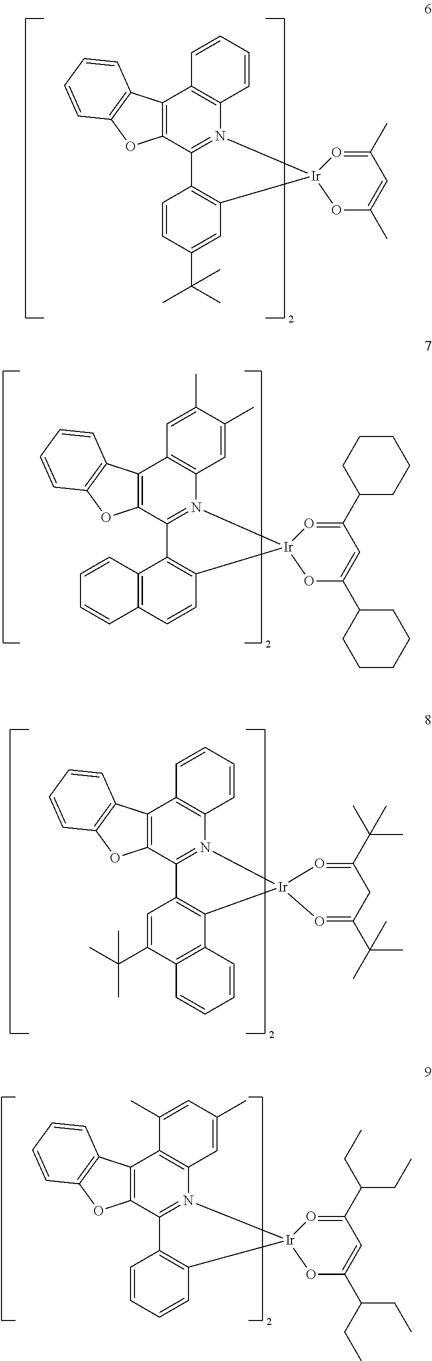

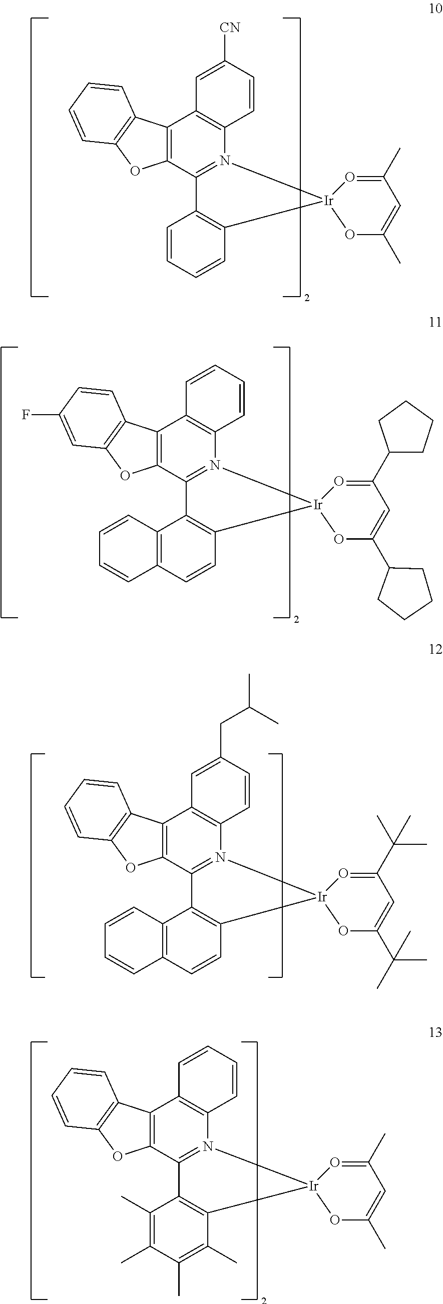

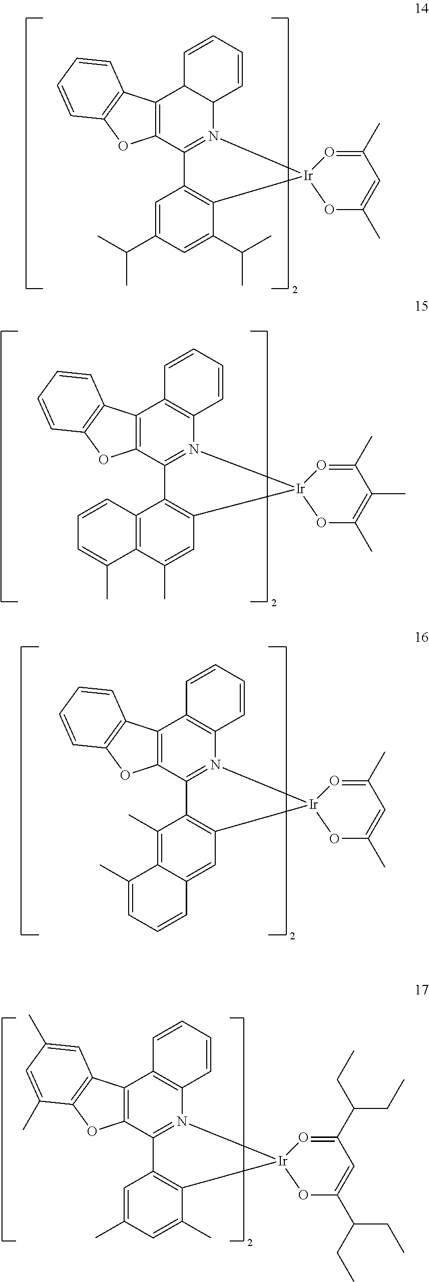

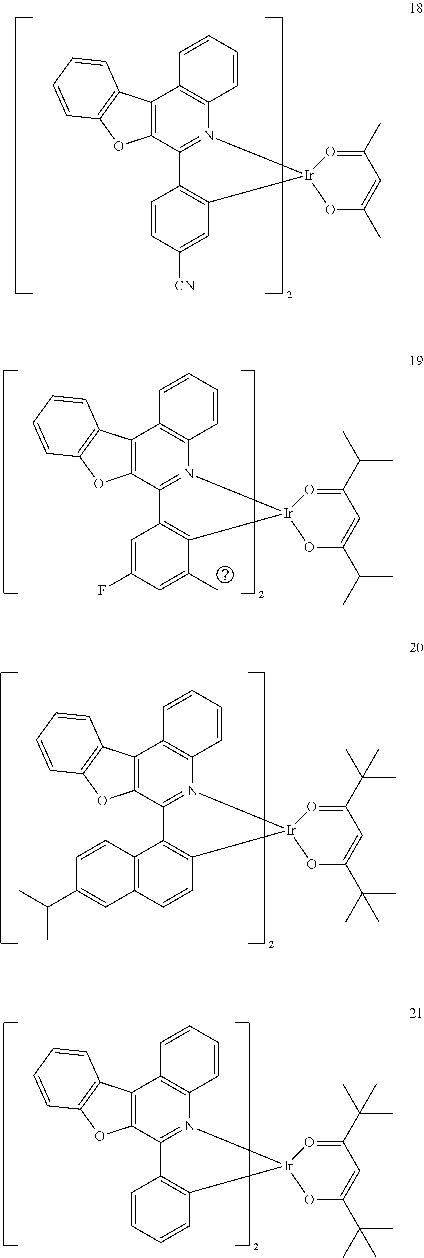

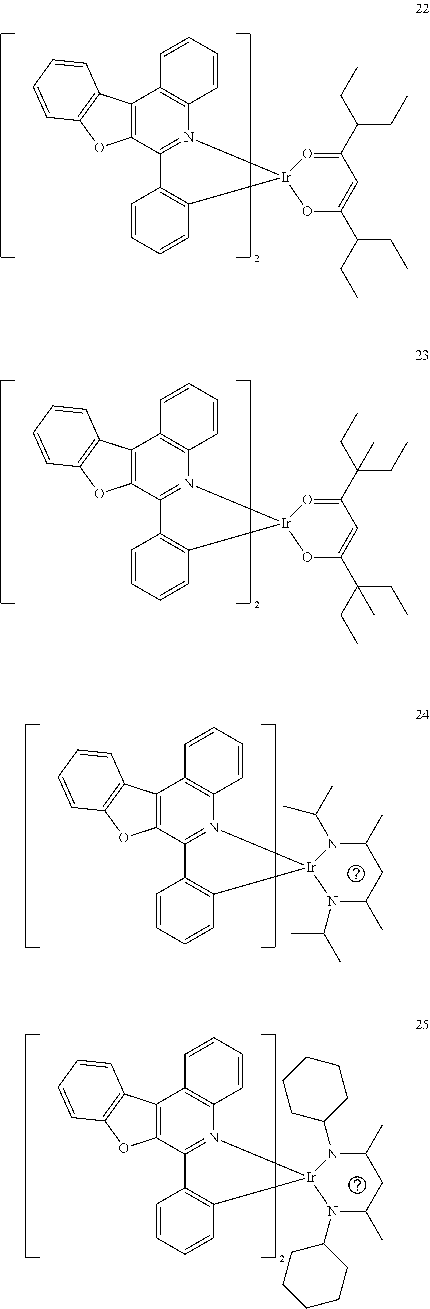

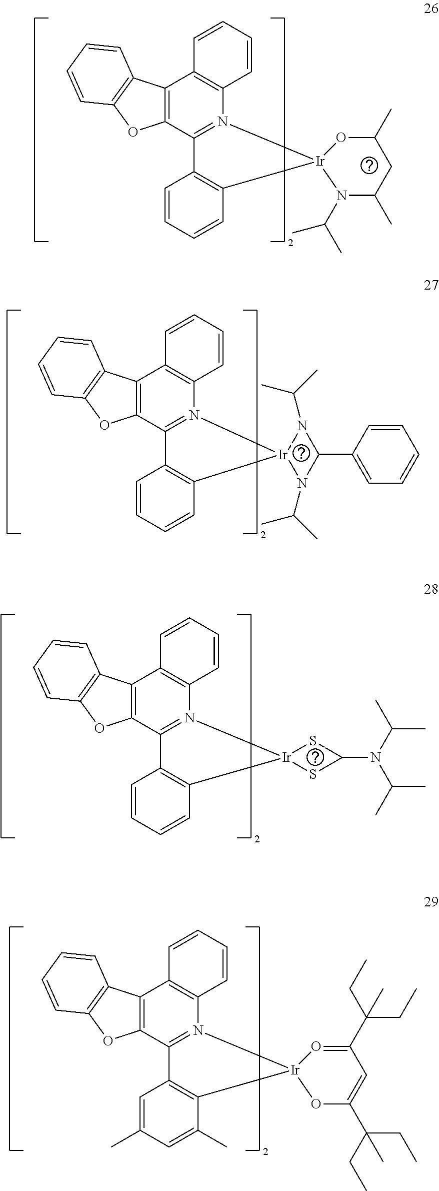

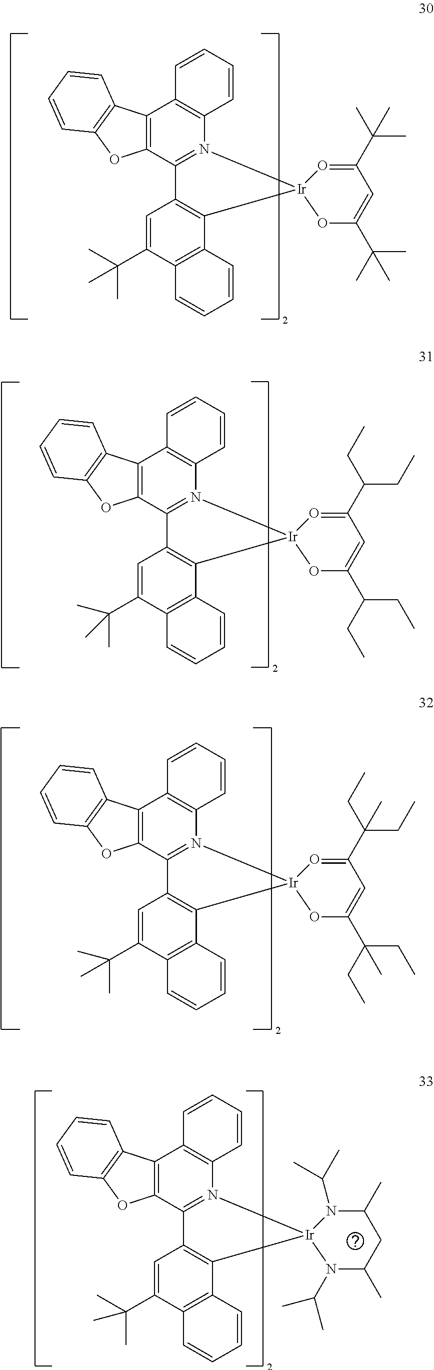

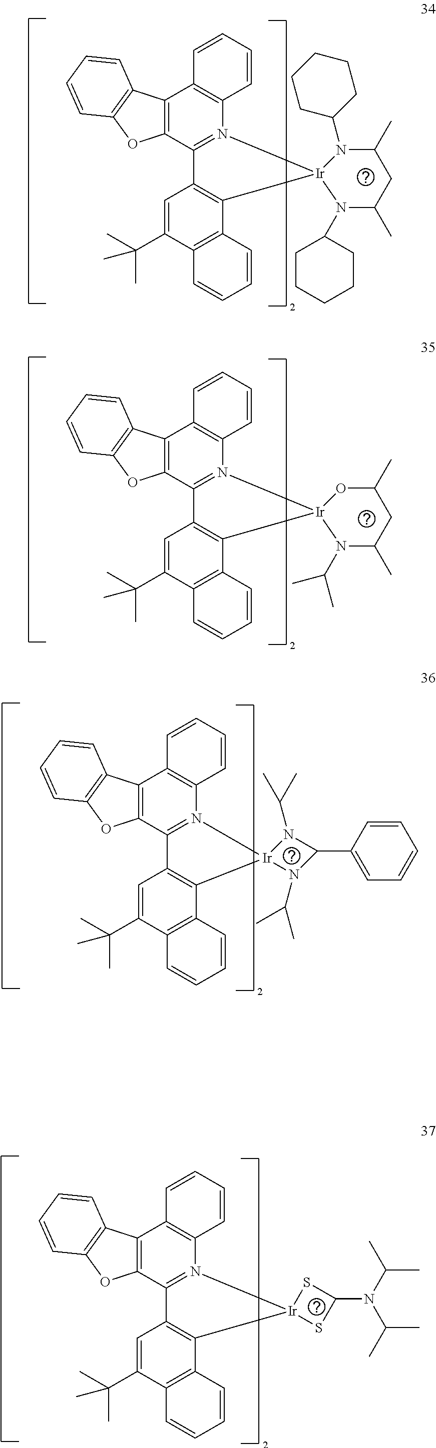

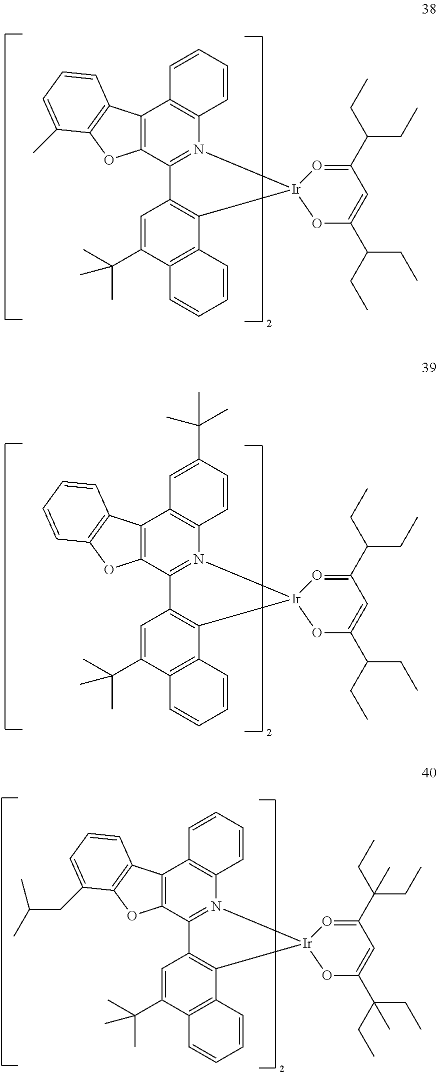

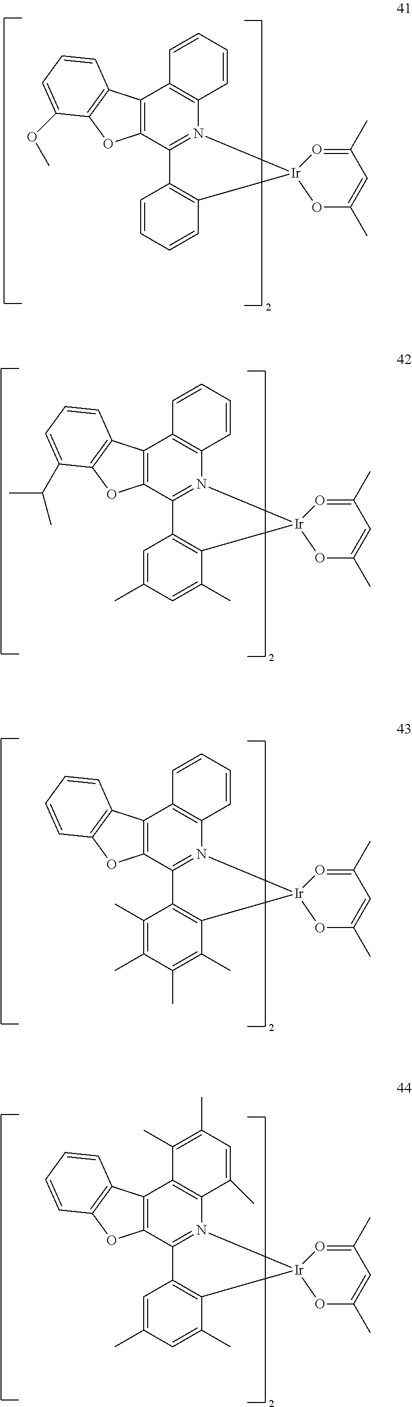

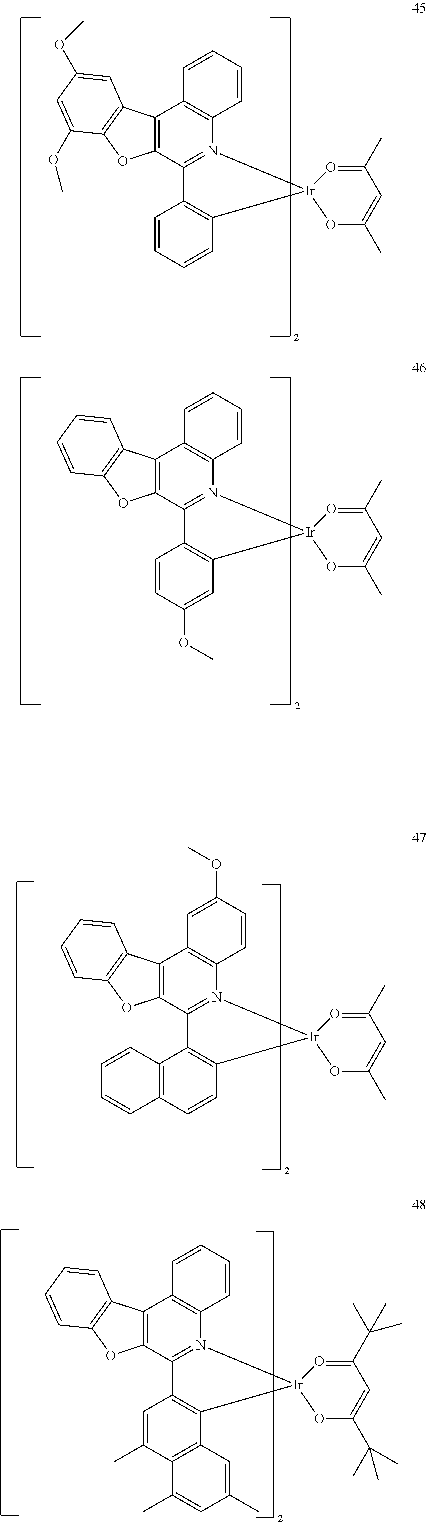

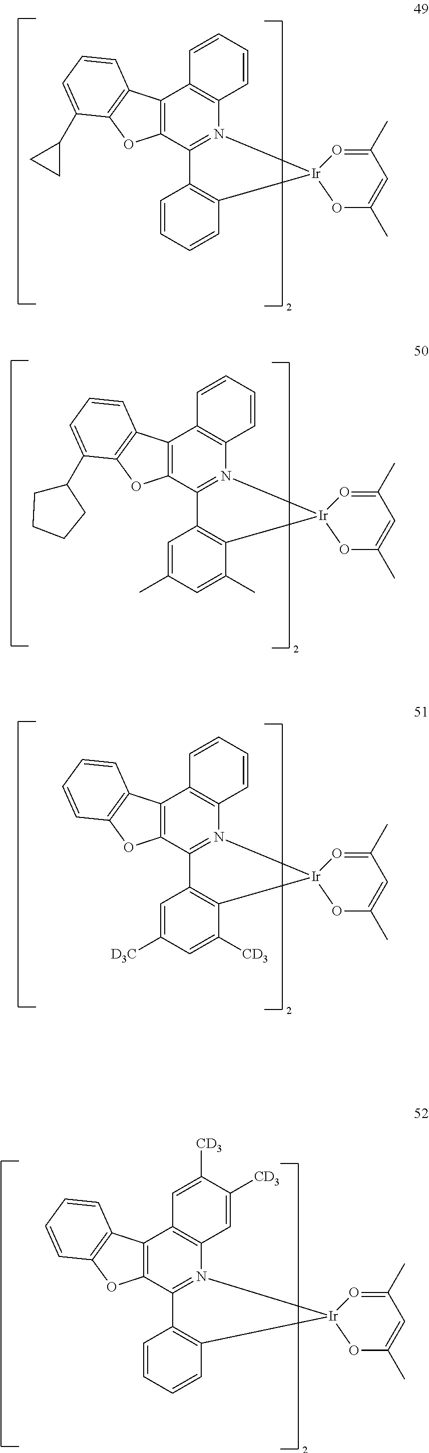

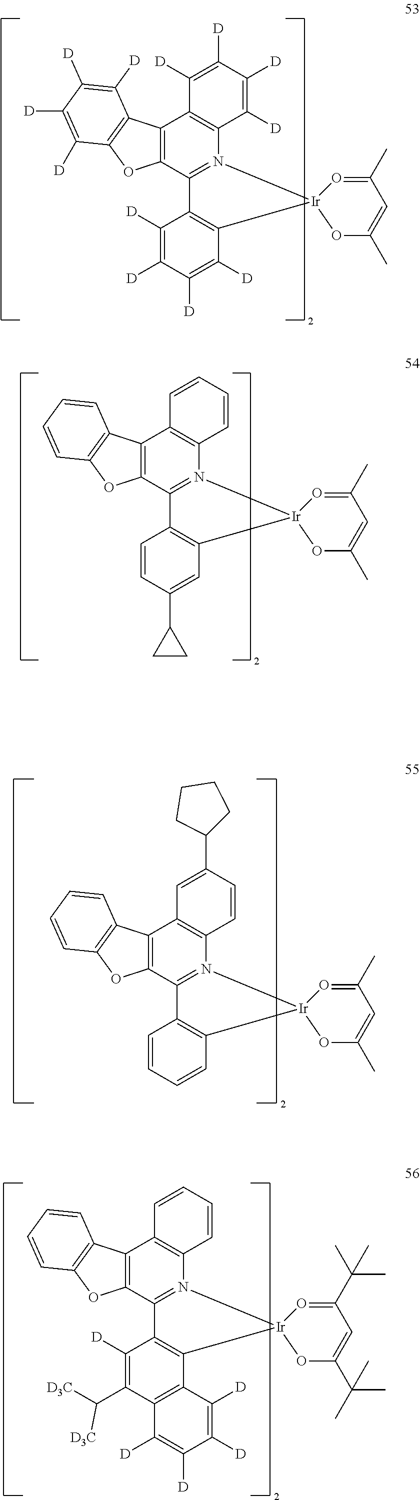

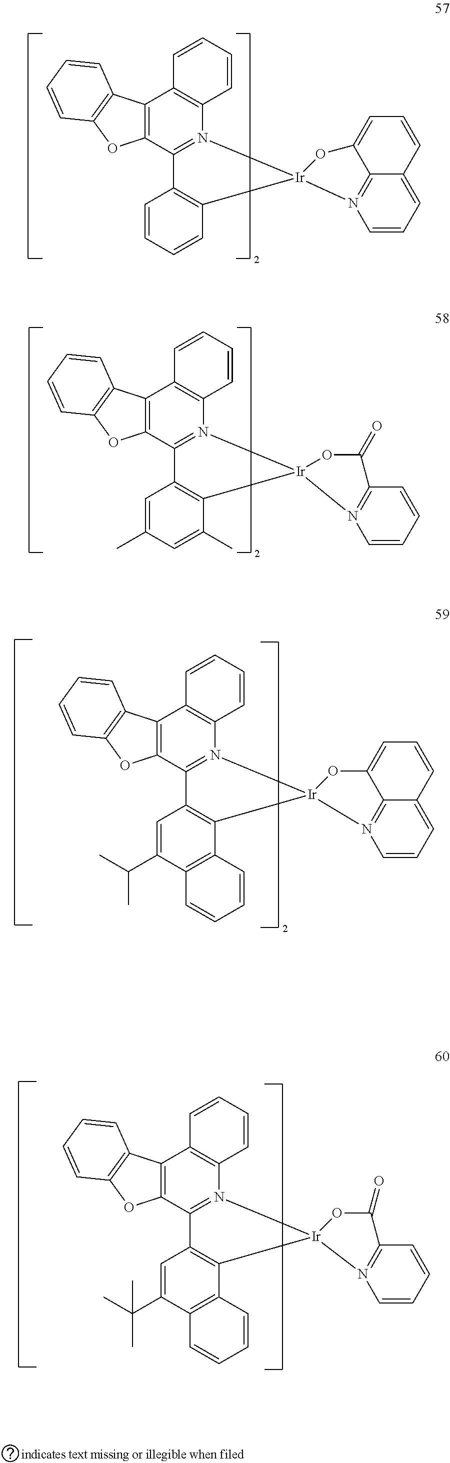

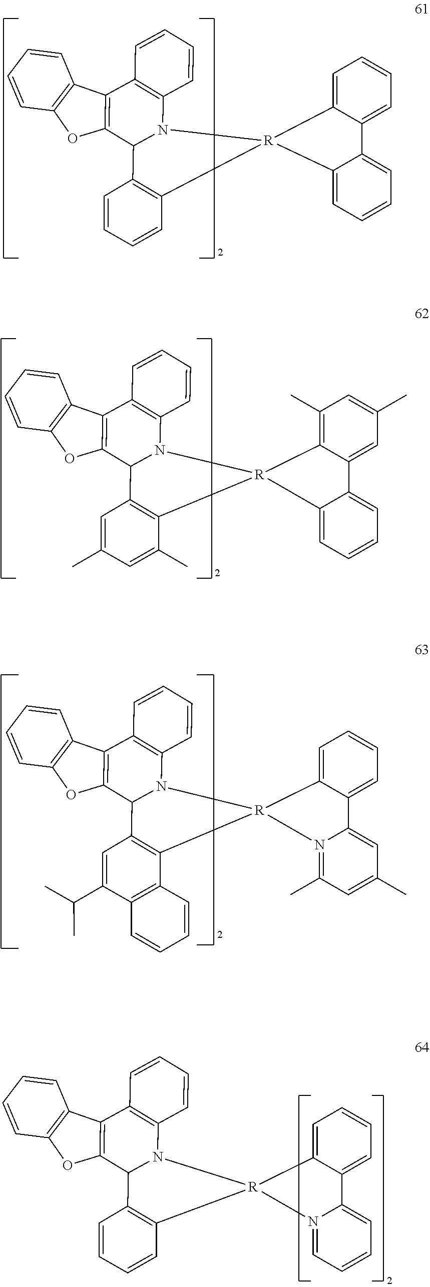

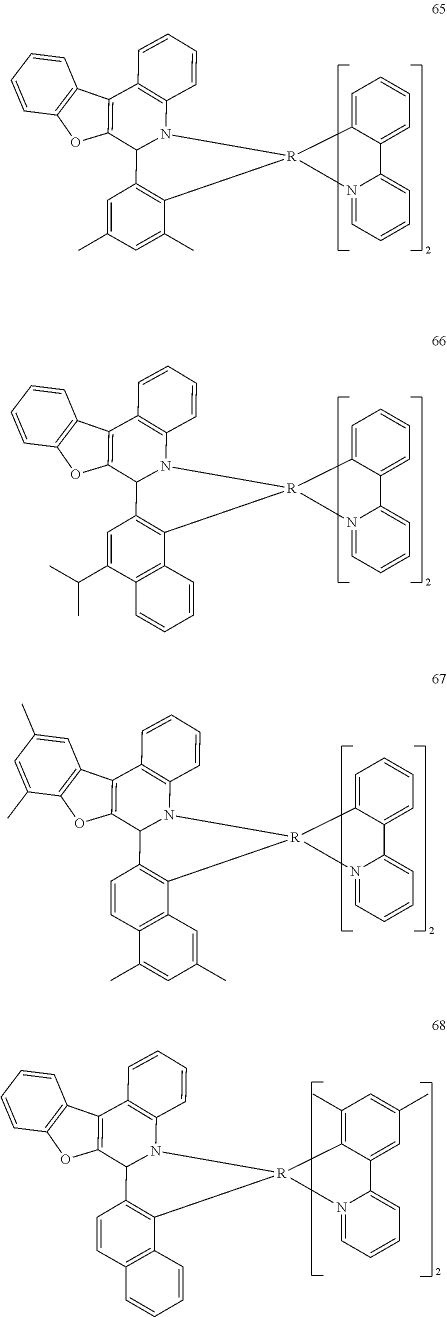

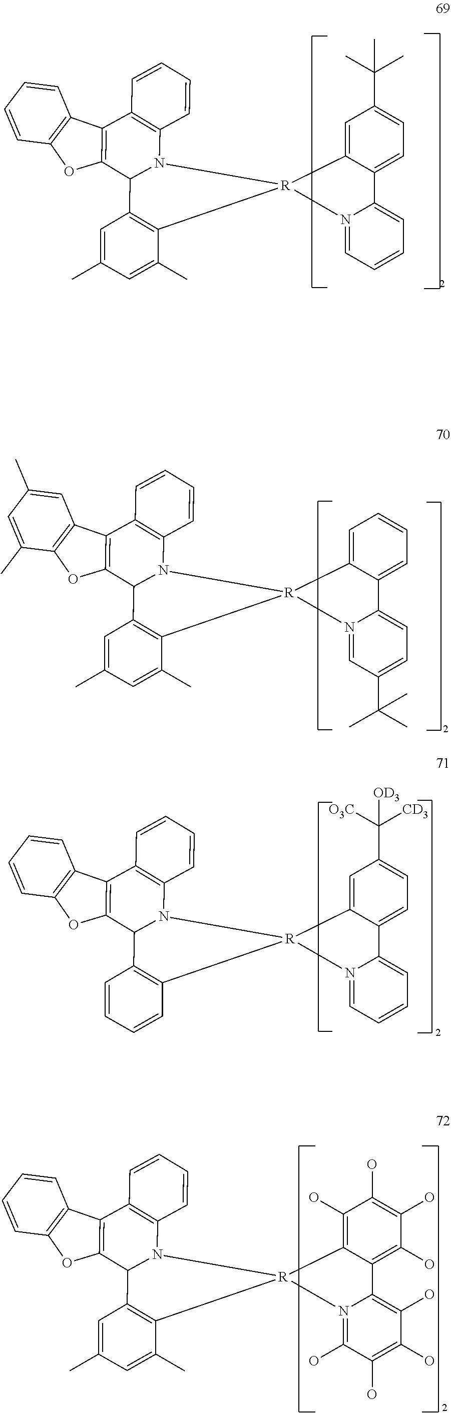

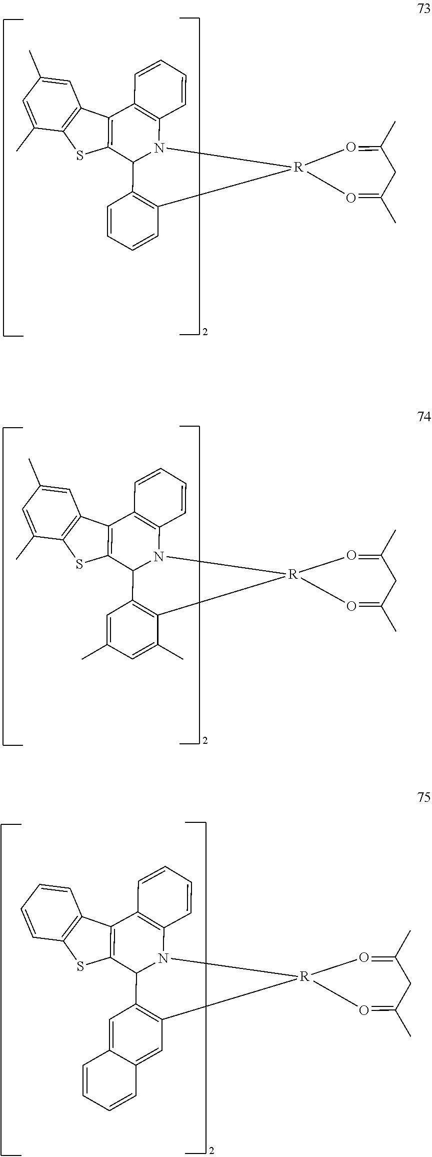

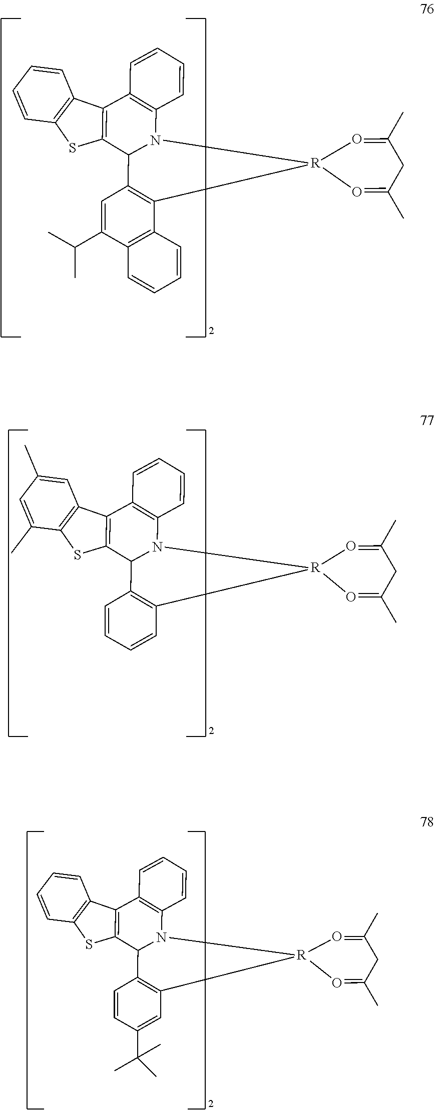

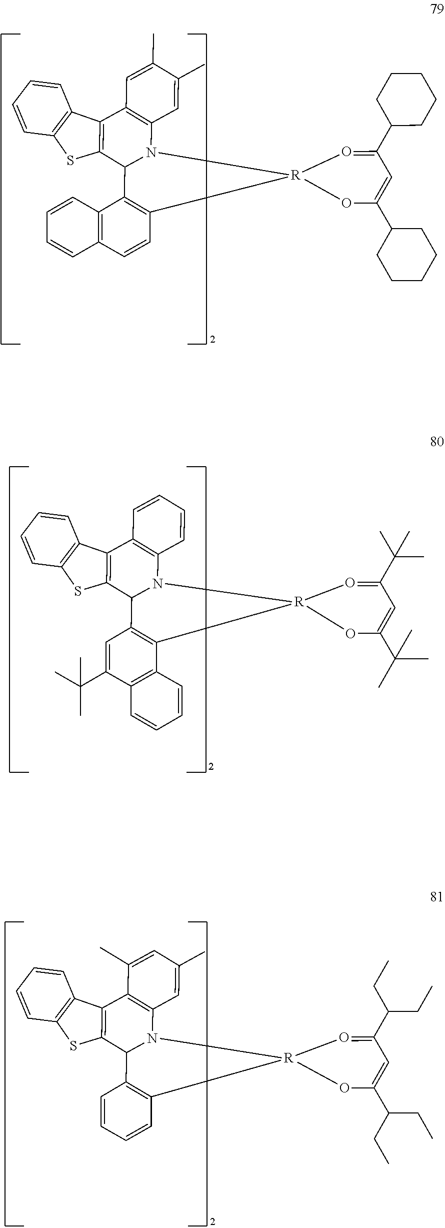

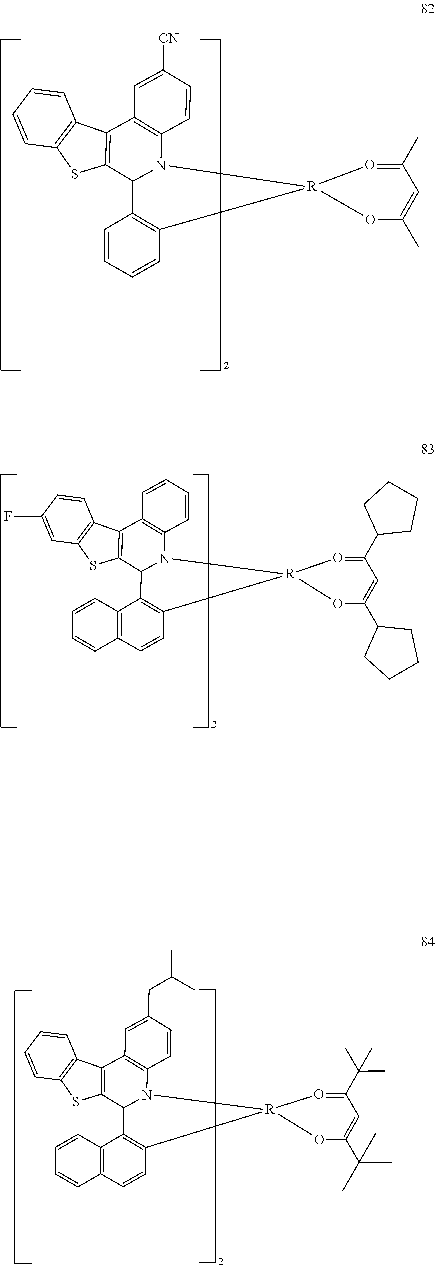

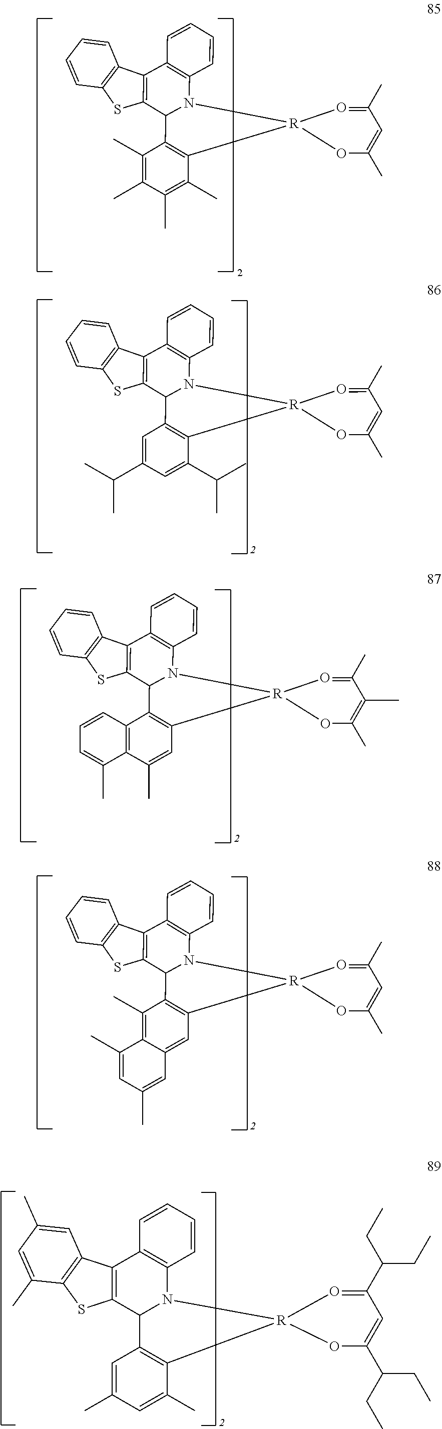

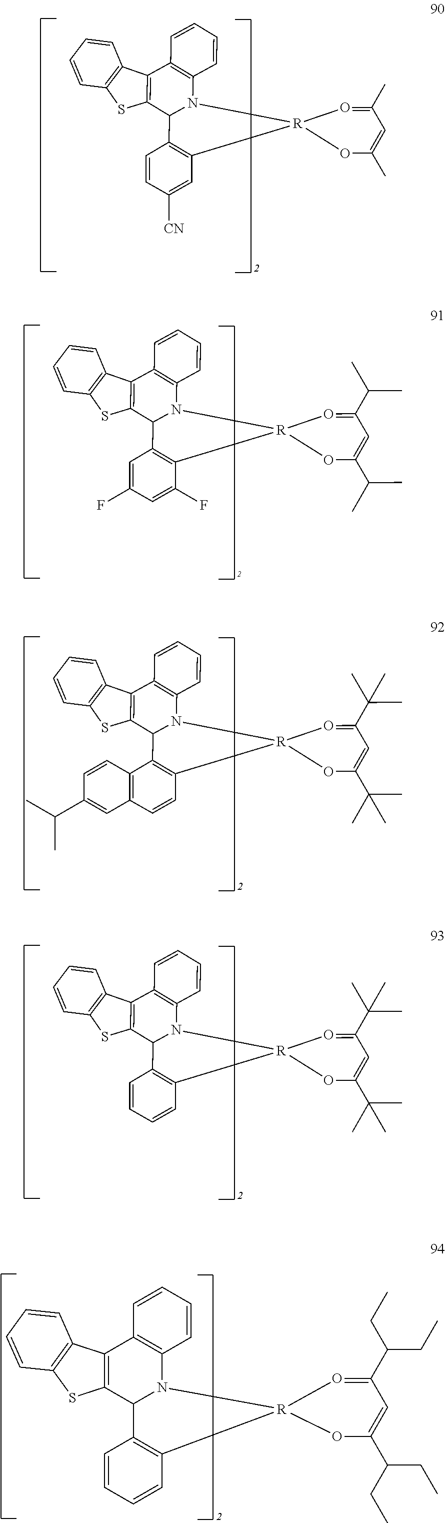

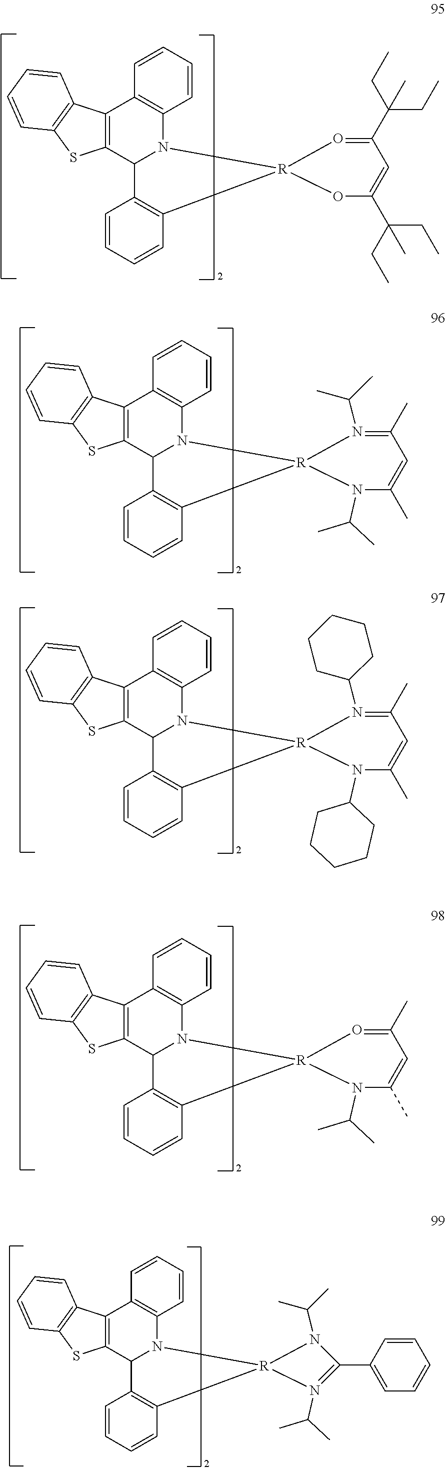

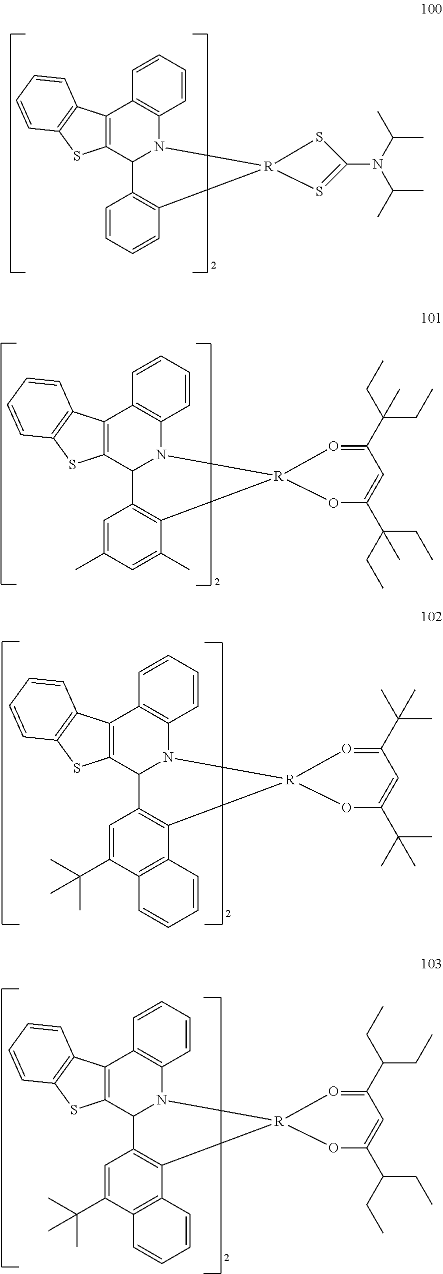

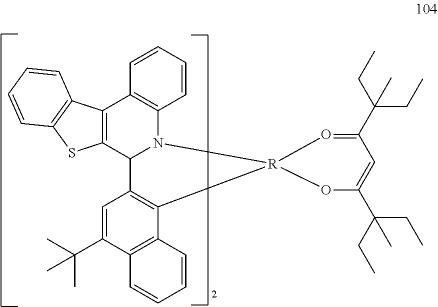

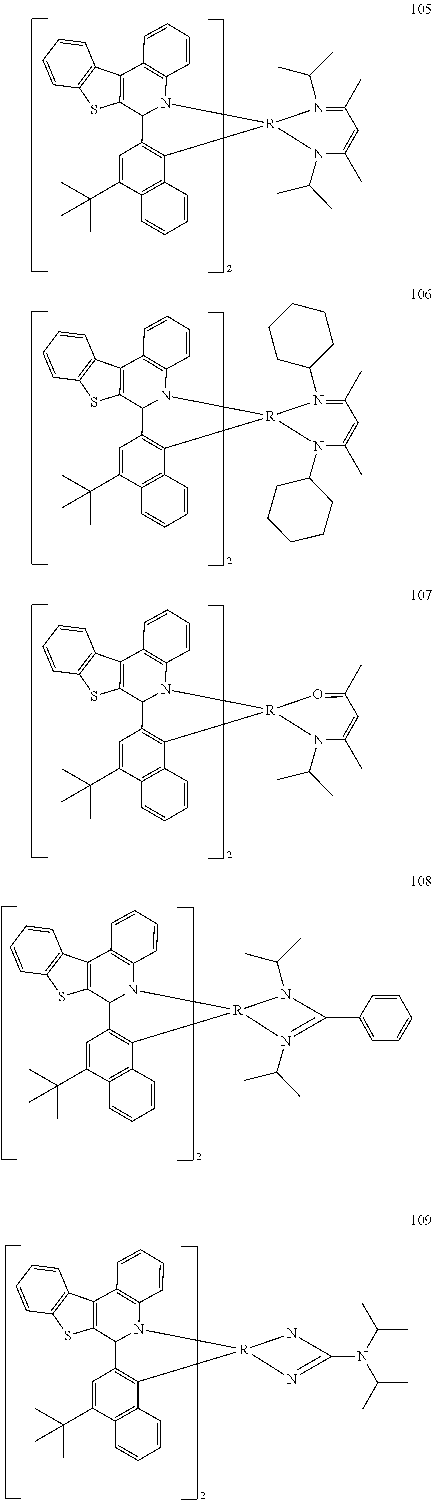

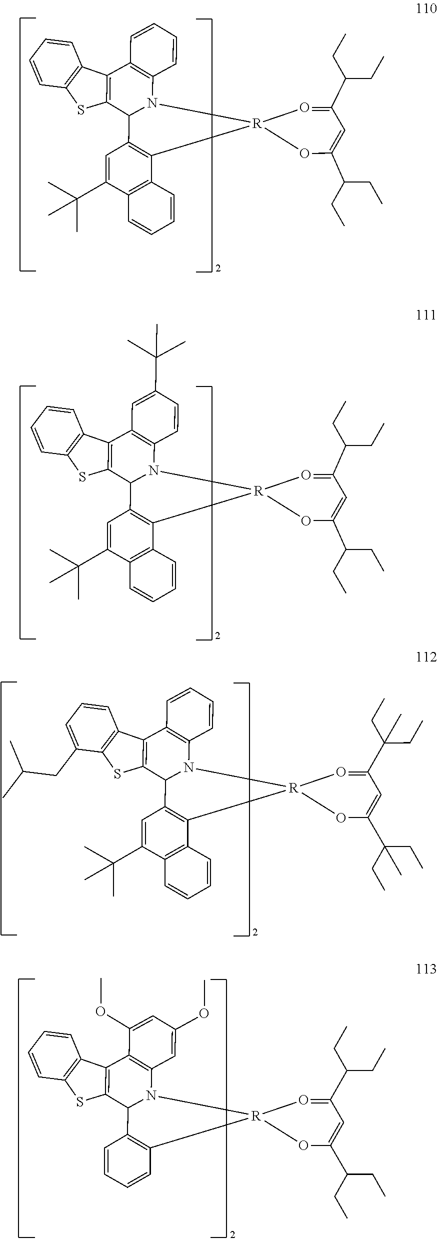

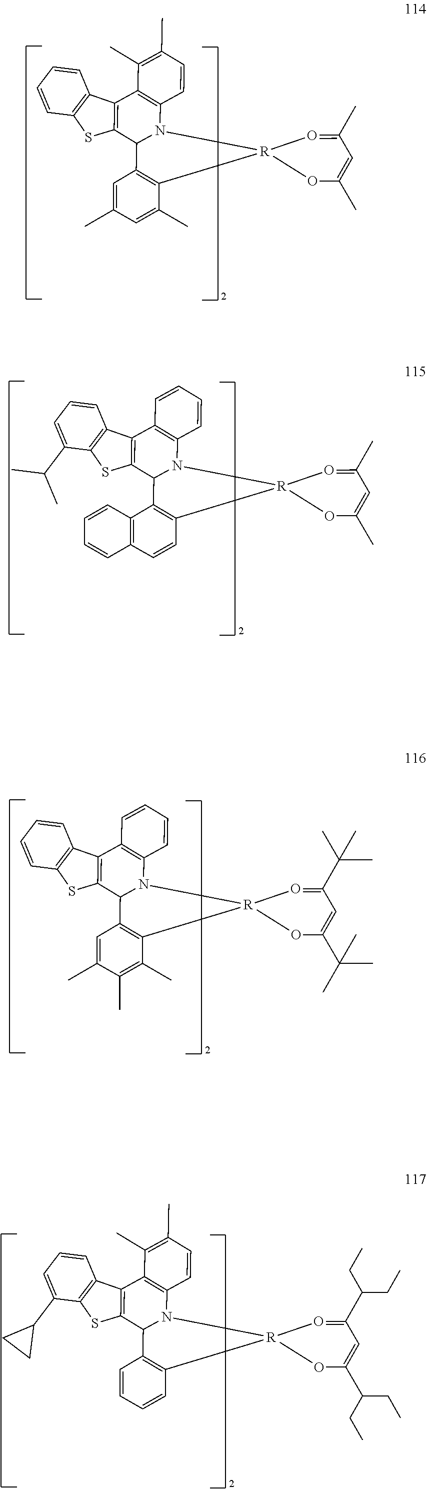

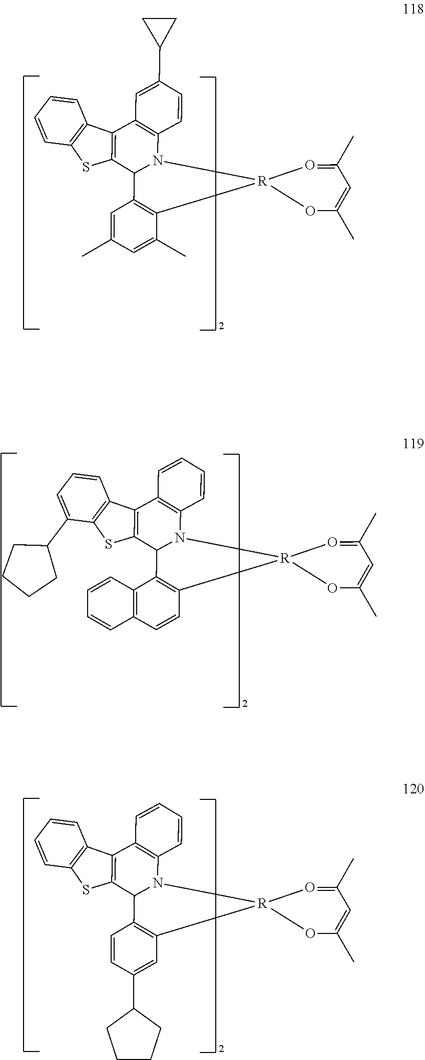

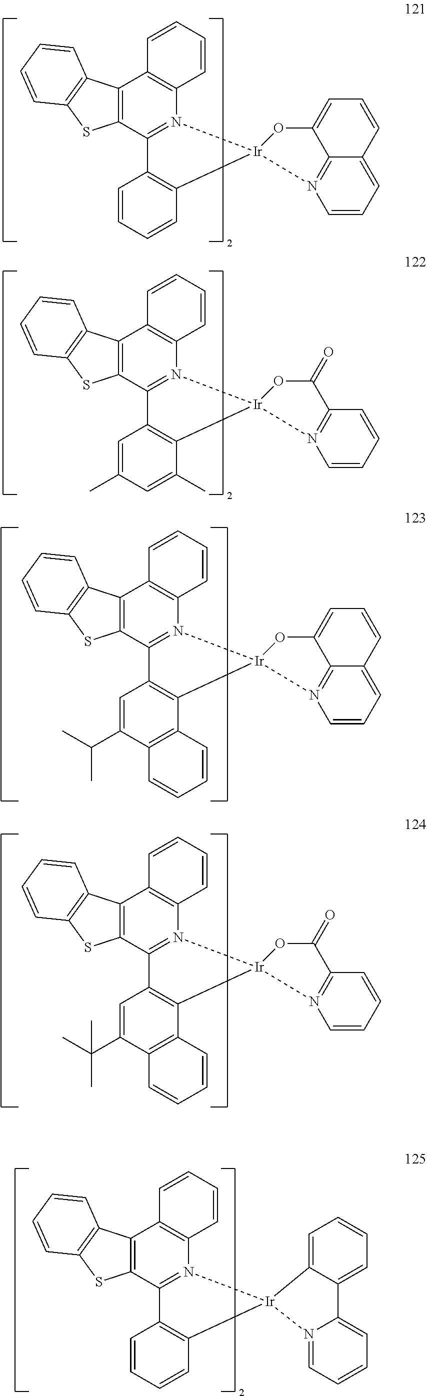

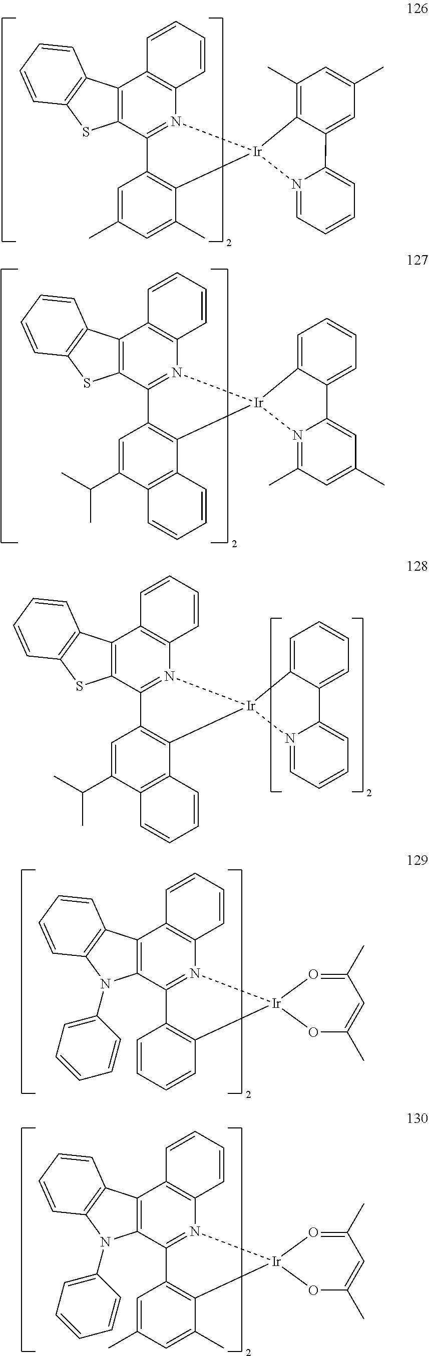

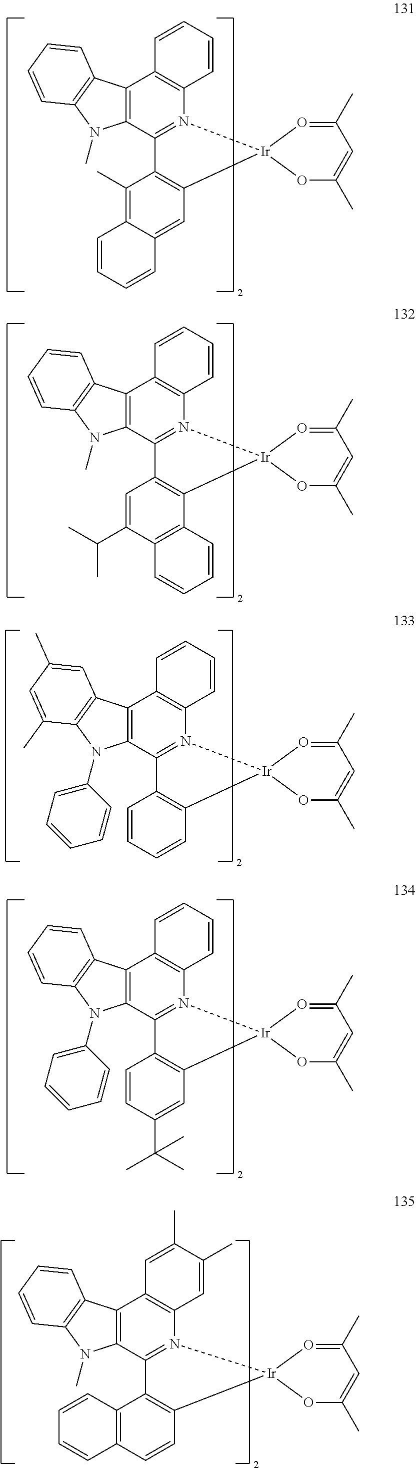

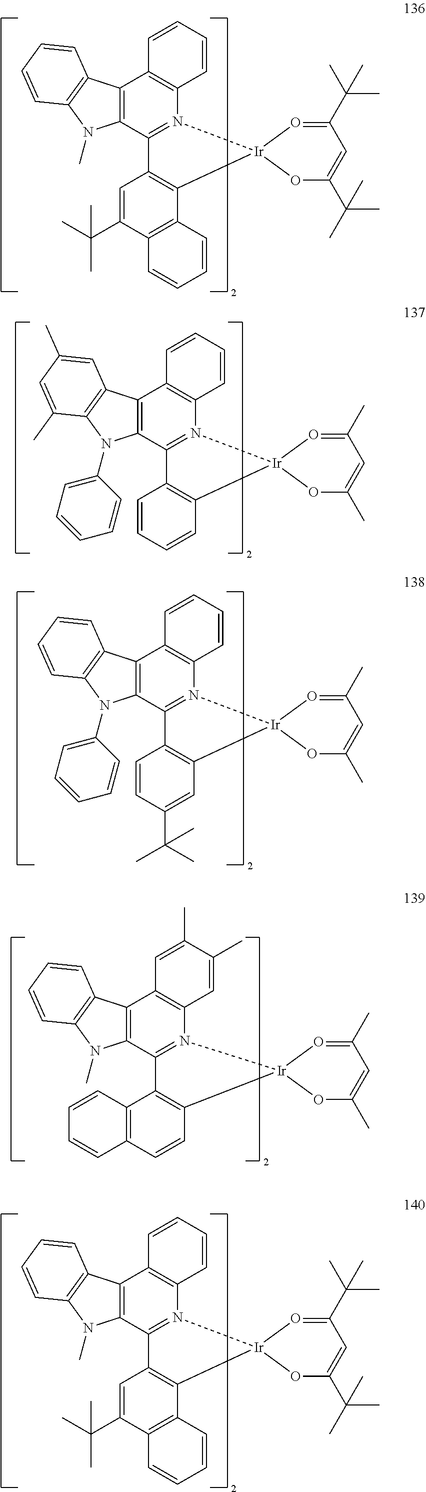

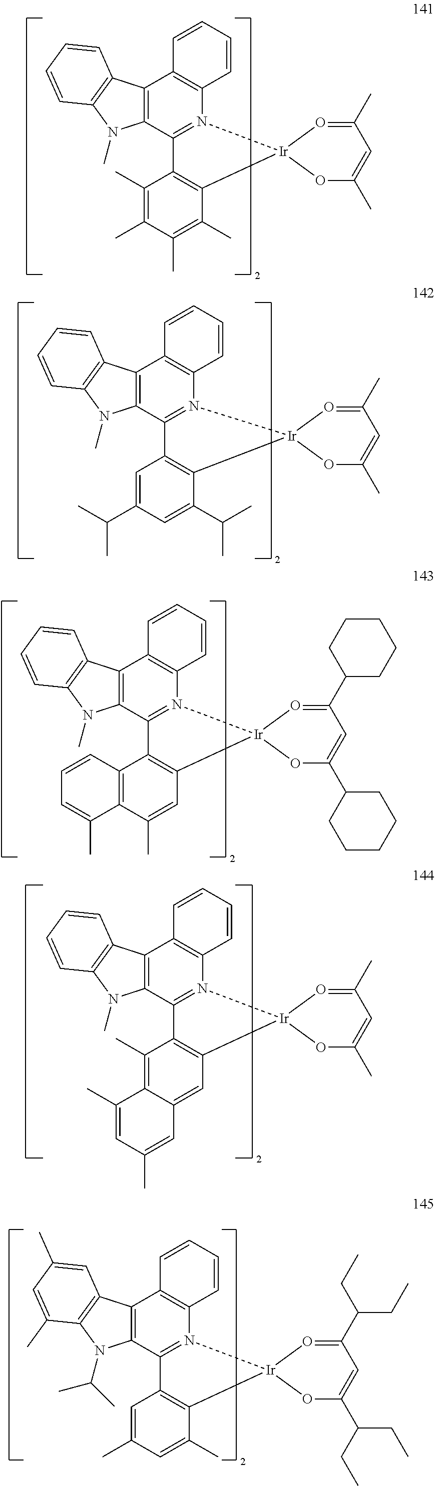

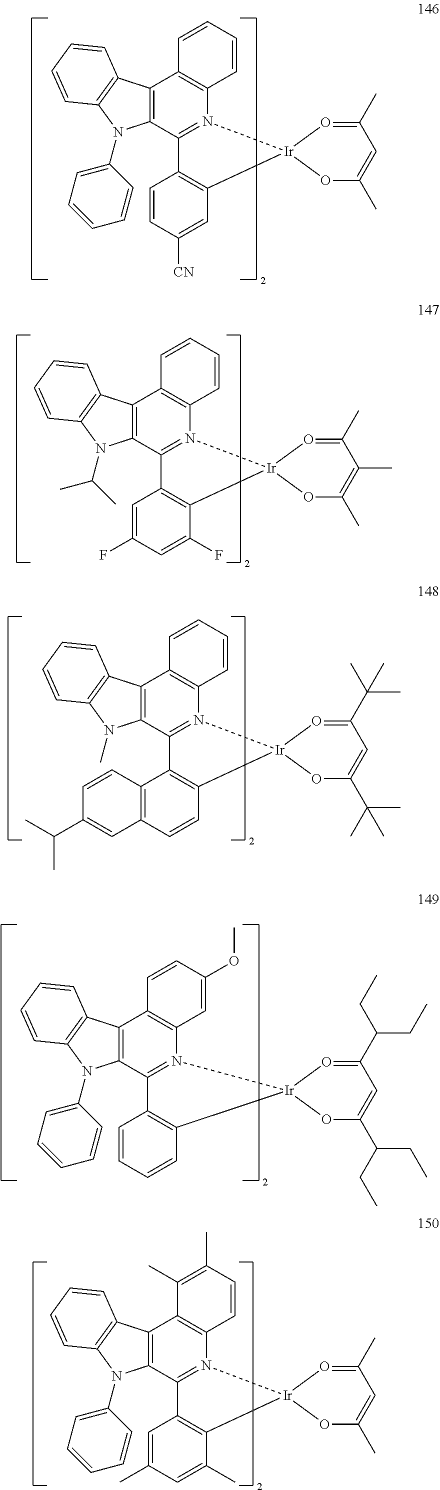

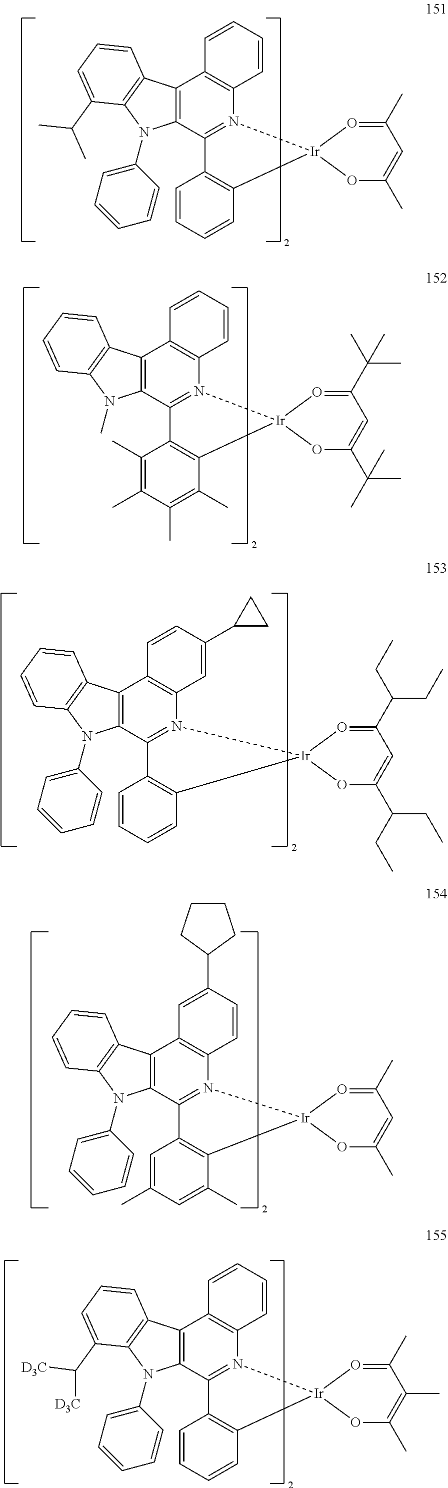

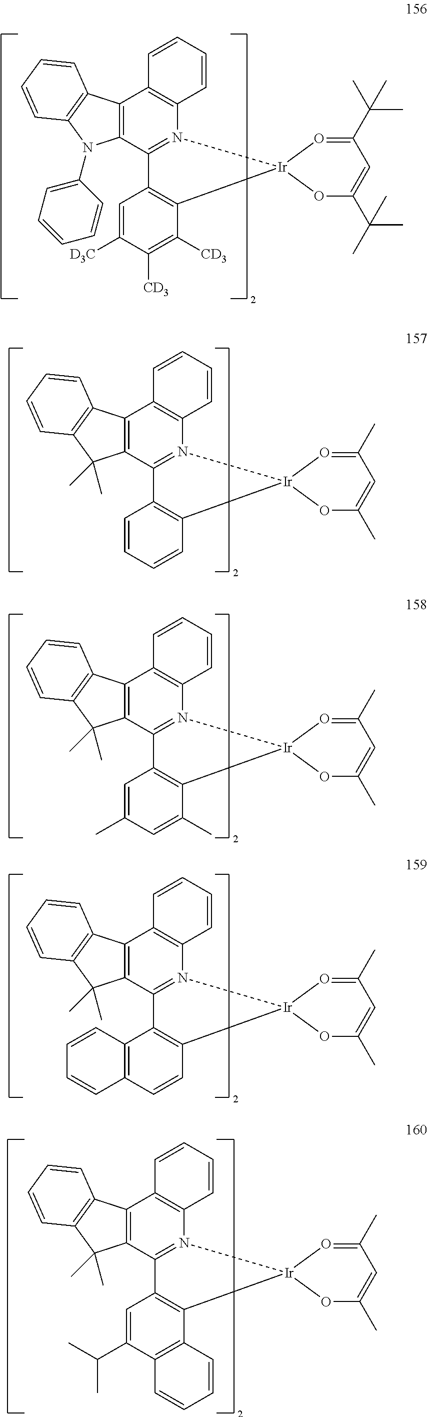

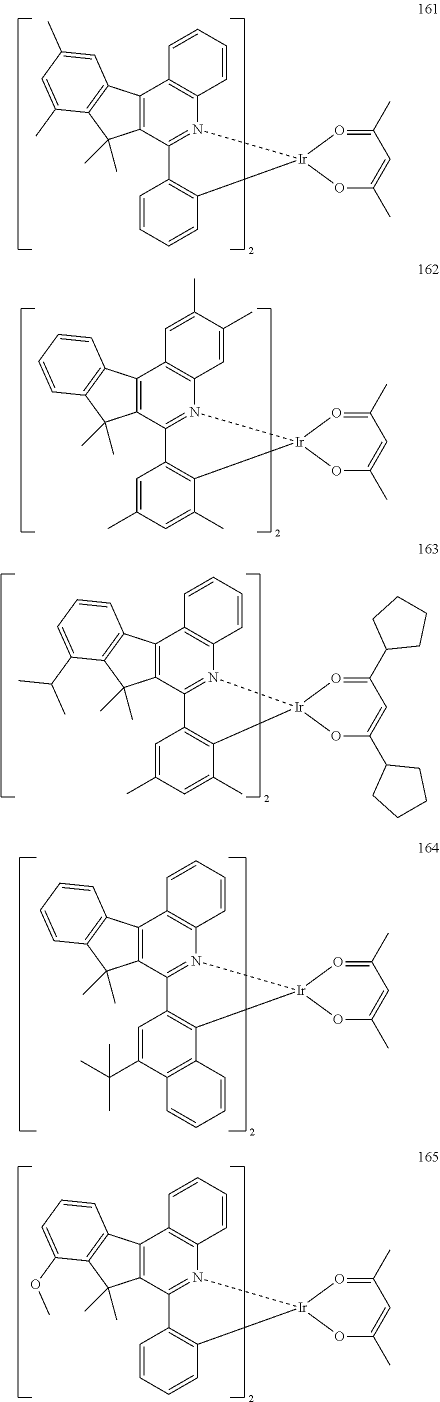

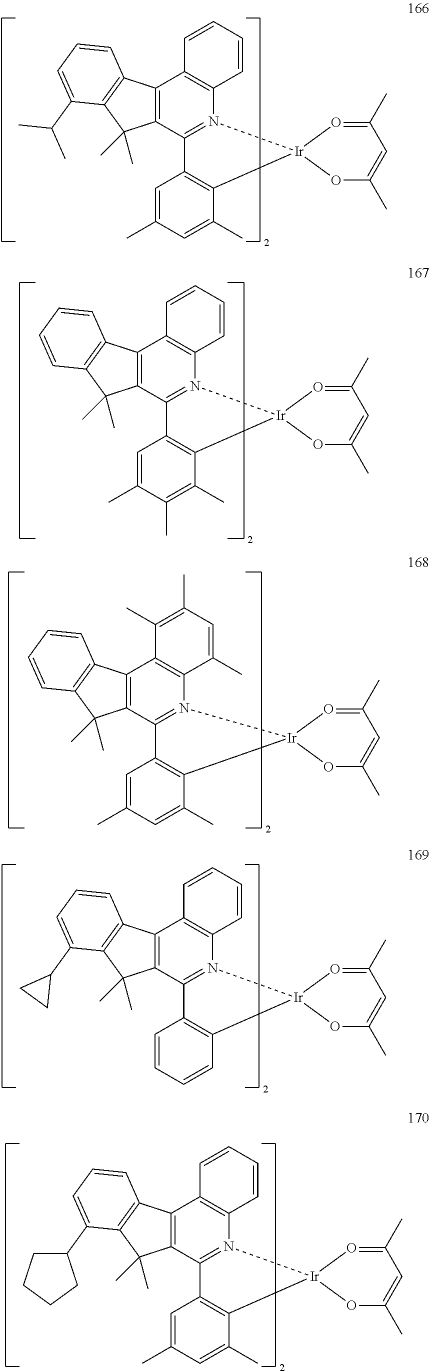

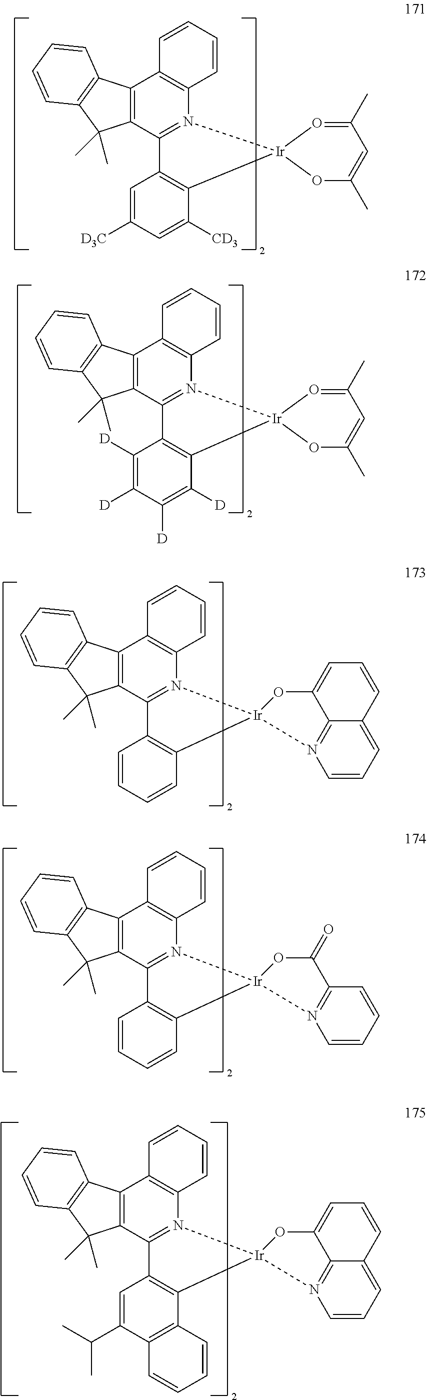

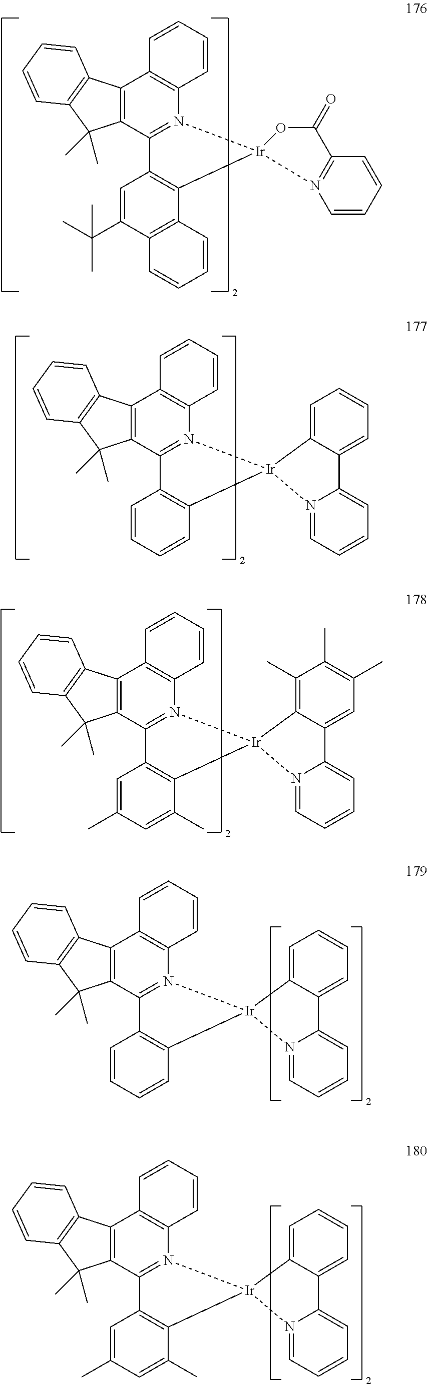

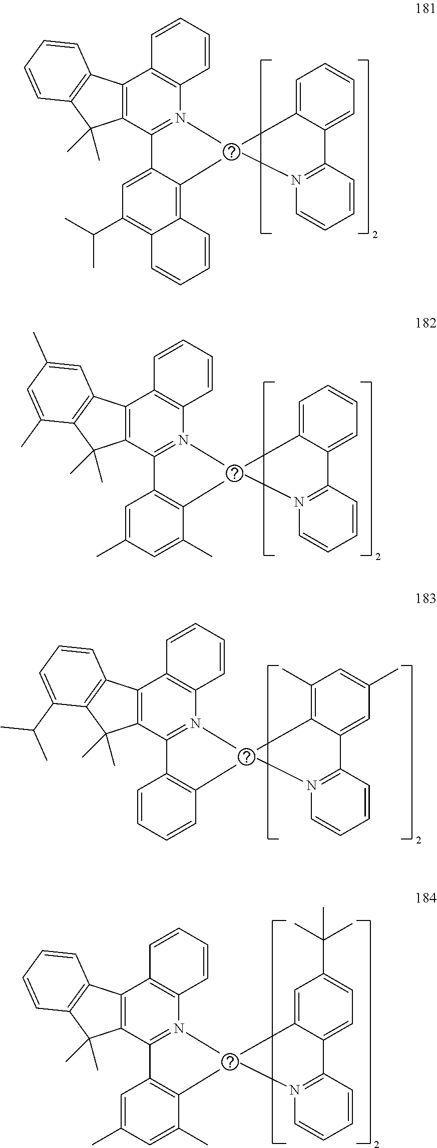

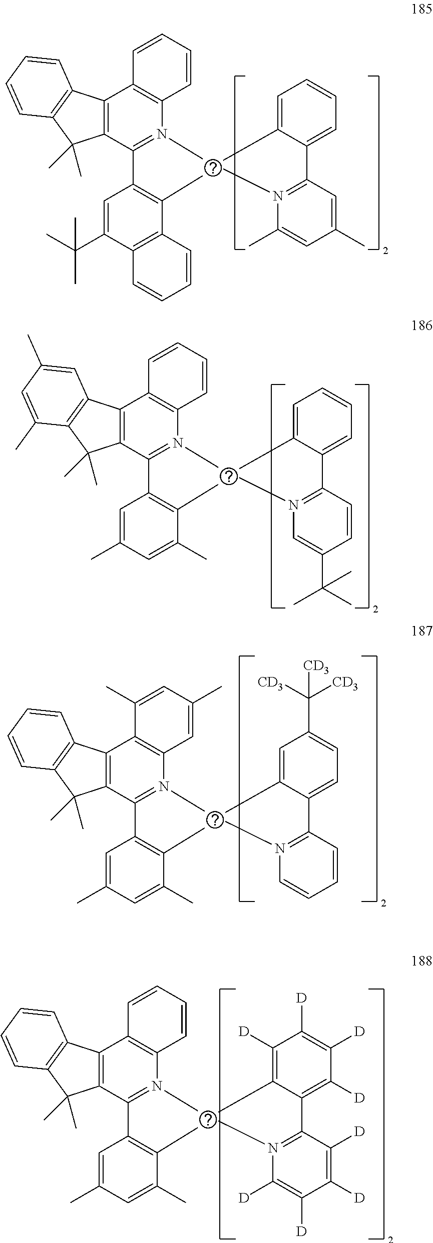

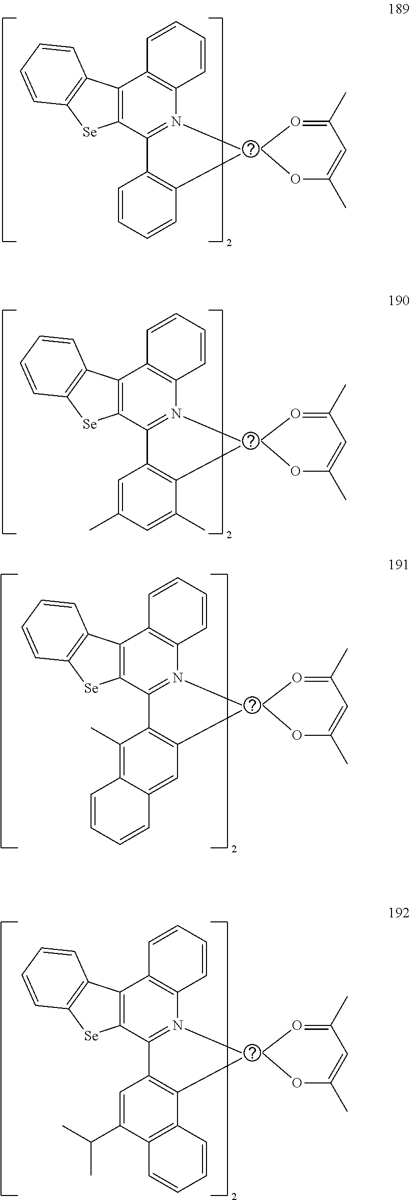

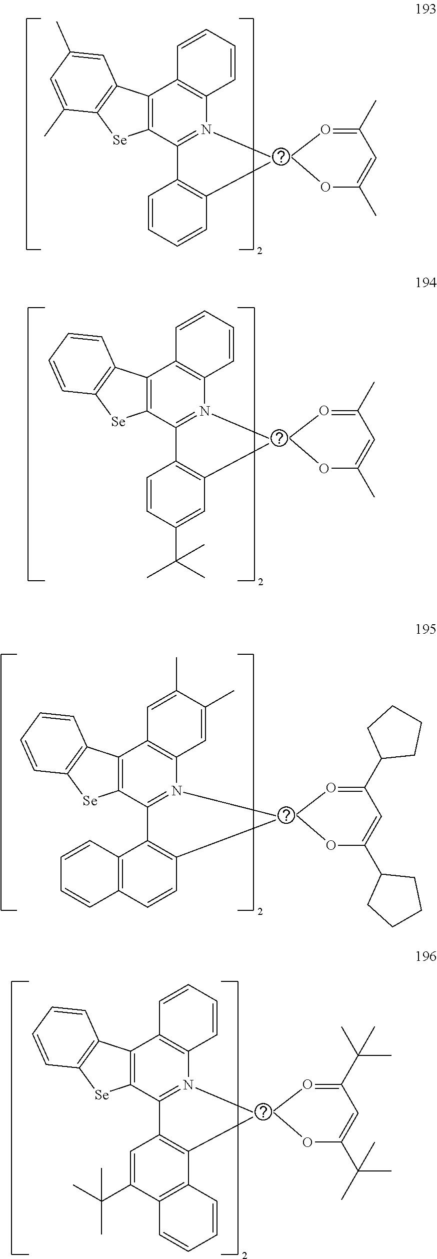

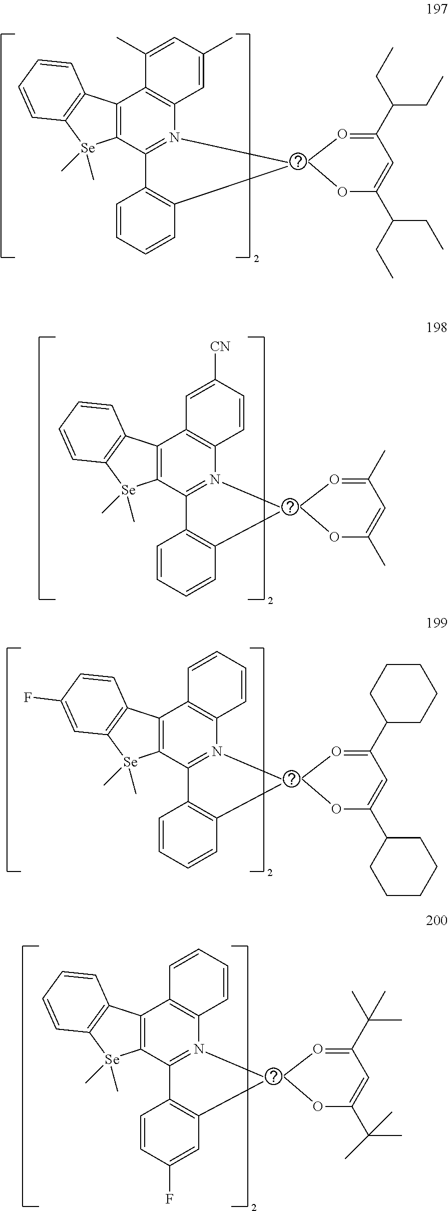

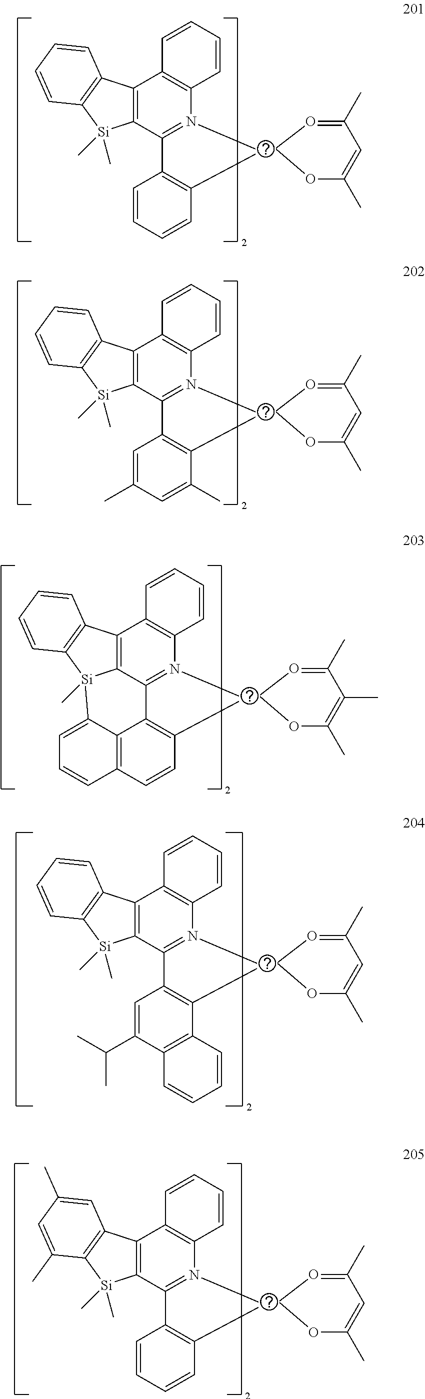

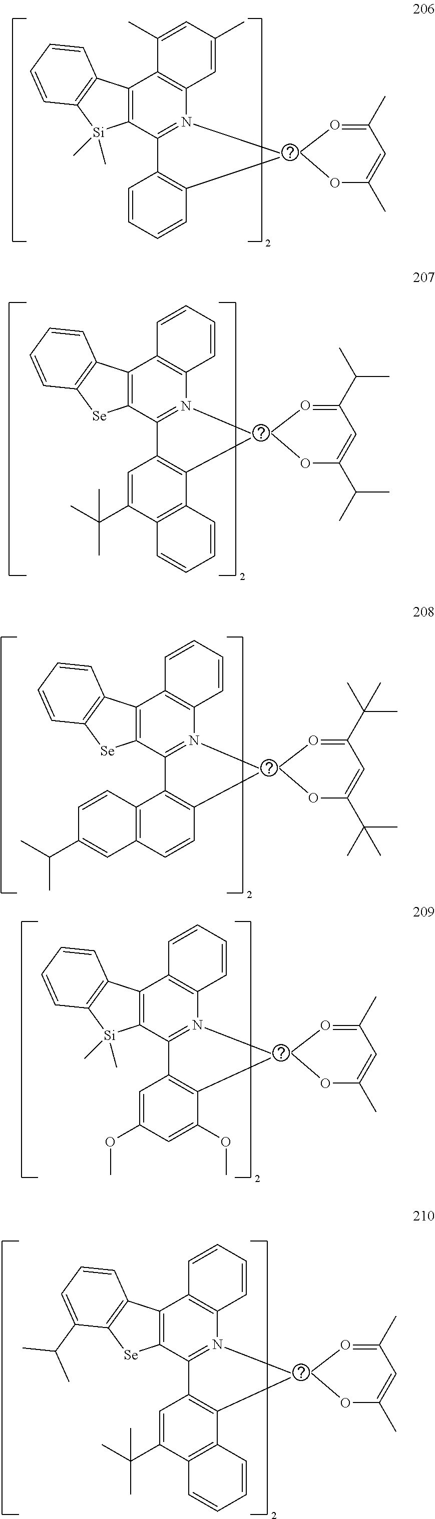

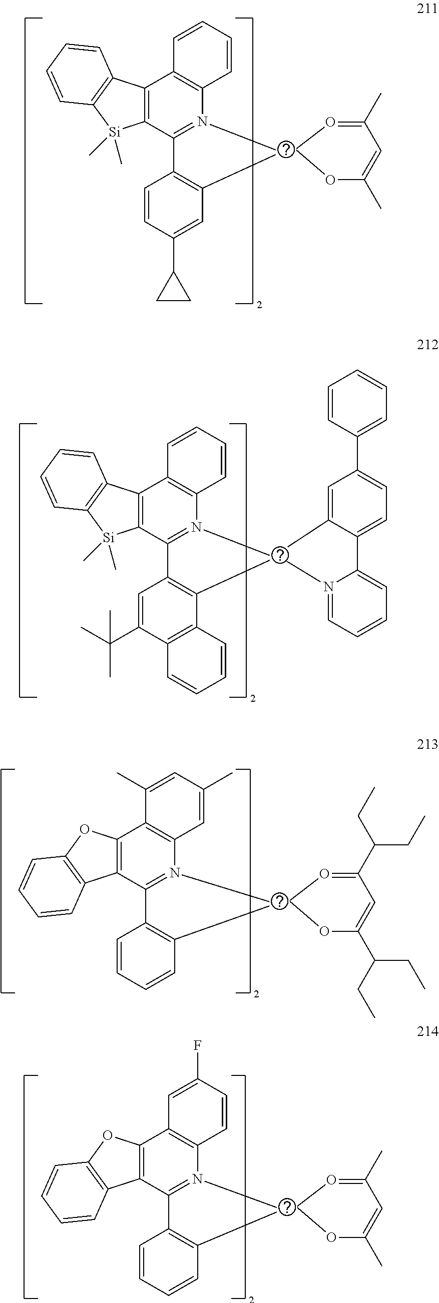

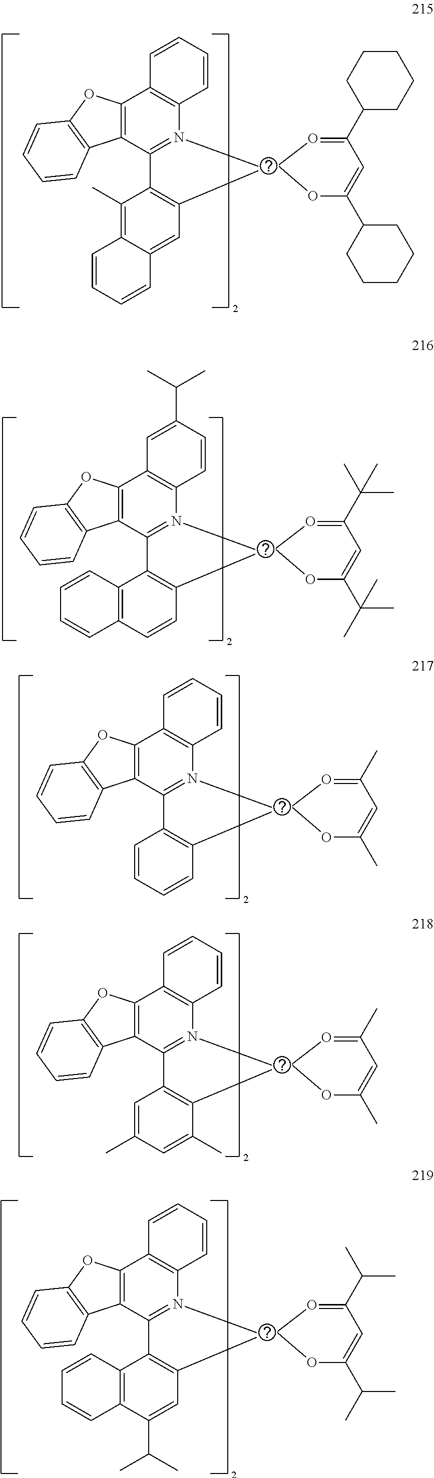

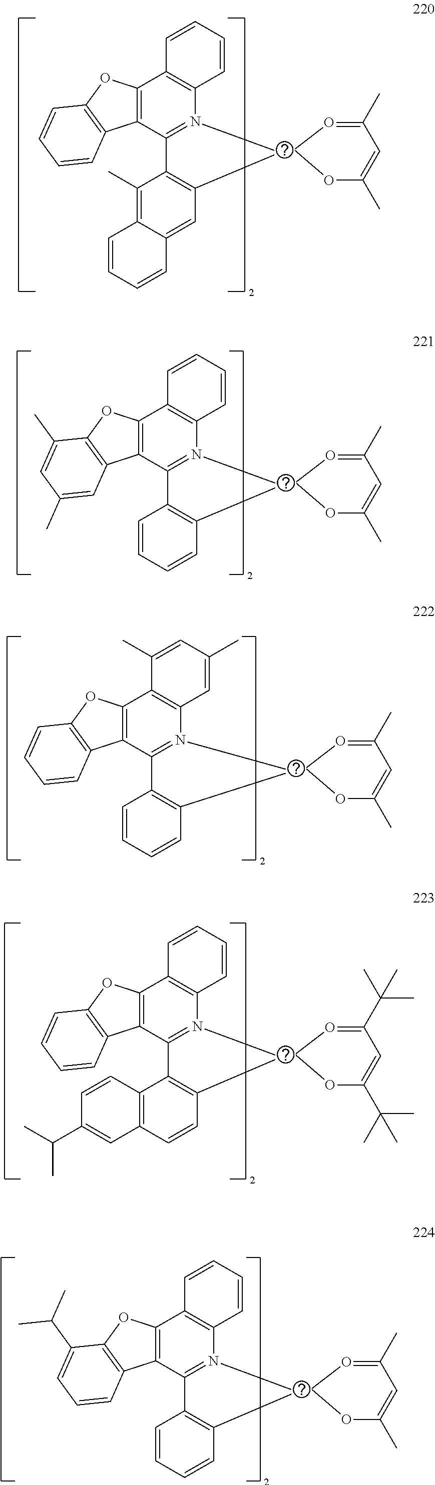

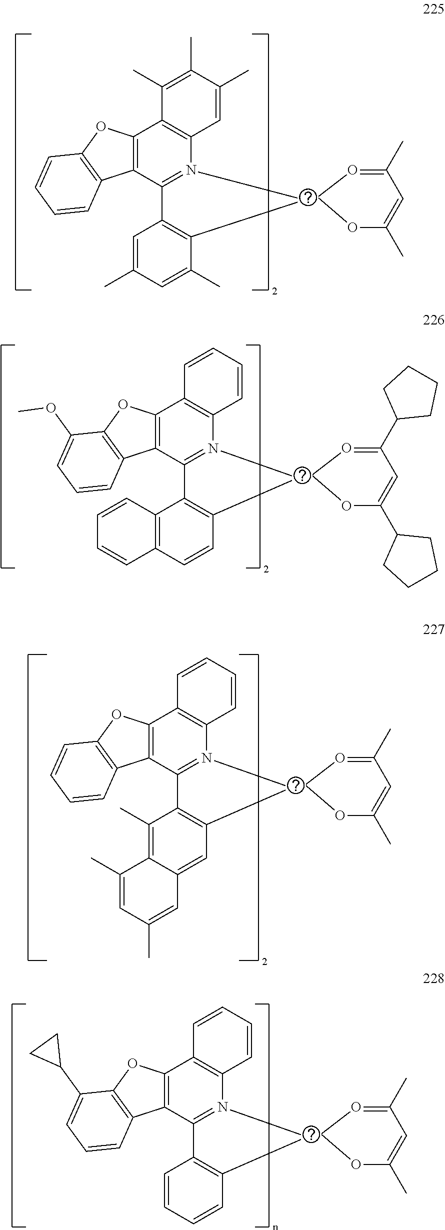

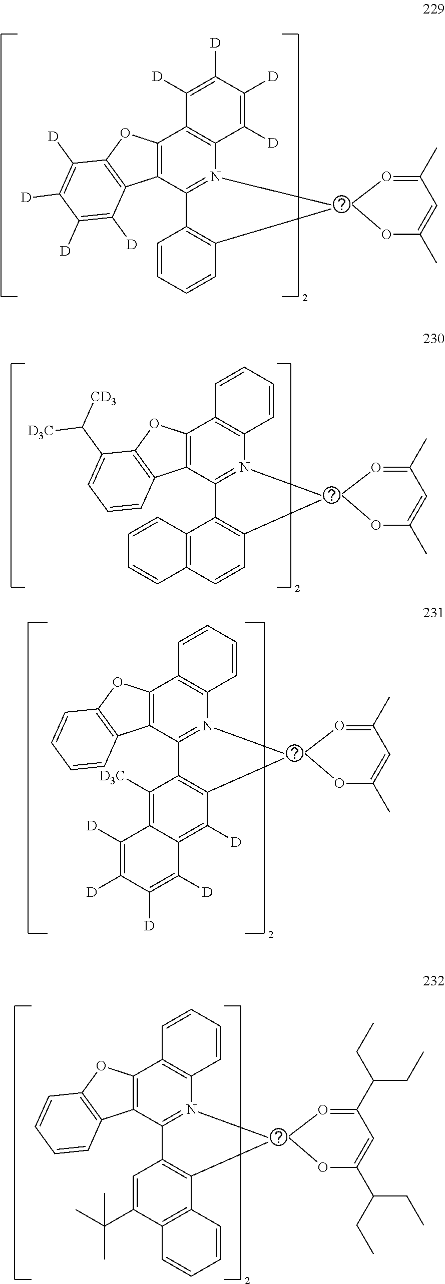

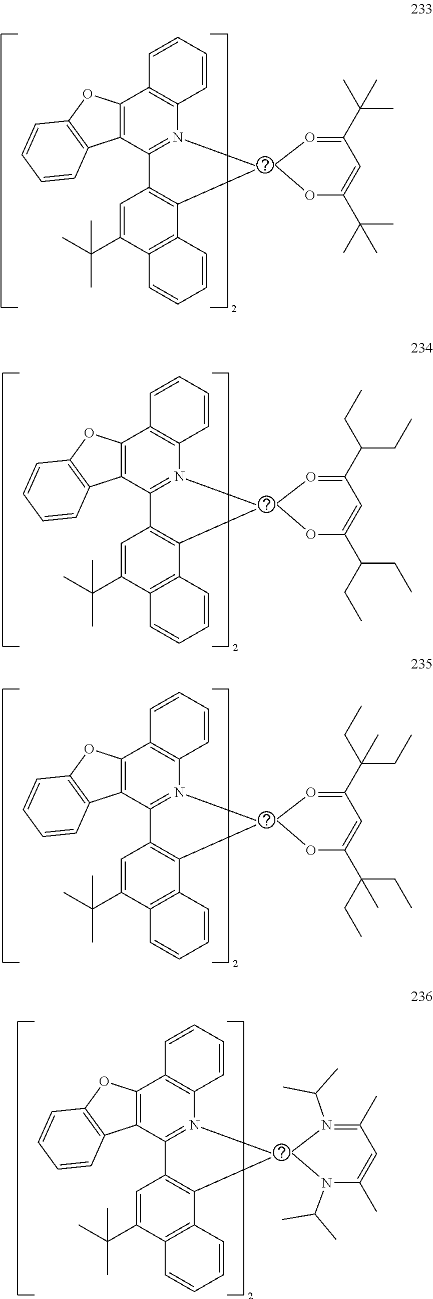

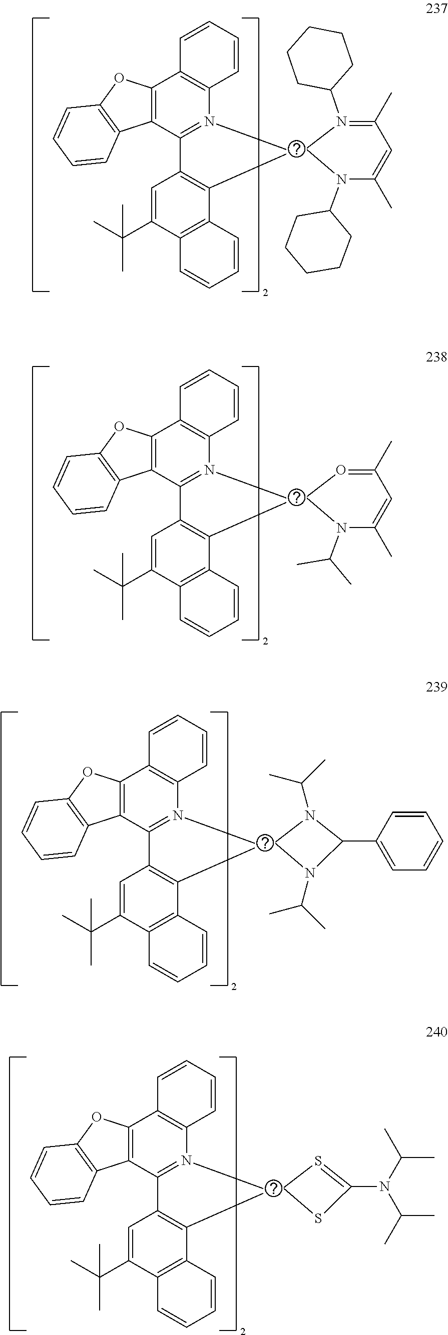

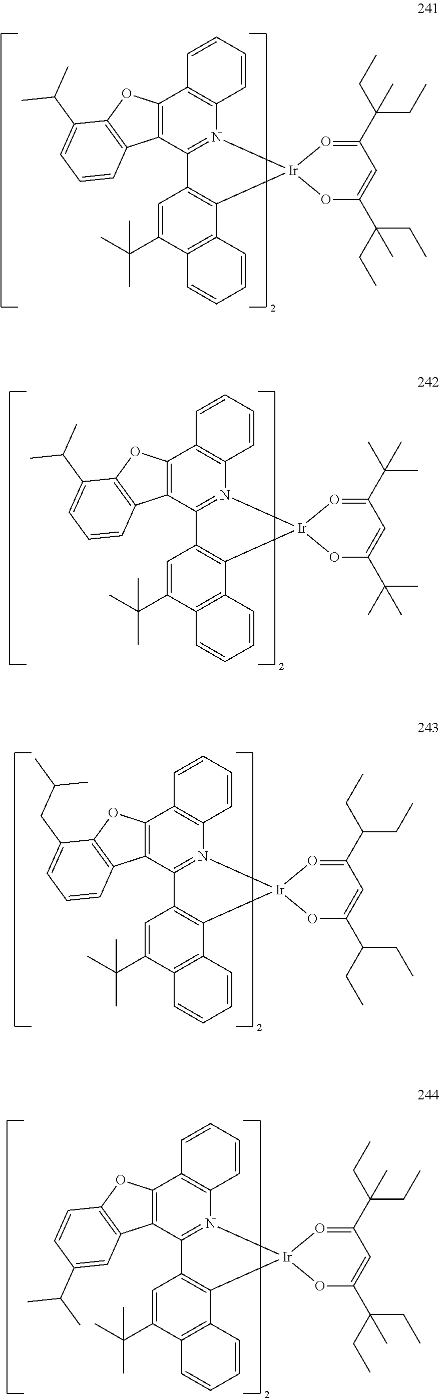

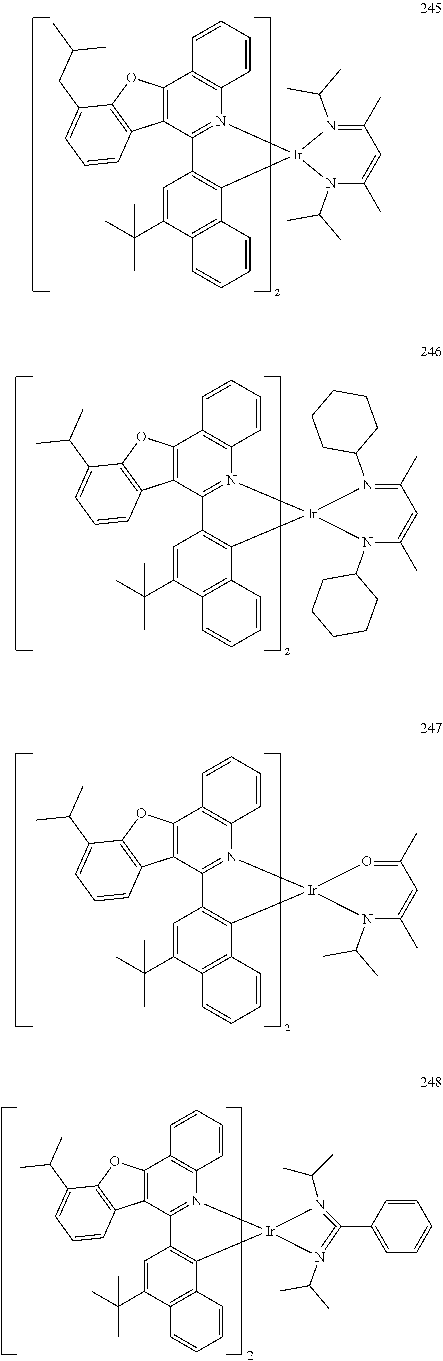

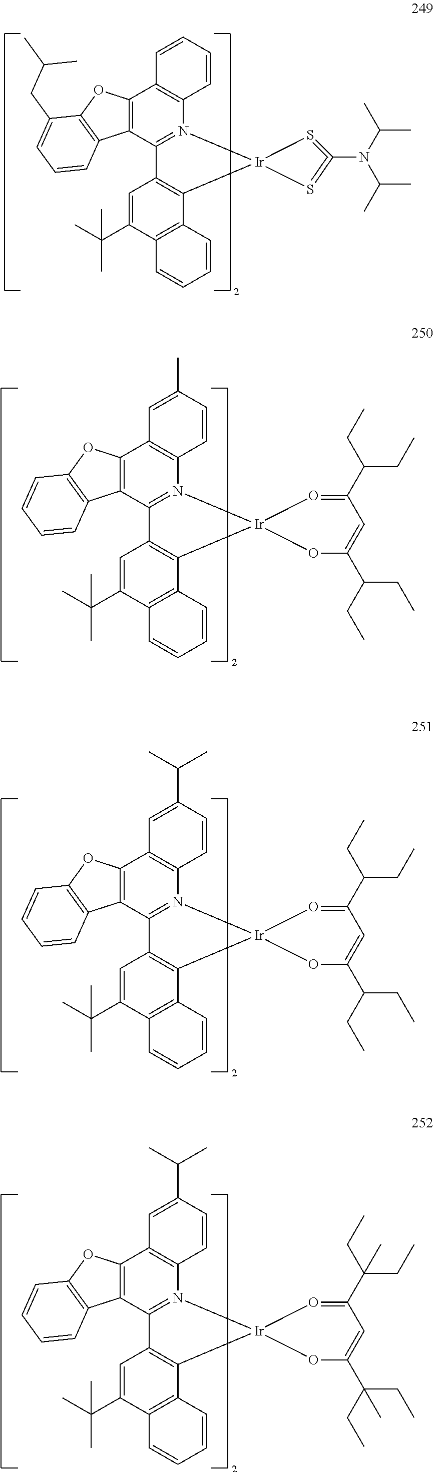

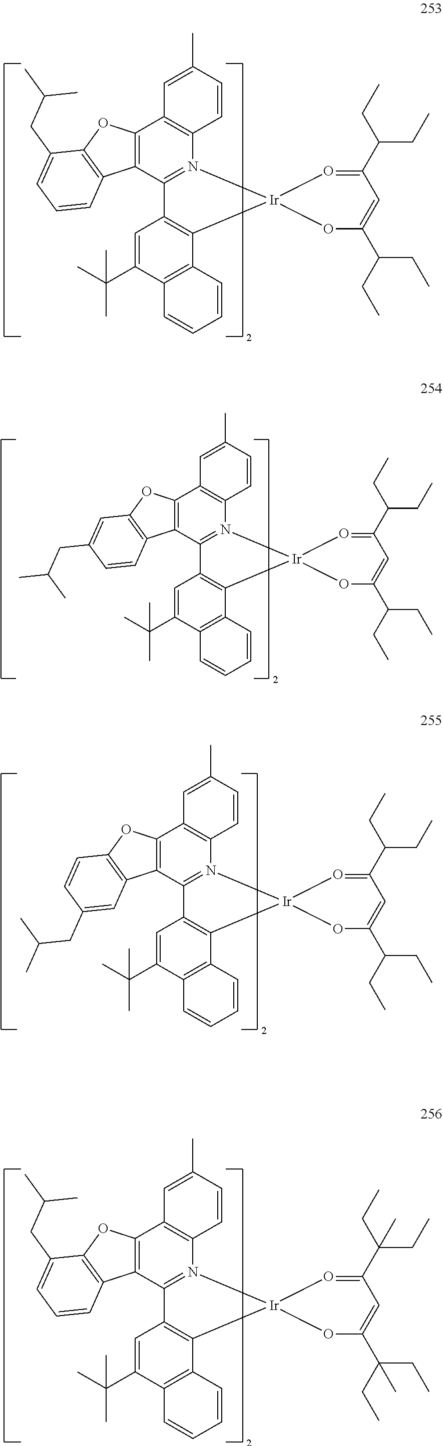

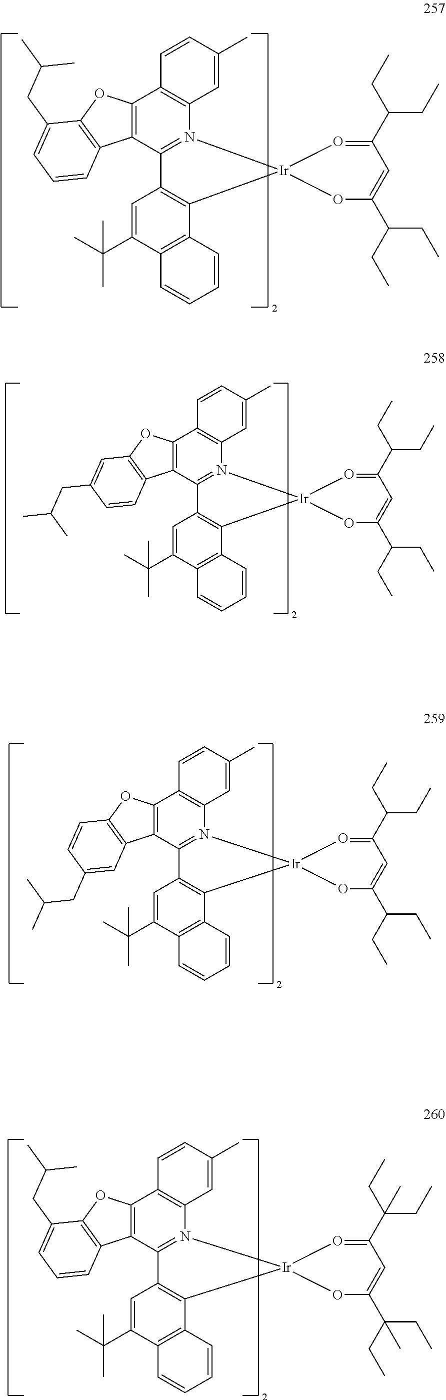

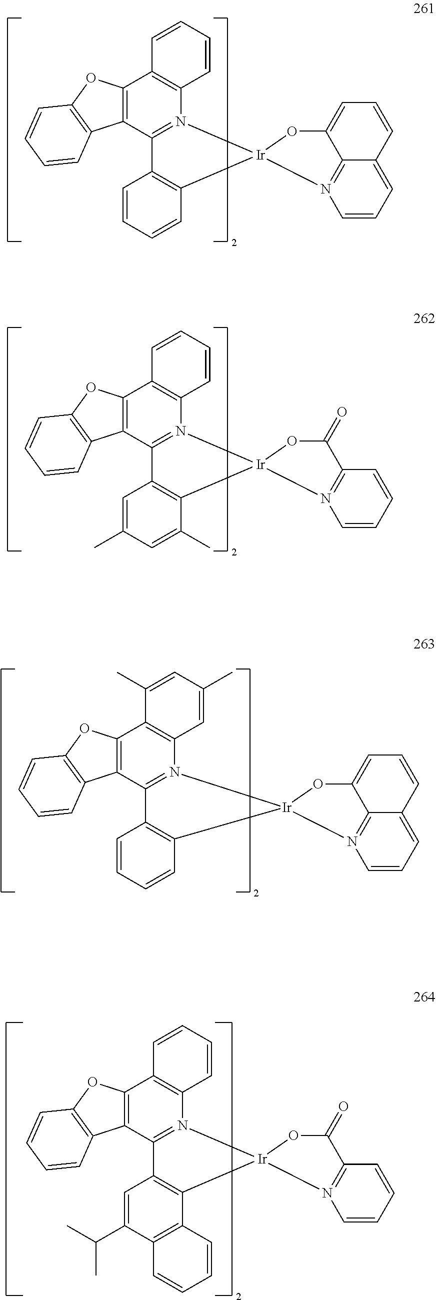

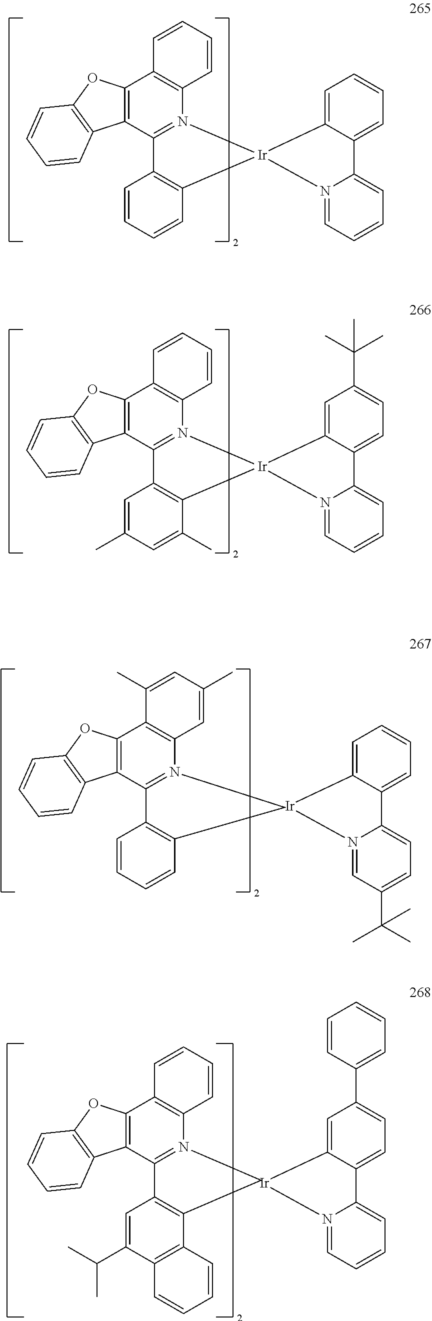

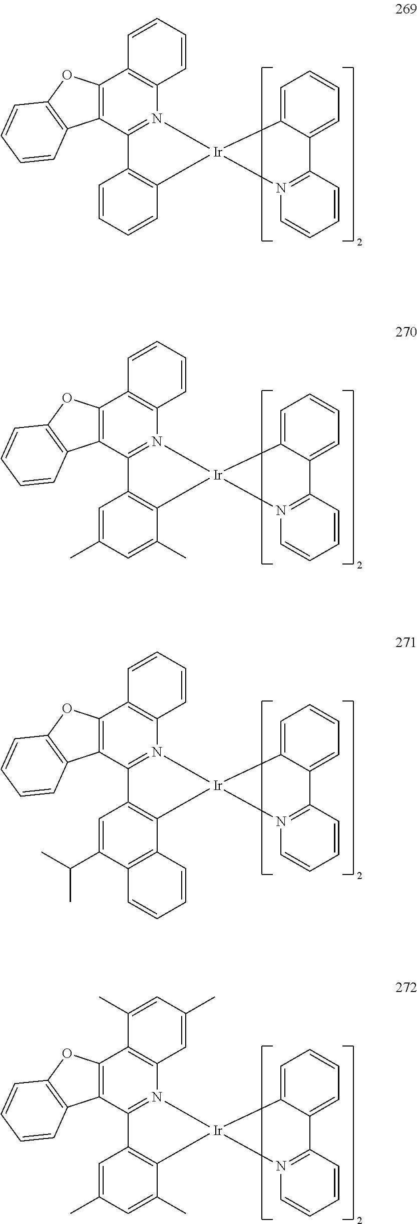

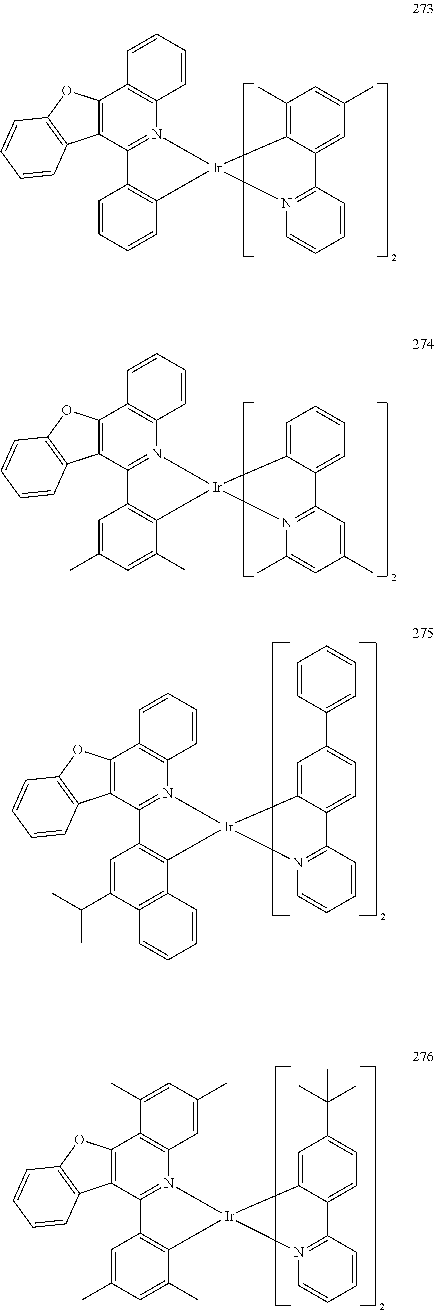

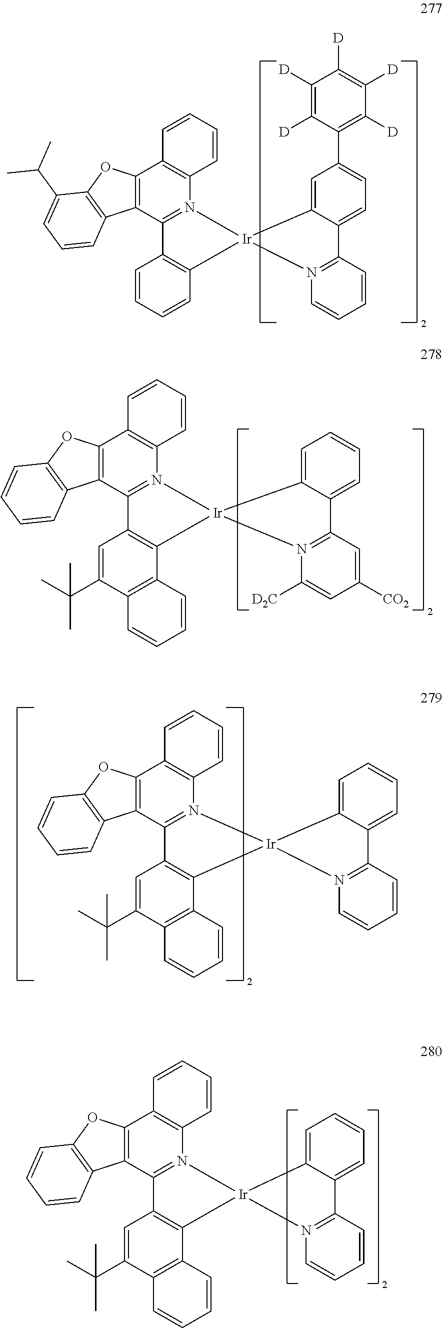

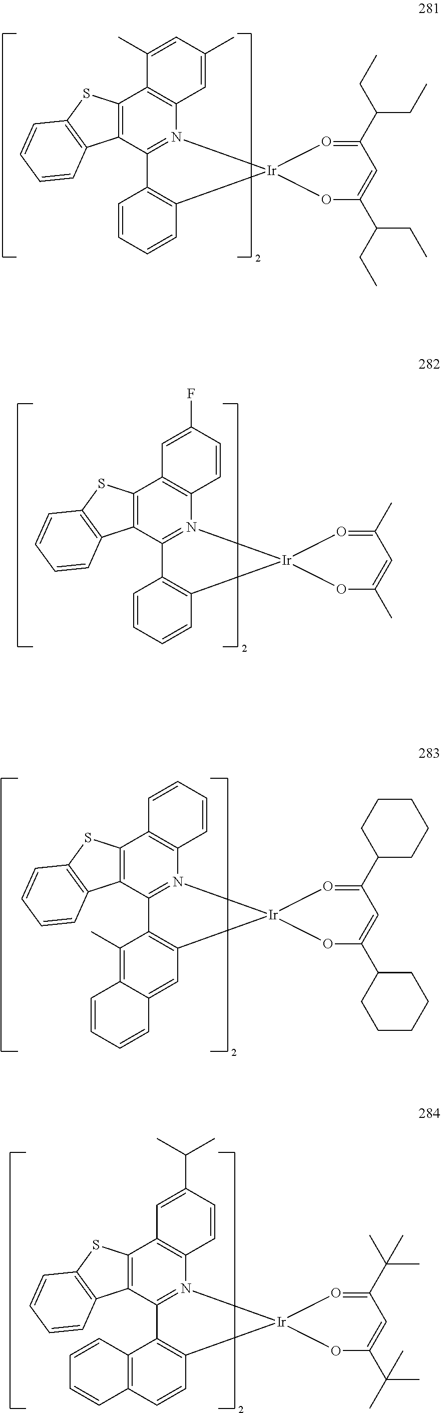

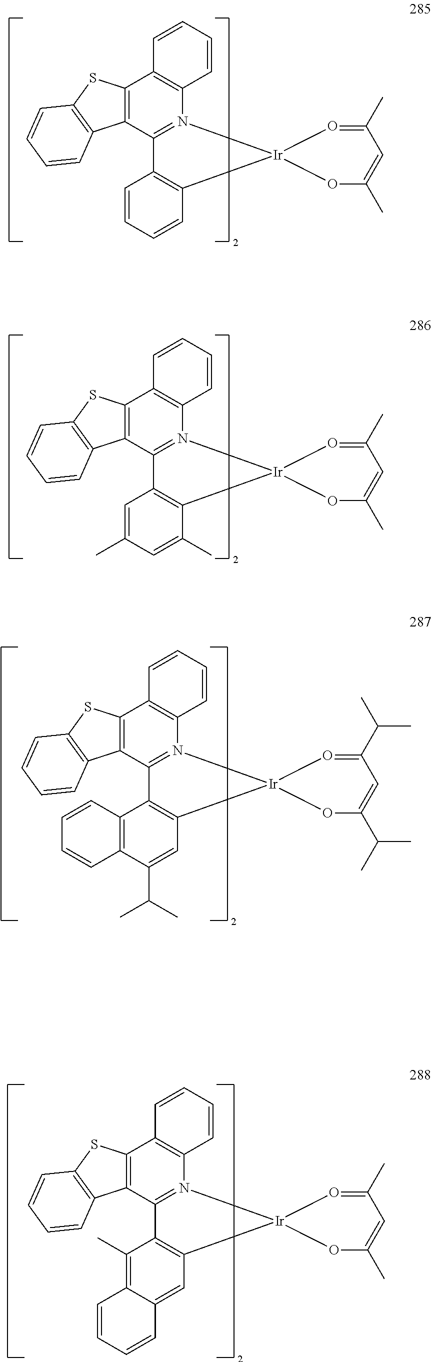

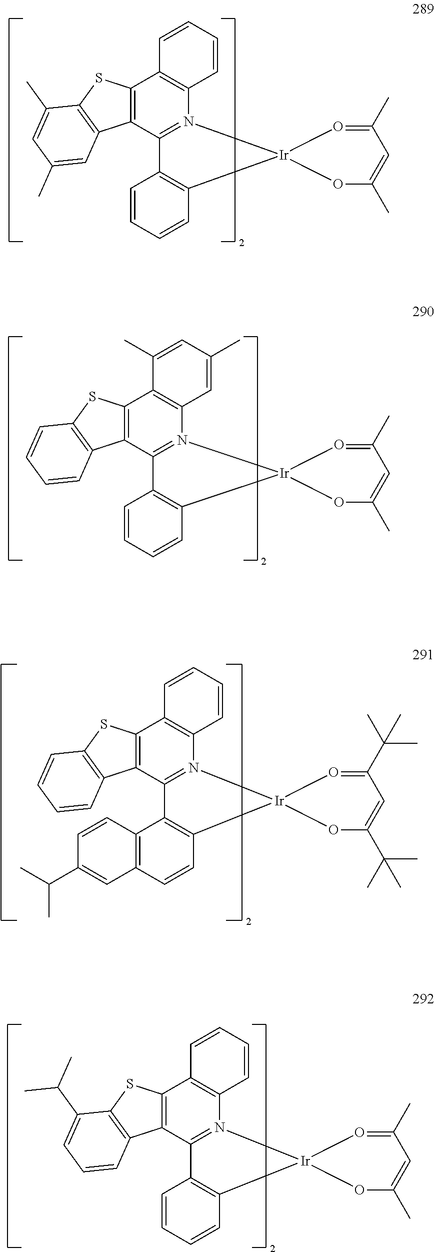

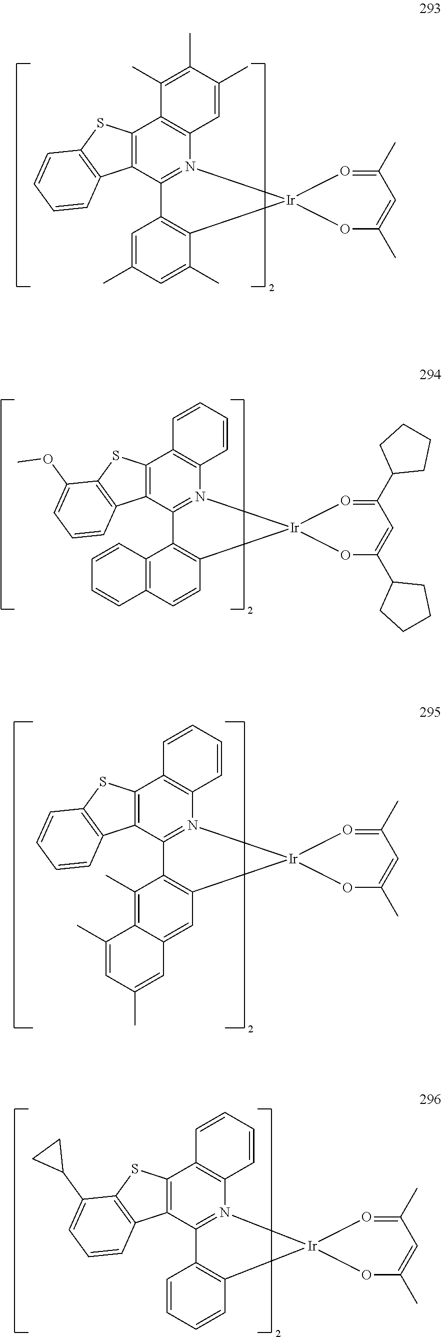

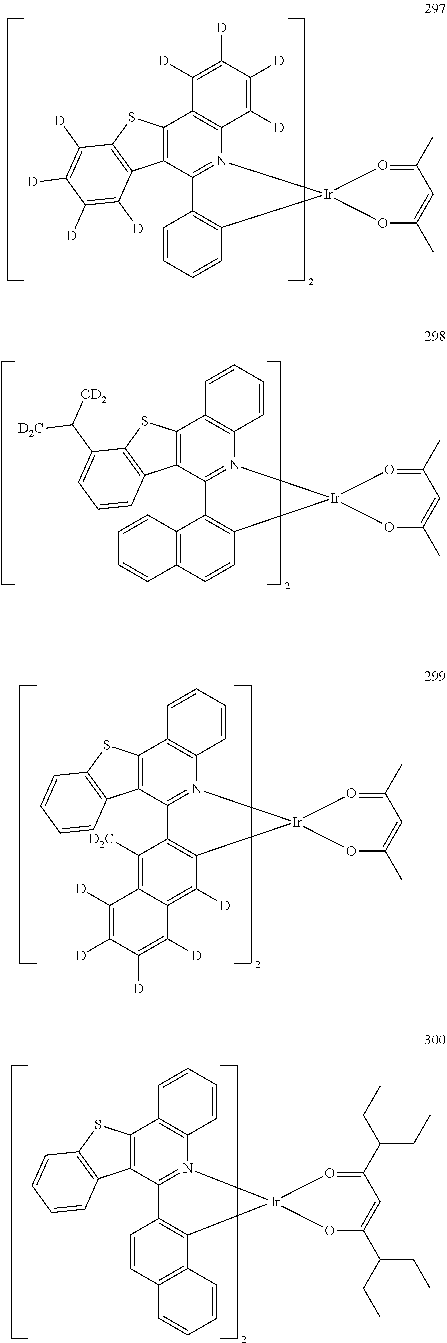

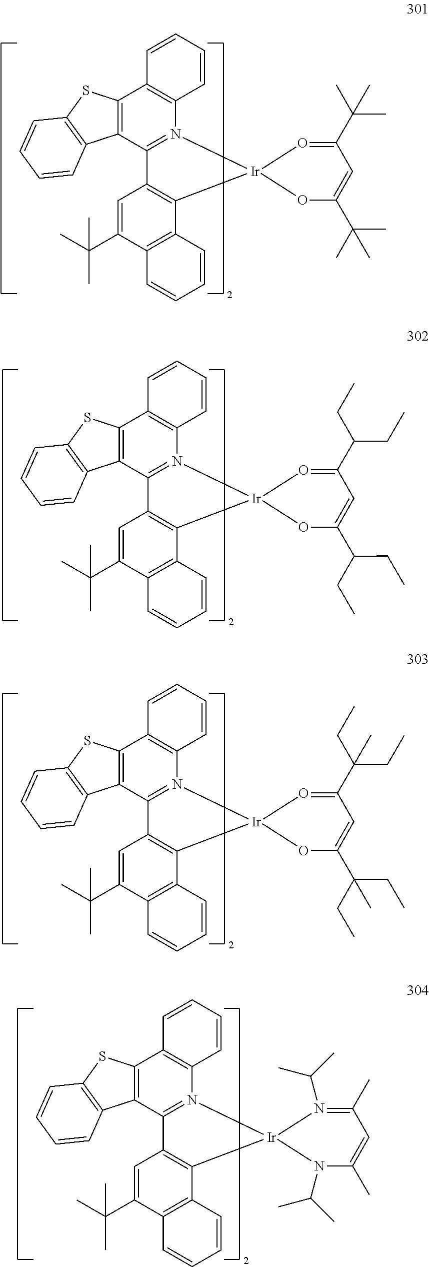

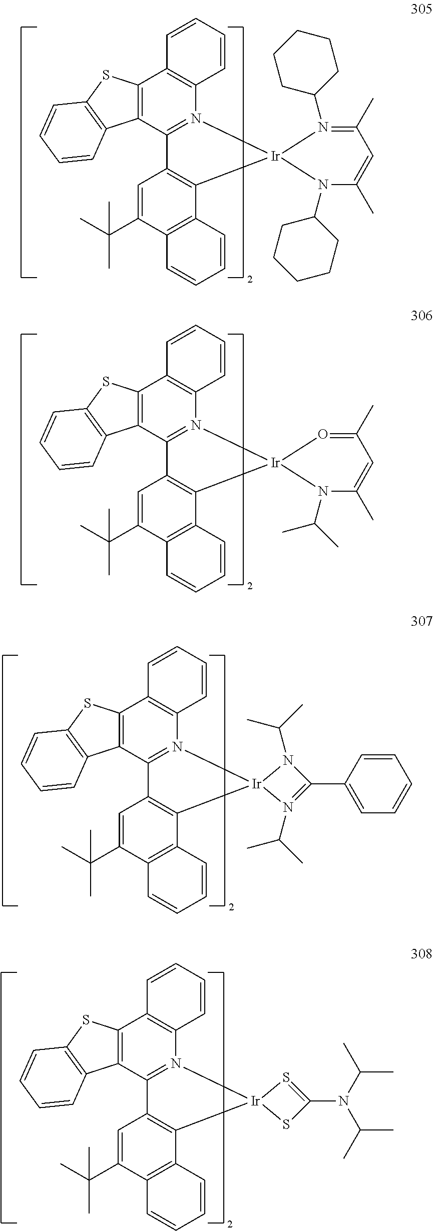

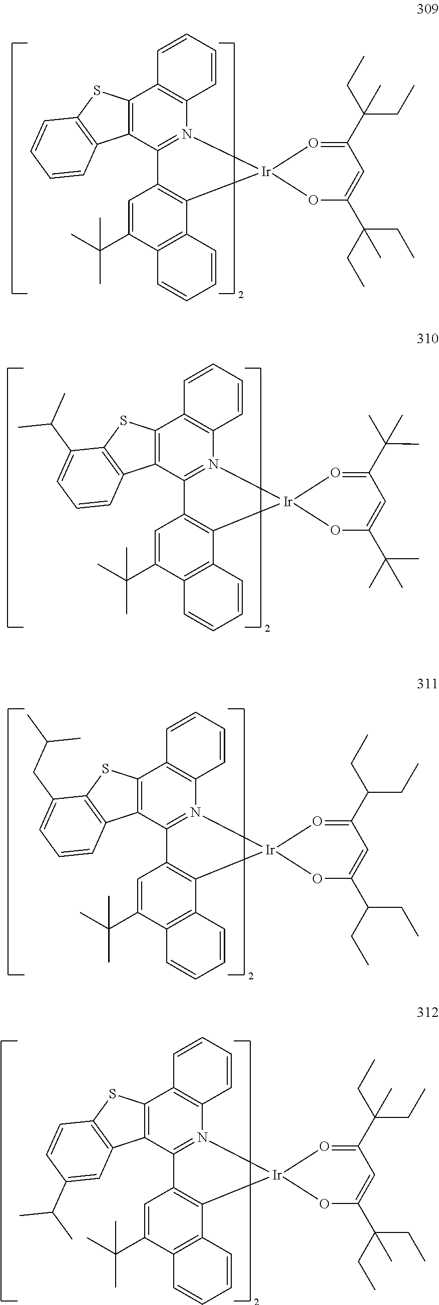

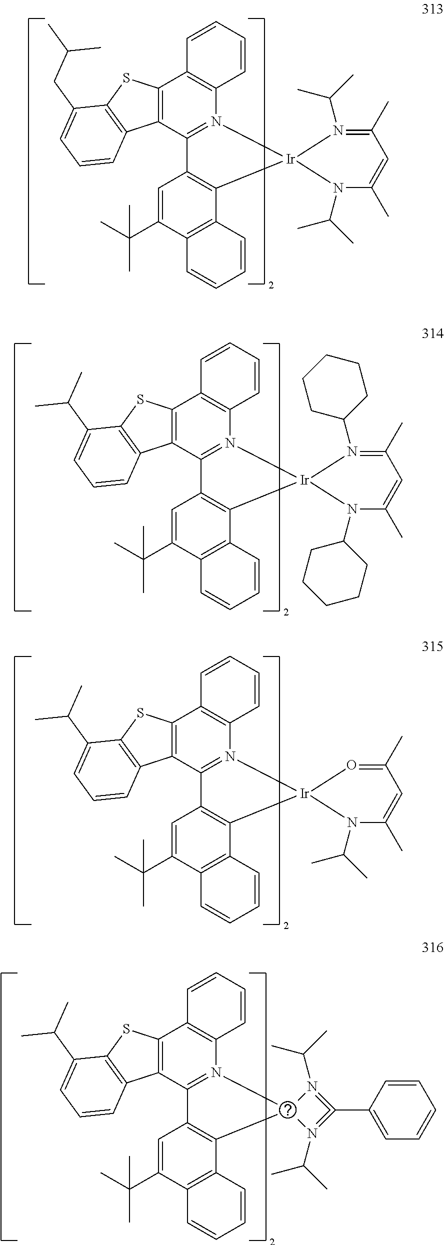

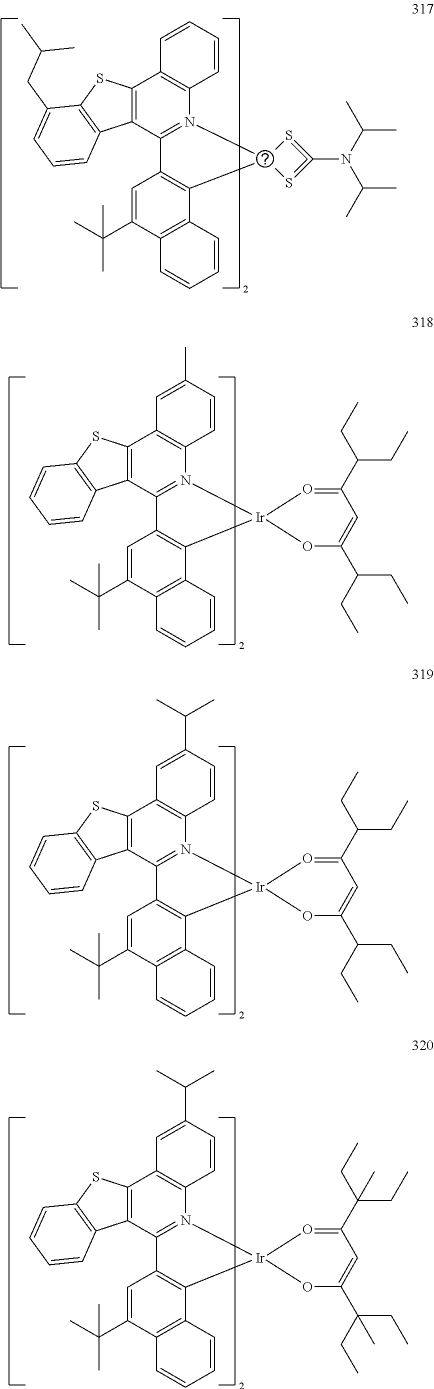

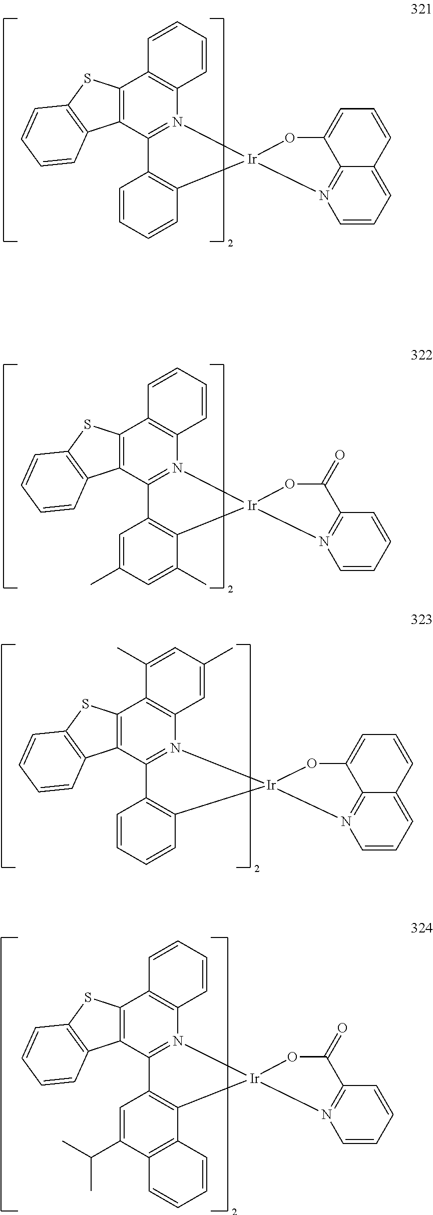

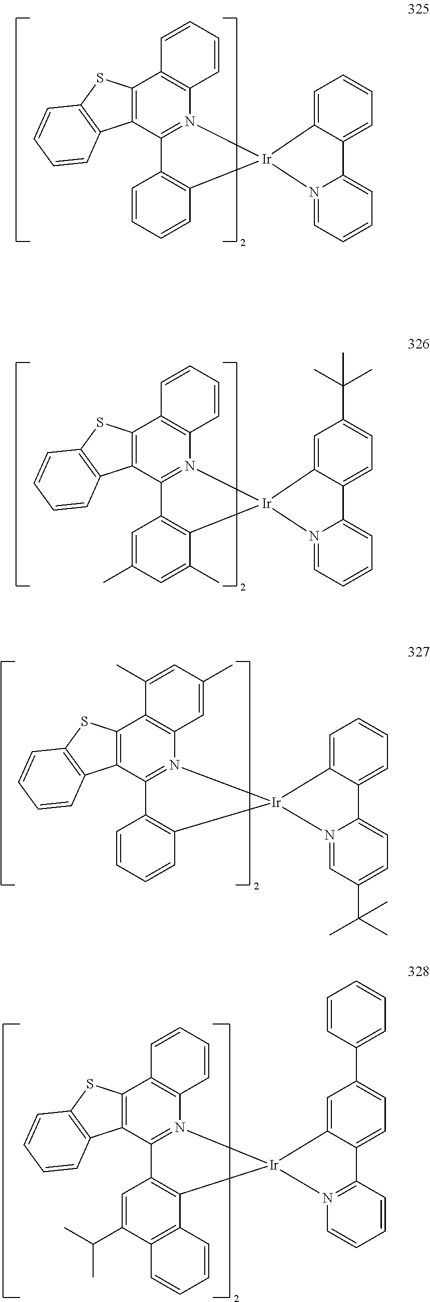

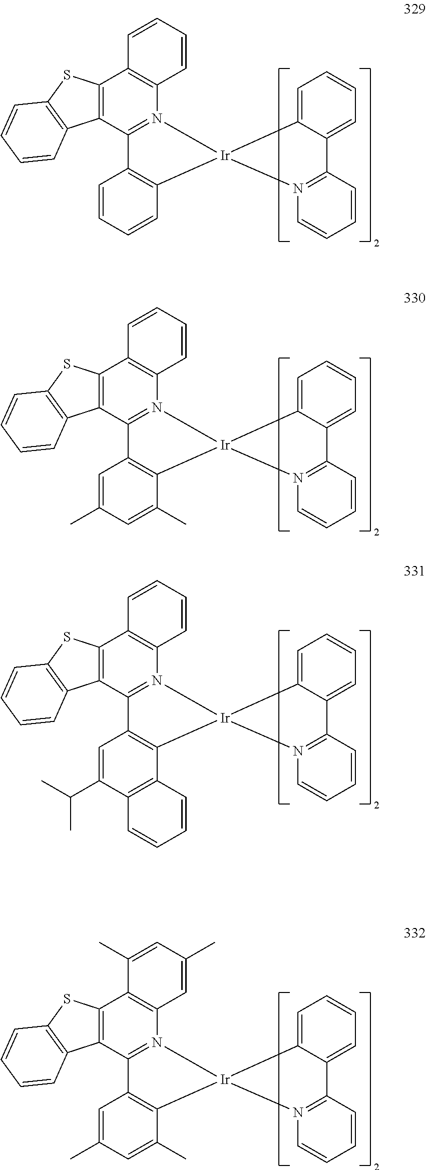

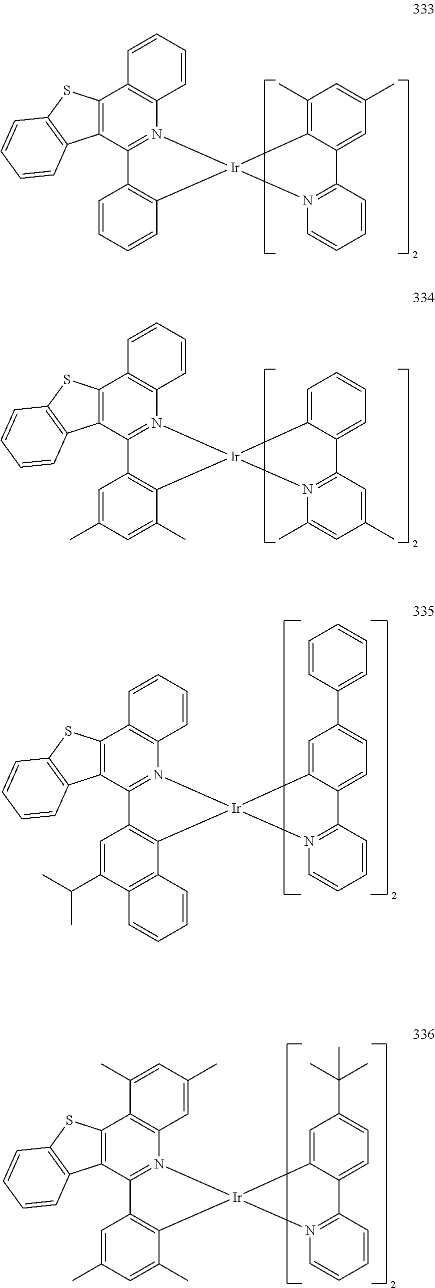

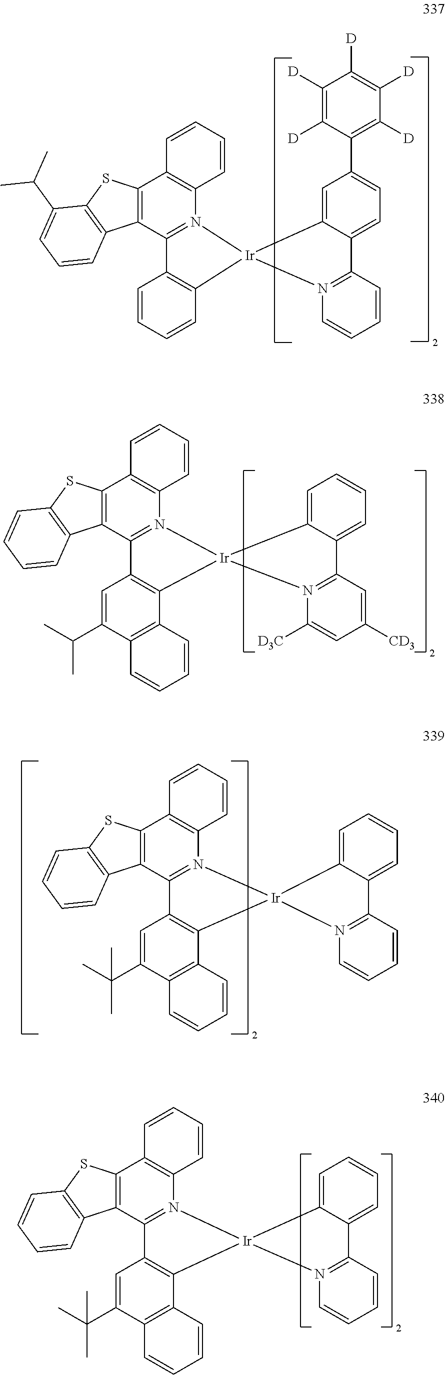

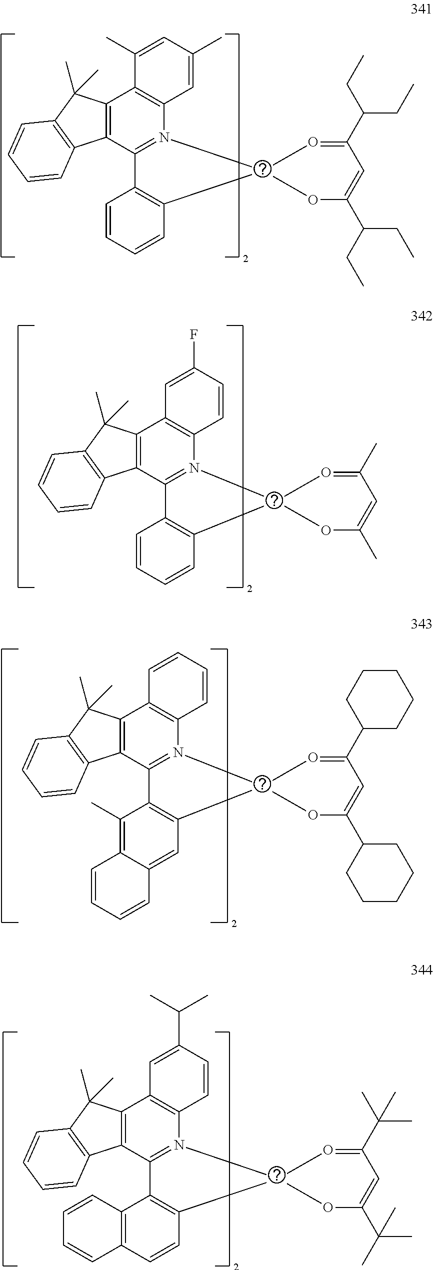

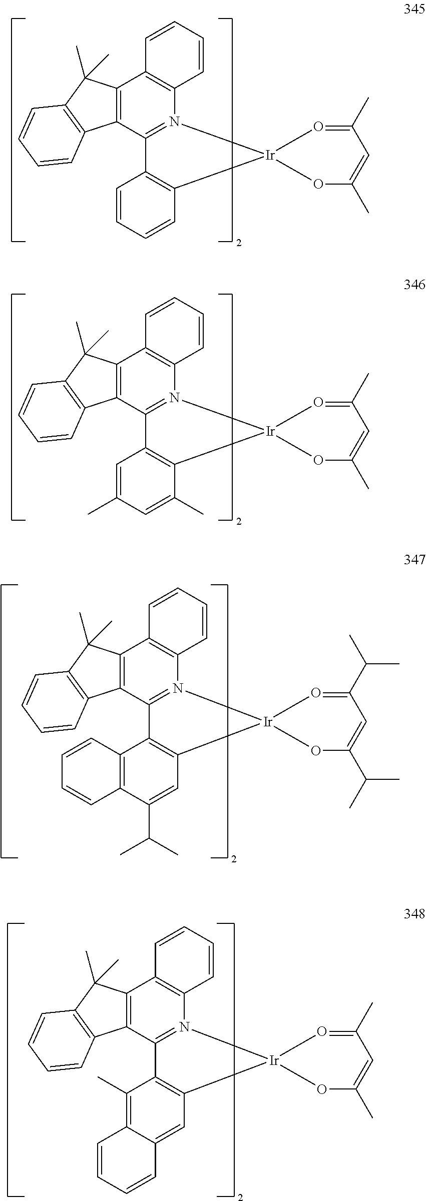

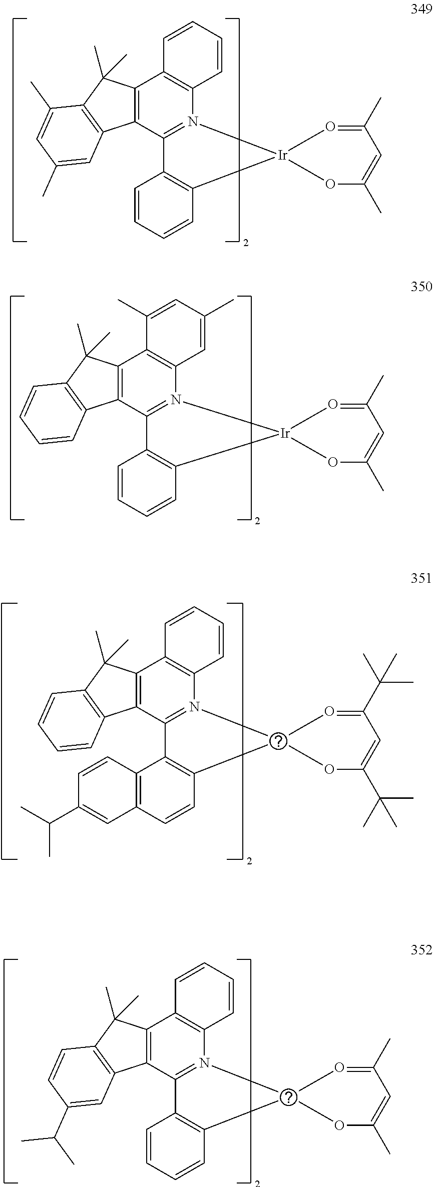

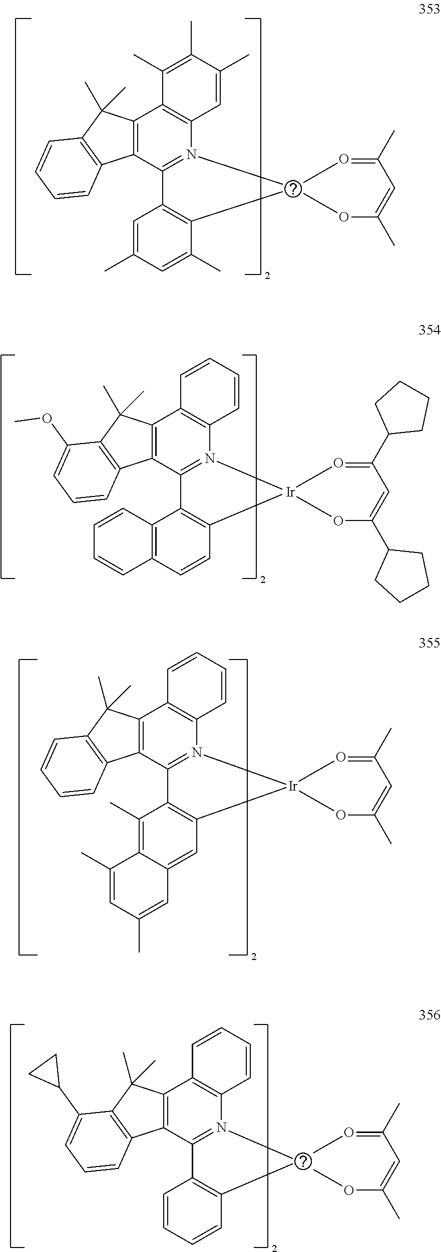

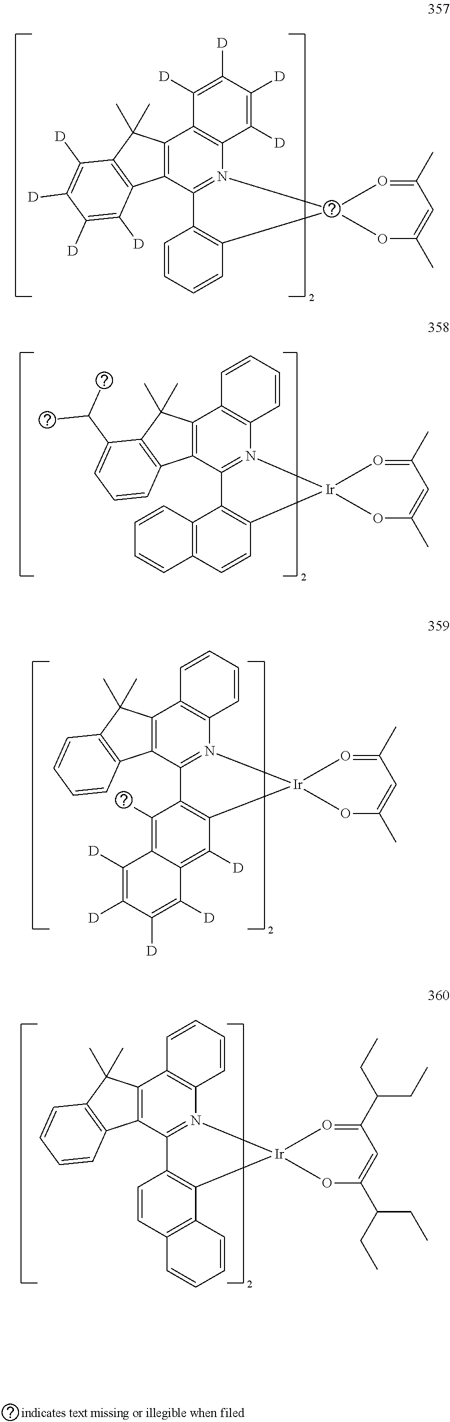

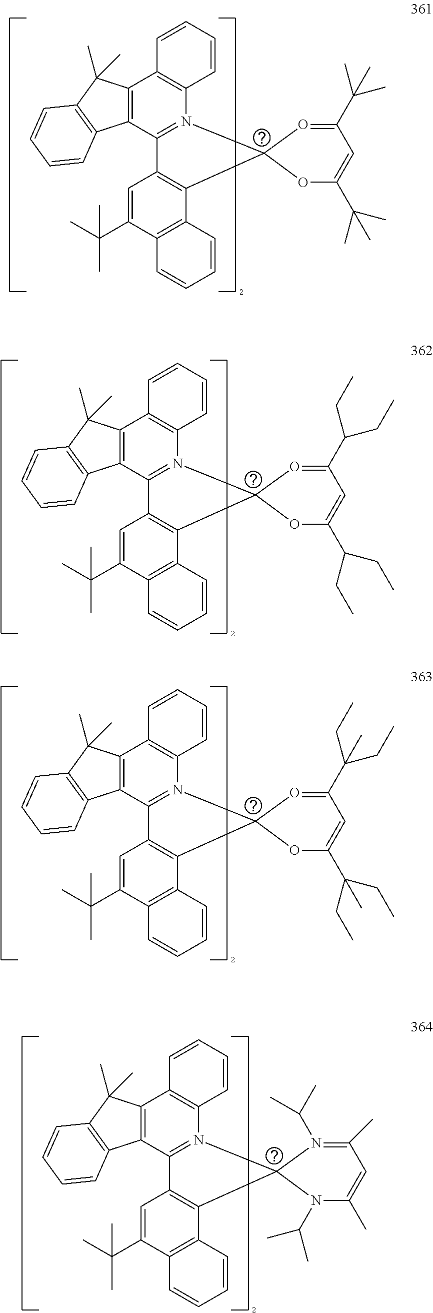

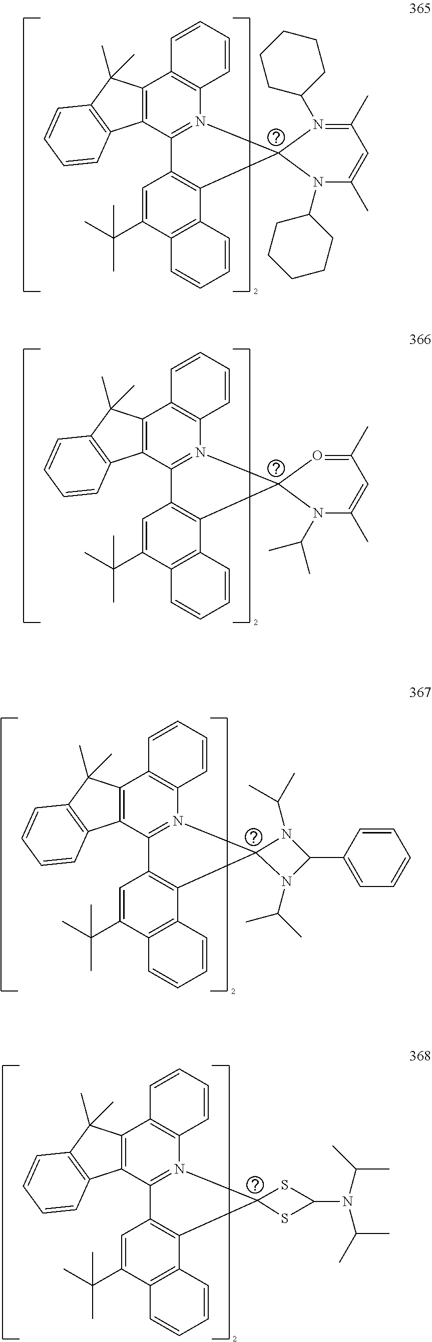

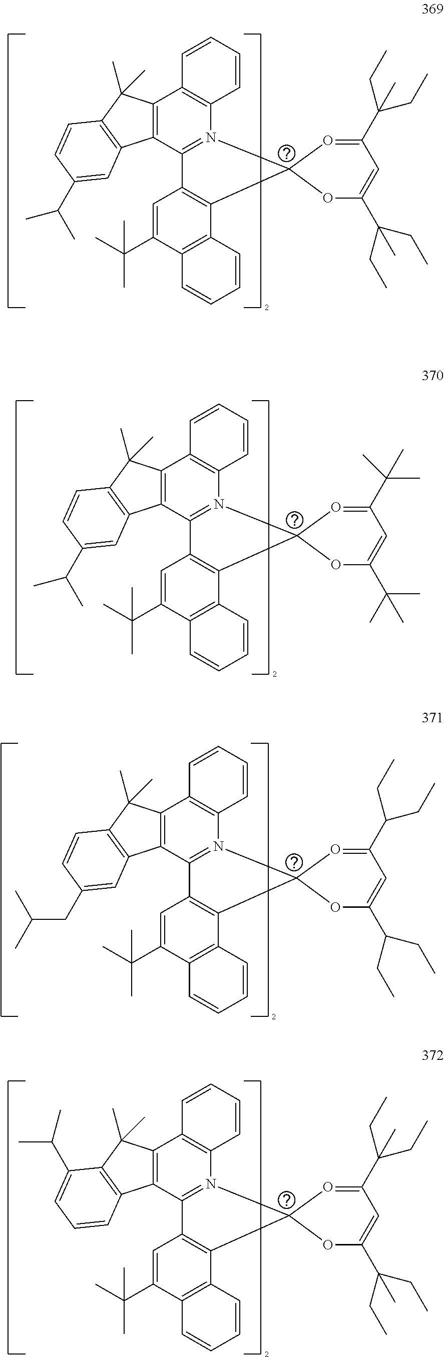

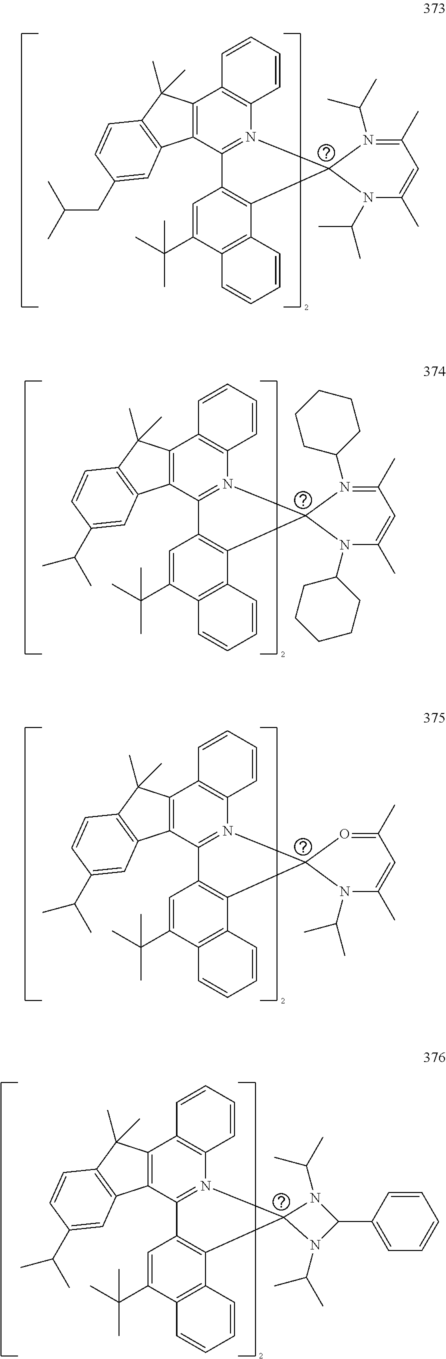

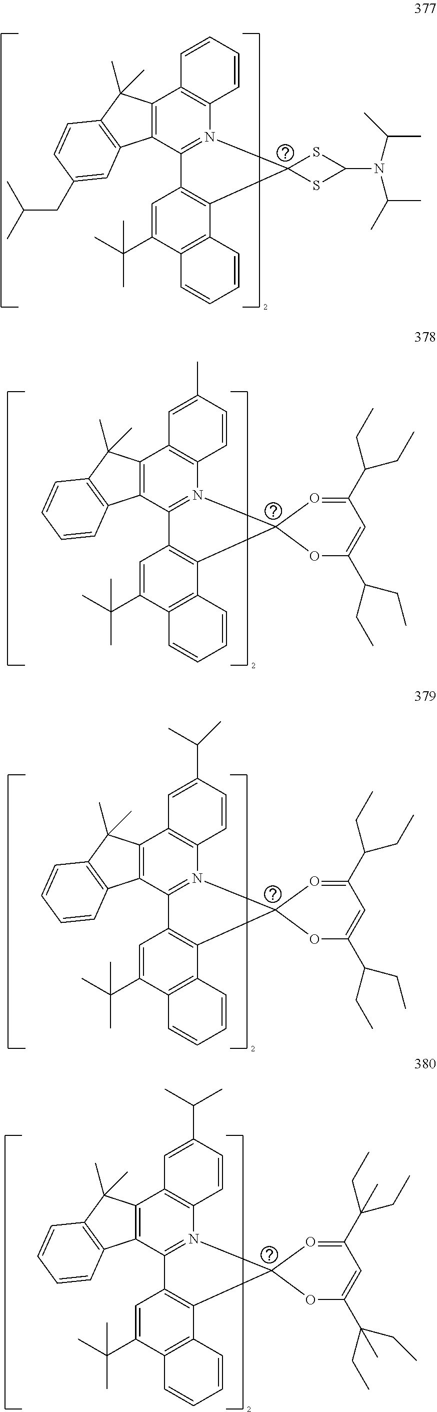

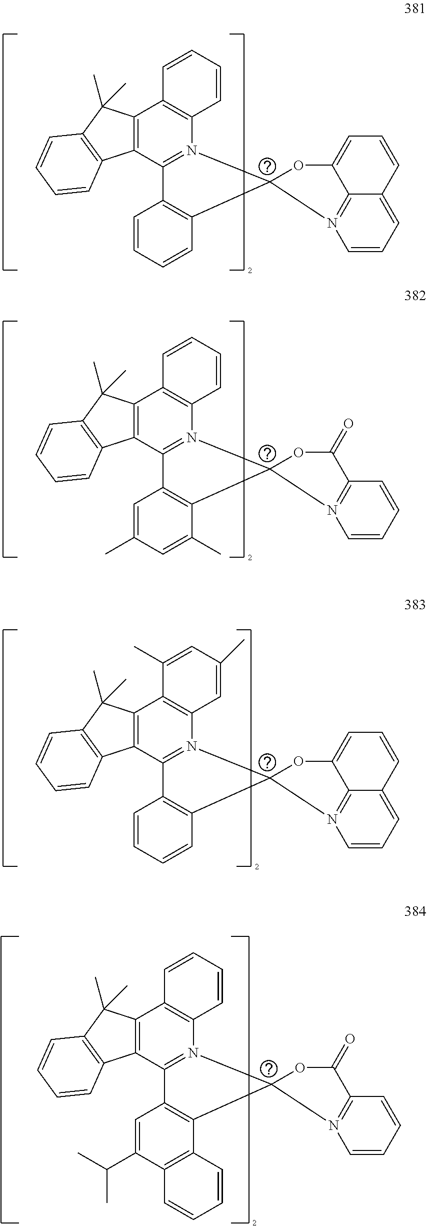

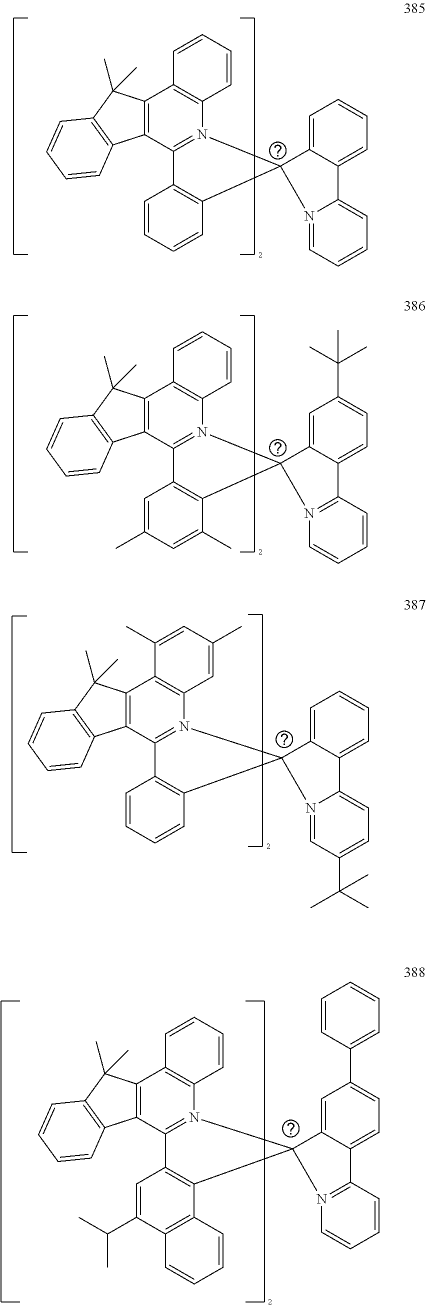

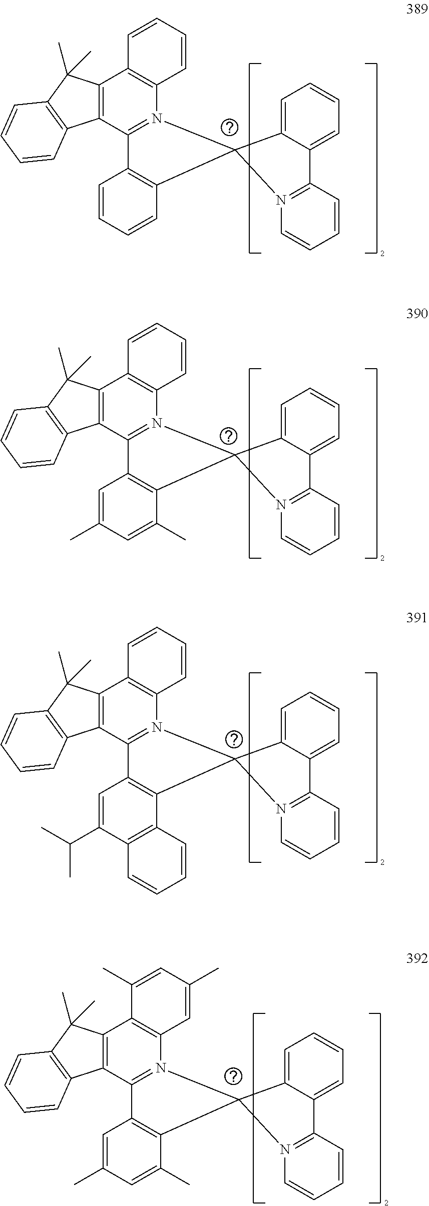

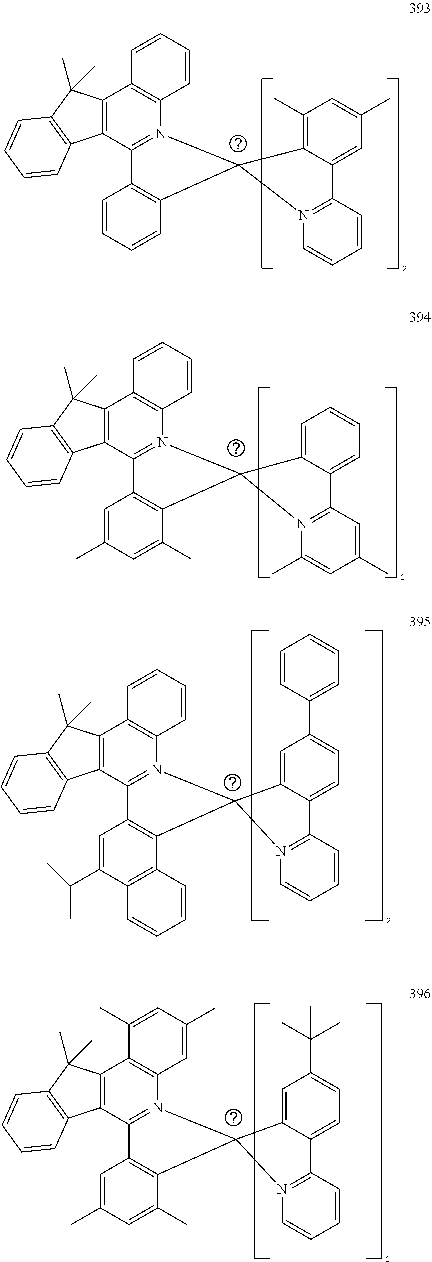

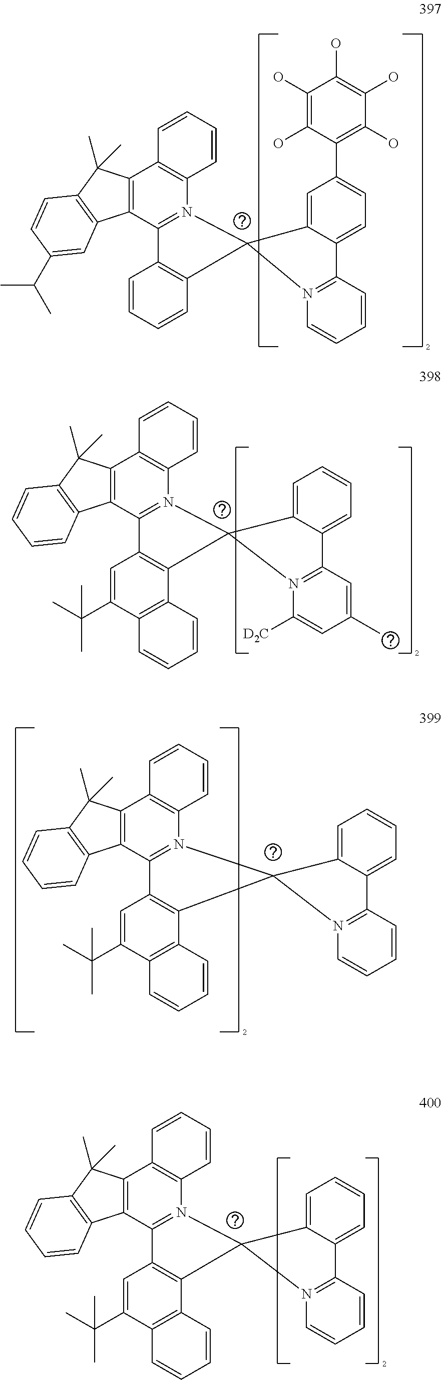

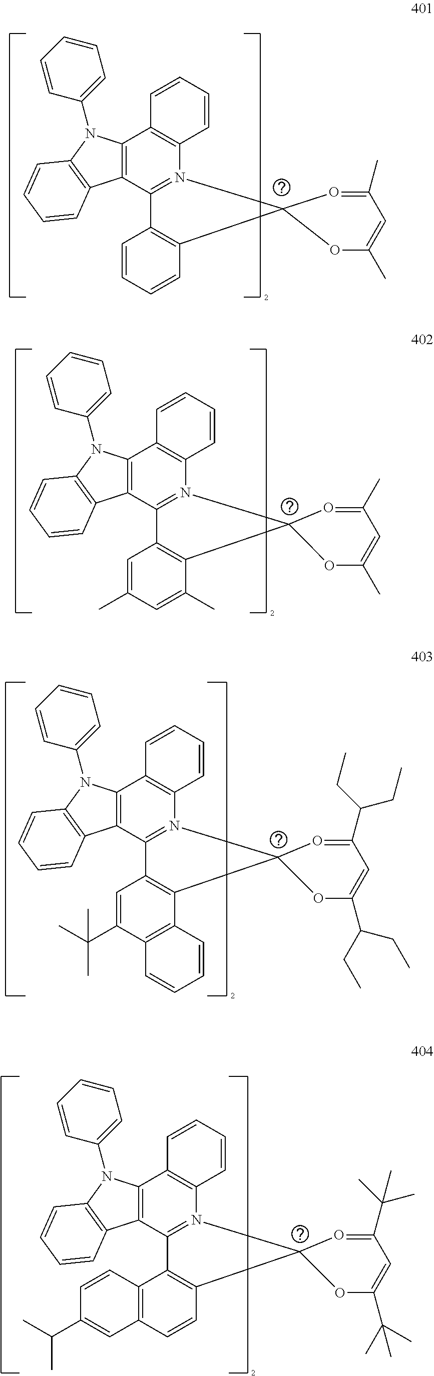

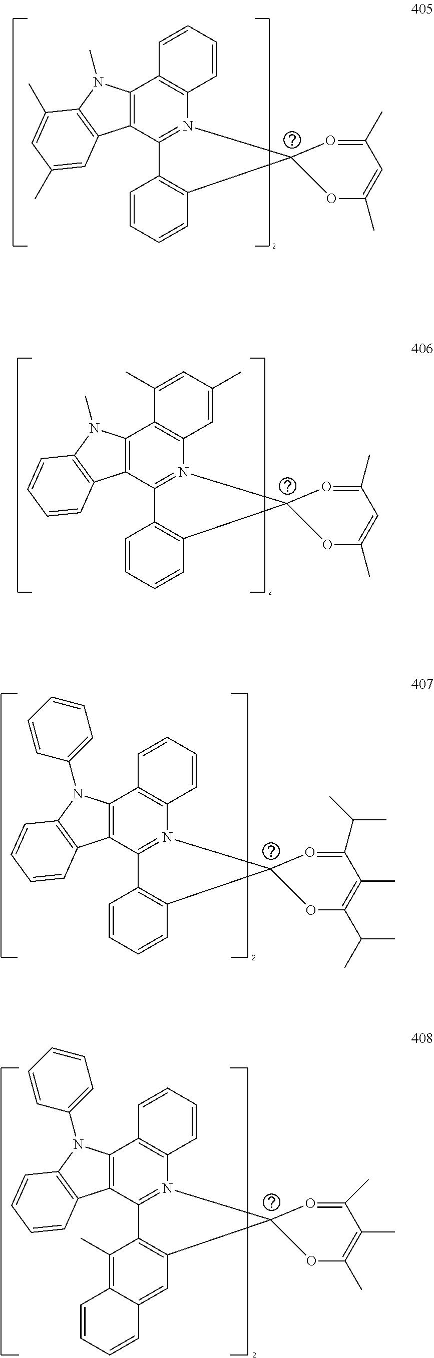

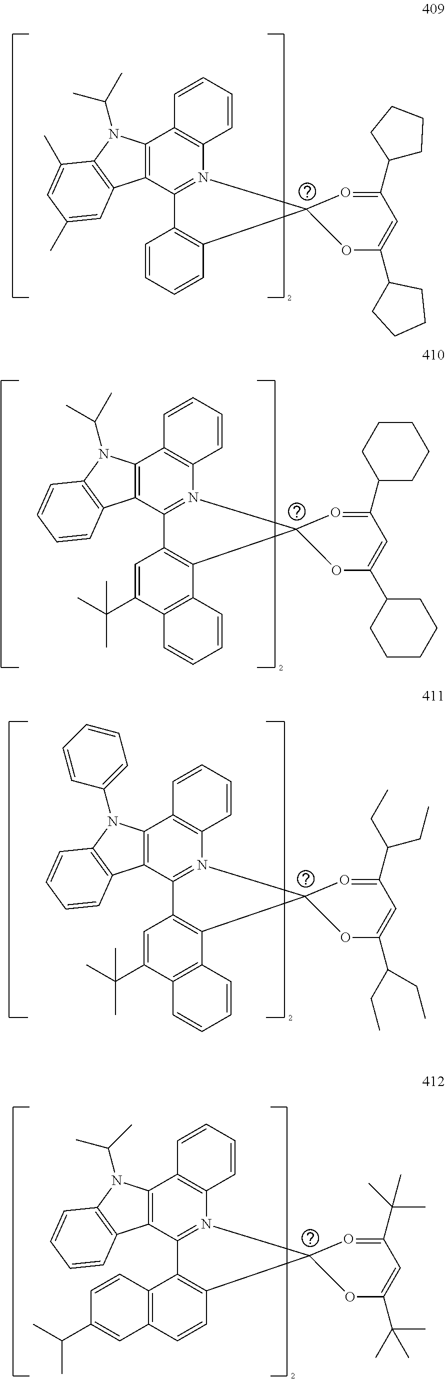

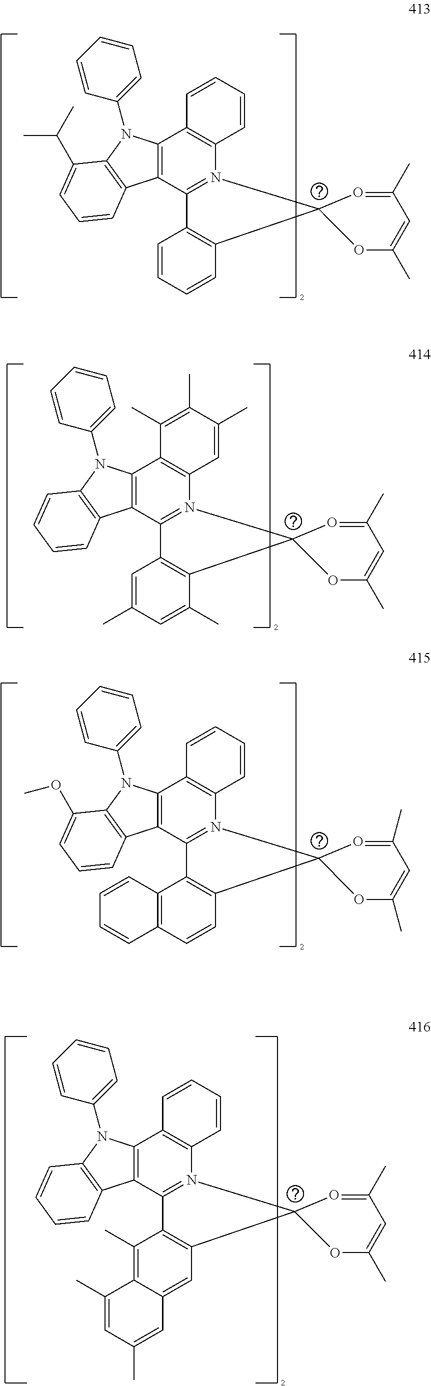

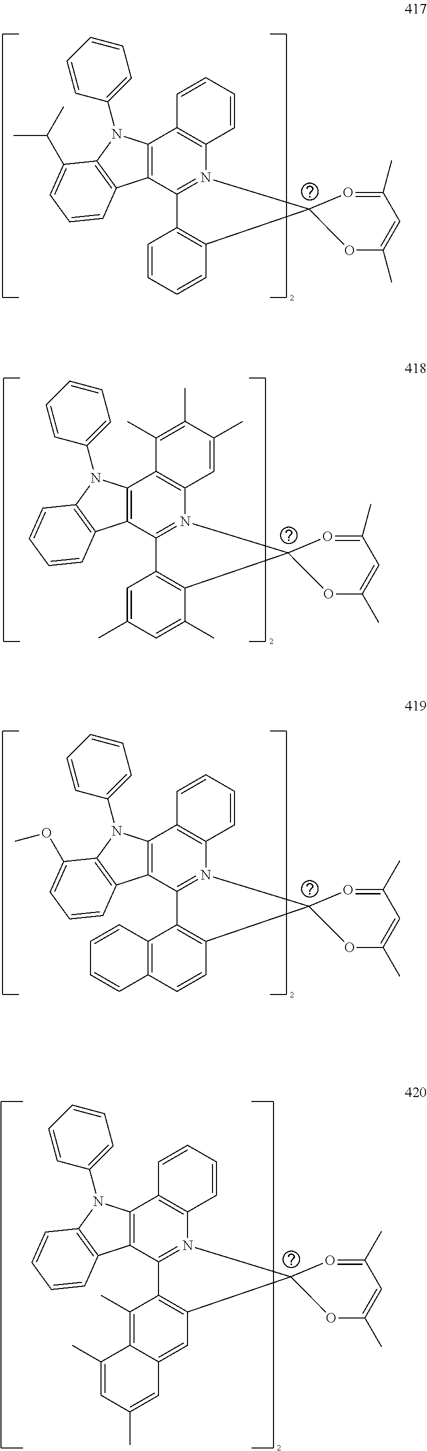

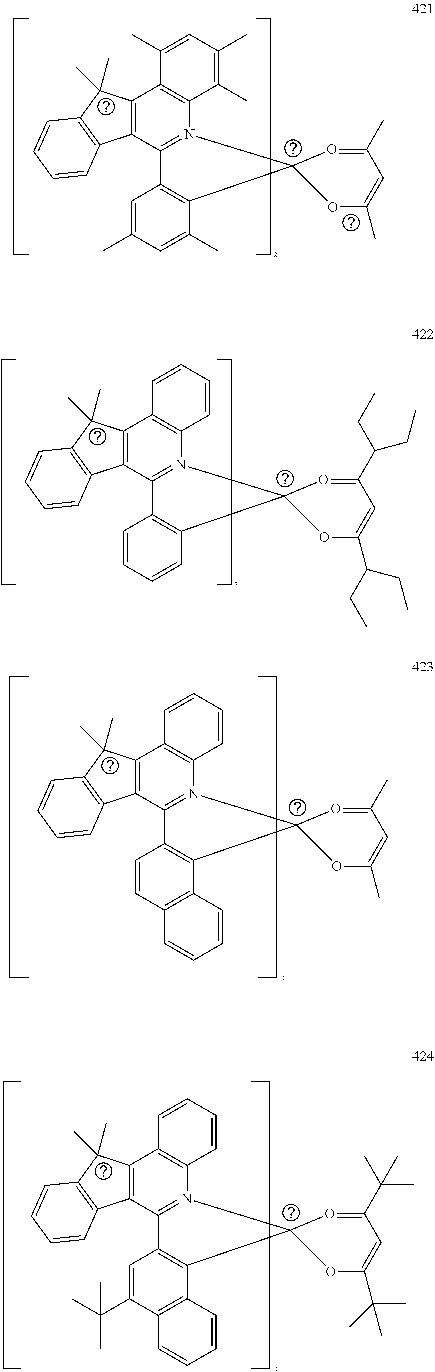

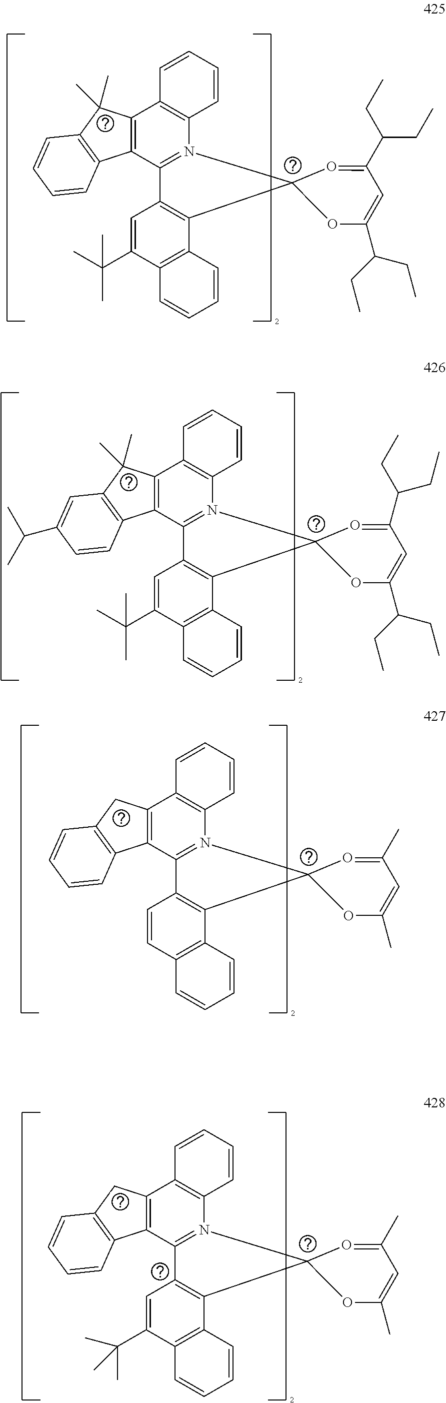

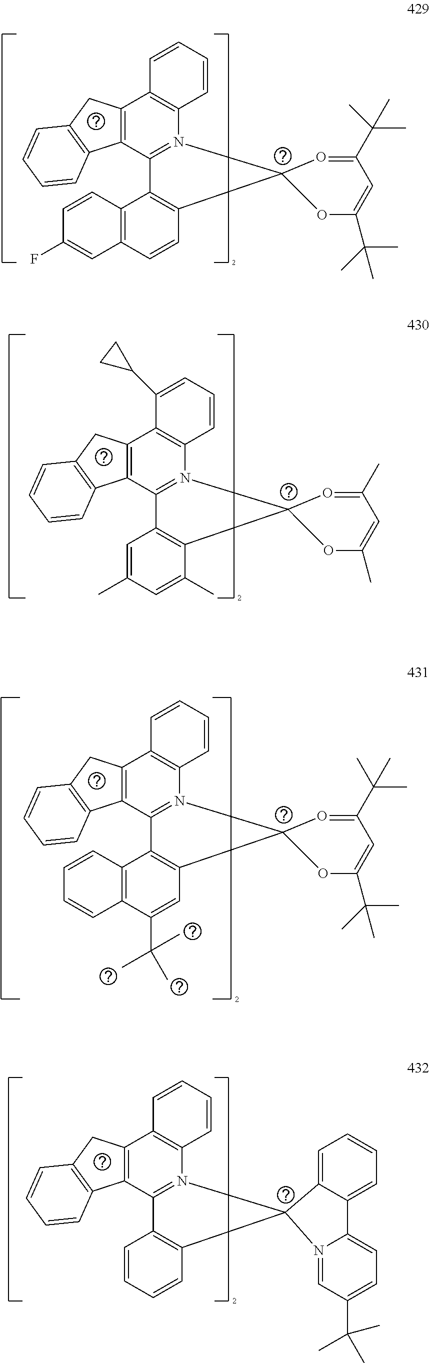

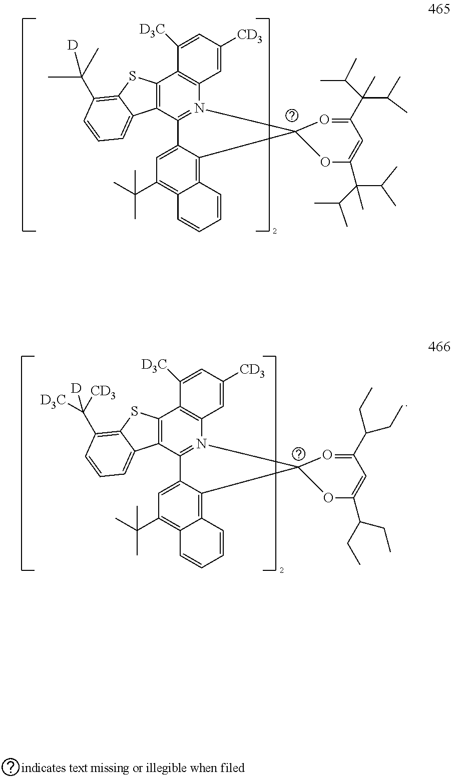

7. The organometallic compound of claim 1, wherein the compound represented by the Chemical Formula 1 is used as a red phosphorescent material or a green phosphorescent material.

8. An organic electroluminescent device comprising:
a first electrode;
a second electrode facing the first electrode; and
an organic layer disposed between the first electrode and the second electrode,
wherein the organic layer includes a light-emitting layer, and
wherein the light-emitting layer contains the organometallic compound according to claim 1.

9. The organic electroluminescent device of claim 7, wherein the organometallic compound is used as dopant of the light-emitting layer.

10. The organic electroluminescent device of claim 7, wherein the organic layer further includes at least one selected from a group consisting of a hole injection layer, a hole transport layer, an electron transport layer and an electron injection layer.

11. An organic light-emitting display device comprising:
a substrate;
a driving element positioned on the substrate; and
an organic light-emitting element disposed on the substrate and connected to the driving element,
wherein the organic light-emitting element includes the organic electroluminescent device according to claim 9.

12. The organic electroluminescent device of claim 8, wherein the organic layer is formed by sequentially stacking a hole injection layer, a hole transport layer, a light emission layer, an electron transport layer and an electron injection layer on the first electrode.

13. The organic electroluminescent device of claim 10, wherein the hole injection layer comprises a compound selected from a group consisting of MTDATA, CuPc, TCTA, NPB(NPD), HATCN, TDAPB, PEDOT/PSS, N-(biphenyl-4-yl)-9,9-dimethyl-N-(4-(9-phenyl-9H-carbazol-3-yl)phenyl)-9H-luoren-2-amine, and NPNPB (N,N′-diphenyl-N,N′-di[4-(N,N-diphenyl-amino)phenyl]benzidine).

14. The organic electroluminescent device of claim 10, wherein the hole transport layer comprises a compound selected from a group consisting of TPD, NPD, CBP, N-(biphenyl-4-yl)-9,9-dimethyl-N-(4-(9-phenyl-9H-carbazol-3-yl)phenyl)-9H-fluoren-2-amine, and N-(biphenyl-4-yl)-N-(4-(9-phenyl-9H-carbazol-3-yl)phenyl)biphenyl)-4-amine.

15. The organic electroluminescent device of claim 8, wherein the light-emitting layer includes a host and the organometallic compound represented by Chemical Formula I as dopant, wherein the host material is selected from a group consisting of CBP (carbazole biphenyl), and mCP (1,3-bis (carbazol-9-yl).

16. The organic electroluminescent device of claim 10, wherein the electron transport layer and the electron injection layer are sequentially stacked between the light-emitting layer and the second electrode.

17. The organic electroluminescent device of claim 10, wherein the electron transport layer comprises a compound selected from a group consisting of Alq3 (tris(8-hydroxyquinolino)aluminum), Liq (8-hydroxyquinolinolatolithium), PBD (2-(4-biphenylyl)-5-(4-tert-butylphenyl)-1,3,4oxadiazole), TAZ (3-(4-biphenyl)4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzthiazole, and ZADN (2-[4-(9,10-Di-naphthalen-2-yl-anthracen-2-yl)-phenyl]-1-phenyl-1H-benzoimidazole).

18. The organic electroluminescent device of claim 10, wherein the electron injection layer comprises a compound selected from a group consisting of Alq3 (tris(8-hydroxyquinolino)aluminum), PBD, TAZ, Spiro-PBD, BAlq, and SAlq.

19. The organic electroluminescent device of claim 10, wherein the electron injection layer comprises a metal compound selected from the group consisting of Liq, LiF, NaF, KF, RbF, CsF, FrF, BeF₂, MgF₂, CaF₂, SrF₂, BaF₂ and RaF₂.

20. The organic electroluminescent device of claim 10, wherein the organic electroluminescent device has a tandem structure comprising two light-emitting stacks or three light-emitting stacks.
